(19) United States
(12) Patent Application Publication
(10) Pub. No.: US 2023/0161254 A1
(43) Pub. Date: May 25, 2023

(54) CHEMICALLY AMPLIFIED RESIST COMPOSITION AND PATTERNING PROCESS

(71) Applicant: Shin-Etsu Chemical Co., Ltd., Tokyo (JP)

(72) Inventors: Masahiro Fukushima, Joetsu-shi (JP); Masayoshi Sagehashi, Joetsu-shi (JP); Kenji Yamada, Joetsu-shi (JP); Kazuhiro Katayama, Joetsu-shi (JP)

(73) Assignee: Shin-Etsu Chemical Co., Ltd., Tokyo (JP)

(21) Appl. No.: 17/984,448

(22) Filed: Nov. 10, 2022

(30) Foreign Application Priority Data
Nov. 17, 2021 (JP) 2021-186799

(51) Int. Cl. G03F 7/039; G03F 7/004; G03F 7/029; G03F 7/20

(52) U.S. Cl. CPC G03F 7/0392; G03F 7/0048; G03F 7/029; G03F 7/2006

(57) ABSTRACT

A chemically amplified resist composition is provided comprising (A) a polymer P comprising repeat units having an acid labile group containing a fluorinated aromatic ring, repeat units having a phenolic hydroxy group, and repeat units adapted to generate an acid upon exposure, (B) an onium salt type quencher, and (C) a solvent. The resist composition exhibits a high sensitivity, low LWR and improved CDU when processed by photolithography.

### CROSS-REFERENCE TO RELATED APPLICATION

This non-provisional application claims priority under 35 U.S.C. § 119(a) on Patent Application No. 2021-186799 filed in Japan on Nov. 17, 2021, the entire contents of which are hereby incorporated by reference.

### TECHNICAL FIELD

This invention relates to a chemically amplified resist composition and a pattern forming process using the resist composition.

### BACKGROUND ART

The currently increasing integration density of integrated circuits requires pattern formation to a smaller feature size. In the lithography process of forming patterns with a feature size of 0.2 μm or less, chemically amplified resist compositions utilizing acid as a catalyst are mostly used. As the energy source for exposure, high-energy radiation such as UV, deep UV or EB is used. The EB lithography utilized as the ultrafine processing technology is indispensable for the processing of photomask blanks to produce photomasks for use in semiconductor device fabrication.

Polymers containing abundant aromatic skeletons with acidic side chains, for example, polyhydroxystyrene are useful as the resist material for KrF excimer laser lithography, but not used as the resist material for ArF excimer laser lithography because of substantial absorption of light near to wavelength 200 nm. The above polymers are yet important, because of high etching resistance, as the resist materials for the EB lithography and EUV lithography which are promising for forming patterns of smaller size than the processing limit of ArF excimer laser.

In positive tone resist materials for the EB lithography and resist materials for the EUV lithography, a base polymer having on a phenol side chain an acidic functional group masked with an acid-decomposable protective group is often used in combination with a photoacid generator. Under the catalysis of an acid generated from the photoacid generator upon exposure to high-energy radiation, the protective group is deprotected so that the polymer may become solubilized in alkaline developer. Tertiary alkyl, tert-butoxycarbonyl, and acetal groups are mainly used as the acid-decomposable protective group. On use of acetal and similar protective groups requiring relatively small activation energy for deprotection, one advantage is that a resist film having a high sensitivity is obtained. Unless the diffusion of the generated acid is fully suppressed, however, deprotection reaction can take place even in the unexposed region of the resist film. There arise problems like degradation of LER and a loss of CDU.

For the control of resist sensitivity and pattern profile, various improvements are made through a choice and combination of components in a resist composition and selection of processing conditions. One of such improvements addresses the diffusion of acid that has a significant impact on the resolution of chemically amplified resist compositions. Enormous studies are made on the problem of acid diffusion that largely affects sensitivity and resolution.

For the purpose of enhancing the sensitivity of resist compositions, Patent Documents 1 to 8 disclose attempts to introduce a multiple bond or aromatic ring into an acid labile group on a base polymer. By introducing such substituent groups, the resist performance is improved to some extent, but not to a satisfactory extent.

### CITATION LIST

Patent Document 1: JP-A 2011-191262
Patent Document 2: JP-A 2013-053196
Patent Document 3: JP-A 2018-092159 (U.S. Pat. No. 10,649,330)
Patent Document 4: JP-A 2008-268741
Patent Document 5: JP-A 2019-120759 (U.S. Pat. No. 11,392,033)
Patent Document 6: JP-A 2020-085917 (US 20200159118)
Patent Document 7: JP 6782569 (U.S. Pat. No. 11,204,551)
Patent Document 8: JP-A 2019-214554

### SUMMARY OF INVENTION

While many chemically amplified resist compositions utilizing acid as a catalyst are known, there is the desire for a resist composition which has a higher sensitivity and is improved in the LWR of line patterns or the CDU of hole patterns.

An object of the invention is to provide a chemically amplified resist composition and a pattern forming process using the resist composition, the resist composition exhibiting a high sensitivity and reduced LWR or improved CDU when processed by the photolithography using high-energy radiation, especially EB or EUV lithography.

The inventors have found that using a chemically amplified resist composition comprising (A) a polymer comprising repeat units having an acid labile group containing a fluorinated aromatic ring, repeat units having a phenolic hydroxy group, and repeat units adapted to generate an acid upon exposure, (B) an onium salt type quencher, and (C) a solvent exhibits a high sensitivity, high contrast, excellent resolution, and wide process margin and forms, for example, line patterns with low LWR or hole patterns with improved CDU.

In one aspect, the invention provides a chemically amplified resist composition comprising

(A) a polymer P comprising repeat units having an acid labile group containing a fluorinated aromatic ring, represented by the formula (A1), repeat units having a phenolic hydroxy group, and repeat units adapted to generate an acid upon exposure, represented by any one of the formulae (C1) to (C4), the polymer P adapted to change its solubility in developer under the action of acid,

(B) an onium salt type quencher, and

(C) a solvent.

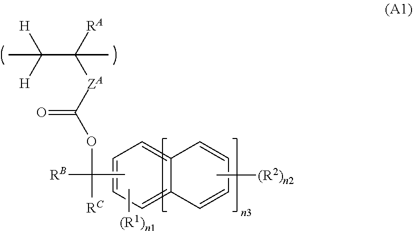

In formula (A1), R^{A} is hydrogen, fluorine, methyl or trifluoromethyl,

Z^{A} is a single bond, phenylene group, naphthylene group or *—C(═O)—O—Z^{A1}—, Z^{A1} is a C₁-C₂₀ aliphatic hydrocarbylene group which may contain a hydroxy moiety, ether bond, ester bond or lactone ring, or a phenylene or naphthylene group, the asterisk (*) designates a point of attachment to the carbon atom in the backbone,

R^{B} and R^{C} are each independently a C₁-C₁₀ hydrocarbyl group which may contain a heteroatom, R^{B} and R^{C} may bond together to form a ring with the carbon atom to which they are attached,

R¹ is each independently fluorine, a C₁-C₅ fluorinated alkyl group or C₁-C₅ fluorinated alkoxy group,

R² is each independently a C₁-C₁₀ hydrocarbyl group which may contain a heteroatom,

n1 is an integer of 1 or 2, n2 is an integer of 0 to 5, and n3 is an integer of 0 to 2.

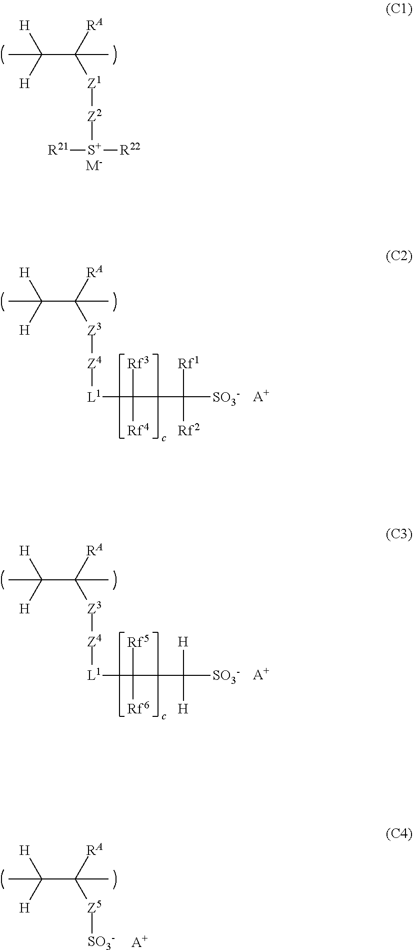

In formulae (C1) to (C4), R^{A} is as defined above,

Z¹ is a single bond or phenylene group,

Z² is *—C(═O)—O—Z²¹—, *—C(═O)—NH—Z²¹— or *—O—Z²¹—, Z²¹ is a C₁-C₆ aliphatic hydrocarbylene group, phenylene group or divalent group obtained by combining the foregoing, which may contain a carbonyl moiety, ester bond, ether bond or hydroxy moiety,

Z³ is a single bond, phenylene group, naphthylene group or *—C(═O)—O—Z³¹—, Z³¹ is a C₁-C₁₀ aliphatic hydrocarbylene group which may contain a hydroxy moiety, ether bond, ester bond or lactone ring, or a phenylene or naphthylene group,

Z⁴ is a single bond or *—Z⁴¹—C(═O)—O—, Z⁴¹ is a C₁-C₂₀ hydrocarbylene group which may contain a heteroatom,

Z⁵ is a single bond, methylene, ethylene, phenylene, fluorinated phenylene, trifluoromethyl-substituted phenylene, *—C(═O)—O—Z⁵¹—, *—C(═O)—N(H)—Z⁵¹— or *—O—Z⁵¹—, Z⁵¹ is a C₁-C₆ aliphatic hydrocarbylene group, phenylene, fluorinated phenylene or trifluoromethyl-substituted phenylene group, which may contain a carbonyl moiety, ester bond, ether bond or hydroxy moiety,

the asterisk (*) designates a point of attachment to the carbon atom in the backbone,

R²¹ and R²² are each independently a C₁-C₂₀ hydrocarbyl group which may contain a heteroatom, R²¹ and R²² may bond together to form a ring with the sulfur atom to which they are attached,

L¹ is a single bond, ether bond, ester bond, carbonyl group, sulfonic ester bond, carbonate bond or carbamate bond,

Rf¹ and Rf² are each independently fluorine or a C₁-C₆ fluorinated alkyl group,

Rf³ and Rf⁴ are each independently hydrogen, fluorine or a C₁-C₆ fluorinated alkyl group,

Rf⁵ and Rf⁶ are each independently hydrogen, fluorine or a C₁-C₆ fluorinated alkyl group, excluding that all Rf⁵ and Rf⁶ are hydrogen at the same time,

M⁻ is a non-nucleophilic counter ion,

A⁺ is an opium cation, and

c is an integer of 0 to 3.

In a preferred embodiment, the repeat units having formula (A1) are represented by the formula (A2):

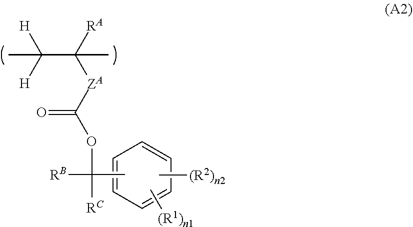

wherein R^{A}, Z^{A}, R^{B}, R^{C}, R¹, R², n1 and n2 are as defined above.

More preferably, R¹ is fluorine, trifluoromethyl or trifluoromethoxy.

In a preferred embodiment, the repeat units having a phenolic hydroxy group are represented by the formula (B1).

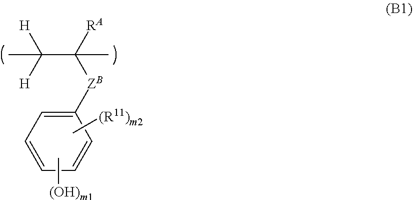

In formula (B1), R^{A} is as defined above,

Z^{B} is a single bond or *—C(═O)—O—, the asterisk (*) designates a point of attachment to the carbon atom in the backbone,

R¹¹ is halogen, cyano, a C₁-C₂₀ hydrocarbyl group which may contain a heteroatom, a C₁-C₂₀ hydrocarbyloxy group which may contain a heteroatom, a C₂-C₂₀ hydrocarbylcarbonyl group which may contain a heteroatom, a C₂-C₂₀ hydrocarbylcarbonyloxy group which may contain a heteroatom, or a C₂-C₂₀ hydrocarbyloxycarbonyl group which may contain a heteroatom,

m1 is an integer of 1 to 4, m2 is an integer of 0 to 4, the sum of m1+m2 is from 1 to 5.

In a preferred embodiment, the onium salt type quencher is represented by the formula (1) or (2).

R^{q1}—SO₃⁻A⁺ (1)

R^{q2}—CO₂⁻A⁺ (2)

Herein R^{q1} is hydrogen or a C₁-C₄₀ hydrocarbyl group which may contain a heteroatom, exclusive of a hydrocarbyl group in which hydrogen attached to the α-carbon relative to the sulfo group is substituted by fluorine or fluoroalkyl,

R^{q2} is hydrogen or a C₁-C₄₀ hydrocarbyl group which may contain a heteroatom, and

A⁺ is an onium cation.

In a preferred embodiment, A⁺ is a cation having the formula (cation-1) or (cation-2):

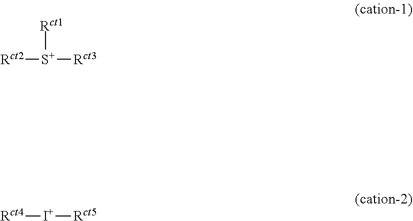

wherein R^{ct1} to R^{ct5} are each independently a C₁-C₂₀ hydrocarbyl group which may contain a heteroatom, R^{ct1} and R^{ct2} may bond together to form a ring with the sulfur atom to which they are attached.

In a preferred embodiment, polymer P further comprise repeat units having the formula (a1) or (a2):

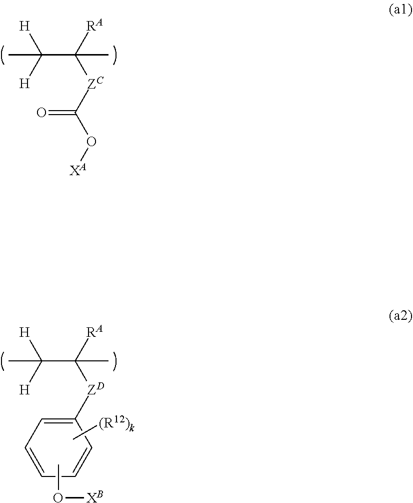

wherein R^{A} is as defined above,

Z^{C} is a single bond, phenylene group, naphthylene group or *—C(═O)—O—Z^{C1}—, Z^{C1} is a C₁-C₂₀ saturated hydrocarbylene group which may contain a hydroxy moiety, ether bond, ester bond or lactone ring, or a phenylene or naphthylene group,

Z^{D} is a single bond or *—C(═O)—O—,

the asterisk (*) designates a point of attachment to the carbon atom in the backbone,

R¹² is a C₁-C₂₀ hydrocarbyl group which may contain a heteroatom,

X^{A} and X^{B} are each independently an acid labile group free of fluorinated aromatic ring, and

k is an integer of 0 to 4.

In a preferred embodiment, polymer P further comprise repeat units having the formula (D1):

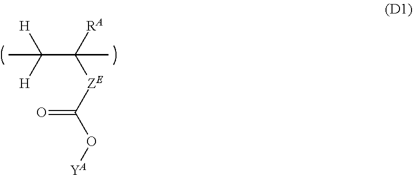

wherein R^{A} is as defined above,

Z^{E} is a single bond, phenylene group, naphthylene group or *—C(═O)—O—Z^{E1}—, Z^{E1} is a C₁-C₂₀ saturated hydrocarbylene group which may contain a hydroxy moiety, ether bond, ester bond or lactone ring, or a phenylene or naphthylene group,

the asterisk (*) designates a point of attachment to the carbon atom in the backbone, and

Y^{A} is hydrogen or a polar group containing at least one moiety selected from the group consisting of hydroxy, cyano, carbonyl, carboxy, ether bond, ester bond, sulfonic ester bond, carbonate bond, lactone ring, sultone ring, and carboxylic anhydride (—C(═O)—O—C(═O)—).

The resist composition may further comprise a photoacid generator and/or a surfactant.

In another aspect, the invention provides a process for forming a pattern comprising the steps of applying the chemically amplified resist composition defined herein to a substrate to form a resist film thereon, exposing the resist film to high-energy radiation, and developing the exposed resist film in a developer.

Typically, the high-energy radiation is i-line, KrF excimer laser, ArF excimer laser, EB, or EUV of wavelength 3 to 15 nm.

### Advantageous Effects of Invention

The chemically amplified resist composition exhibits a high sensitivity and forms patterns with improved LWR and CDU, high contrast, excellent resolution, and wide process margin.

### DESCRIPTION OF EMBODIMENTS

As used herein, the singular forms “a,” “an” and “the” include plural referents unless the context clearly dictates otherwise. “Optional” or “optionally” means that the subsequently described event or circumstances may or may not occur, and that description includes instances where the event or circumstance occurs and instances where it does not. The notation (Cn-Cm) means a group containing from n to m carbon atoms per group. In chemical formulae, the broken line designates a valence bond, Me stands for methyl, and Ac for acetyl.

The abbreviations and acronyms have the following meaning.

EB: electron beam

EUV: extreme ultraviolet

Mw: weight average molecular weight

Mn: number average molecular weight

Mw/Mn: molecular weight dispersity

GPC: gel permeation chromatography

PEB: post-exposure bake

PAG: photoacid generator

LWR: line width roughness

CDU: critical dimension uniformity

### Chemically Amplified Resist Composition

One embodiment of the invention is a chemically amplified resist composition comprising (A) a polymer P comprising repeat units having an acid labile group containing a fluorinated aromatic ring, repeat units having a phenolic hydroxy group, and repeat units adapted to generate an acid upon exposure, (B) an onium salt type quencher, and (C) a solvent.

### (A) Polymer P

Component (A) or Polymer P functions as a base polymer and comprises repeat units having an acid labile group containing a fluorinated aromatic ring, which are referred to as repeat units A, hereinafter. Repeat units A are represented by the formula (A1).

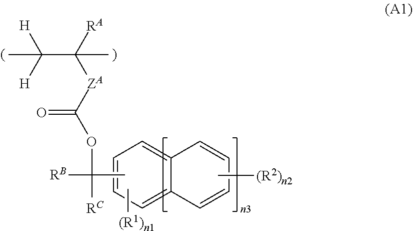

In formula (A1), R^{A} is hydrogen, fluorine, methyl or trifluoromethyl.

In formula (A1), Z^{A} is a single bond phenylene group, naphthylene group or *—C(═O)—O—Z^{A1}—. Z^{A1} is a C₁-C₂₀ aliphatic hydrocarbylene group which may contain a hydroxy moiety, ether bond, ester bond or lactone ring, or a phenylene or naphthylene group. The asterisk (*) designates a point of attachment to the carbon atom in the backbone.

The aliphatic hydrocarbylene group Z^{A1} may be straight, branched or cyclic. Examples thereof include C₁-C₂₀ alkanediyl groups such as methanediyl, ethane-1,1-diyl, ethane-1,2-diyl, propane-1,1-diyl, propane-1,2-diyl, propane-1,3-diyl, propane-2,2-diyl, butane-1,1-diyl, butane-1,2-diyl, butane-1,3-diyl, butane-2,3-diyl, butane-1,4-diyl, 1,1-dimethylethane-1,2-diyl, pentane-1,5-diyl, 2-methylbutane-1,2-diyl, hexane-1,6-diyl, heptane-1,7-diyl, octane-1,8-diyl, nonane-1,9-diyl, and decane-1,10-diyl; C₃-C₂₀ cycloalkanediyl groups such as cyclopropanediyl, cyclobutane-1,1-diyl, cyclopentanediyl, and cyclohexanediyl; C₄-C₂₀ polycyclic saturated hydrocarbylene groups such as adamantanediyl and norbornanediyl; and divalent groups obtained by combining the foregoing.

Examples of the structure having formula (A1) wherein Z^{A} is a variant are shown below, but not limited thereto. Herein R^{A} is as defined herein. The broken line designates a point of attachment to the carbon atom to which R^{B} and R^{C} in formula (A1) are attached.

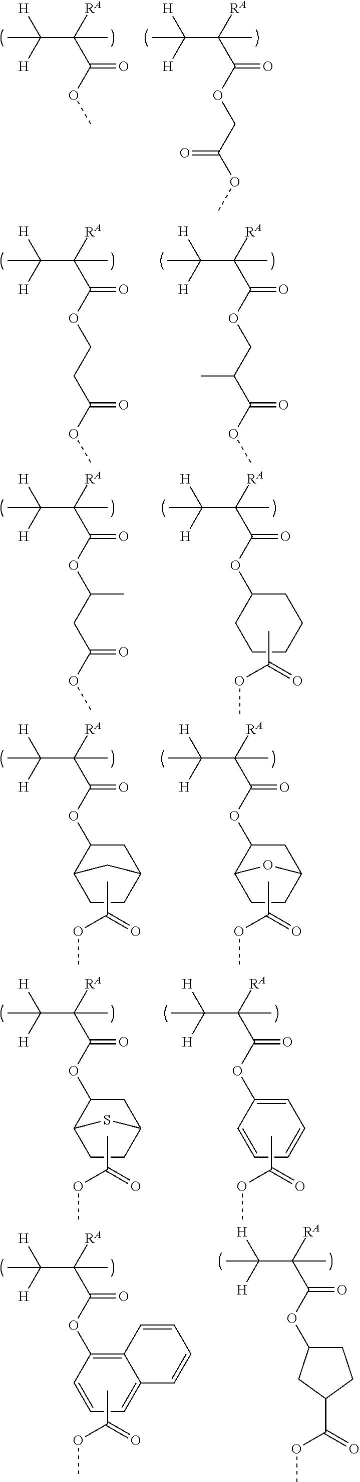

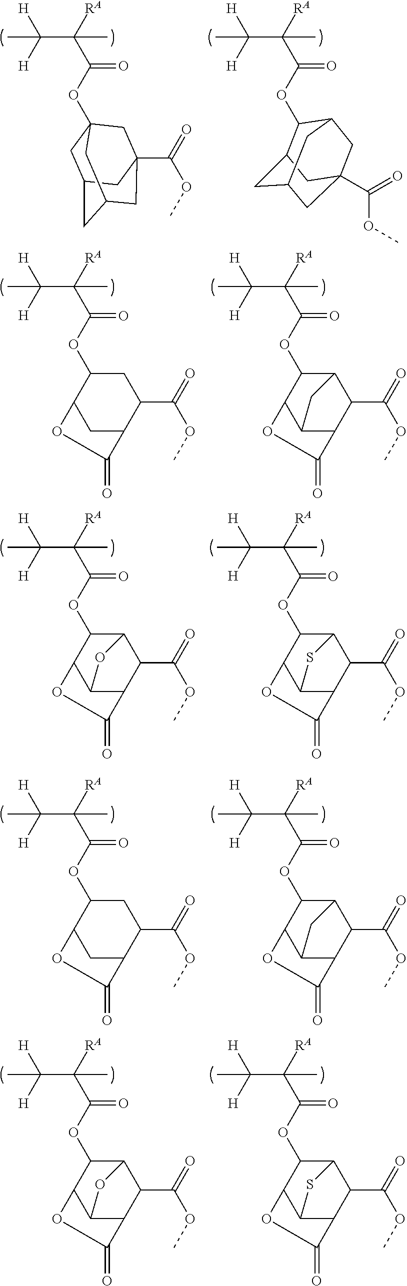

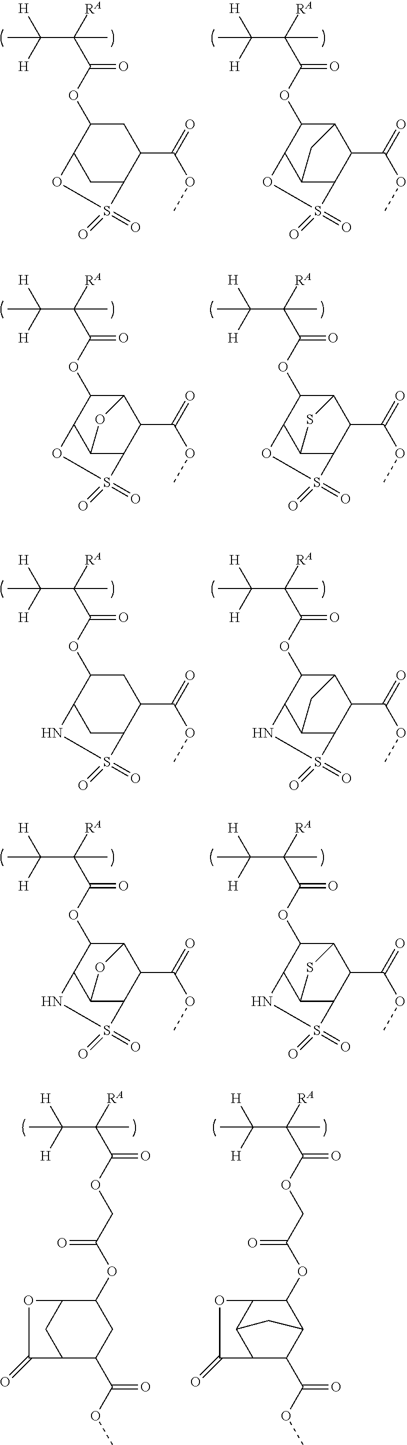

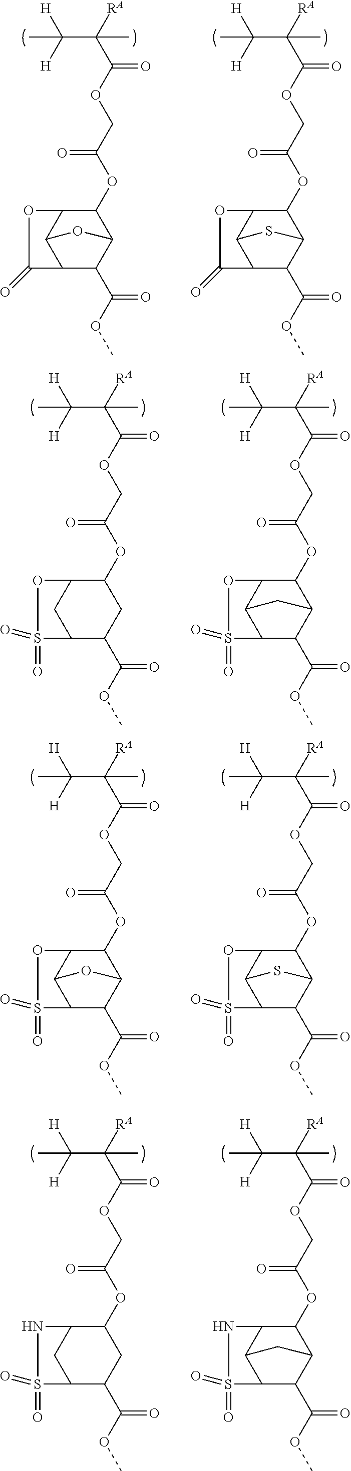

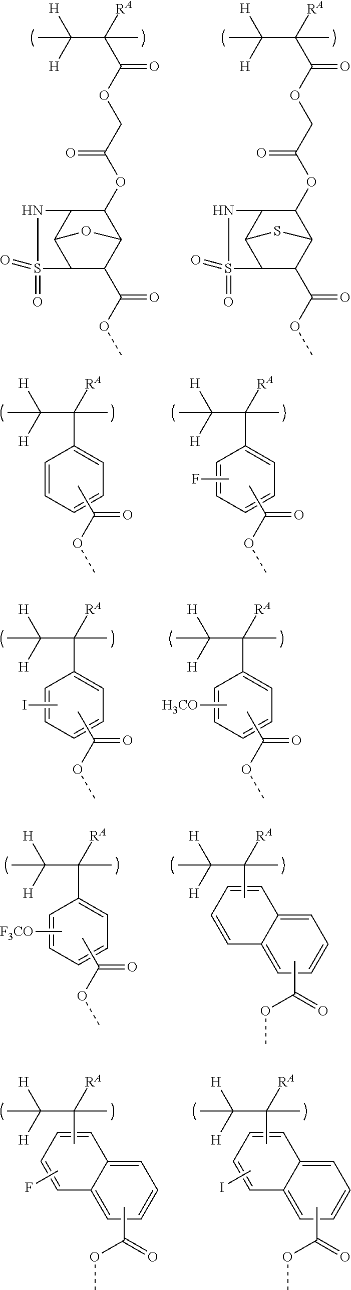

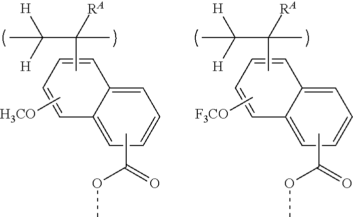

In formula (A1), R^{B} and R^{C} are each independently a C₁-C₁₀ hydrocarbyl group which may contain a heteroatom. The hydrocarbyl group may be saturated or unsaturated and straight, branched or cyclic. Suitable hydrocarbyl groups include alkyl groups such as methyl, ethyl, n-propyl, isopropyl, n-butyl, sec-butyl, tert-butyl, 2-ethylhexyl, and n-octyl; cyclic saturated hydrocarbyl groups such as cyclopentyl, cyclohexyl, norbornyl, tricyclodecanyl, and adamantyl.

R^{B} and R^{C} may bond together to form a ring with the carbon atom to which they are attached. Examples of the ring include cyclopropane, cyclobutane, cyclopentane, and cyclohexane rings. Inter alia, cyclopentane and cyclohexane rings are preferred.

In formula (A1), R¹ is each independently fluorine, a C₁-C₅ fluorinated alkyl group or C₁-C₅ fluorinated alkoxy group. Exemplary of the fluorinated alkyl group are fluoromethyl, difluoromethyl, trifluoromethyl, 2,2,2-trifluoroethyl, pentafluoroethyl, pentafluoropropyl, 1,1,1,3,3,3-hexafluoro-2-propyl, and nonafluorobutyl. Exemplary of the fluorinated alkoxy group are fluoromethoxy, difluoromethoxy, trifluoromethoxy, 2,2,2-trifluoroethoxy, pentafluoroethoxy, pentafluoropropoxy, 1,1,1,3,3,3-hexafluoro-2-propoxy, and nonafluorobutoxy. Inter alia, R¹ is preferably fluorine or a C₁-C₅ fluoroalkyl group, more preferably fluorine, trifluoromethyl or trifluoromethoxy, most preferably fluorine.

In formula (A1), R² is each independently a C₁-C₁₀ hydrocarbyl group which may contain a heteroatom. The hydrocarbyl group may be saturated or unsaturated and straight, branched or cyclic. Examples thereof are as exemplified above for the hydrocarbyl groups R^{B} and R^{C}.

In formula (A1), n1 is an integer of 1 or 2, n2 is an integer of 0 to 5, preferably 0 or 1, and n3 is an integer of 0 to 2. The relevant structure is a benzene ring in case of n3=0, a naphthalene ring in case of n3=1, and an anthracene ring in case of n3=2. Of these, a benzene ring corresponding to n3=0 is preferred from the aspect of solvent solubility.

Of repeat units A, units having the formula (A2) are preferred.

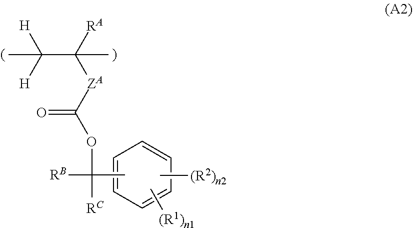

Herein R^{A}, Z^{A}, R^{B}, R^{C}, R¹, R², n1 and n2 are as defined above.

A monomer A1 from which repeat unit A is derived may be prepared, for example, according to the following scheme although the preparation route is not limited thereto.

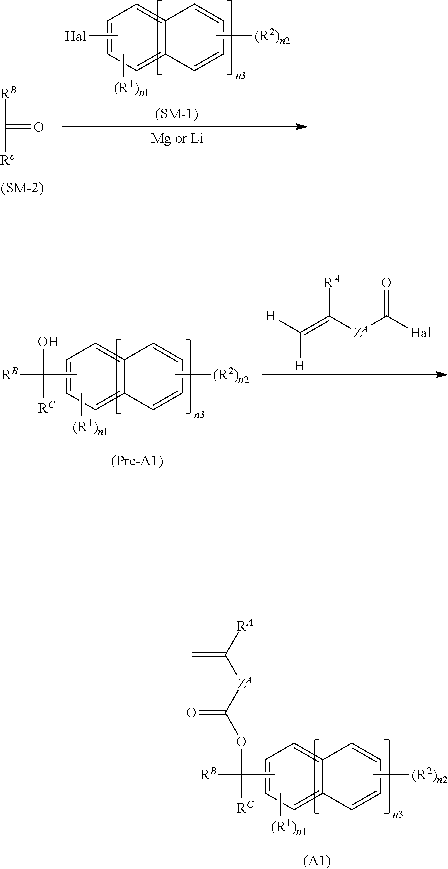

Herein R^{A}, Z^{A}, R^{B}, R^{C}, R¹, R², n1, n2 and n3 are as defined above. Hal is halogen other than fluorine.

The first step is to react a ketone compound SM-2, which is commercially available or synthesized by a well-known synthesis technique, with a Grignard reagent or organic lithium reagent, which is prepared from halide SM-1, to form a monomer precursor Pre-A1.

The reaction may be performed by any well-known organic synthesis technique. Specifically, a Grignard reagent or organic lithium reagent is prepared by suspending metallic magnesium or metallic lithium in an ether solvent such as tetrahydrofuran (THF) or diethyl ether and adding dropwise a dilution of halide SM-1 in the same solvent to the suspension. In the preparation of Grignard reagent, when halide SM-1 is a chloride, it is recommended for efficient start of the reaction that a minor amount of 1,2-dibromoethane or iodine is added to the suspension before the start of dropwise addition of halide SM-1. To the Grignard reagent or organic lithium reagent thus prepared, a dilution of ketone compound SM-2 in the same solvent is added dropwise. The reaction temperature is from room temperature to approximately the boiling point of the solvent. While it is preferred in view of yield to drive the reaction to completion by monitoring the reaction by gas chromatography (GC) or silica gel thin-layer chromatography (TLC), the reaction time is typically about 30 minutes to about 2 hours. By ordinary aqueous work-up of the reaction mixture, monomer precursor Pre-A1 is obtained. If necessary, monomer precursor Pre-A1 may be purified by a standard technique such as distillation, chromatography or recrystallization.

The second step is to introduce a polymerizable group into monomer precursor Pre-A1 or tertiary alcohol resulting from the first step, via an ester bond to form monomer A1.

The reaction may be performed by any well-known organic synthesis technique. Specifically, monomer precursor Pre-A1 or tertiary alcohol is dissolved in a solvent (e.g., toluene, hexane, THF or acetonitrile) in the presence of an organic base (e.g., triethylamine or pyridine). An acid halide (e.g., methacrylic chloride or acrylic chloride) is added dropwise to the solution for conducting reaction. For accelerating the reaction rate, 4-dimethylaminopyridine may be added to the solution. The reaction temperature is from 5° C. to approximately the boiling point of the solvent. While it is preferred in view of yield to drive the reaction to completion by monitoring the reaction by GC or TLC, the reaction time is typically about 1 to 24 hours. By ordinary aqueous work-up of the reaction mixture, monomer A1 is obtained. If necessary, monomer A1 may be purified by a standard technique such as distillation, chromatography or recrystallization.

Examples of repeat unit A having formula (A1) are shown below, but not limited thereto. Herein, R^{A} is as defined above.

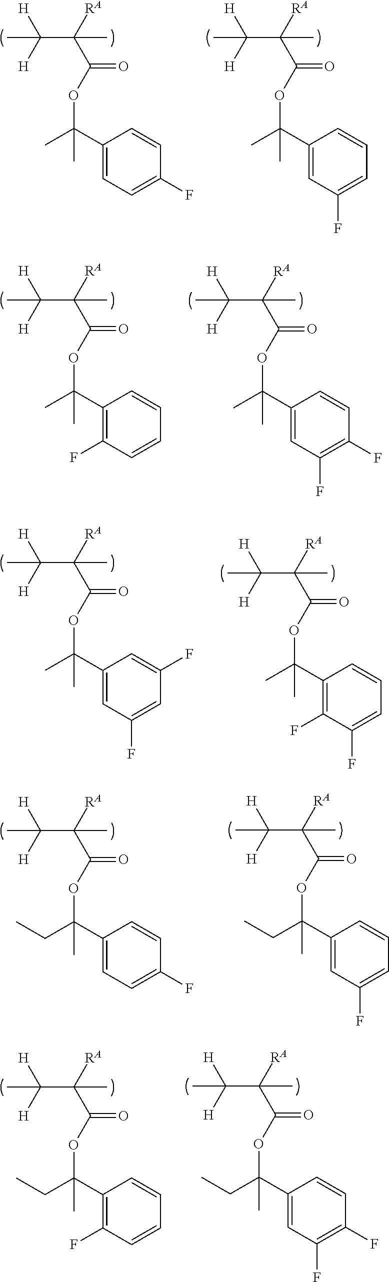

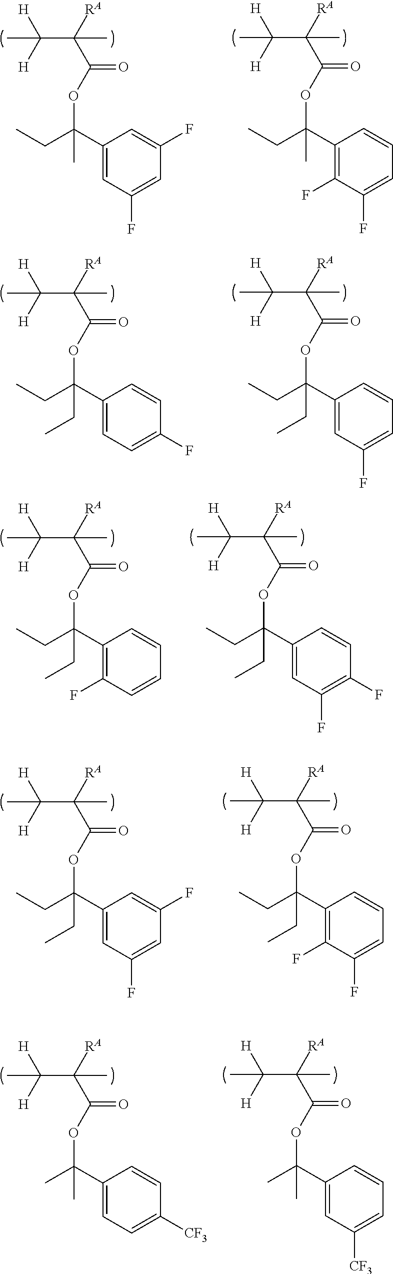

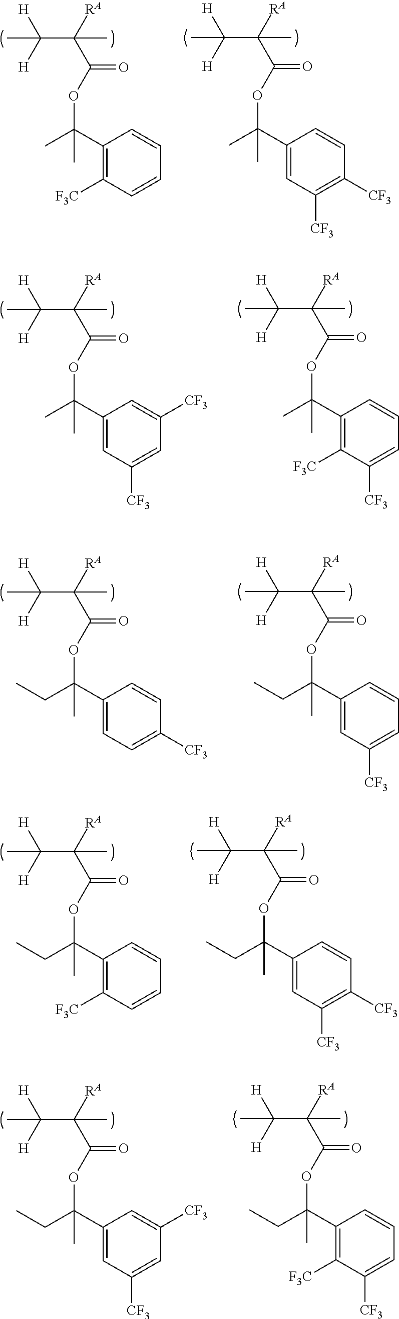

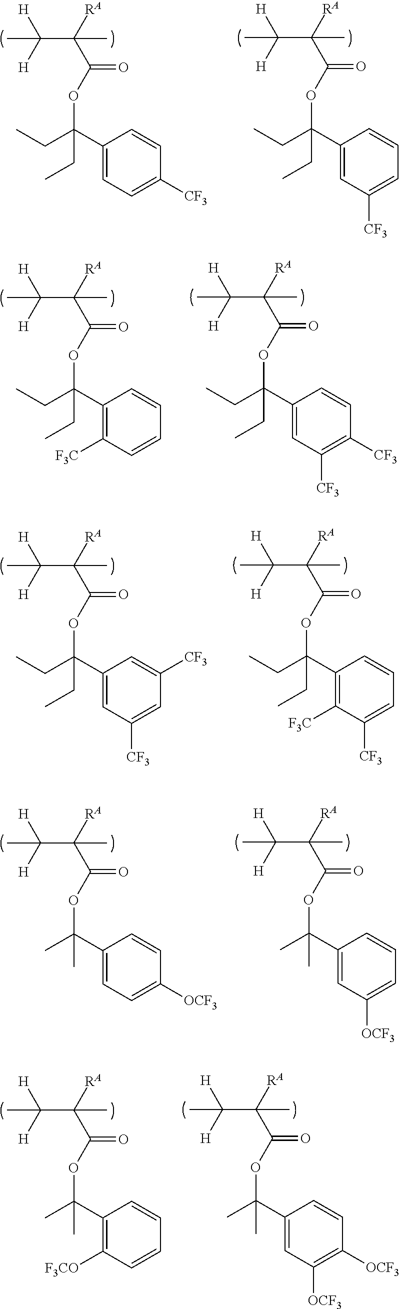

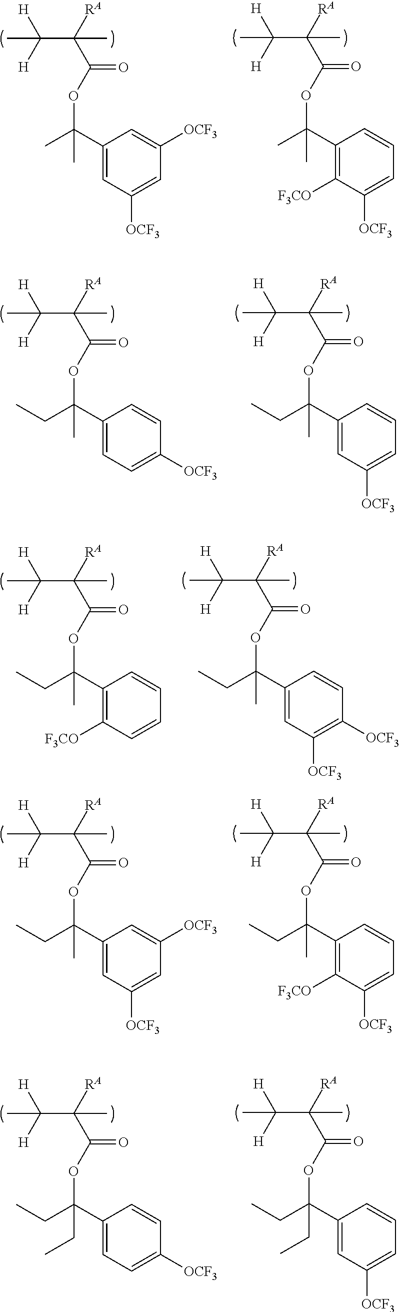

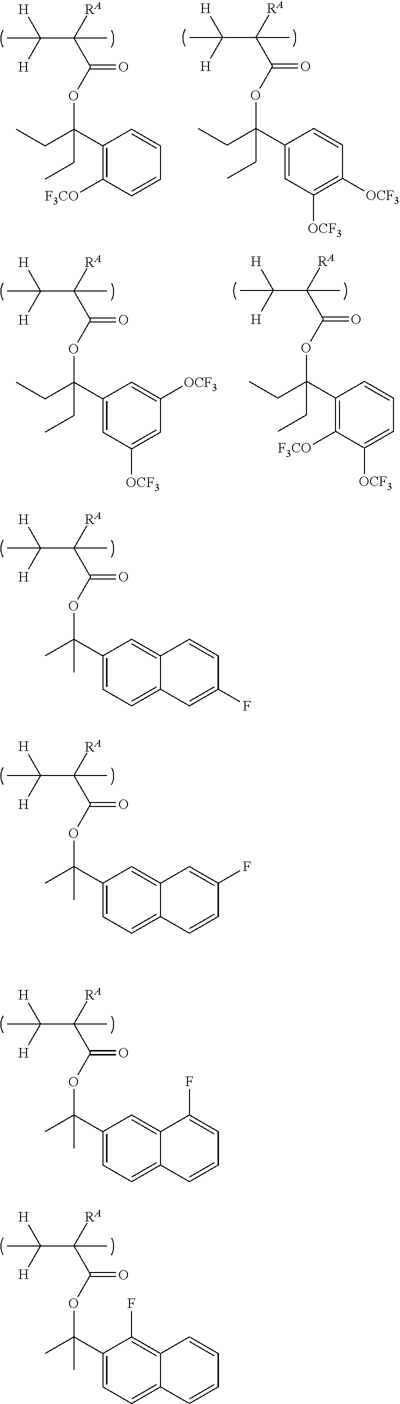

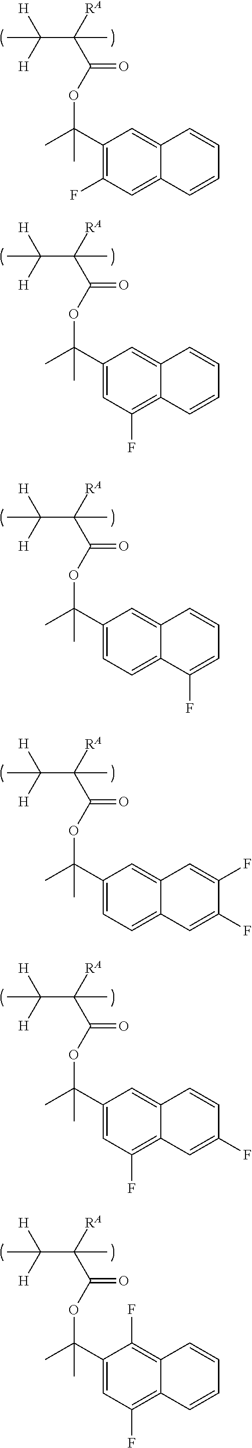

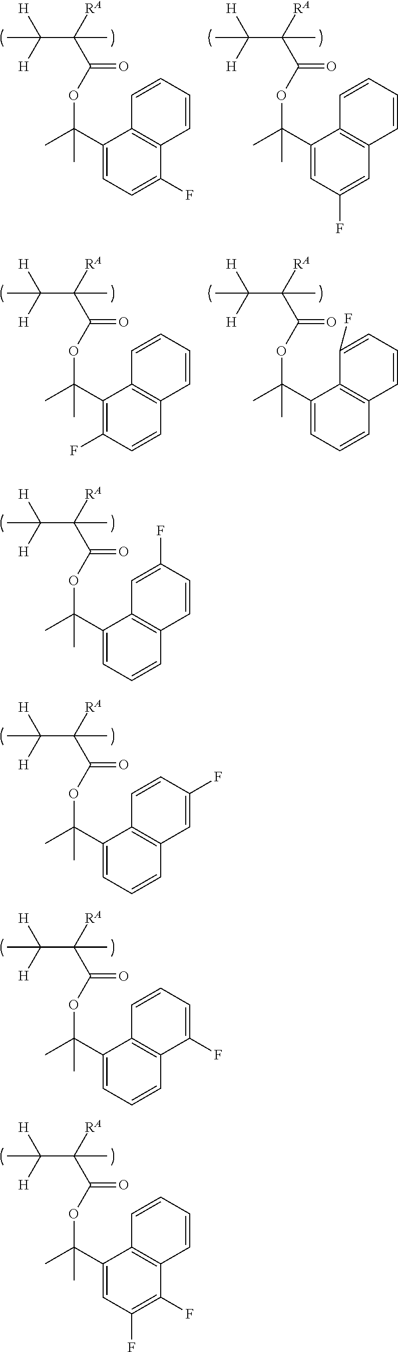

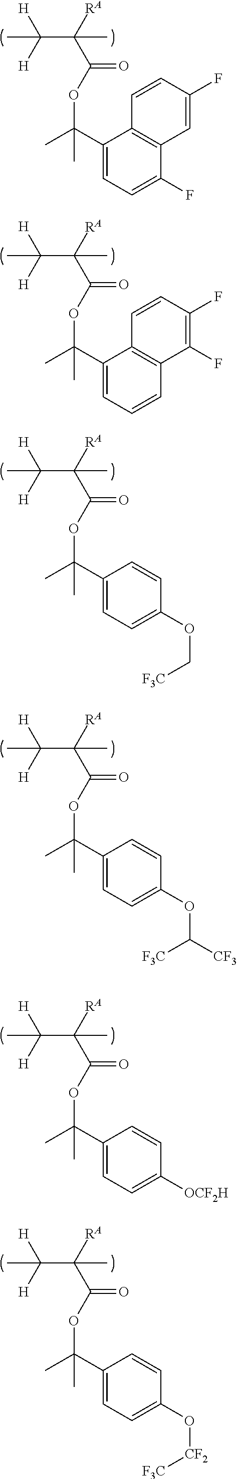

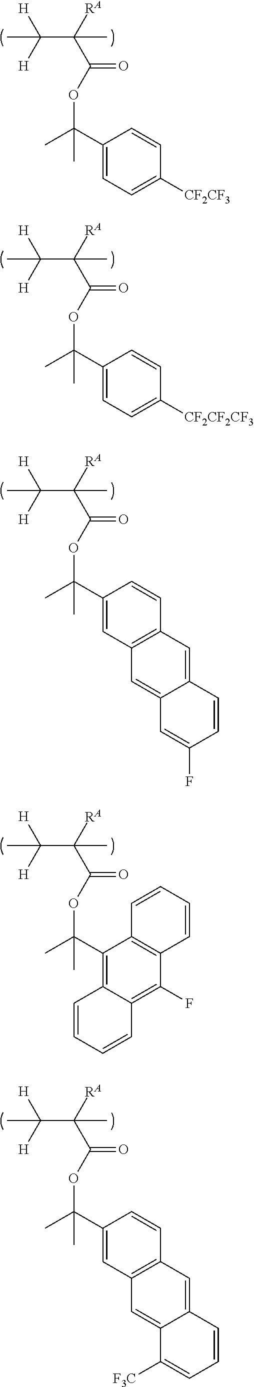

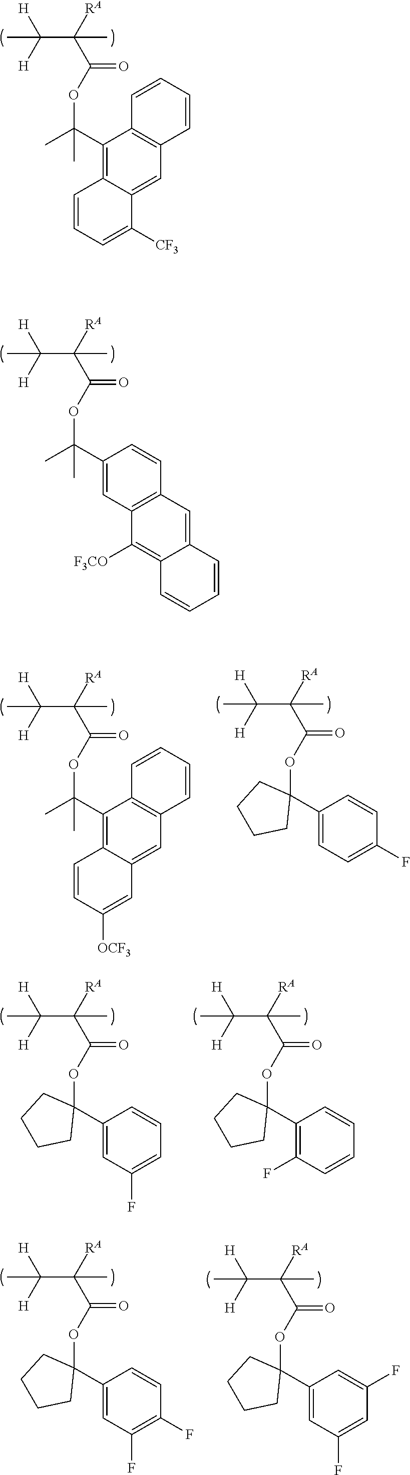

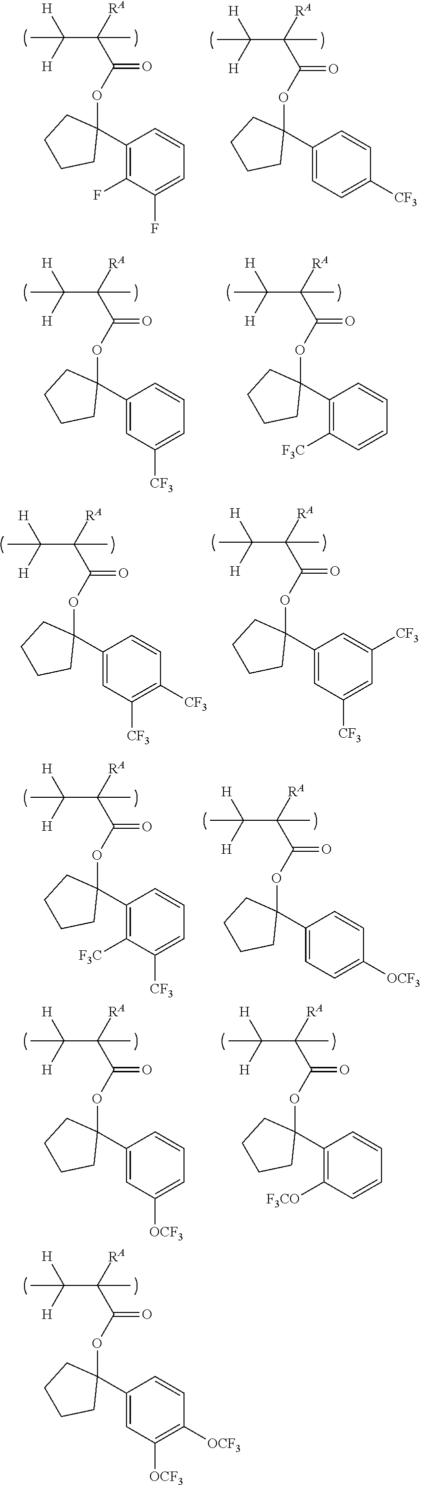

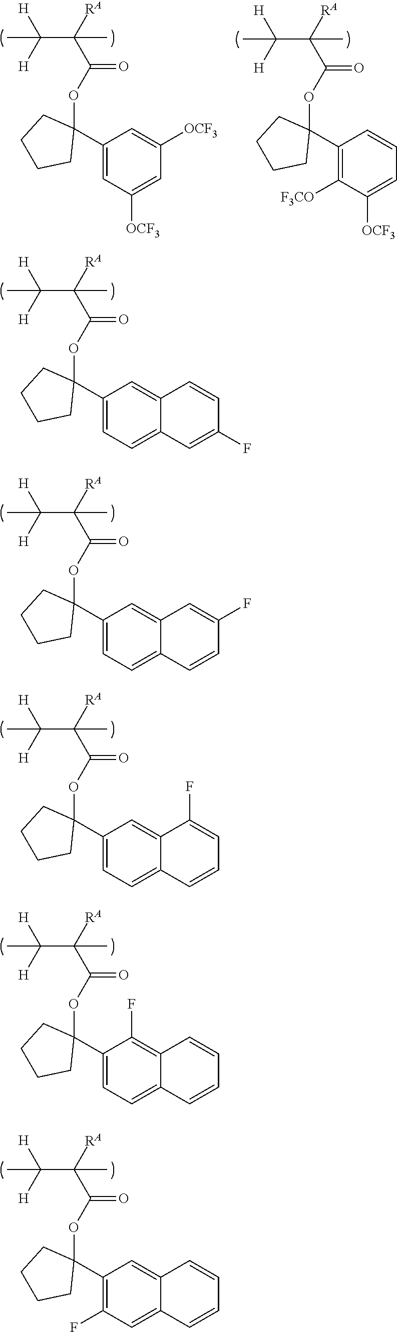

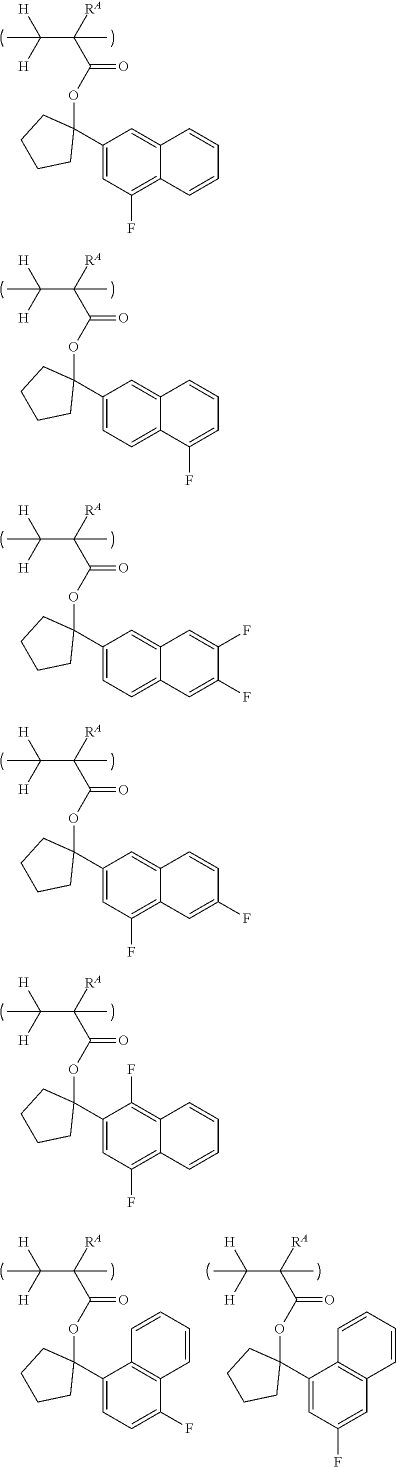

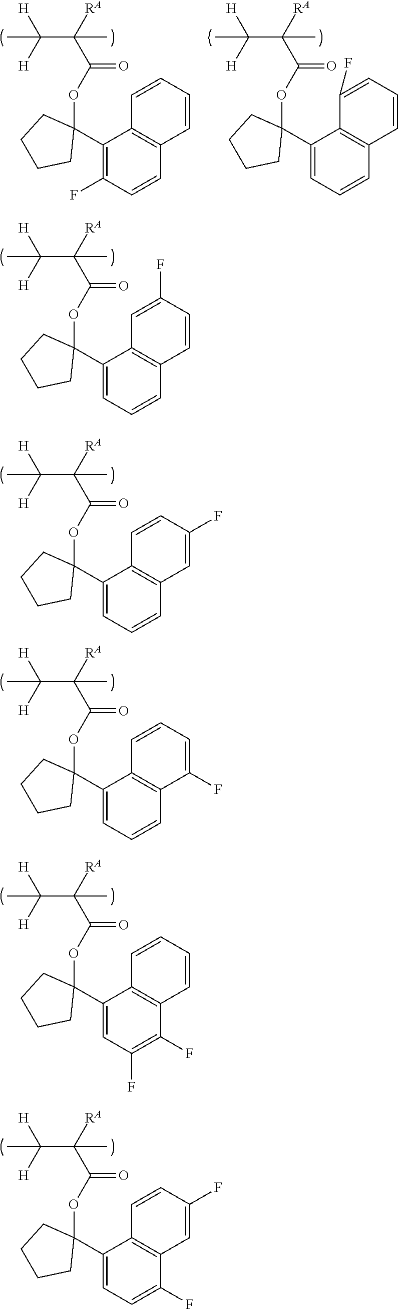

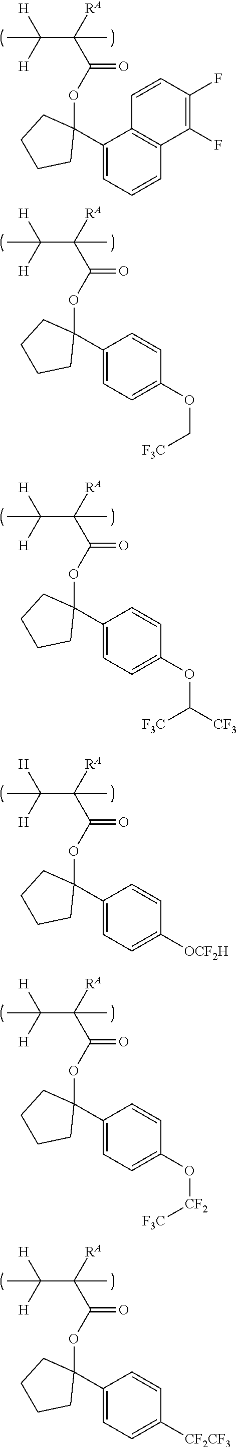

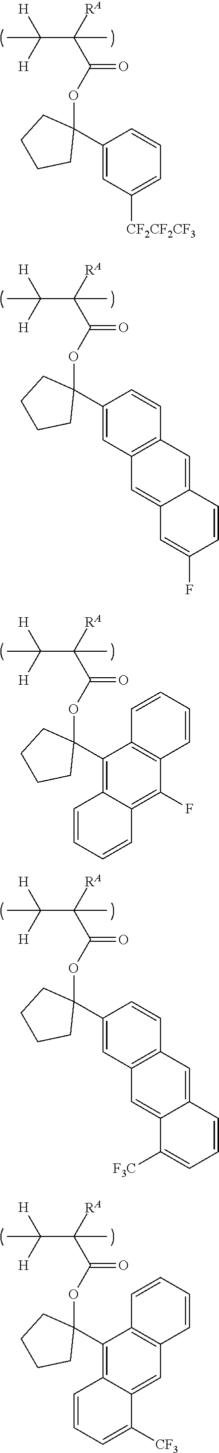

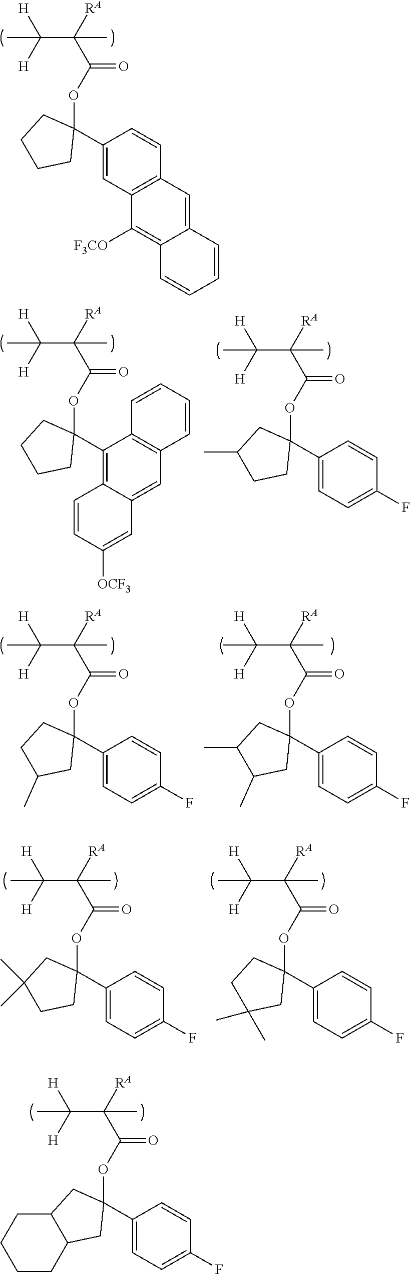

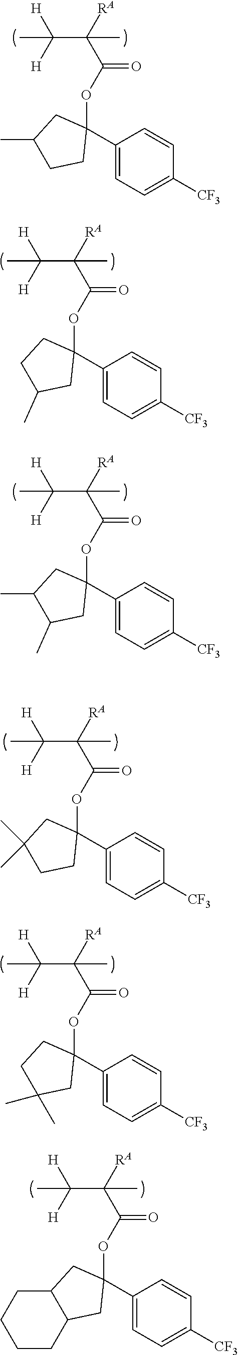

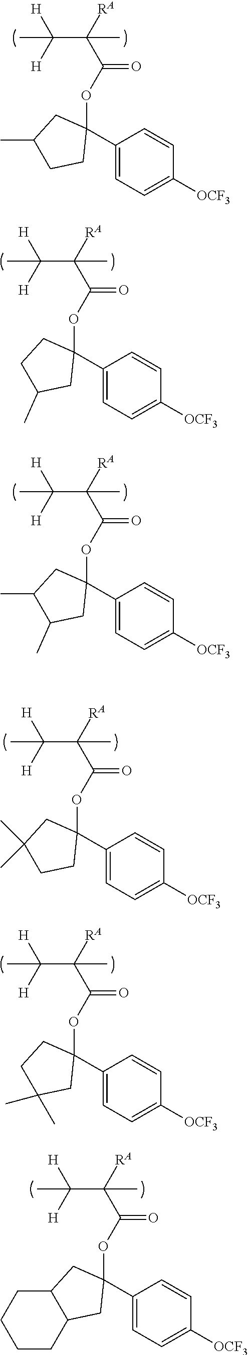

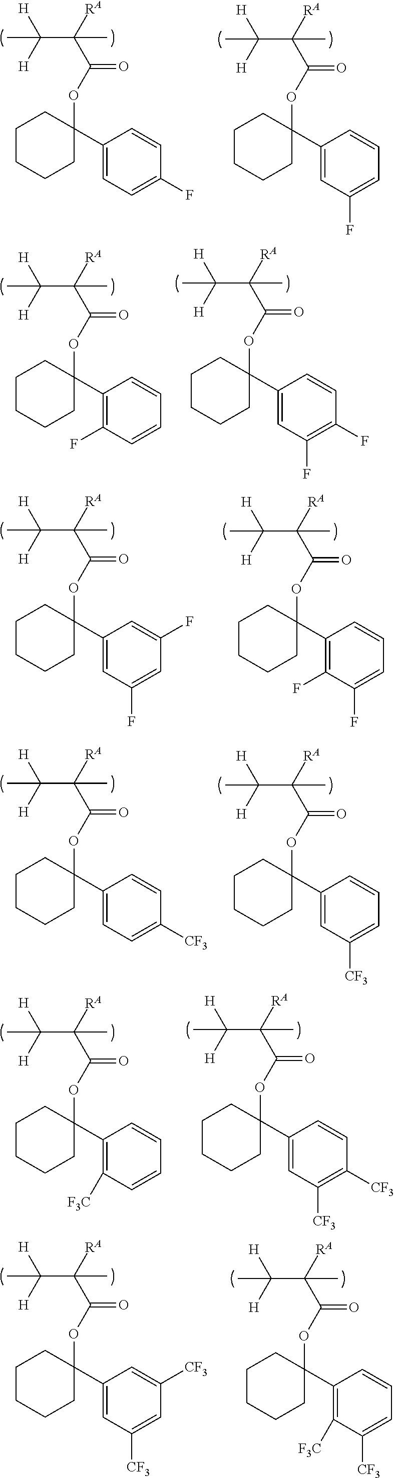

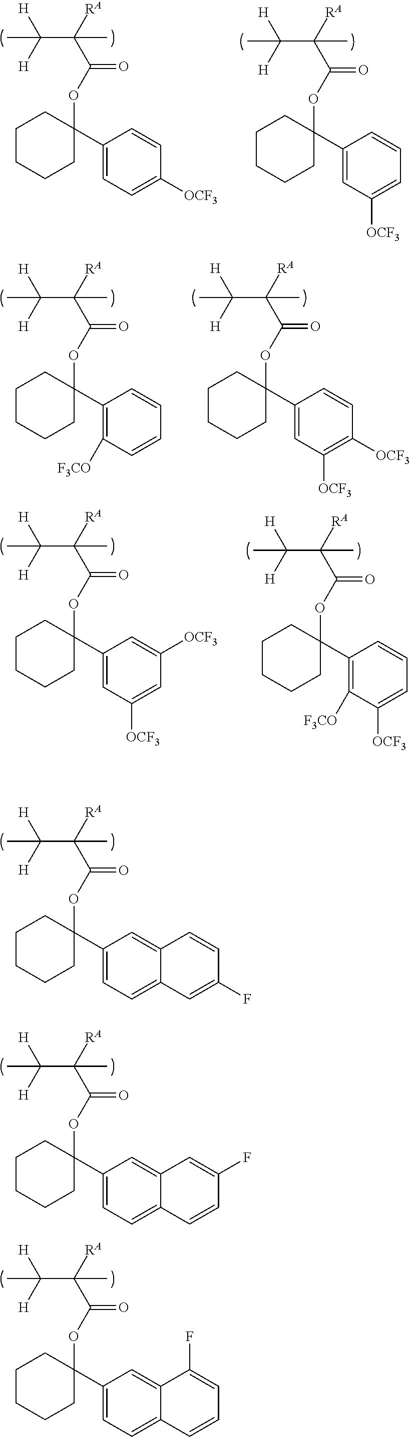

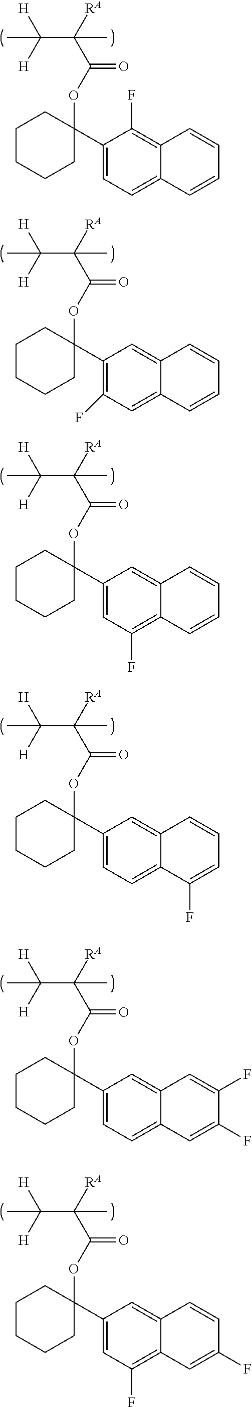

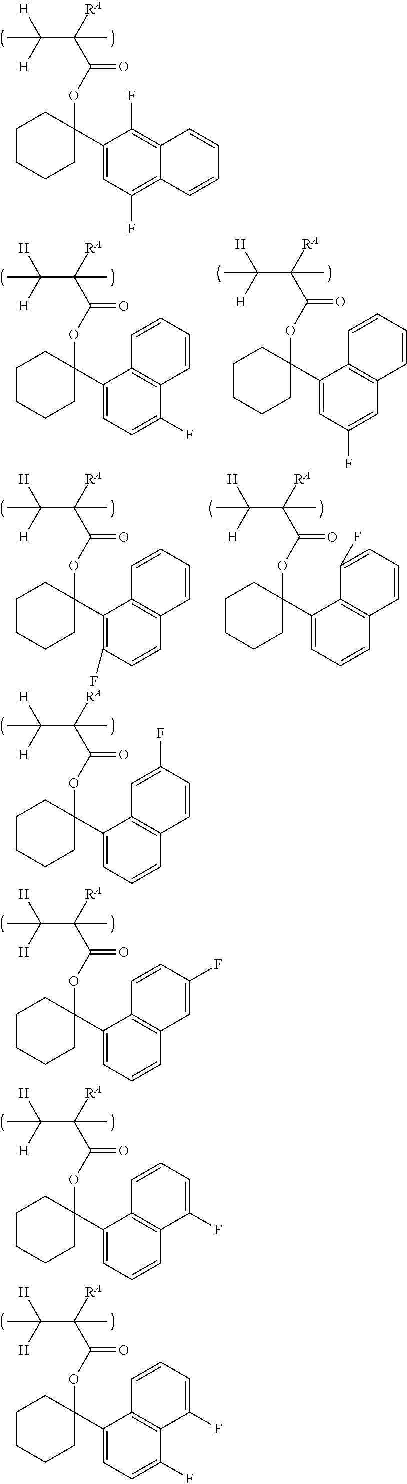

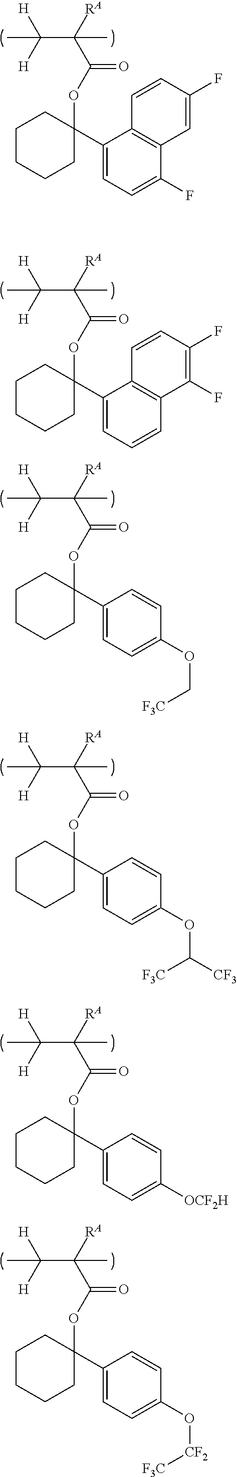

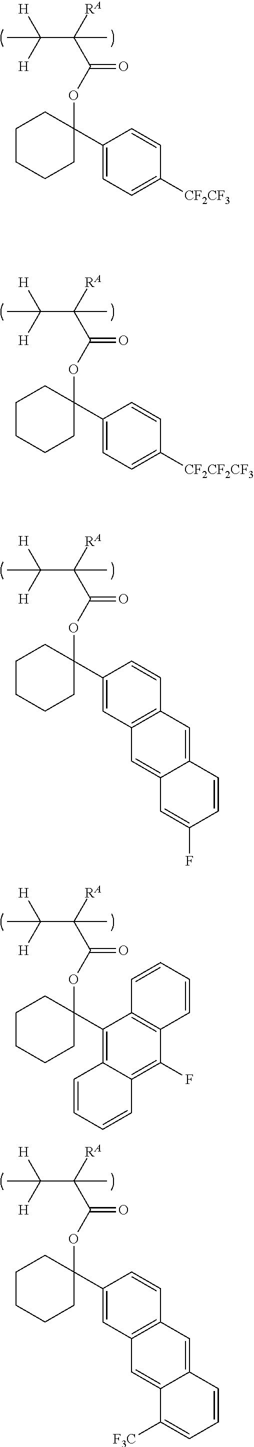

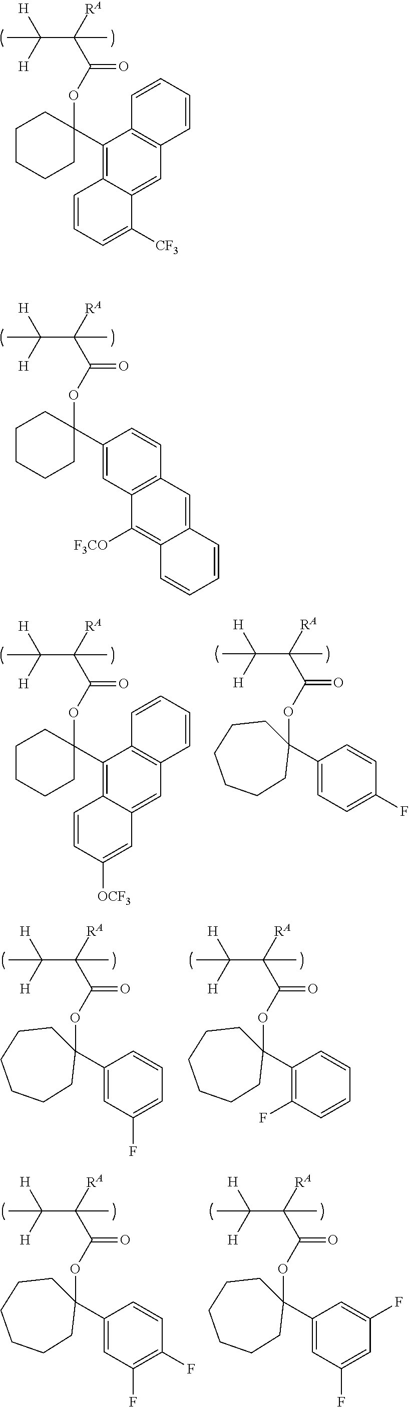

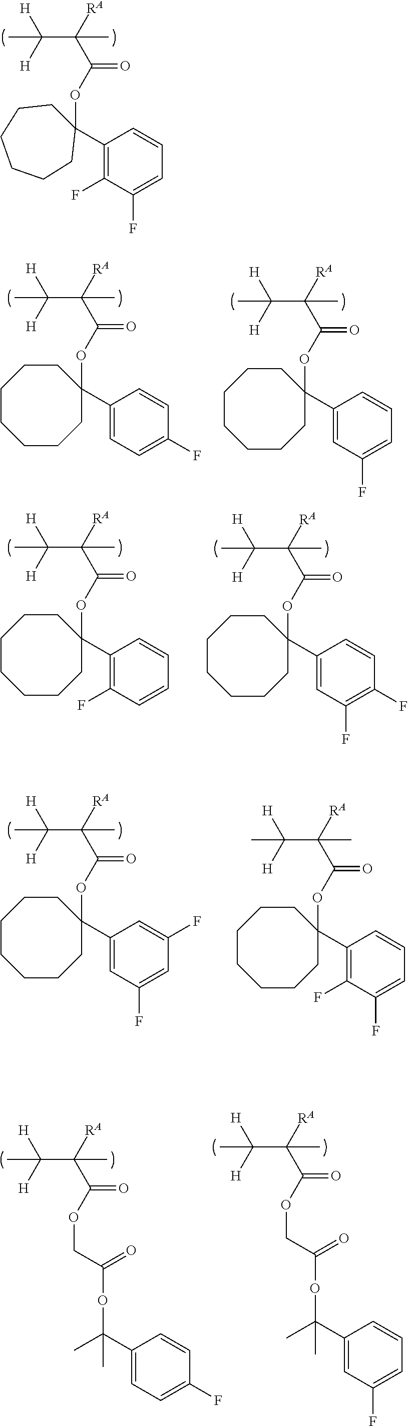

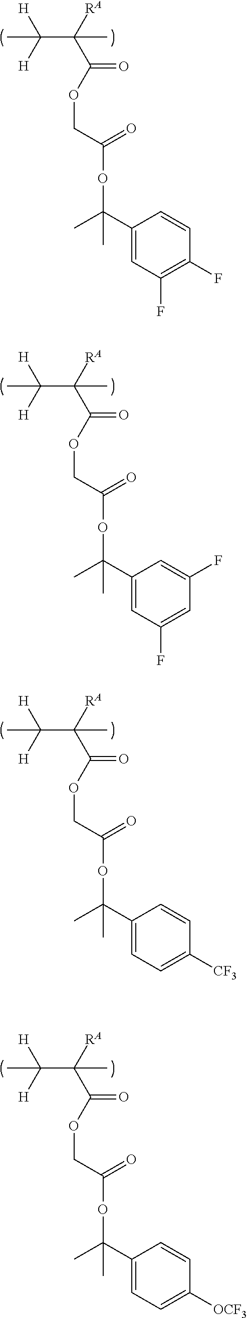

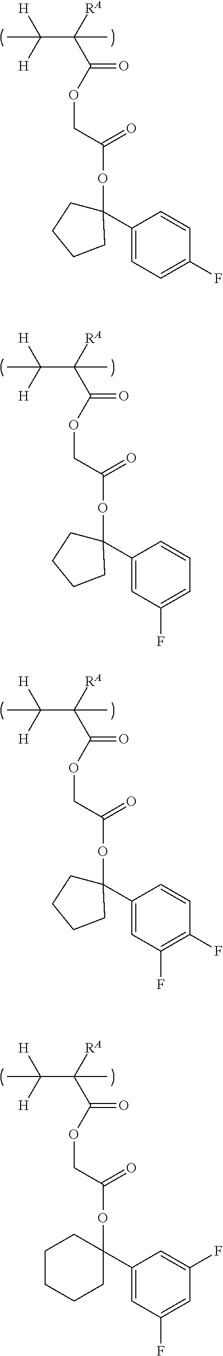

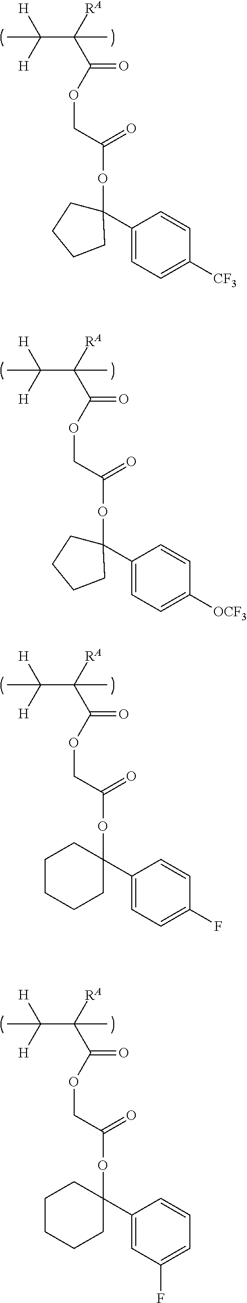

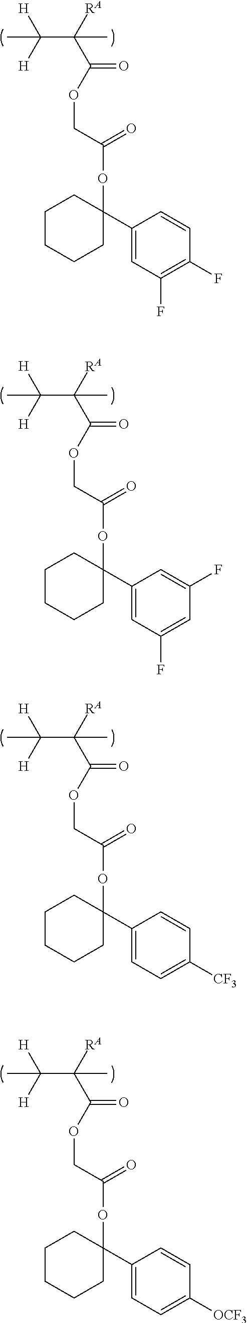

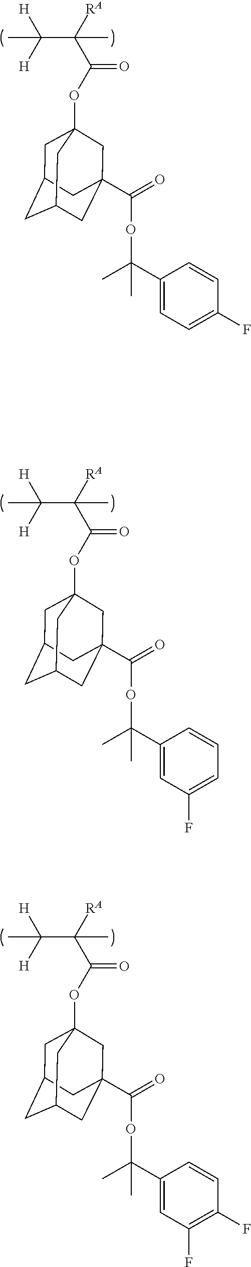

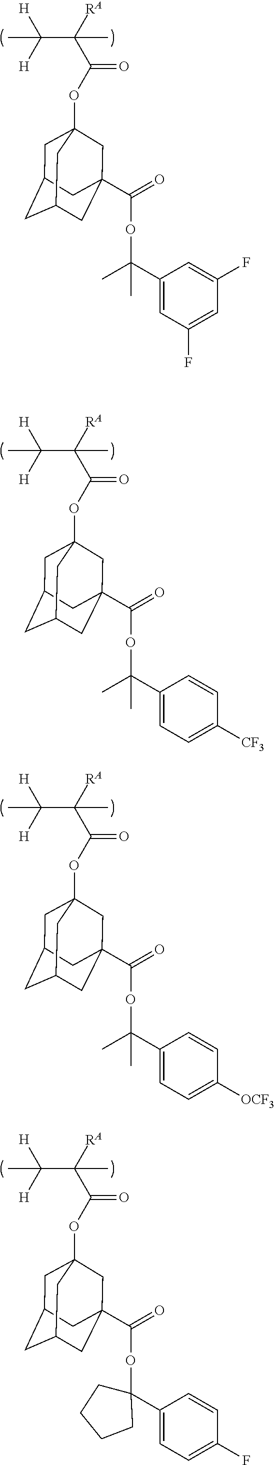

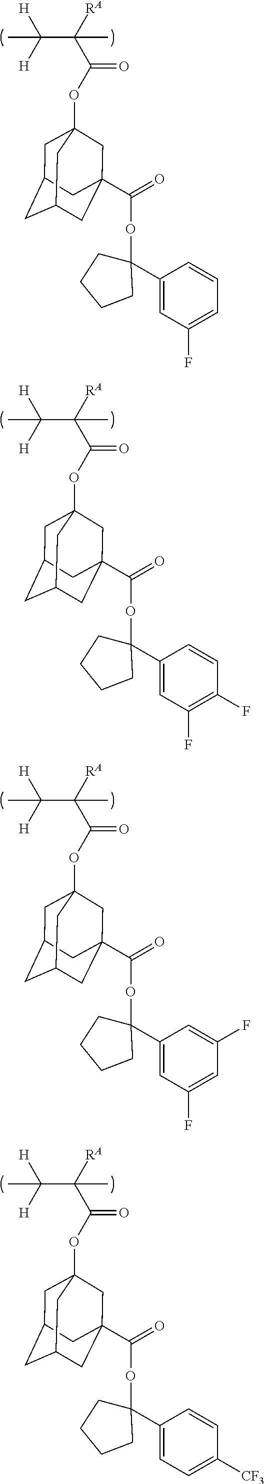

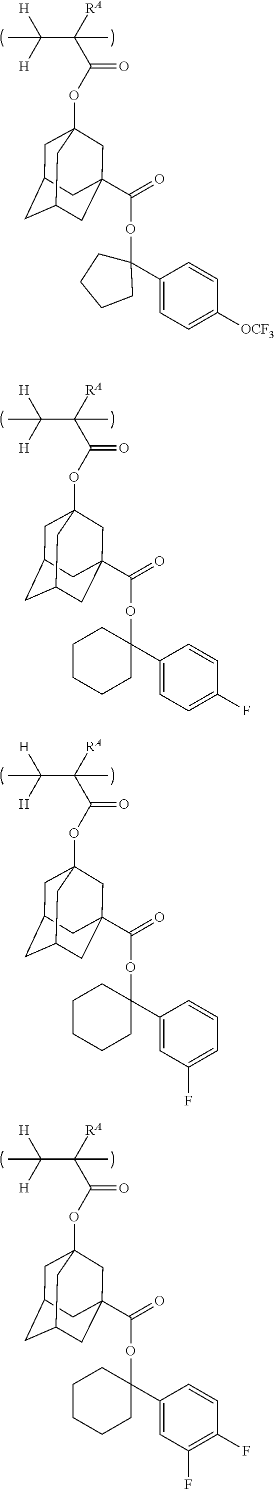

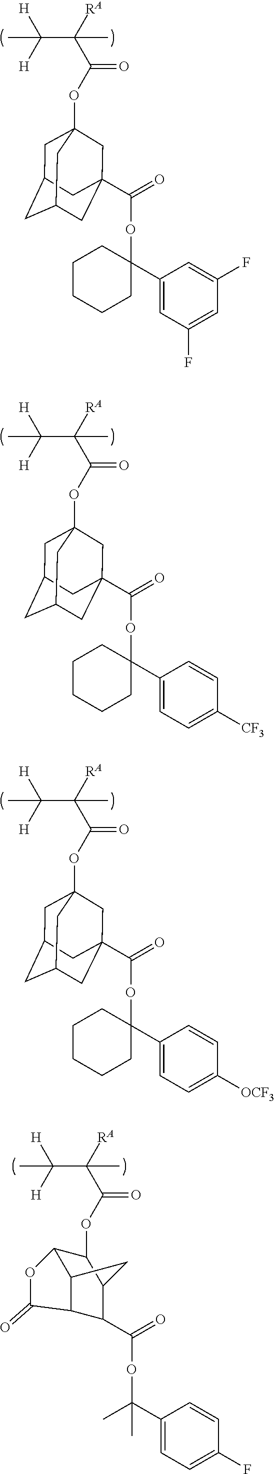

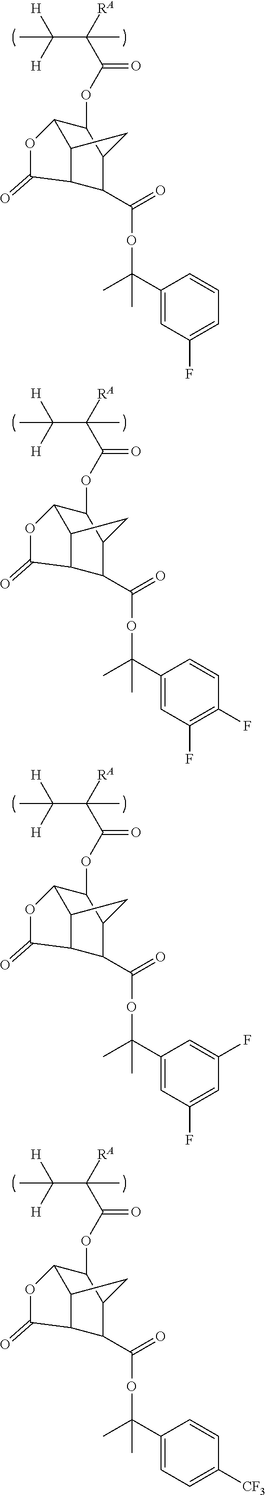

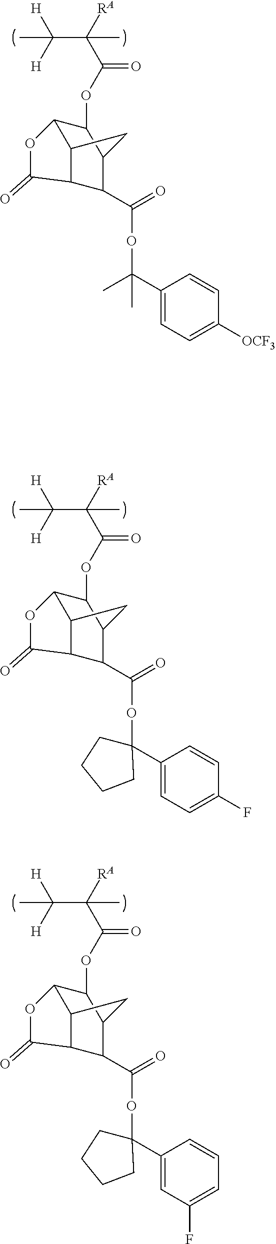

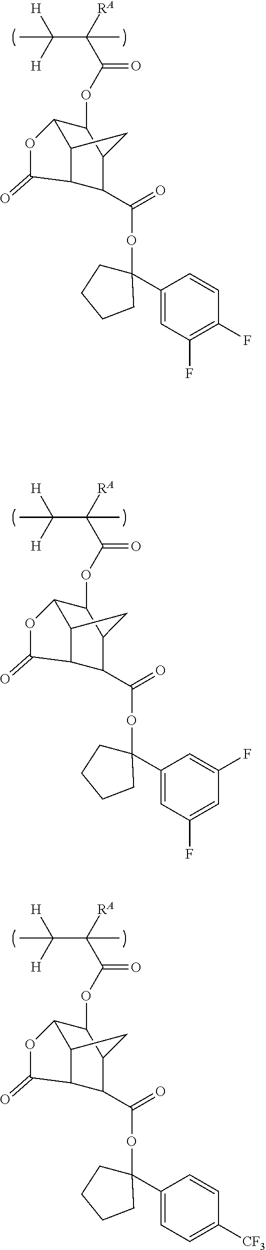

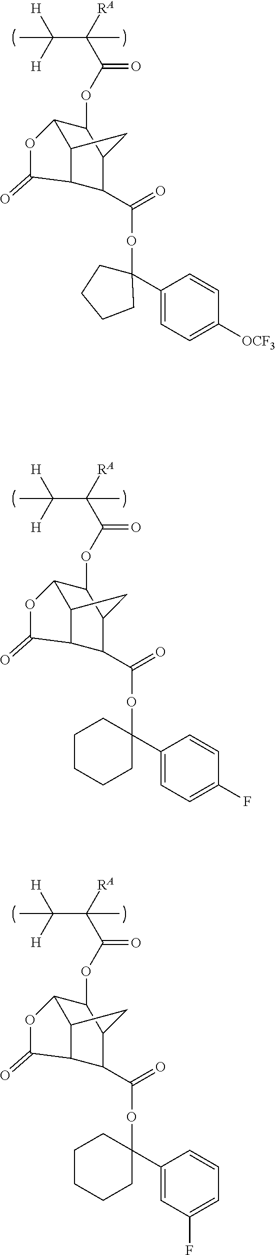

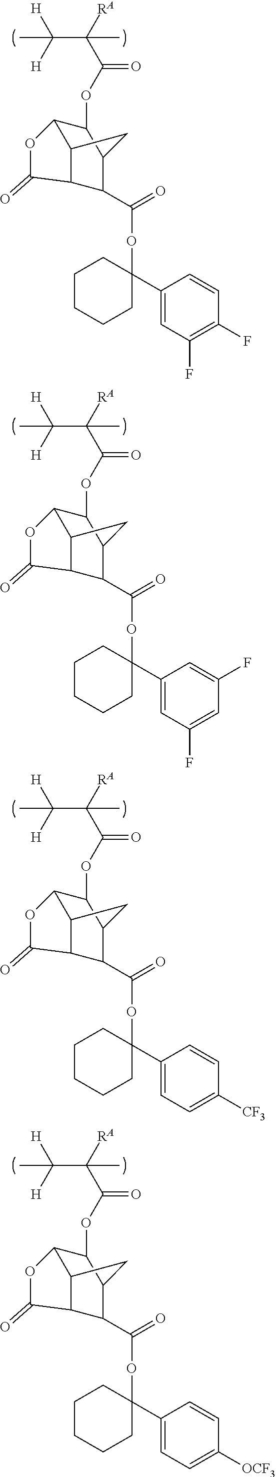

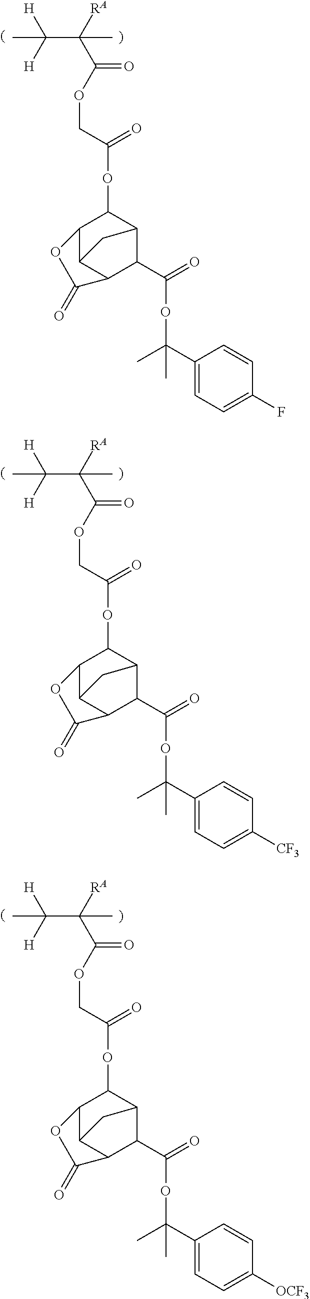

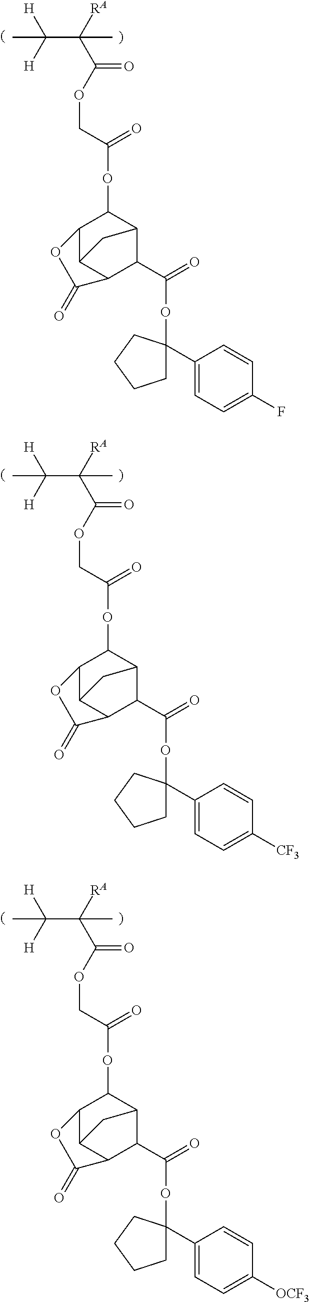

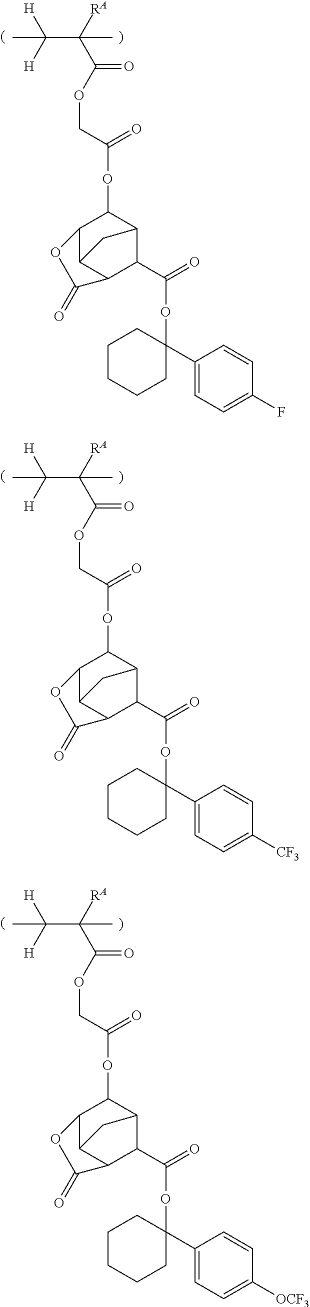

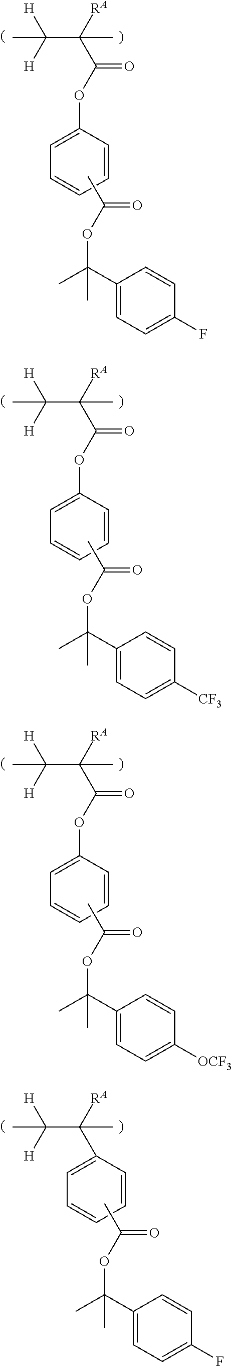

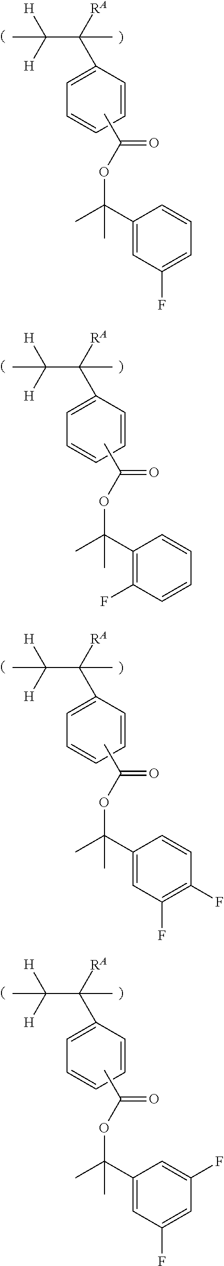

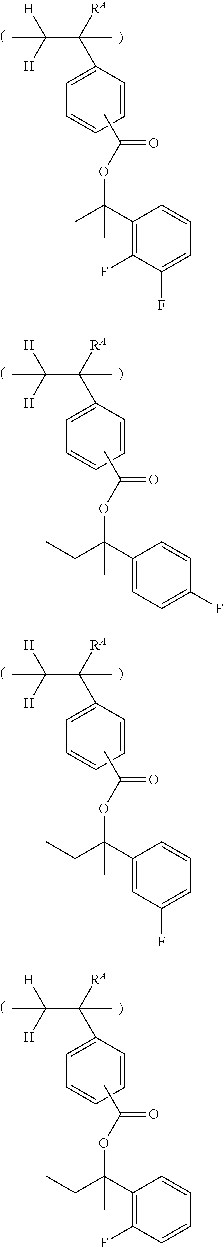

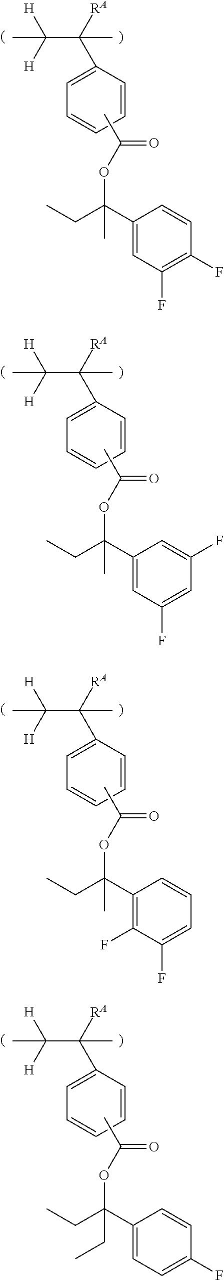

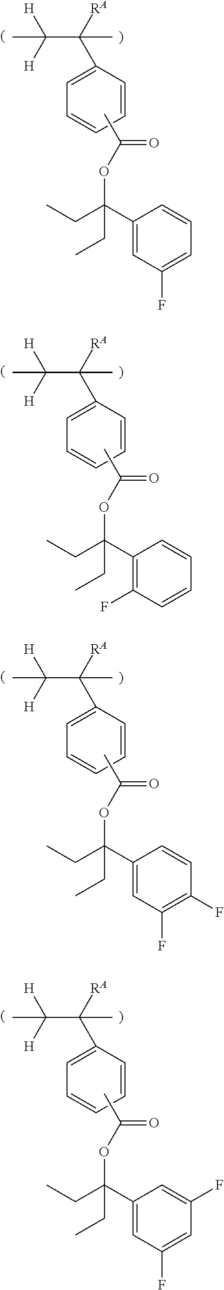

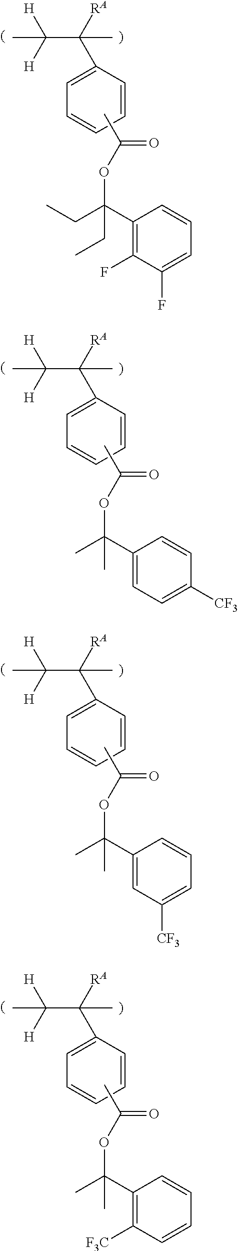

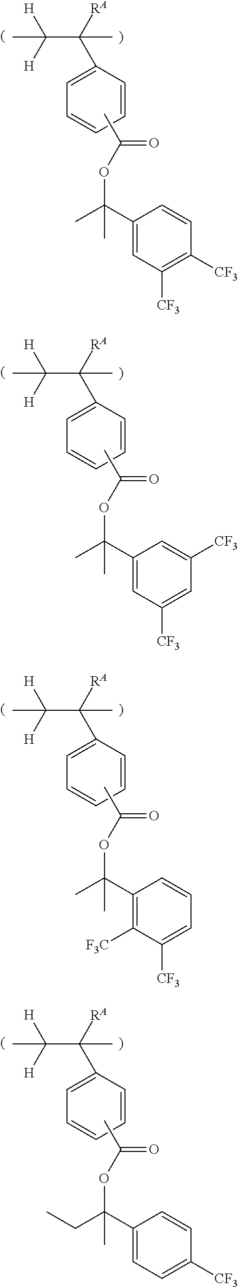

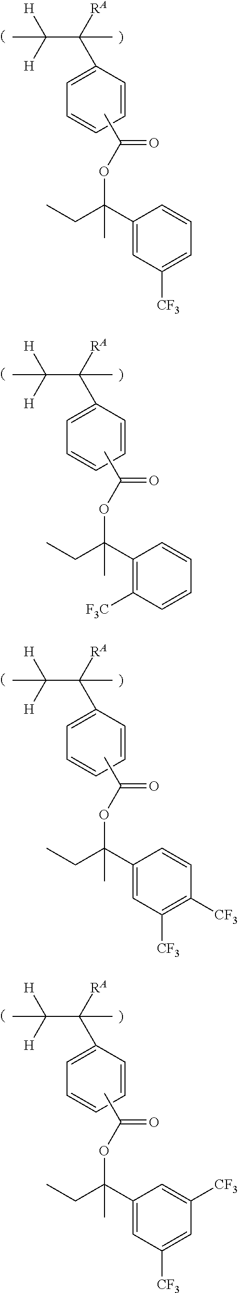

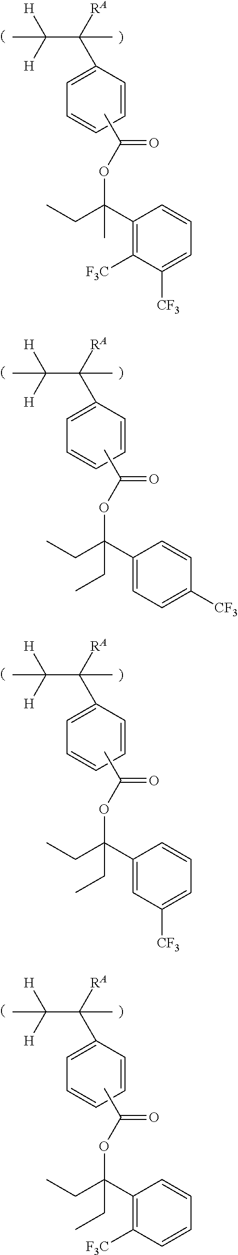

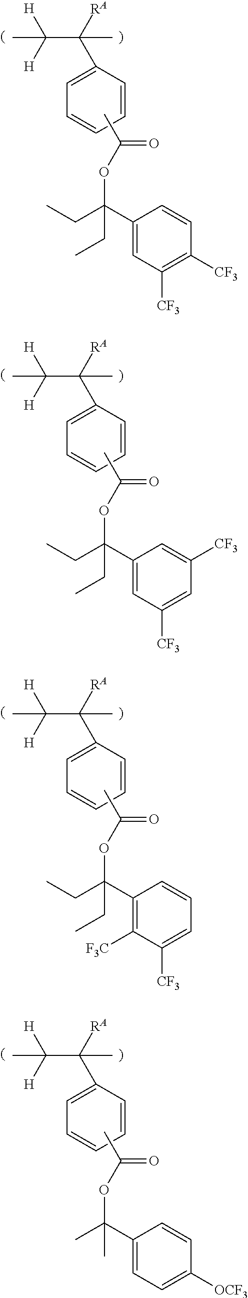

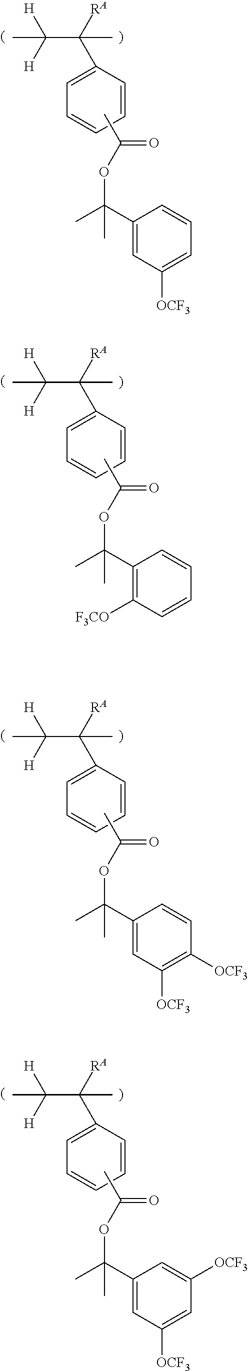

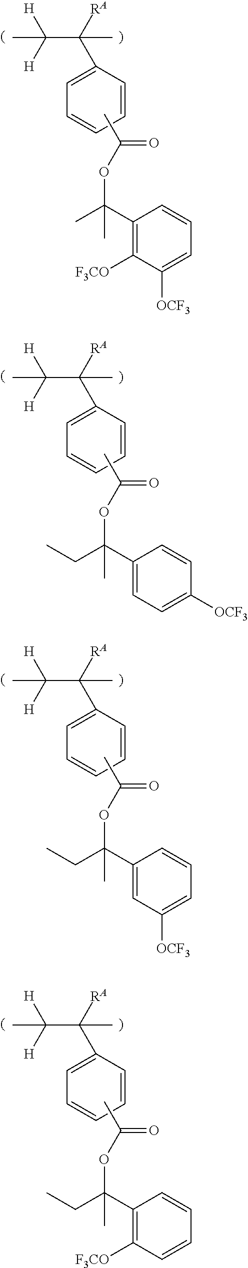

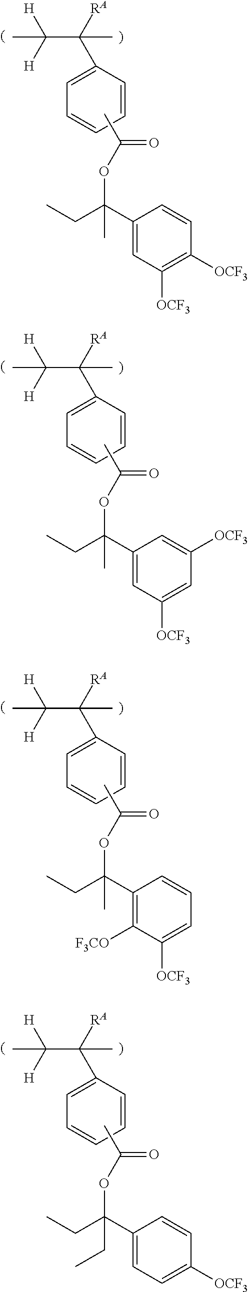

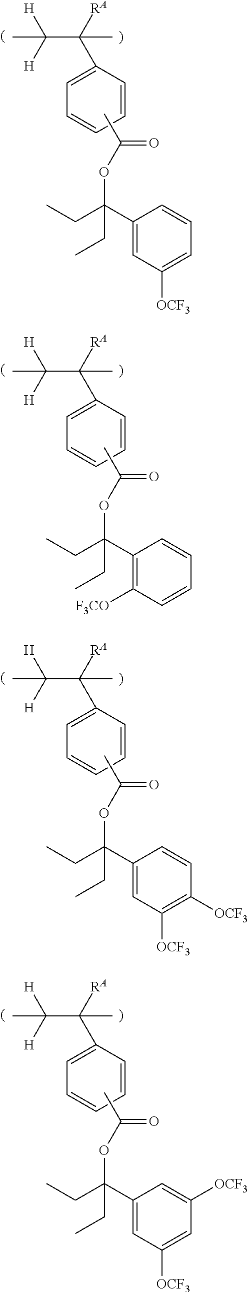

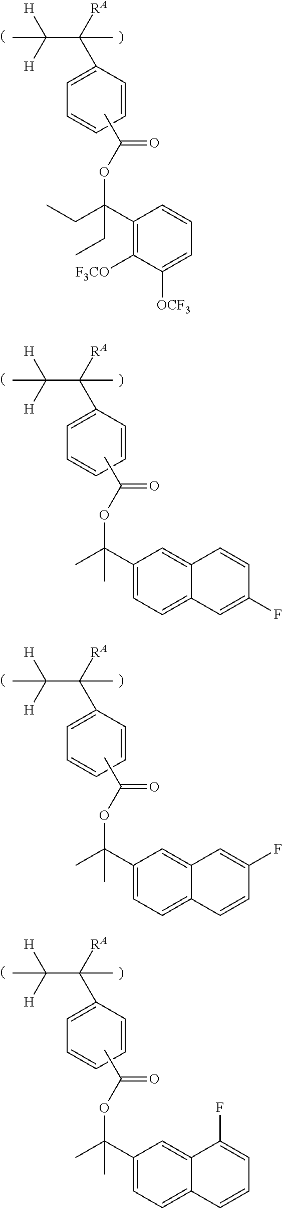

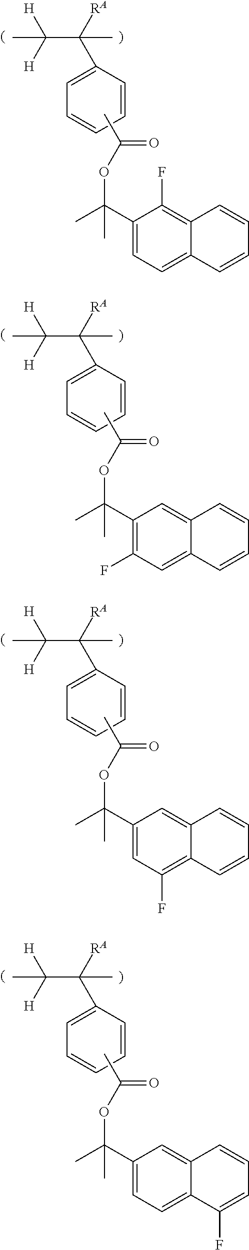

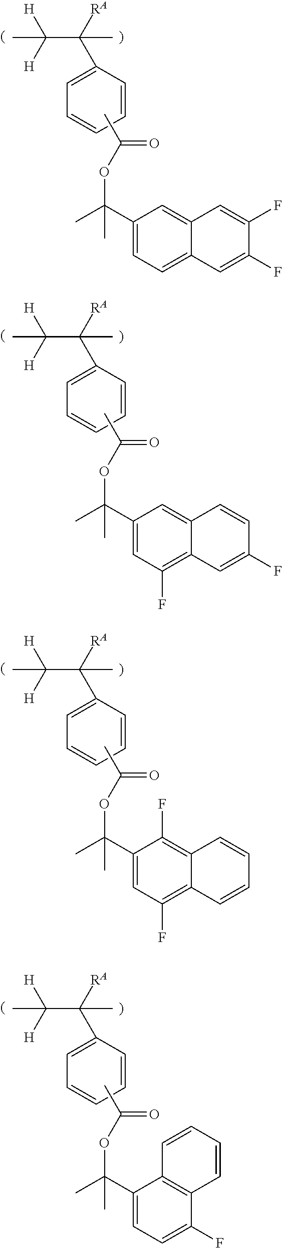

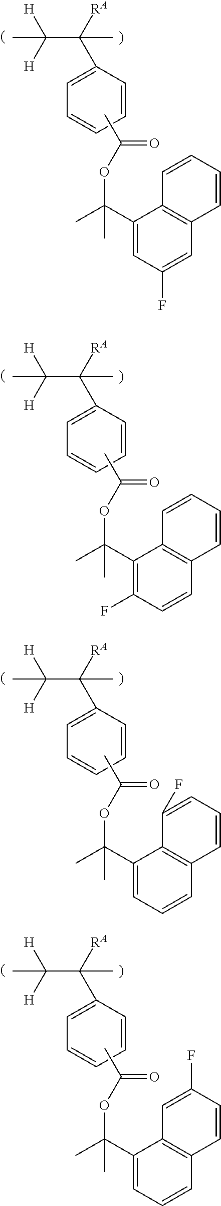

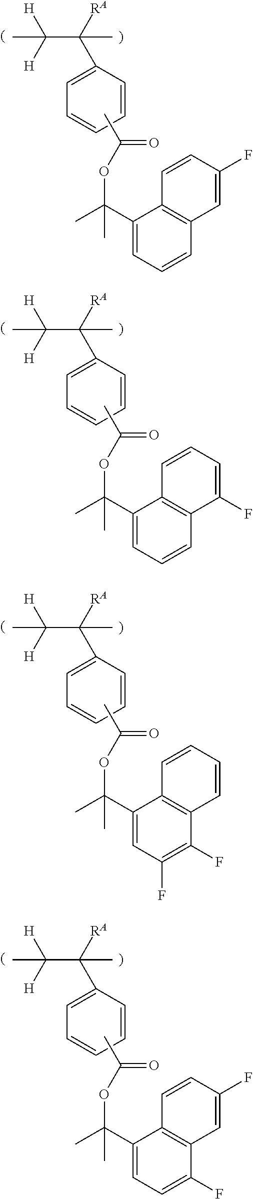

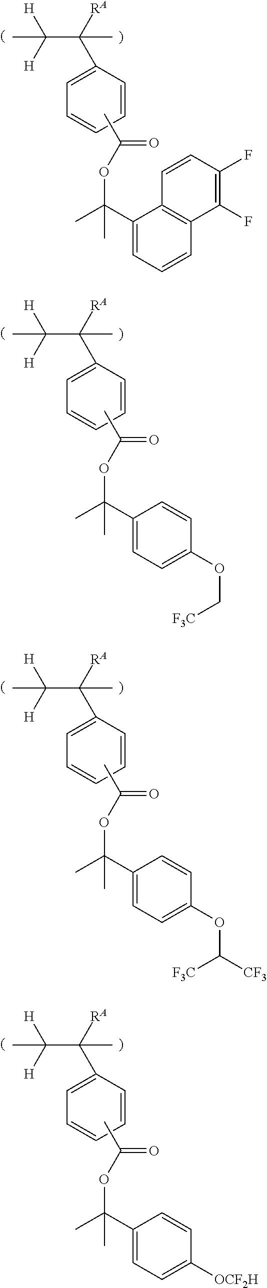

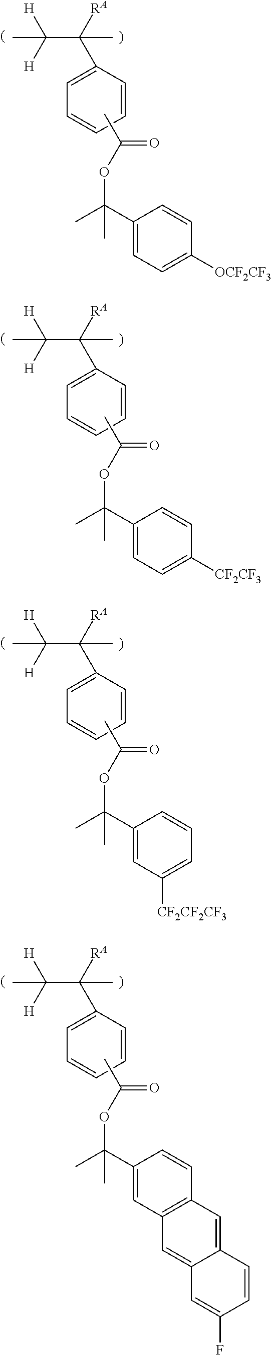

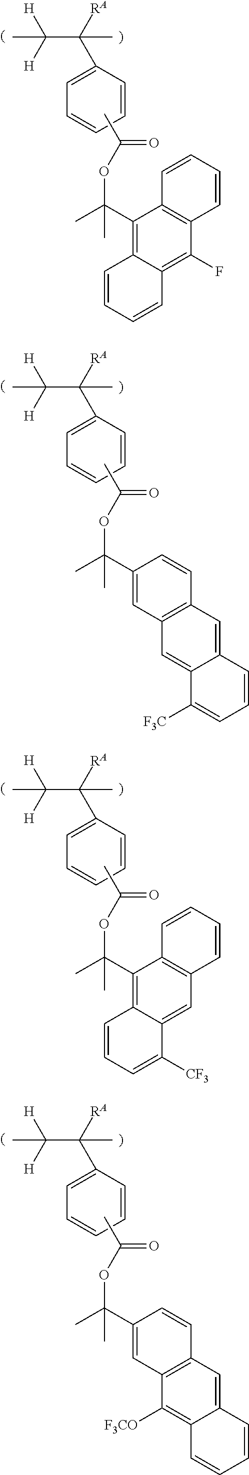

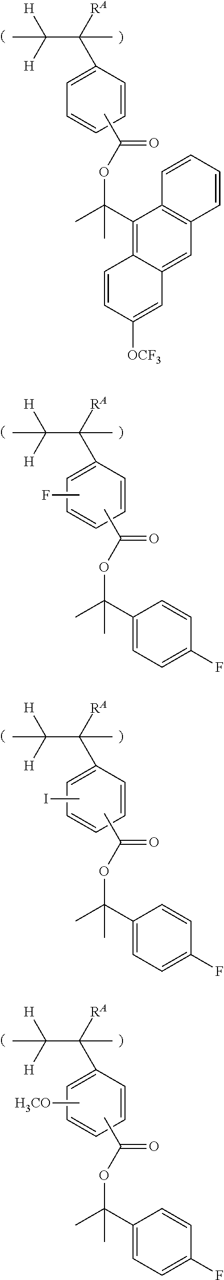

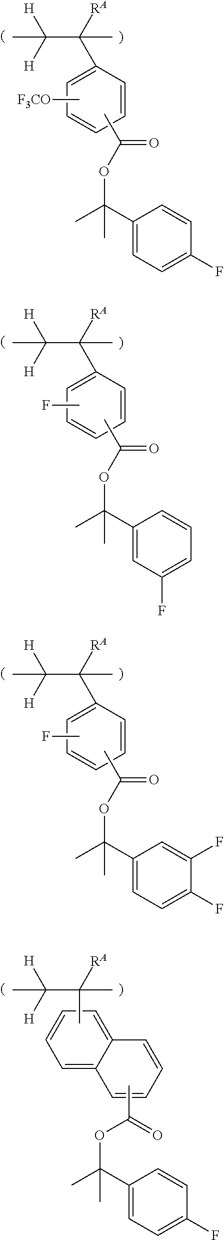

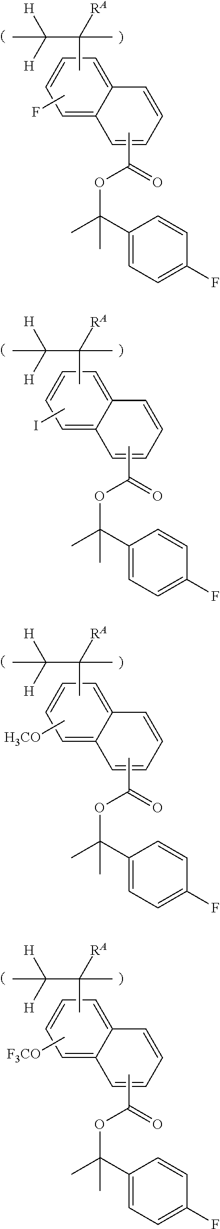

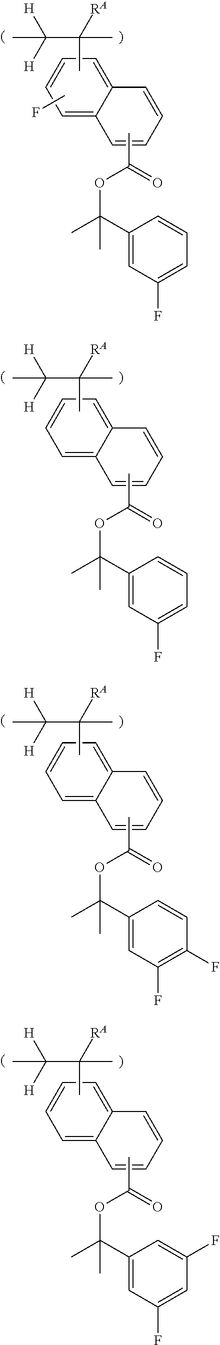

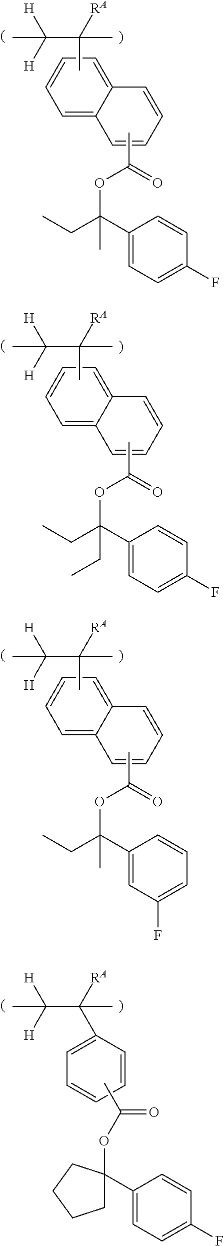

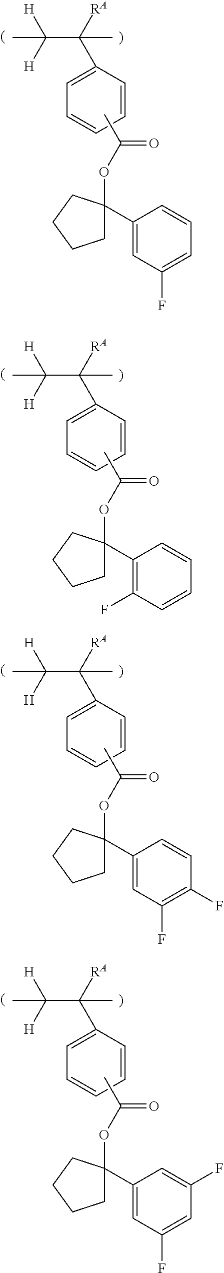

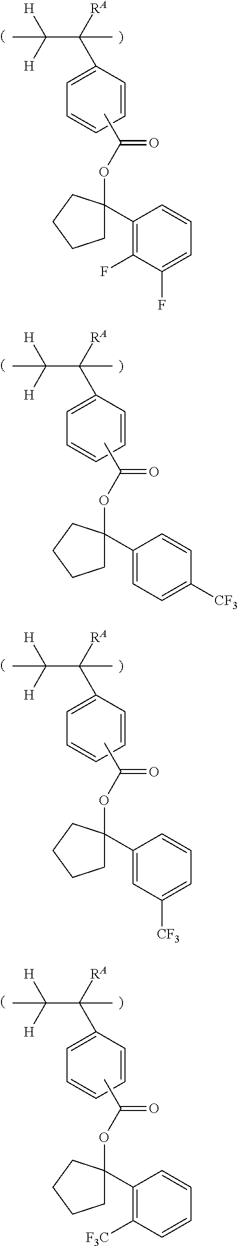

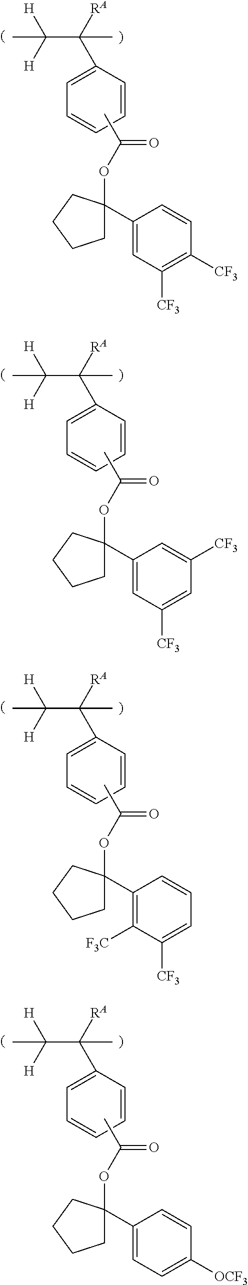

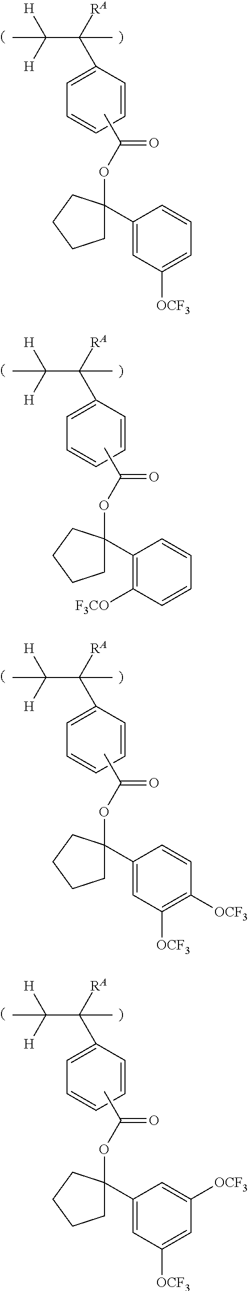

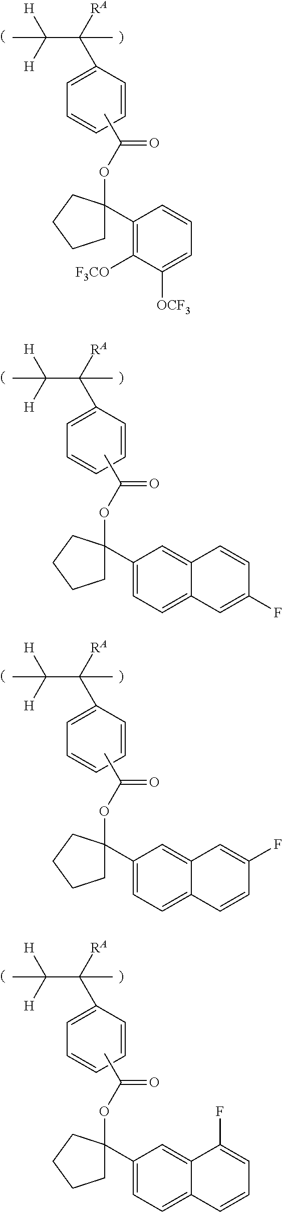

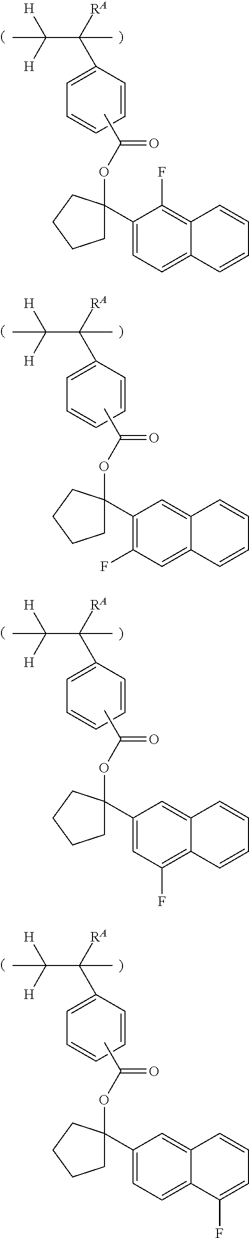

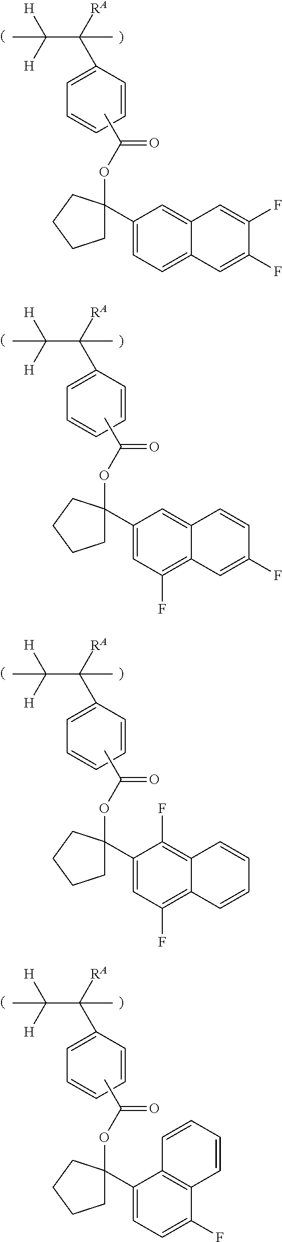

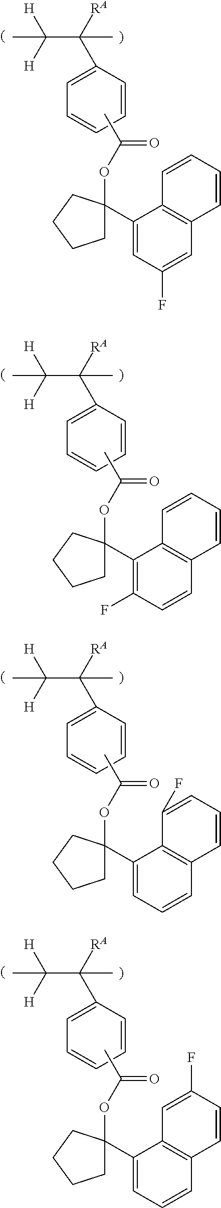

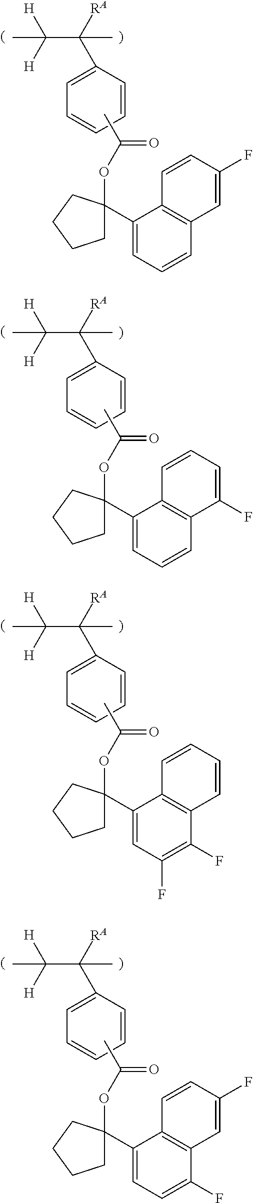

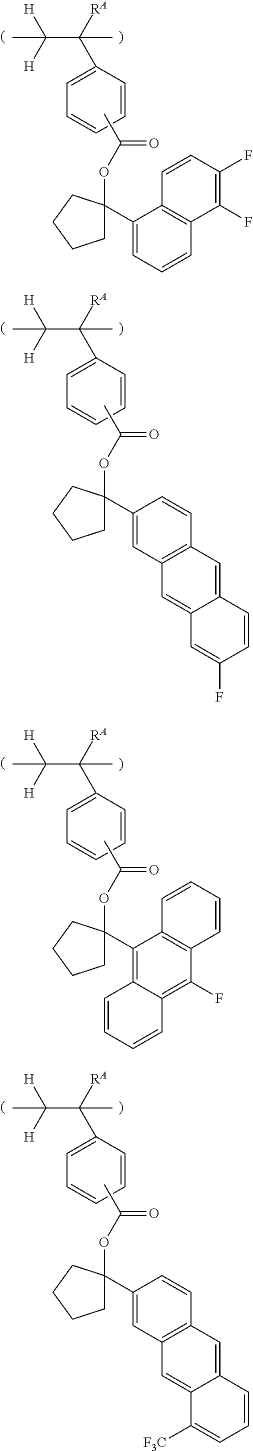

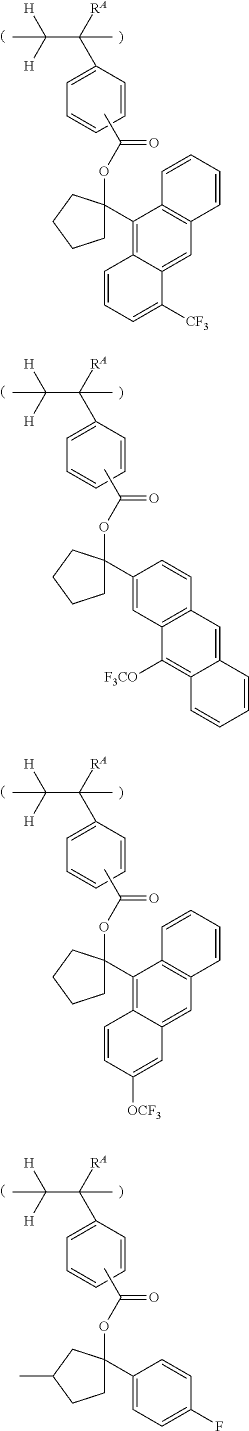

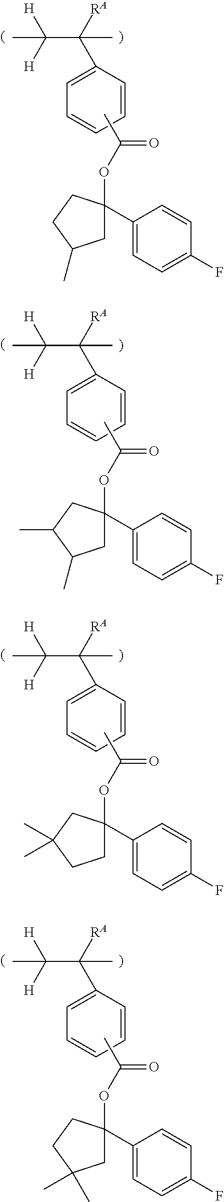

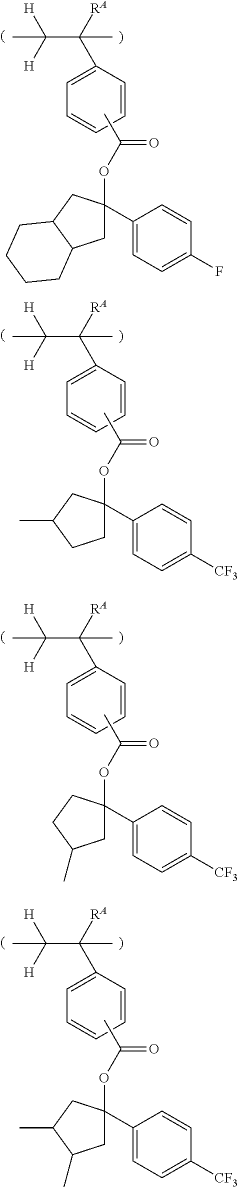

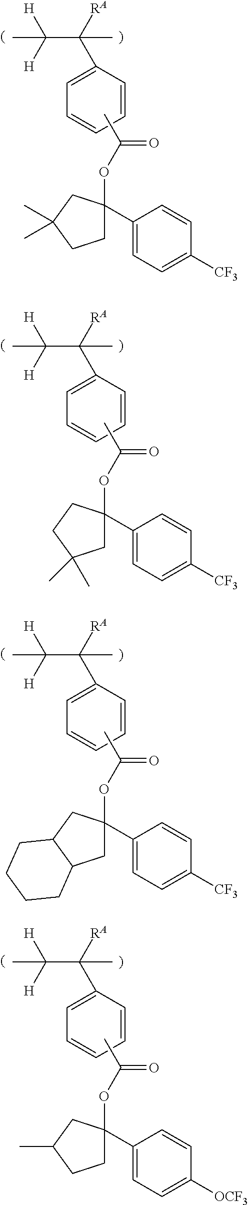

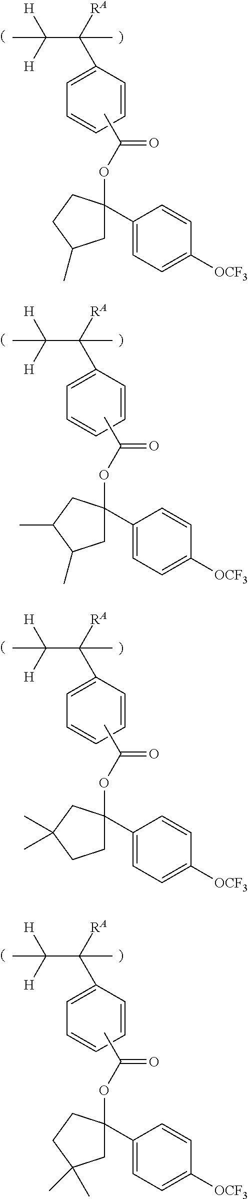

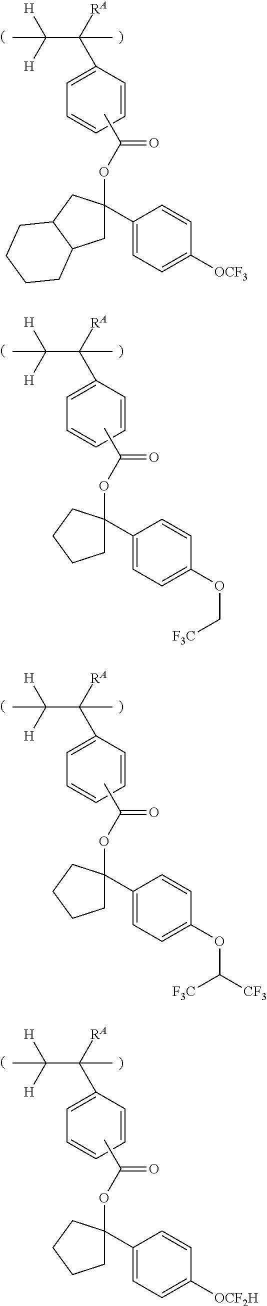

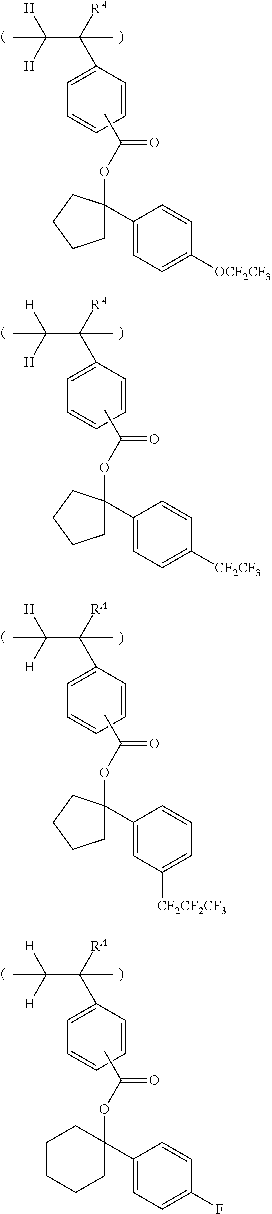

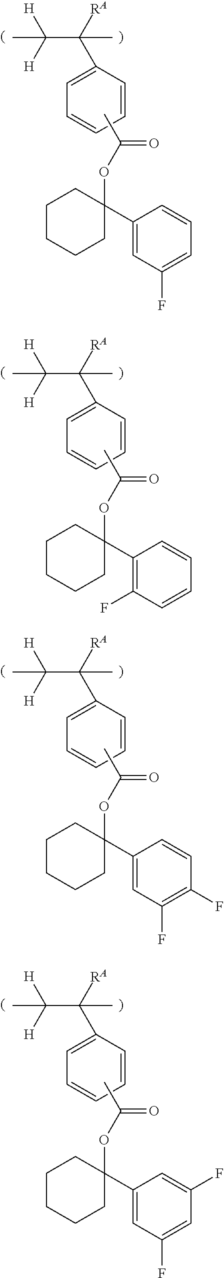

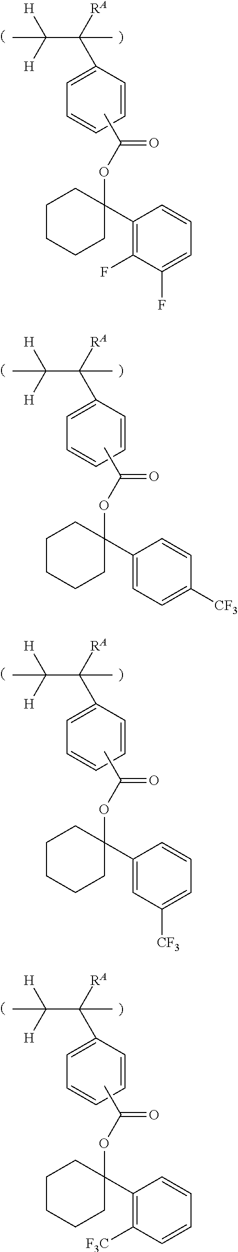

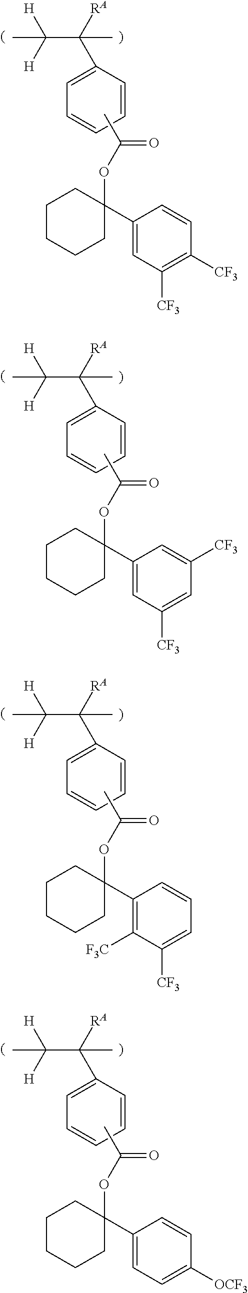

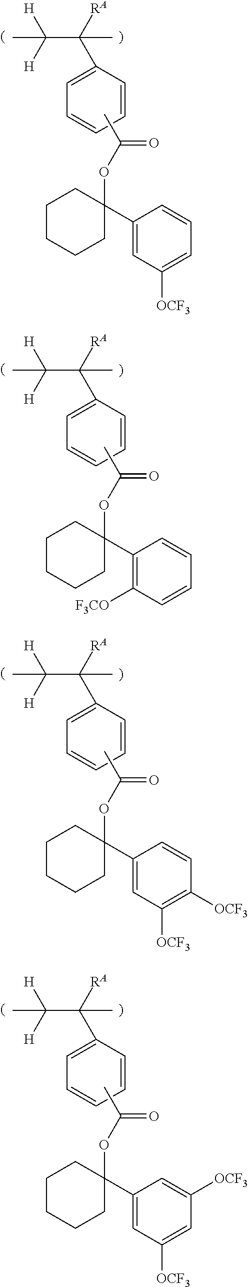

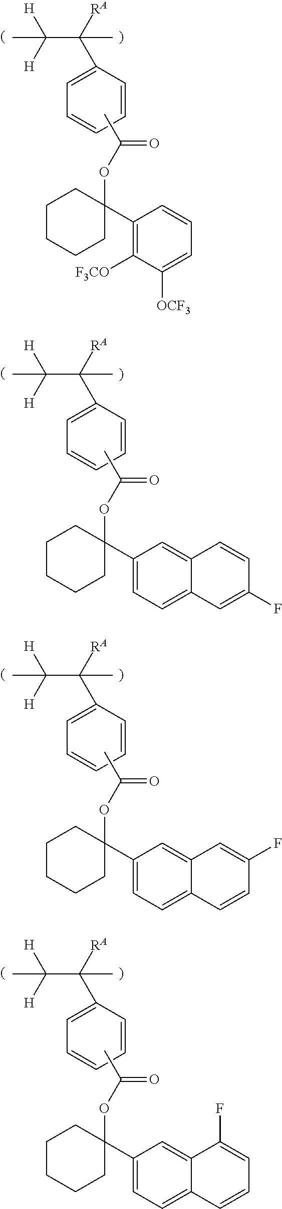

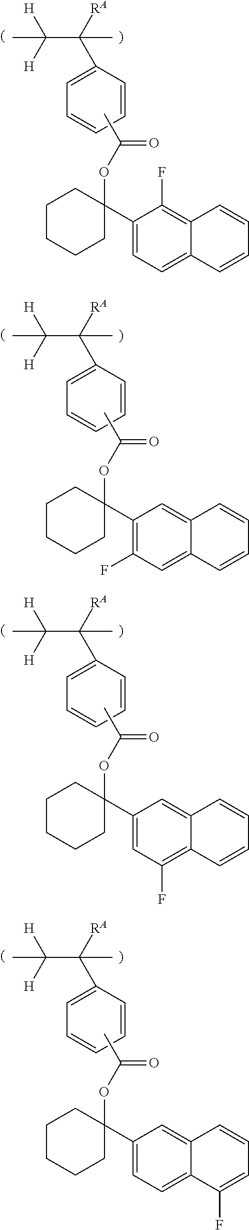

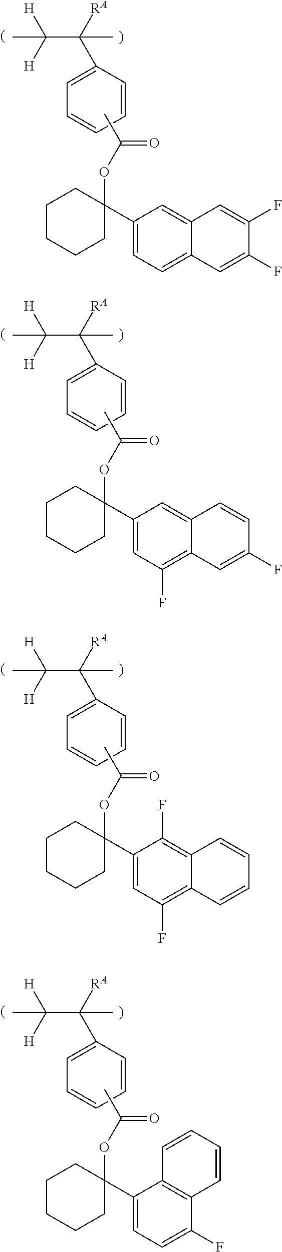

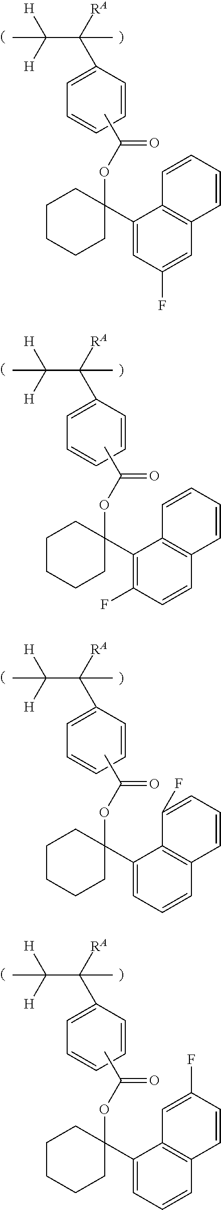

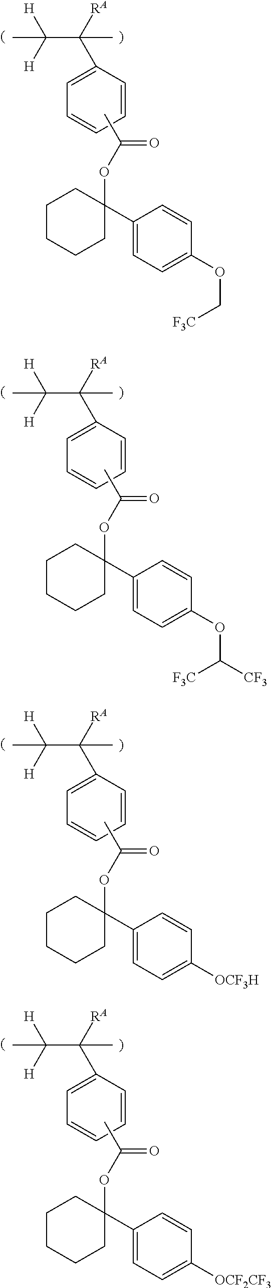

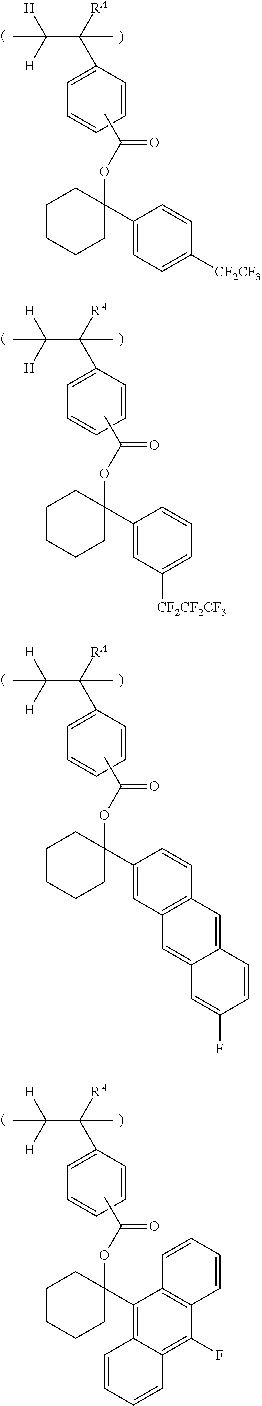

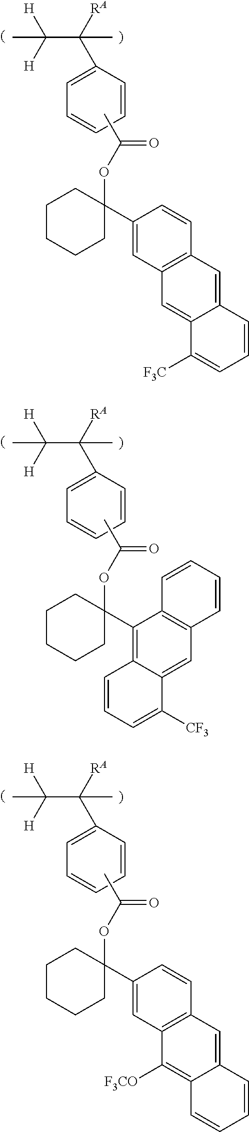

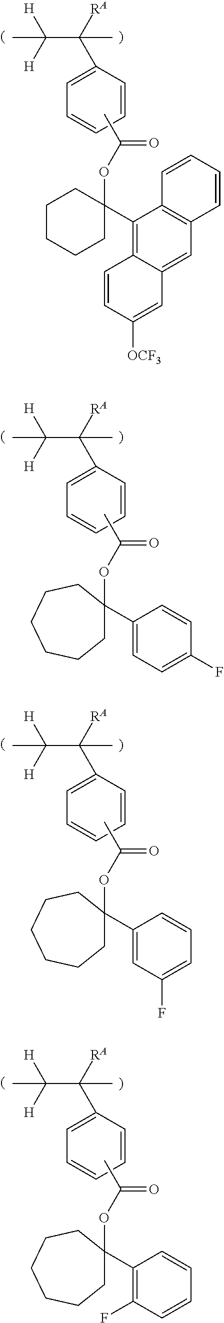

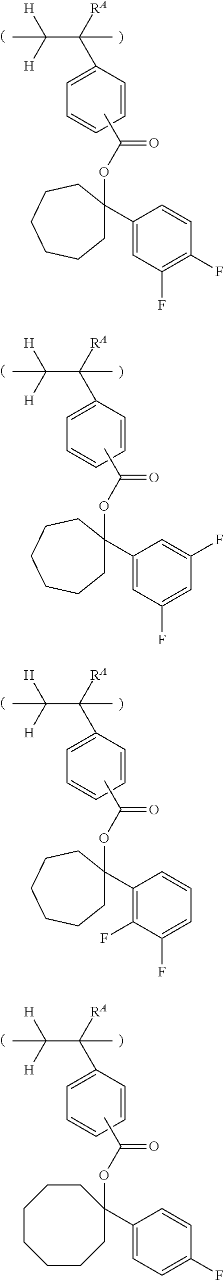

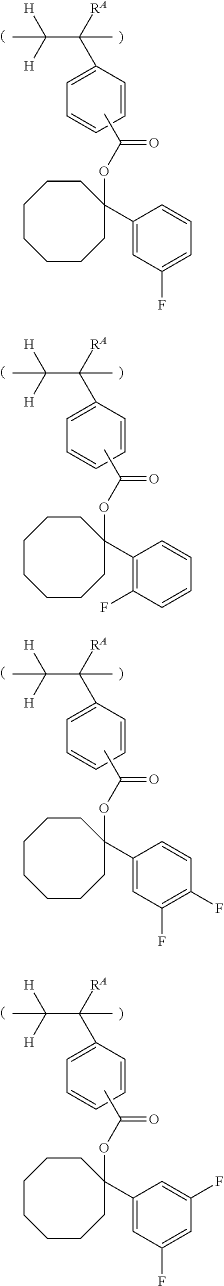

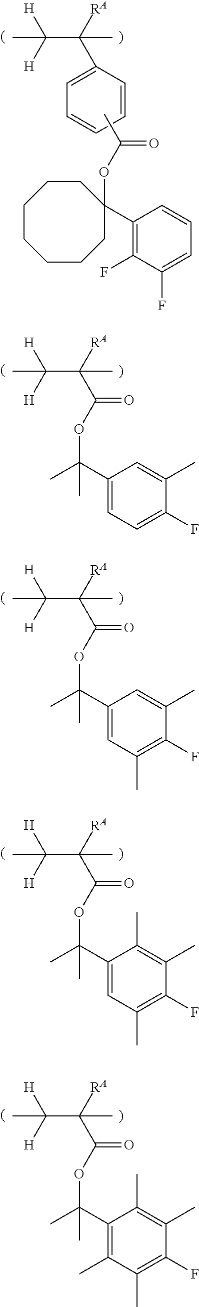

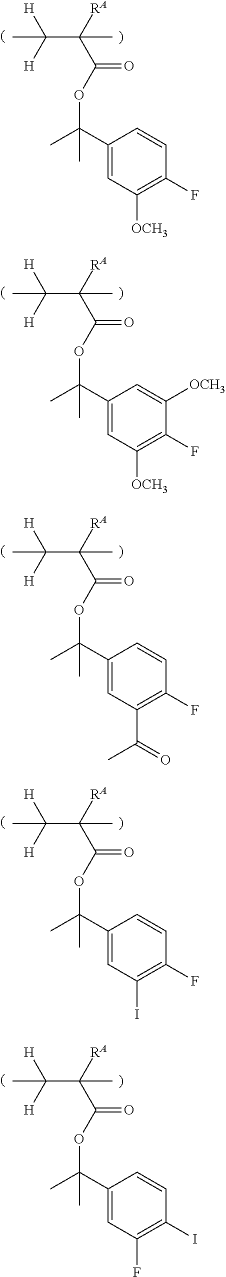

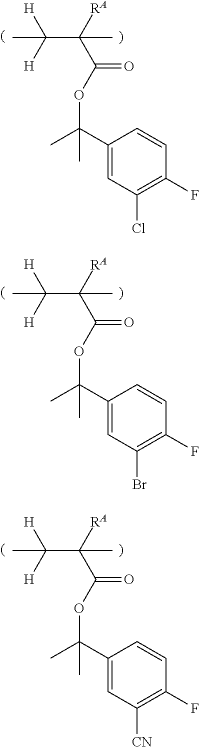

Since the acid labile group having carboxylic acid protected with a tertiary benzyl alcohol is extremely low in activation energy for acid-catalyzed deprotection reaction as compared with the acid labile group in the form of tertiary alkyl group, typically tert-butyl, deprotection reaction takes place even at a temperature around 50° C. When a polymer having an acid labile group with extremely low activation energy for deprotection reaction is used as the base polymer, the PEB temperature is too low, suggesting difficulty to control the temperature uniformity or difficulty to control the acid diffusion. If the distance of acid diffusion cannot be controlled, the CDU or maximum resolution of patterns after development is degraded. An adequate PEB temperature is necessary for acid diffusion control, and most often the range of 80 to 100° C. is adequate.

Another problem arising from the use of a low-activation energy protective group is possible elimination of the protective group during polymerization in the case of a polymer with which a PAG is to be copolymerized. Although the PAG in the form of onium salt is basically neutral, the onium salt can be partially dissociated by the heat during polymerization. When a repeat unit having a phenolic hydroxy group is concurrently copolymerized, an exchange reaction takes place between the proton of the phenolic hydroxy group and the cation of the PAG to generate an acid whereby deprotection of the protective group can occur. The deprotection during polymerization becomes outstanding particularly when a low-activation energy protective group is used.

As mentioned above, the acid labile group having carboxylic acid protected with a tertiary benzyl alcohol has the advantage of satisfactory etching resistance due to the benzene ring. When a PAG is copolymerized, elimination of the protective group occurs during polymerization. When an electron attractive group is attached to a benzene ring, the activation energy for deprotection becomes high. It is believed that this is because the stability of a benzyl cation in a deprotection intermediate is lowered by the electron attractive group. It is possible to attach an electron attractive group to a protective group quite susceptible to deprotection to hold down the reactivity of deprotection reaction to an optimum level.

It is generally believed that fluorine atoms are highly absorptive to EUV of wavelength 13.5 nm and have a sensitizing effect of enhancing sensitivity. It is thus expected that sensitivity is enhanced by introducing fluorine into a protective group. However, when fluorine is introduced into an acid labile group of tertiary alkyl form, the stability of intermediate cation during deprotection reaction is largely reduced by the electron attractive effect of fluorine. As a result, creation of olefin does not occur and deprotection reaction does not occur. However, the tertiary acid labile group having a fluorinated aromatic group provides the intermediate cation with optimum stability and shows adequate reactivity for deprotection.

When polymer P is used as the base polymer in a chemically amplified positive resist composition for the purpose of controlling acid diffusion to improve the dissolution contrast and etching resistance, the chemically amplified positive resist composition shows a significantly high contrast of alkaline dissolution rate before and after light exposure, fully suppressed acid diffusion, a high resolution, satisfactory pattern profile and LWR after light exposure, and high etching resistance.

The chemically amplified resist composition has advantages including a high dissolution contrast of a resist film due to optimum deprotection reaction, acid diffusion controlling effect, high resolution, exposure latitude, process adaptability, satisfactory pattern profile after light exposure, and high etching resistance. By virtue of these advantages, the resist composition is fully useful in commercial application and suited as a mask pattern-forming material.

### Repeat Unit Having Phenolic Hydroxy Group

Polymer P also contains repeat units having a phenolic hydroxy group, which are referred to as repeat units B, hereinafter. Repeat units B are preferably represented by the formula (B1).

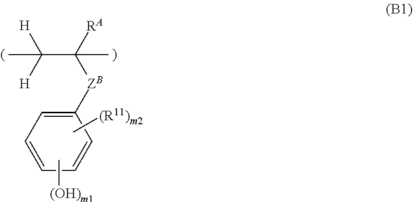

In formula (B1). R^{A} is as defined above. Z^{B} is a single bond or *—C(═O)—O—. The asterisk (*) designates a point of attachment to the carbon atom in the backbone. R¹¹ is halogen, cyano, a C₁-C₂₀ hydrocarbyl group which may contain a heteroatom, a C₁-C₂₀ hydrocarbyloxy group which may contain a heteroatom, a C₂-C₂₀ hydrocarbylcarbonyl group which may contain a heteroatom, a C₂-C₂₀ hydrocarbylcarbonyloxy group which may contain a heteroatom, or a C₂-C₂₀ hydrocarbyloxycarbonyl group which may contain a heteroatom. The subscript m1 is an integer of 1 to 4, m2 is an integer of Q to 4, and the sun of m1+m2 is from 1 to 5.

The hydrocarbyl group and hydrocarbyl moiety of the hydrocarbyloxy, hydrocarbylcarbonyl, hydrocarbylcarbonyloxy and hydrocarbyloxycarbonyl groups may be saturated or unsaturated and straight, branched or cyclic. Examples thereof are as exemplified above for the hydrocarbyl groups R^{B} and R^{C} in formula (A1).

Examples of repeat unit B are shown below, but not limited thereto. Herein, R^{A} is as defined above.

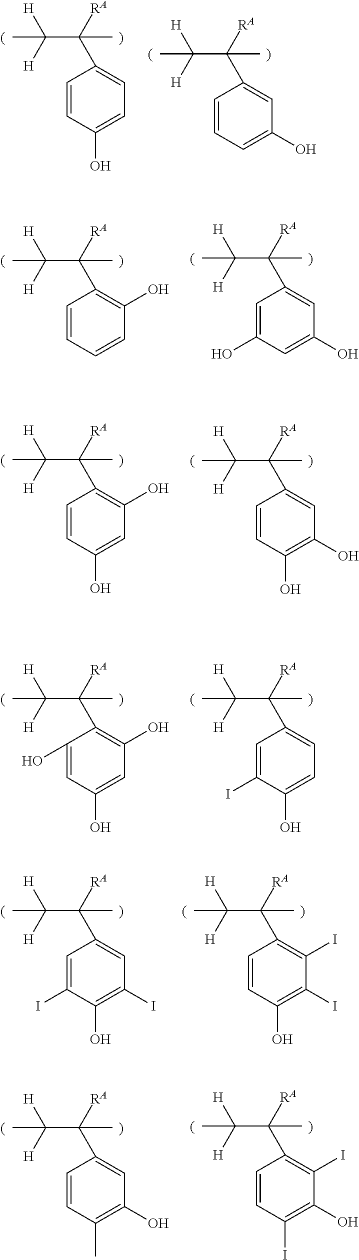

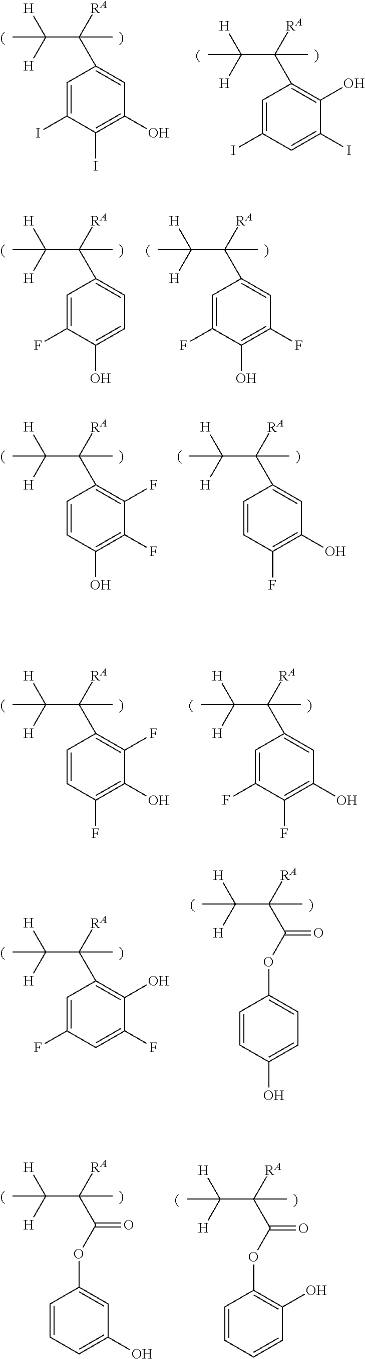

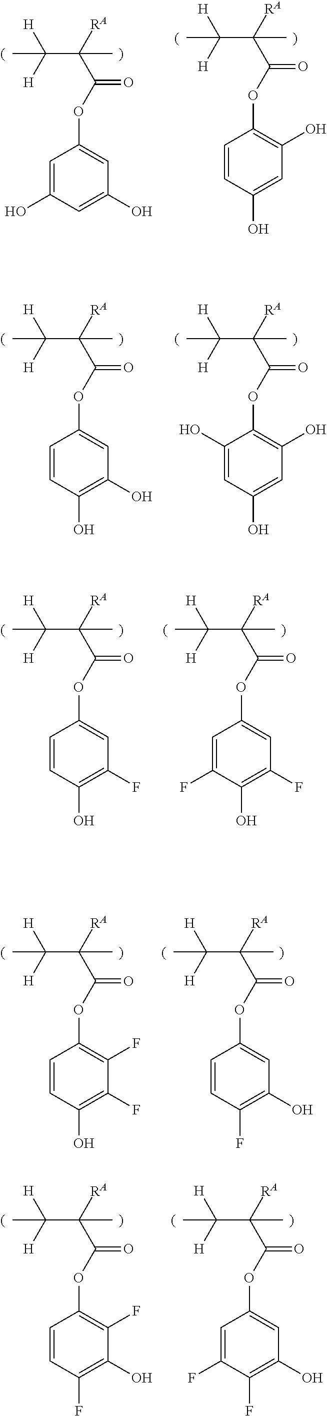

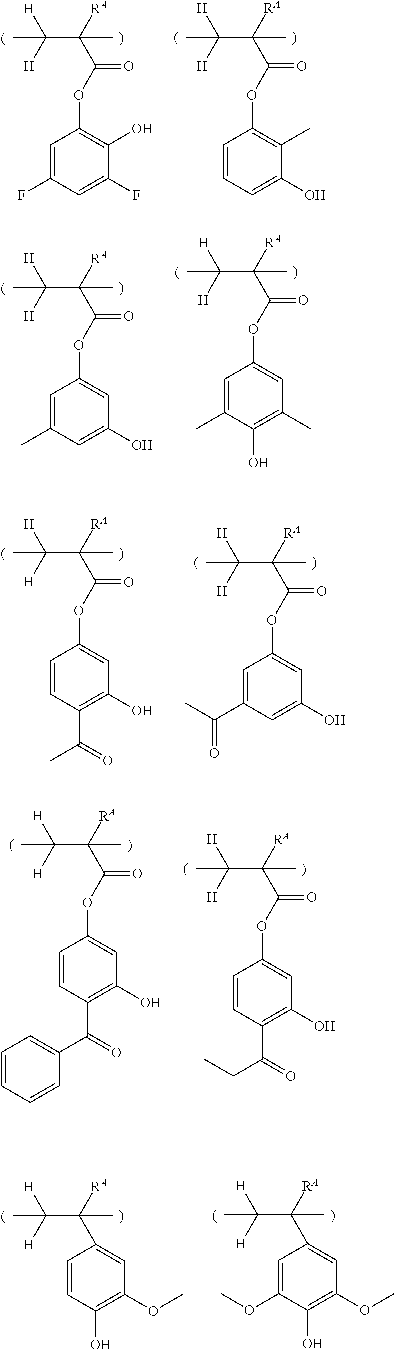

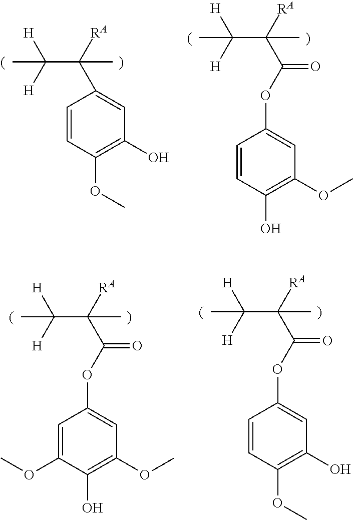

### Repeat Units Adapted to Generate Acid Upon Exposure

Polymer P also contains repeat units adapted to generate an acid upon light exposure, which are referred to as repeat units C, hereinafter. Suitable repeat units C are repeat units having the formula (C1), repeat units having the formula (C2), repeat units having the formula (C3), and repeat units having the formula (C4), which are referred to as repeat units C1, C2, C3, and C4, respectively.

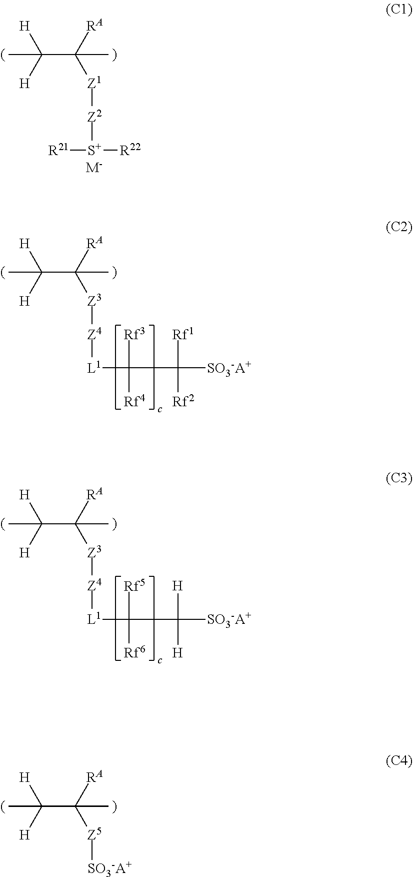

In formulae (C1) to (C4), R^{A} is as defined above. Z¹ is a single bond or phenylene group. Z² is *—C(═O)—O—Z²¹—, *—C(═O)—NH—Z²¹— or *—O—Z²¹—, wherein Z²¹ is a C₁-C₆ aliphatic hydrocarbylene group, phenylene group or divalent group obtained by combining the foregoing, which may contain a carbonyl moiety, ester bond, ether bond or hydroxy moiety. Z³ is a single bond, phenylene group, naphthylene group or *—C(═O)—O—Z³¹—, wherein Z³¹ is a C₁-C₁₀ aliphatic hydrocarbylene group which may contain a hydroxy moiety, ether bond, ester bond or lactone ring, or a phenylene or naphthylene group. Z⁴ is a single bond or *—Z⁴¹—C(═O)—O—, wherein Z¹⁴ is a C₁-C₂₀ hydrocarbylene group which may contain a heteroatom. Z⁵ is a single bond, methylene, ethylene, phenylene, fluorinated phenylene, trifluoromethyl-substituted phenylene, *—C(═O)—O—Z⁵¹—, *—C(═O)—N(H)—Z⁵¹— or *—O—Z⁵¹—, wherein Z⁵¹ is a C₁-C₆ aliphatic hydrocarbylene group, phenylene, fluorinated phenylene or trifluoromethyl-substituted phenylene group, which may contain a carbonyl moiety, ester bond, ether bond or hydroxy moiety. The asterisk (*) designates a point of attachment to the carbon atom in the backbone.

The aliphatic hydrocarbylene groups Z²¹, Z³¹ and Z⁵¹ may be straight, branched or cyclic. Examples thereof are as exemplified above for Z^{A1} in formula (A1).

The hydrocarbylene group Z⁴¹ may be saturated or unsaturated and straight, branched or cyclic. Examples thereof are shown below, but not limited thereto.

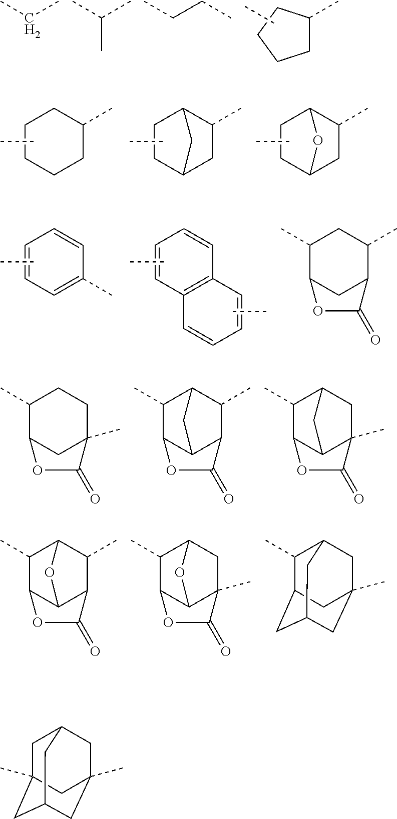

In formula (C1), R²¹ and R²² are each independently a C₁-C₂₀ hydrocarbyl group which may contain a heteroatom. The hydrocarbyl group may be saturated or unsaturated and straight, branched or cyclic. Examples thereof include C₁-C₂₀ alkyl groups such as methyl, ethyl, n-propyl, isopropyl, n-butyl, and tert-butyl; C₃-C₂ cyclic saturated hydrocarbyl groups such as cyclopropyl, cyclopentyl, cyclohexyl, cyclopropylmethyl, 4-methylcyclohexyl, cyclohexylmethyl, norbornyl, and adamantyl; C₂-C₂₀ alkenyl groups such as vinyl, ally, propenyl, butenyl and hexenyl; C₃-C₂₀ cyclic unsaturated hydrocarbyl groups such as cyclohexenyl; C₆-C₂₀ awl groups such as phenyl, naphthyl, and thienyl; aralkyl groups such as benzyl, 1-phenylethyl and 2-phenylethyl; and combinations thereof. Inter alia, aryl groups are preferred. In the hydrocarbyl group, some or all of the hydrogen atoms may be substituted by a moiety containing a heteroatom such as oxygen, sulfur, nitrogen or halogen, or some constituent —CH₂— may be replaced by a moiety containing a heteroatom such as oxygen, sulfur or nitrogen, so that the group may contain hydroxy, fluorine, chlorine, bromine, iodine, cyano, carbonyl, ether bond, ester bond, sulfonic ester bond, carbonate bond, lactone ring, sultone ring, carboxylic anhydride (—C(═O)—O—C(═O)—) or haloalkyl moiety.

R²¹ and R²² may bond together to form a ring with the sulfur atom to which they are attached. Examples of the ring are shown below, but not limited thereto. Herein, the broken line designates a point of attachment to Z².

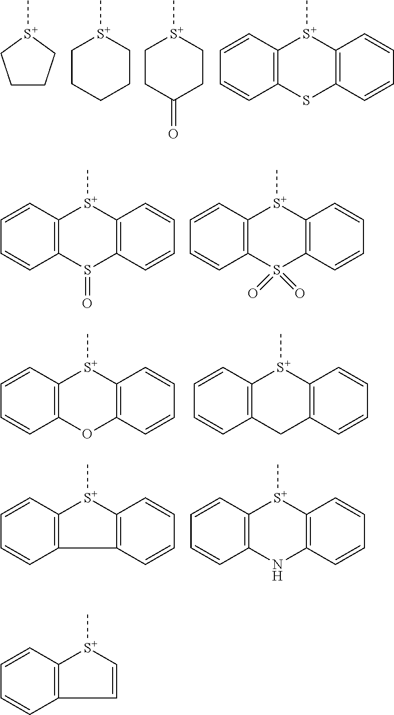

Examples of the cation in the repeat unit having formula (C1) are shown below, but not limited thereto. Herein, R^{A} is as defined above.

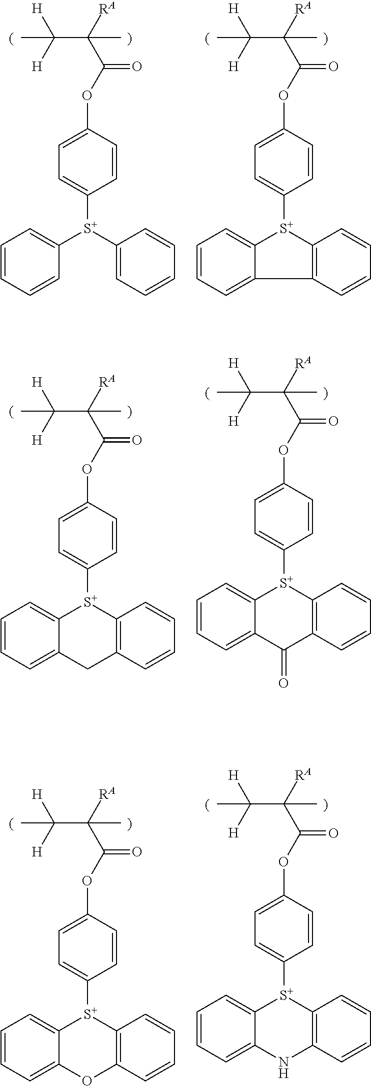

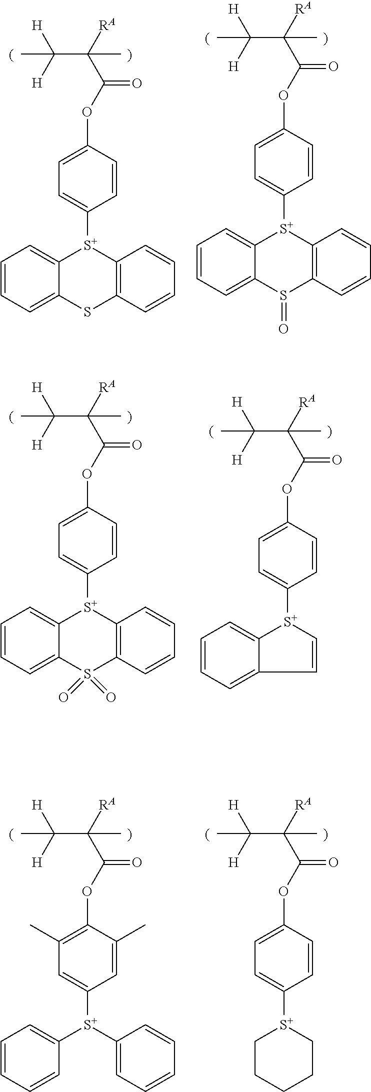

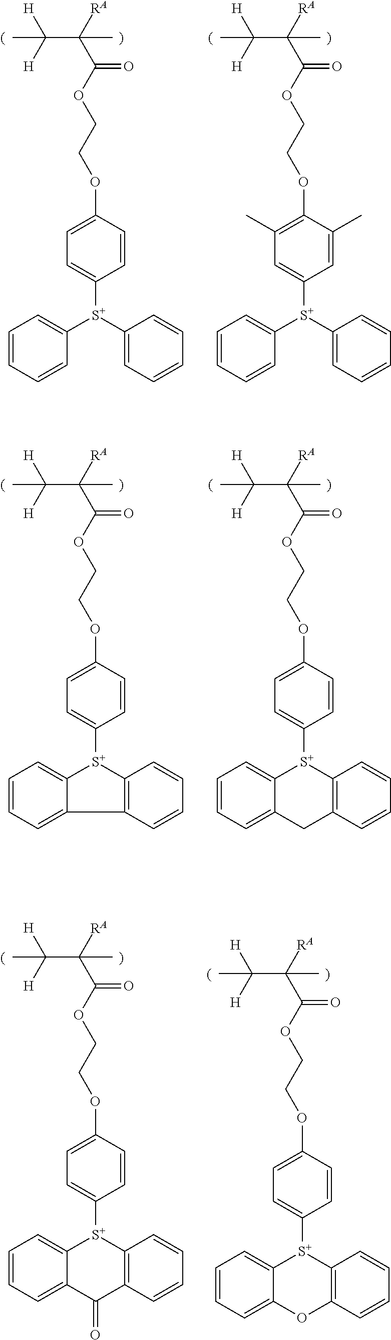

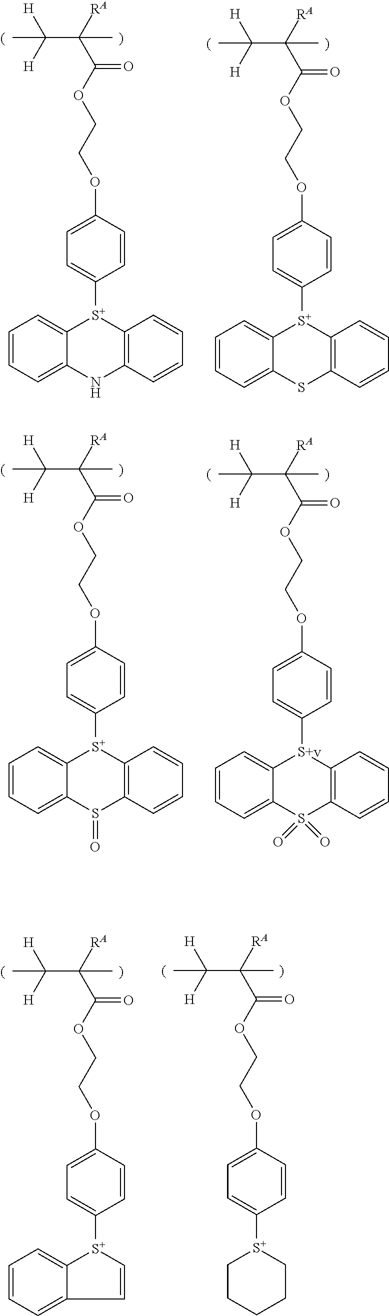

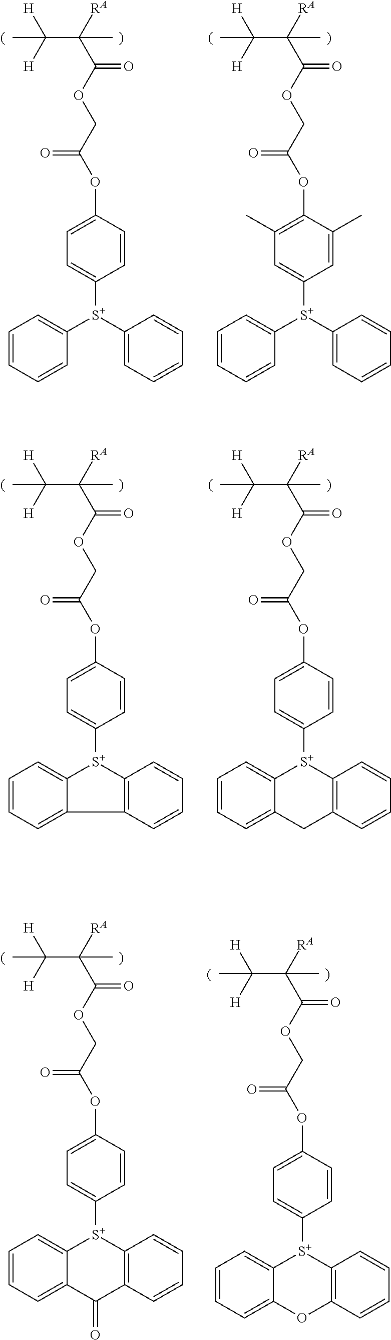

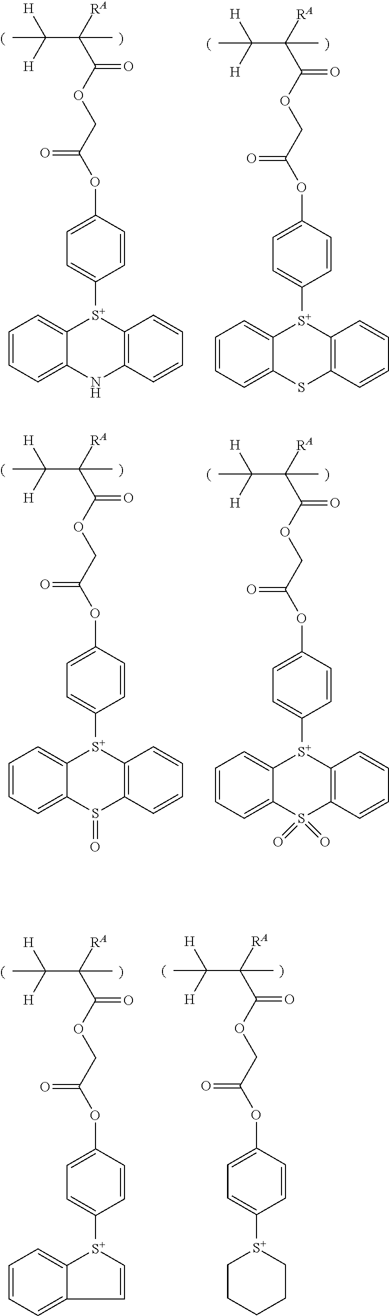

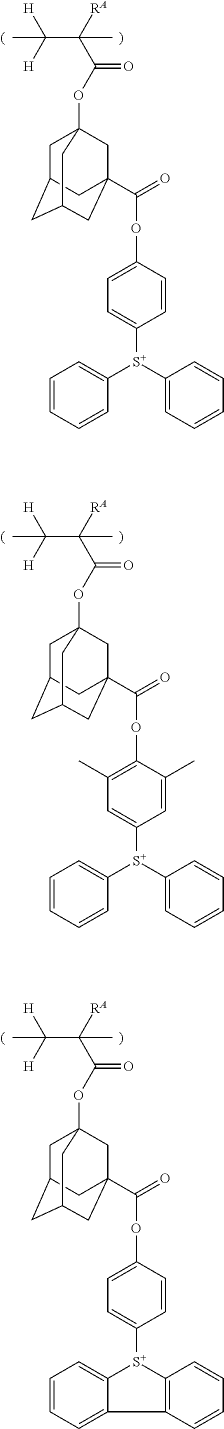

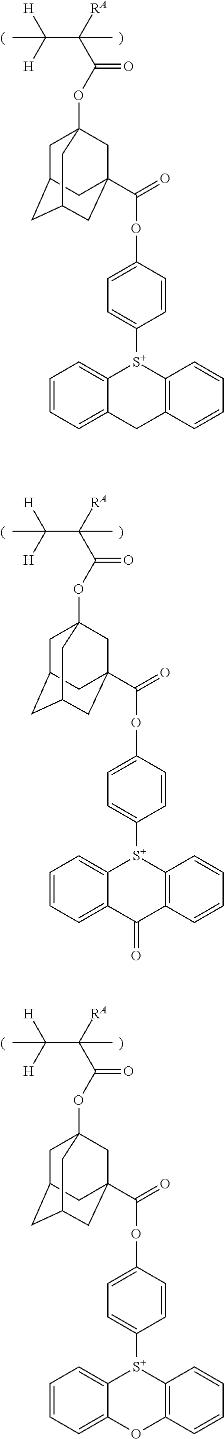

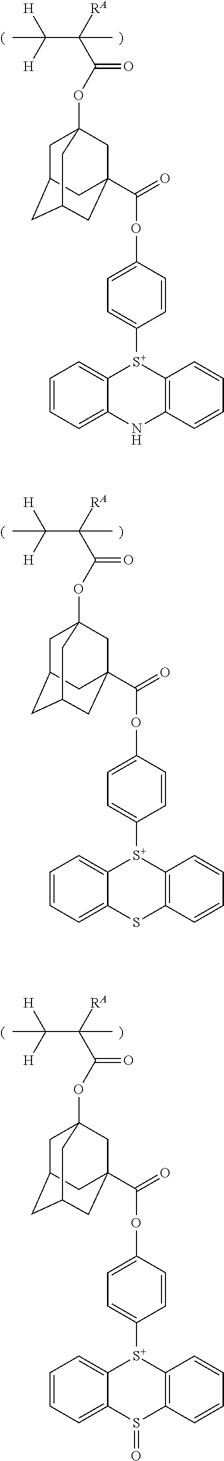

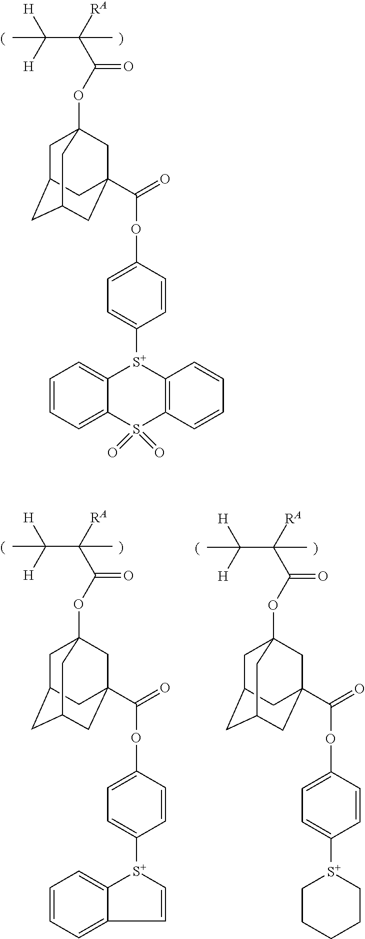

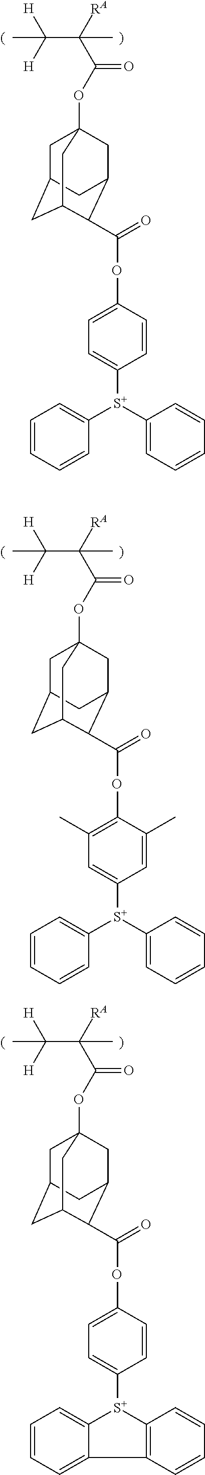

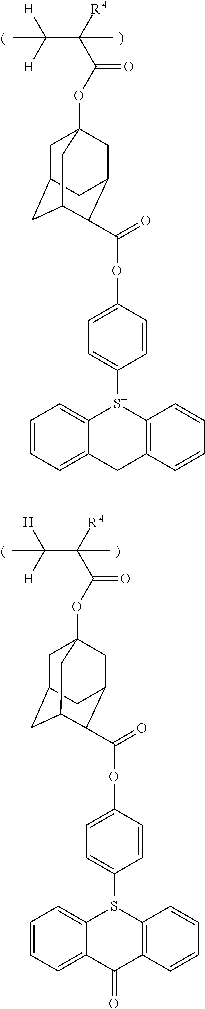

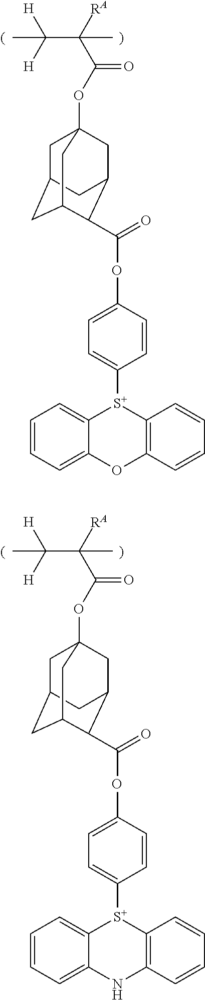

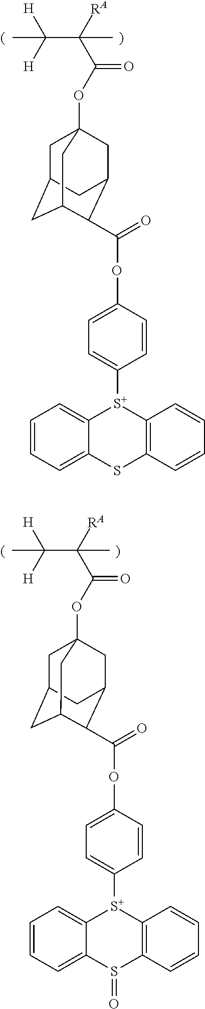

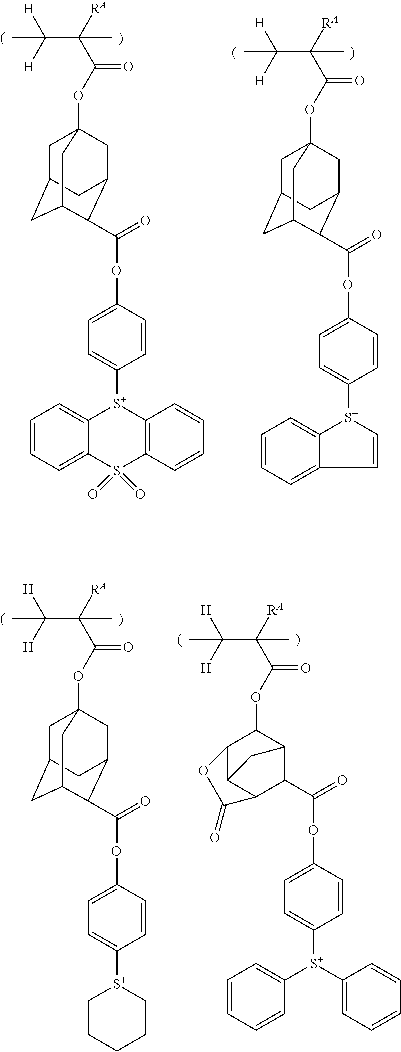

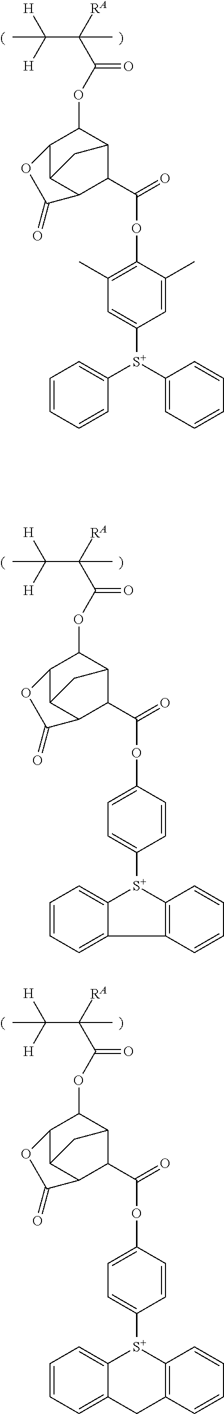

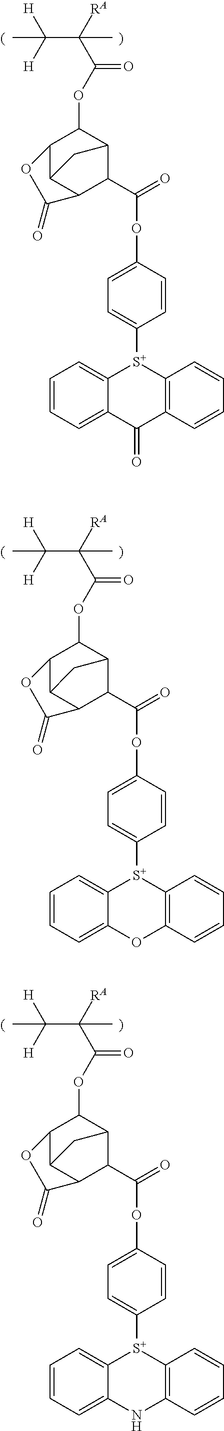

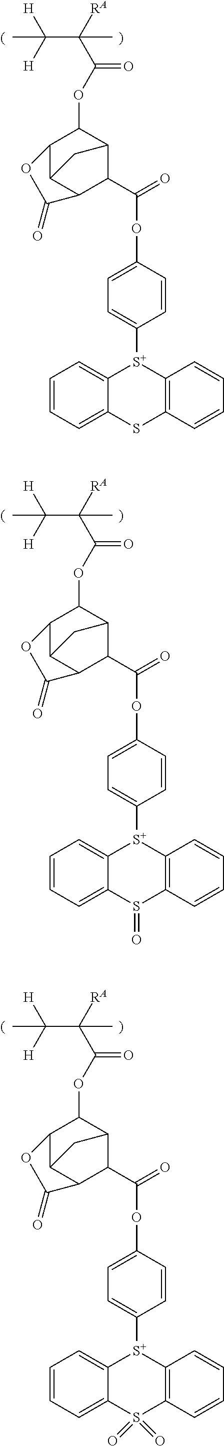

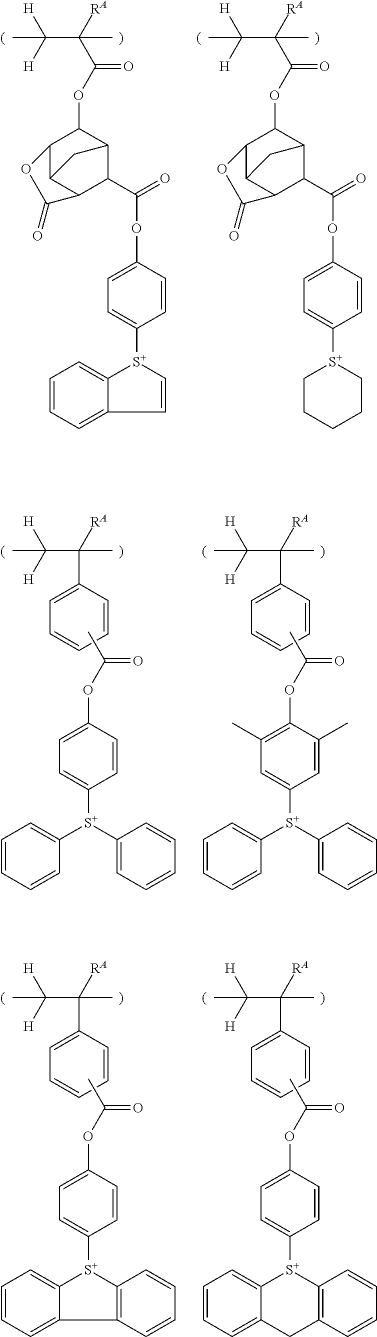

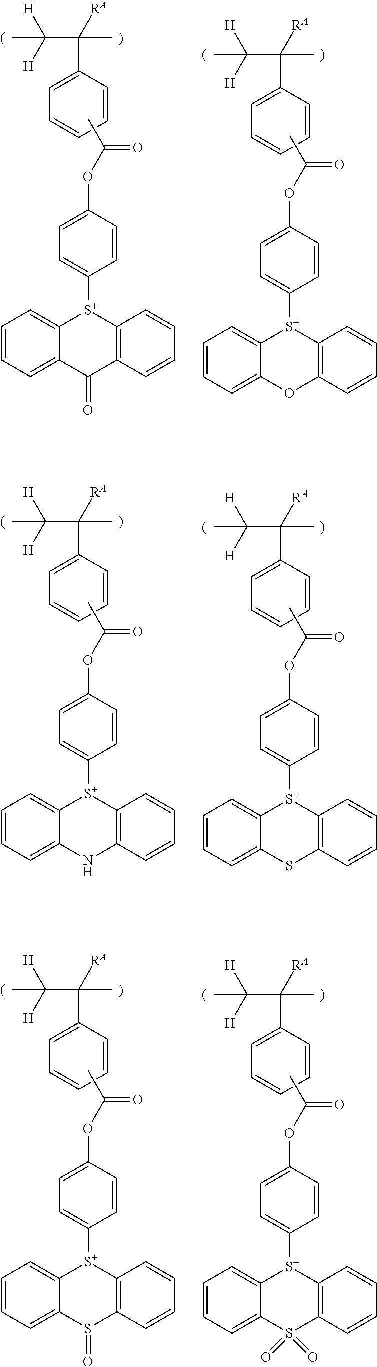

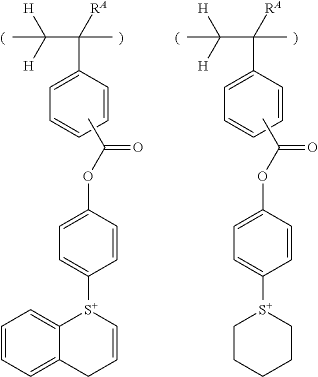

In formula (C1), M⁻ is a non-nucleophilic counter ion. Examples of the non-nucleophilic counter ion include halide ions such as chloride and bromide ions; fluoroalkylsulfonate ions such as triflate, 1,1,1-trifluoroethanesulfonate, and nonafluorobutanesulfonate; arylsulfonate ions such as tosylate, benzenesulfonate, 4-fluorobenzenesulfonate, and 1,2,3,4,5-pentafluorobenzenesulfonate; alkylsulfonate ions such as mesylate and butanesulfonate; imide ions such as bis(trifluoromethylsulfonyl)imide, bis(perfluoroethylsulfonyl)imide and bis(perfluorobutylsulfonyl)imide; methide ions such as tris(trifluoromethylsulfonyl)methide and tris(perfluoroethylsulfonyl)methide.

Also included are sulfonate anions having fluorine substituted at α-position as represented by the formula (C1-1) and sulfonate anions having fluorine substituted at α-position and trifluoromethyl at β-position as represented by the formula (C1-2).

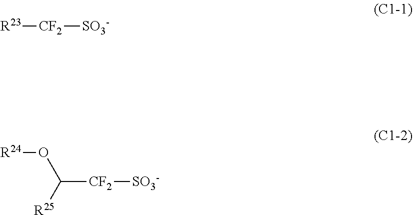

In formula (C1-1), R²³ is hydrogen or a C₁-C₃₀ hydrocarbyl group, C₂-C₃₀ hydrocarbylcarbonyloxy group, or C₂-C₃₀ hydrocarbyloxycarbonyl group, which may contain a halogen atom, ether bond, ester bond, carbonyl moiety, or lactone ring. The hydrocarbyl group and hydrocarbyl moiety of the hydrocarbylcarbonyloxy and hydrocarbyloxycarbonyl groups may be saturated or unsaturated and straight, branched or cyclic, and examples thereof are as will be exemplified later for the hydrocarbyl group R¹⁰⁵ in formula (3A′).

In formula (C1-2), R²⁴ is hydrogen, or a C₁-C₃₀ hydrocarbyl group or C₂-C₃₀ hydrocarbylcarbonyl group, which may contain a halogen atom, ether bond, ester bond, carbonyl moiety or lactone ring. R²⁵ is hydrogen, fluorine, or a C₁-C₆ fluorinated alkyl group. The hydrocarbyl group and hydrocarbyl moiety of the hydrocarbylcarbonyl group may be saturated or unsaturated and straight, branched or cyclic, and examples thereof are as will be exemplified later for the hydrocarbyl group R¹⁰⁵ in formula (3A′). Preferably, R²⁵ is trifluoromethyl.

Examples of the sulfonate anion having formula (C1-1) or (C1-2) are shown below, but not limited thereto. Herein R²⁵ is as defined above.

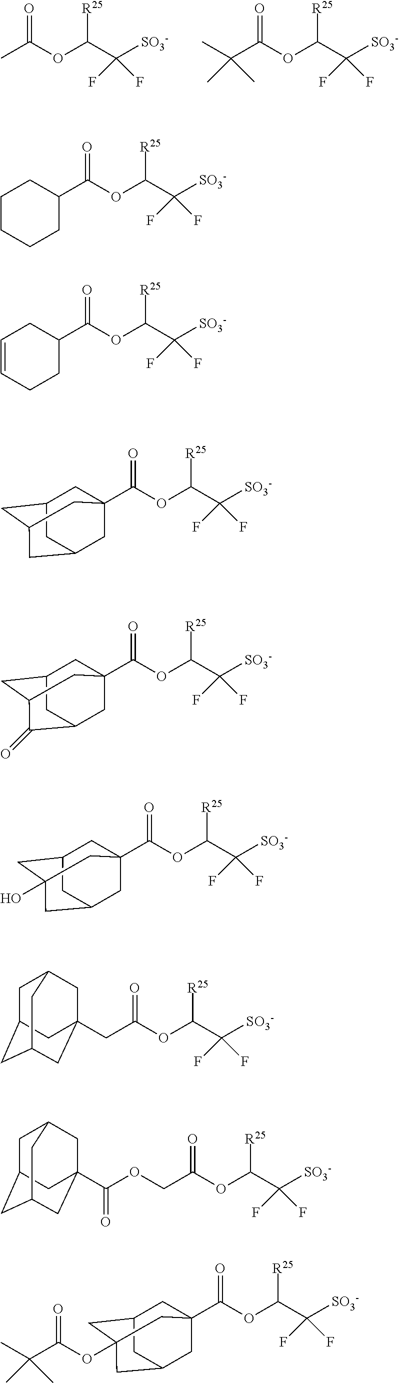

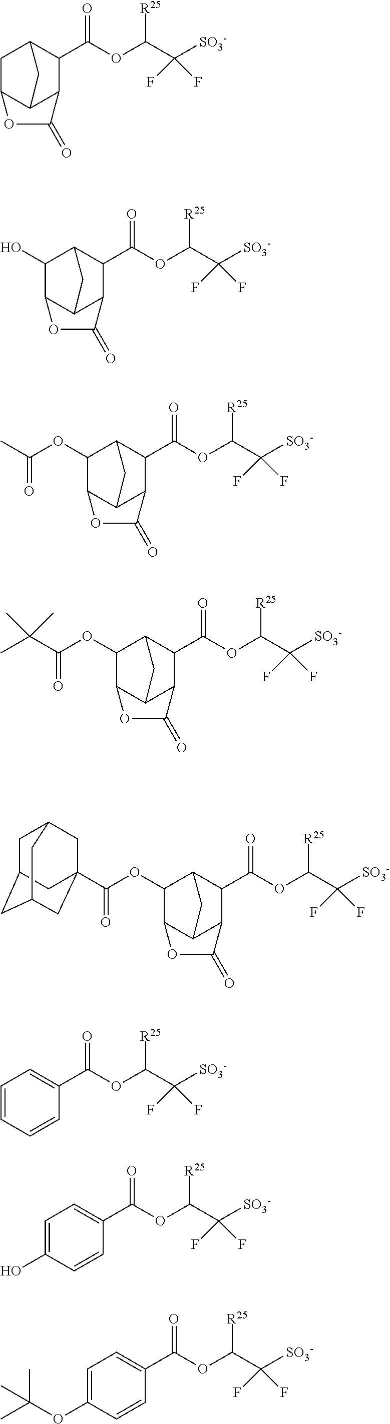

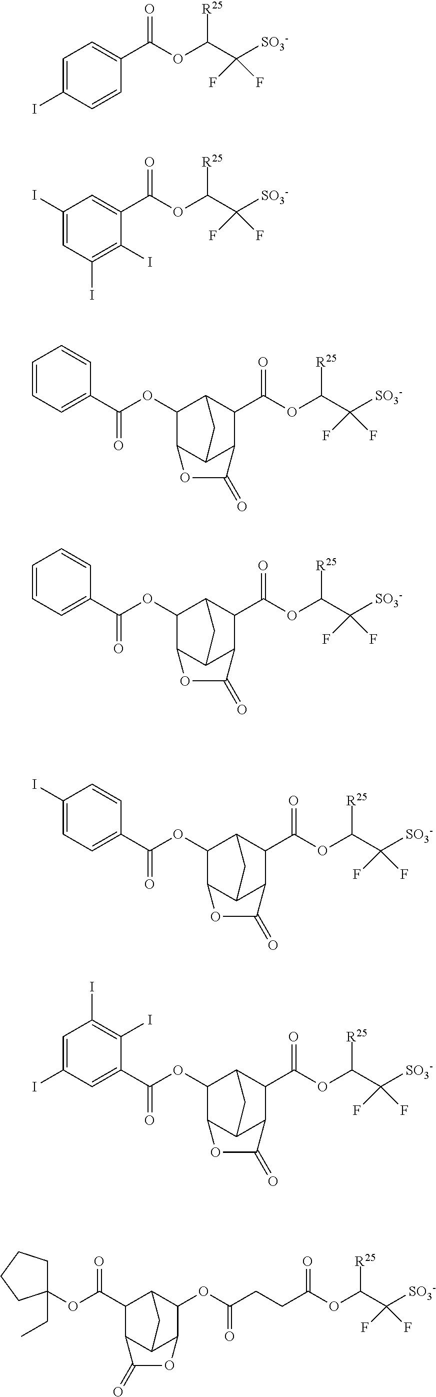

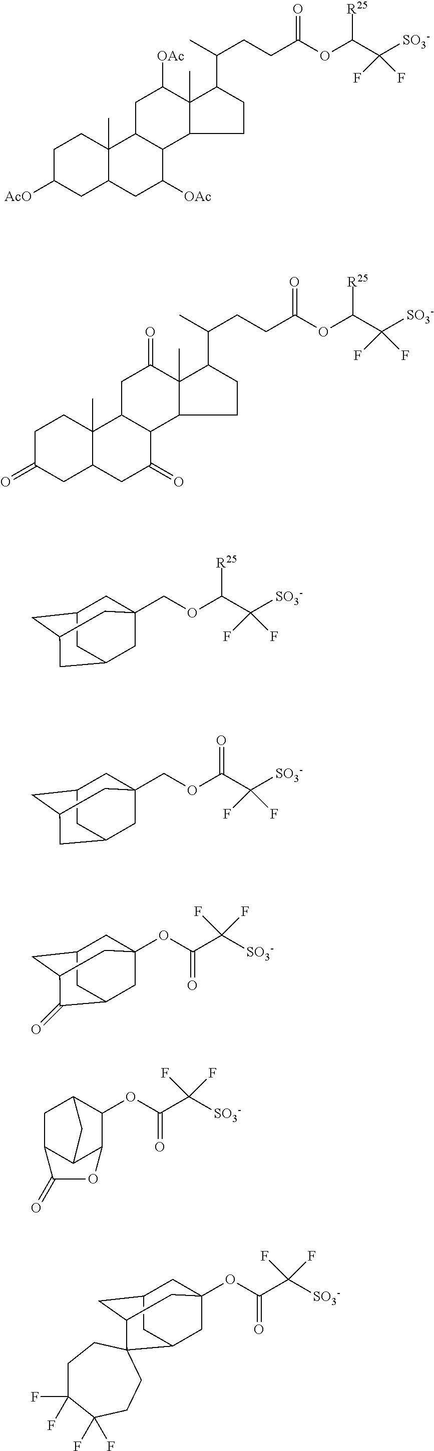

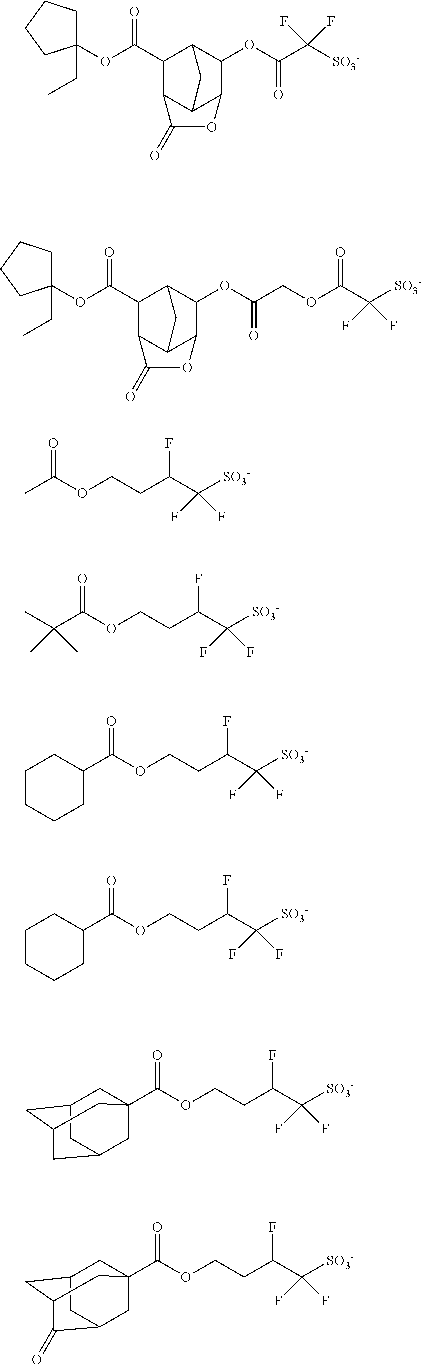

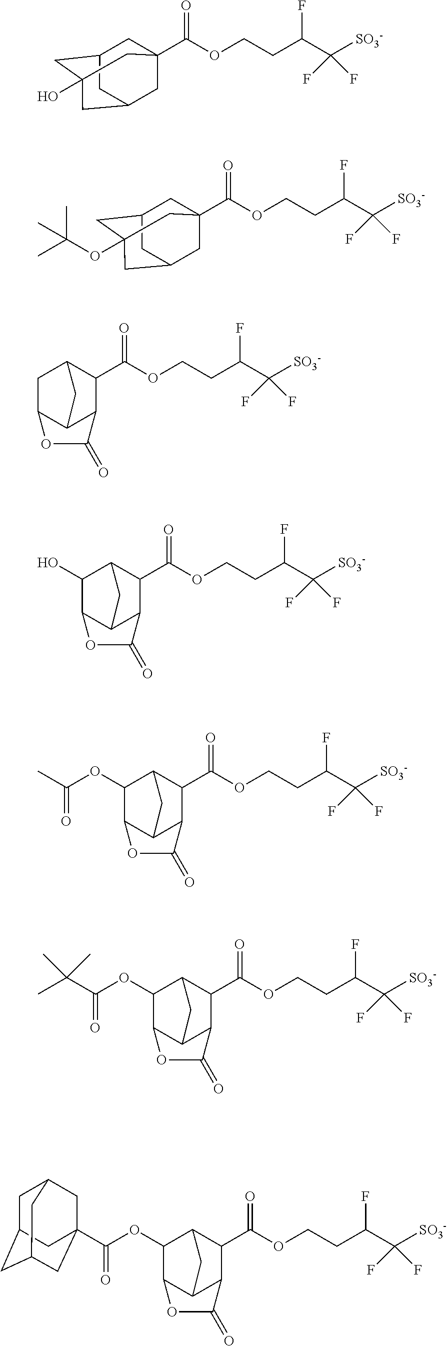

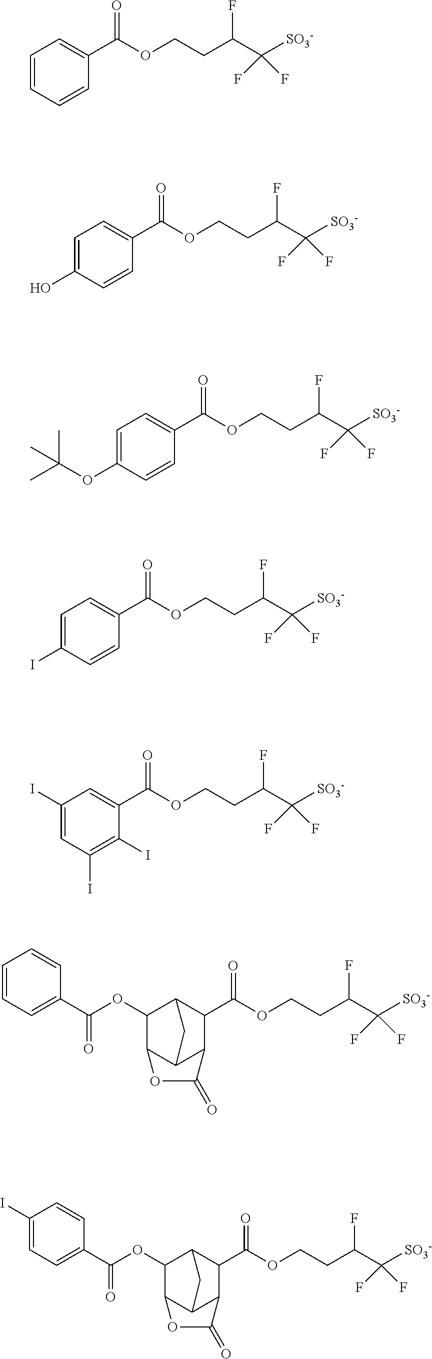

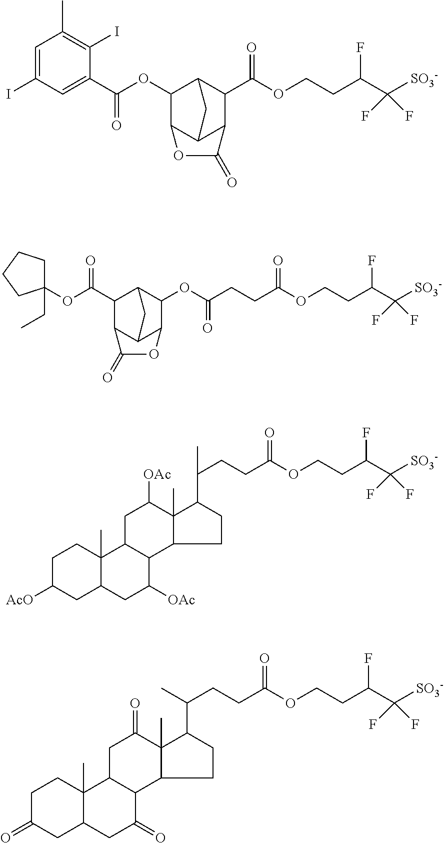

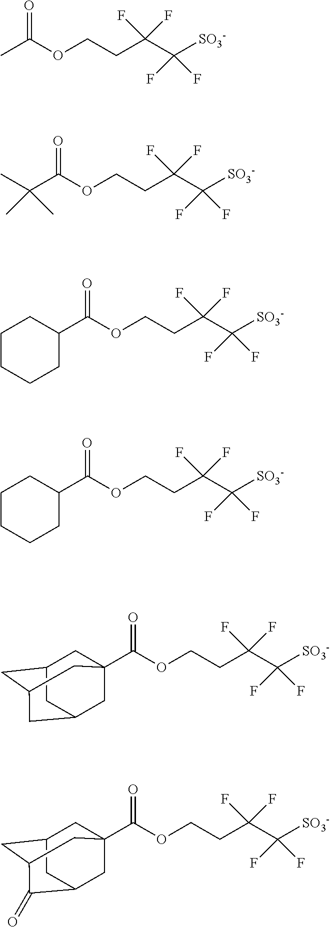

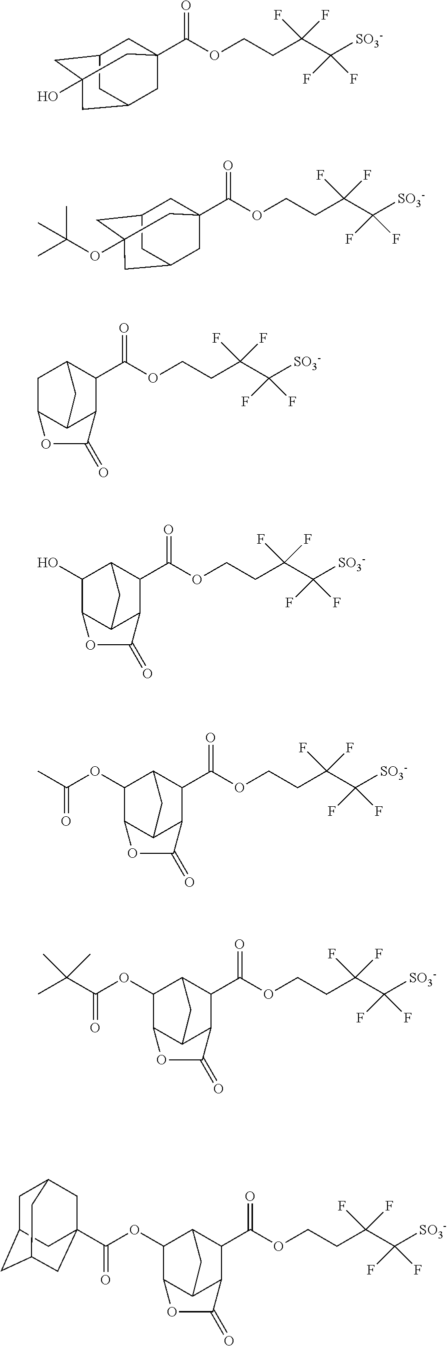

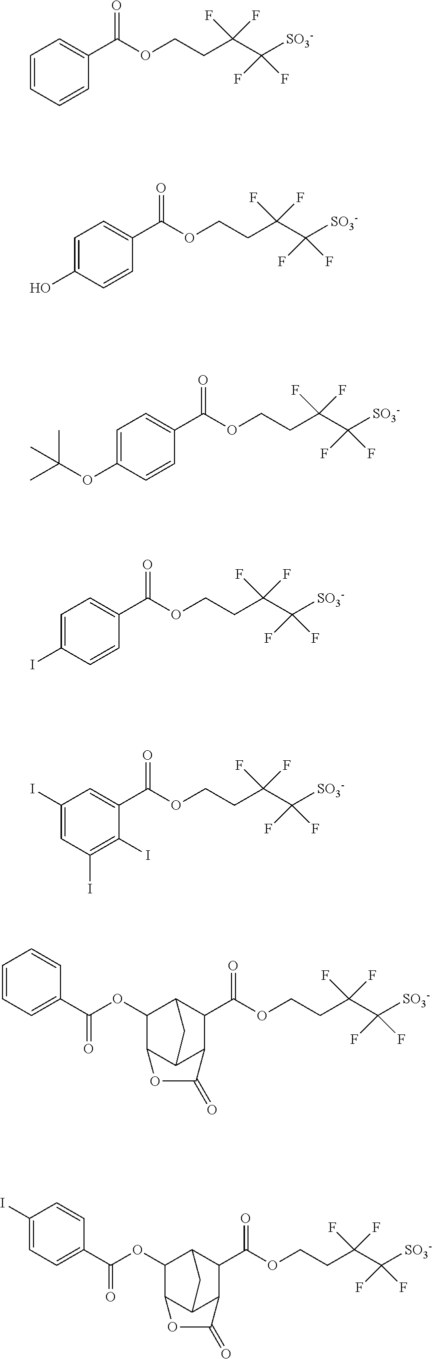

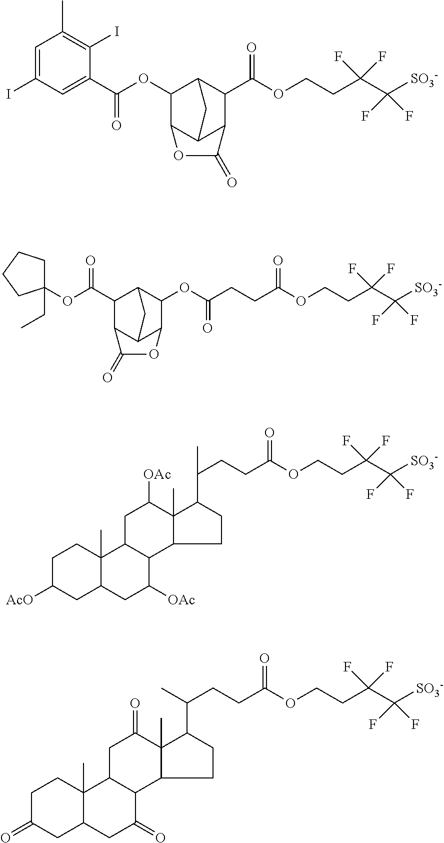

In formulae (C2) and (C3), L¹ is a single bond, ether bond, ester bond, carbonyl group, sulfonic ester bond, carbonate bond or carbamate bond From the aspect of synthesis, L¹ is preferably an ether bond, ester bond or carbonyl group, more preferably ester bond or carbonyl group.

In formula (C2), Rf¹ and Rf² are each independently fluorine or a C₁-C₆ fluorinated alkyl group. It is preferred for enhancing the strength of the generated acid that both Rf¹ and Rf² be fluorine. Rf³ and Rf⁴ are each independently hydrogen, fluorine or a C₁-C₆ fluorinated alkyl group. It is preferred for enhancing the solvent solubility that at least one of Rf³ and Rf⁴ be trifluoromethyl.

In formula (C3), Rf⁵ and Rf⁶ are each independently hydrogen, fluorine or a C₁-C₆ fluorinated alkyl group. Not all Rf⁵ and Rf⁶ are hydrogen at the same time. It is preferred for enhancing the solvent solubility that at least one of Rf⁵ and Rf⁶ be trifluoromethyl.

In formulae (C2) and (C3), c is an integer of 0 to 3, preferably 1.

Examples of the anion in the repeat unit having formula (C2) are shown below, but not limited thereto. Herein R^{A} is as defined above.

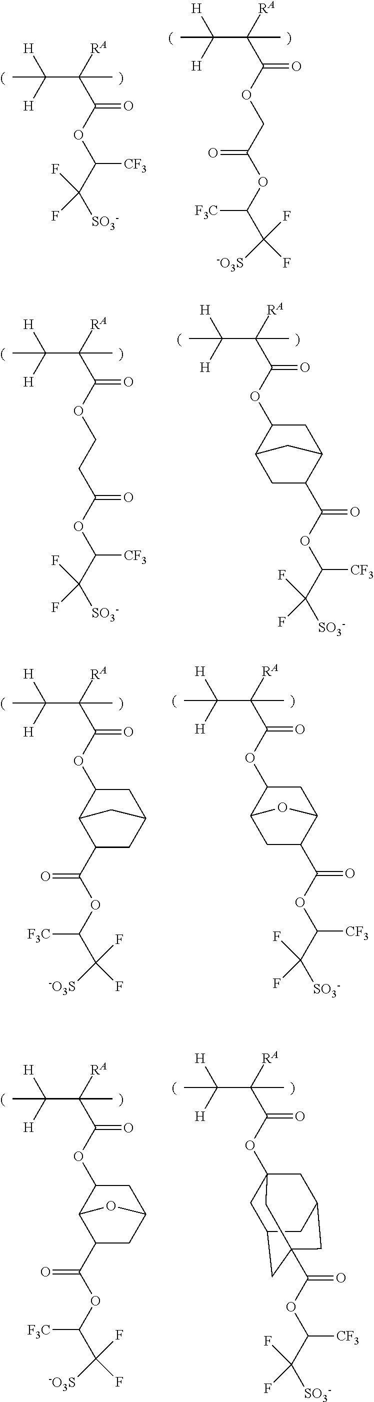

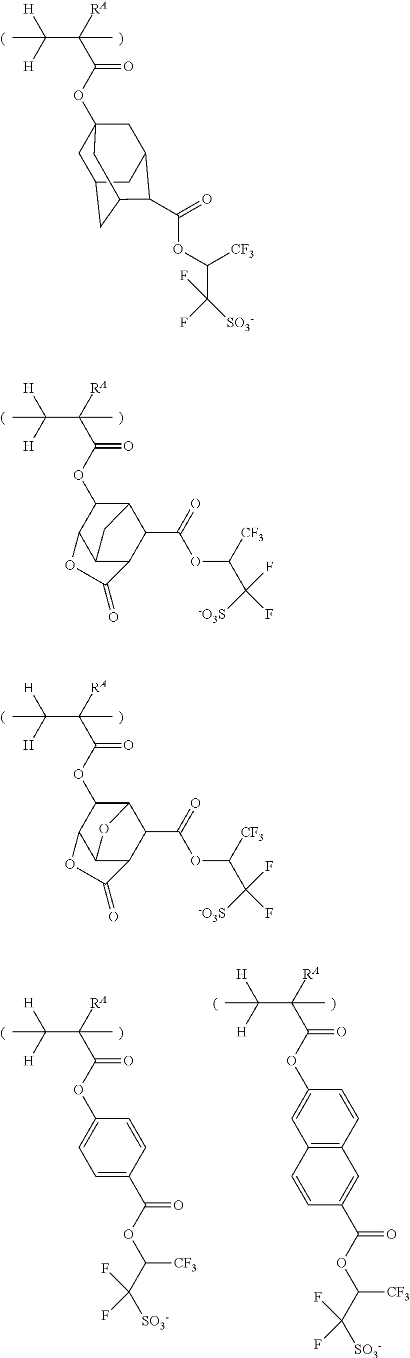

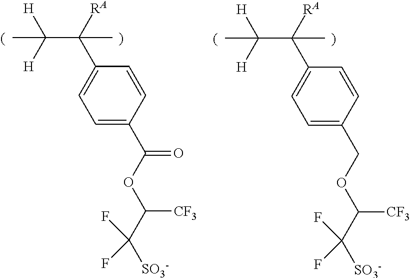

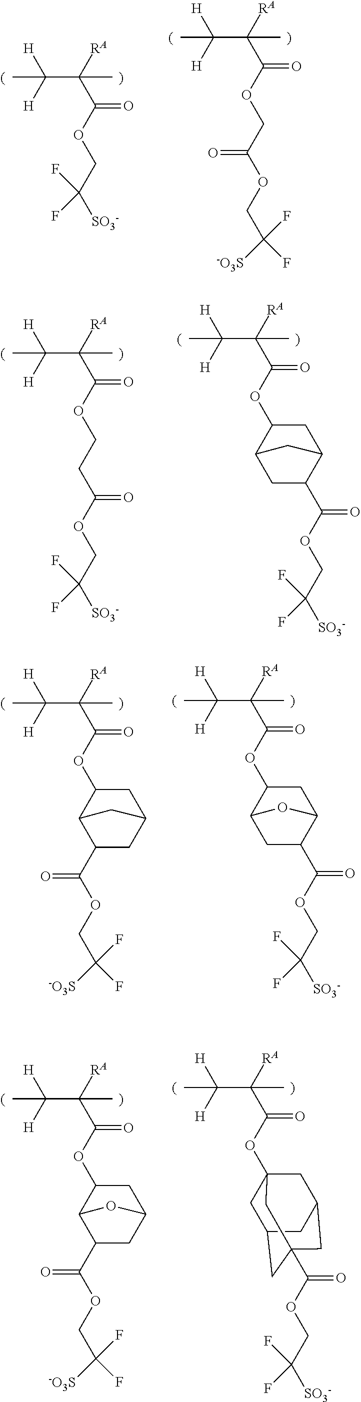

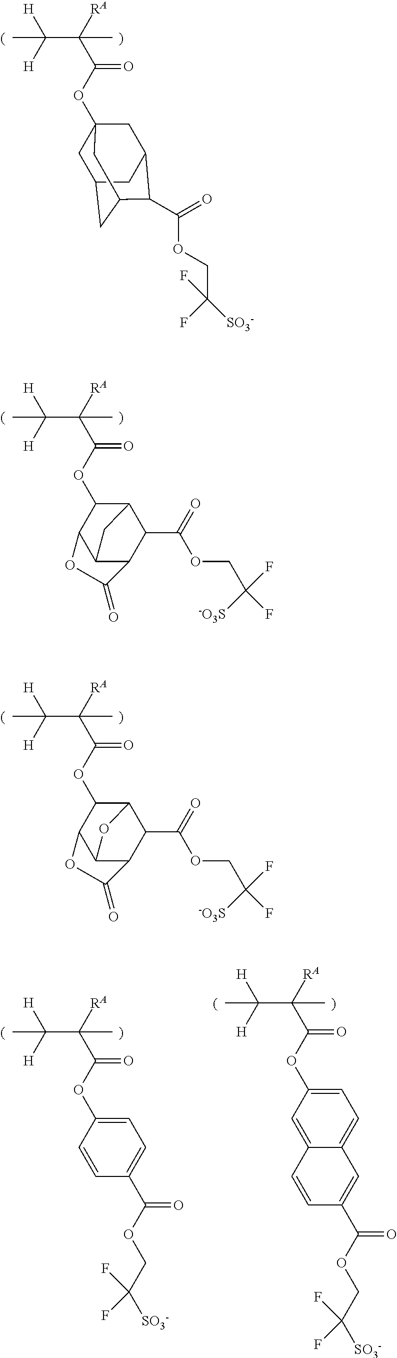

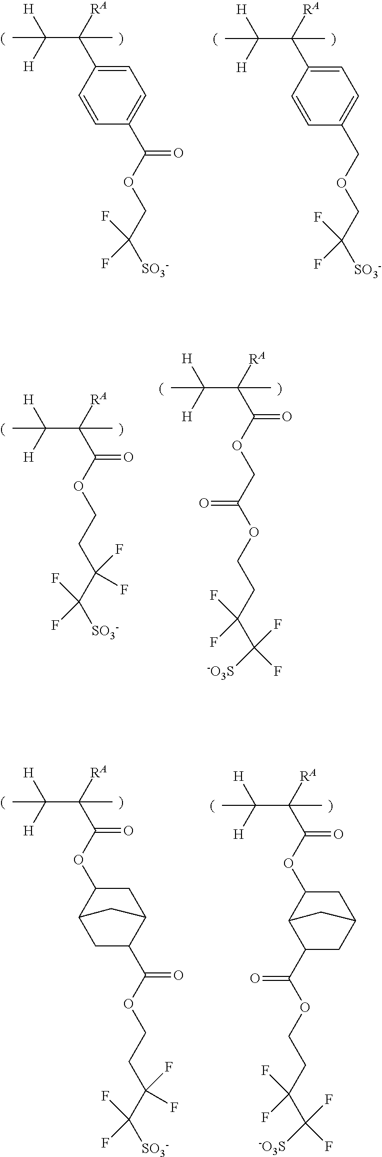

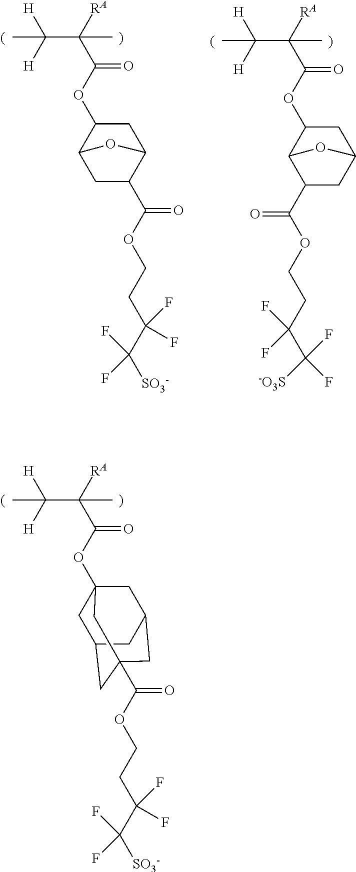

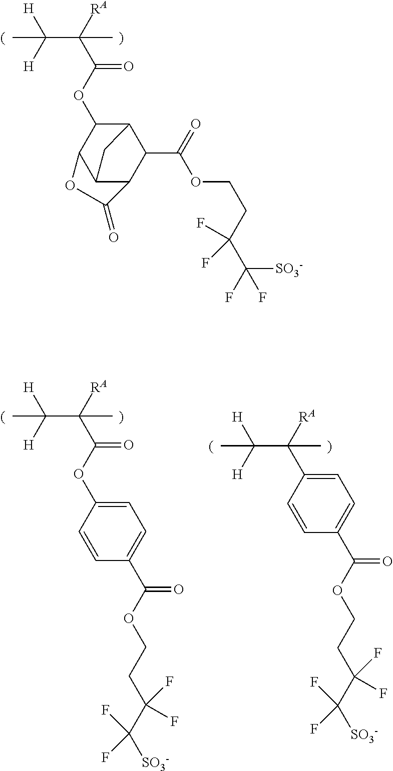

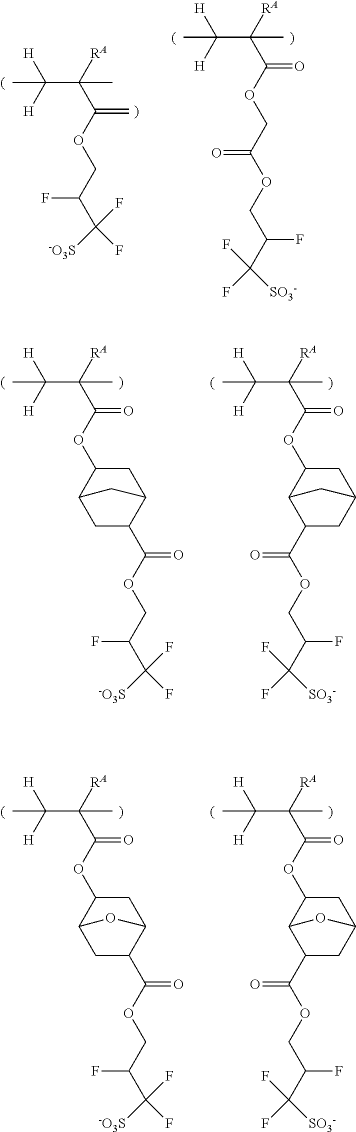

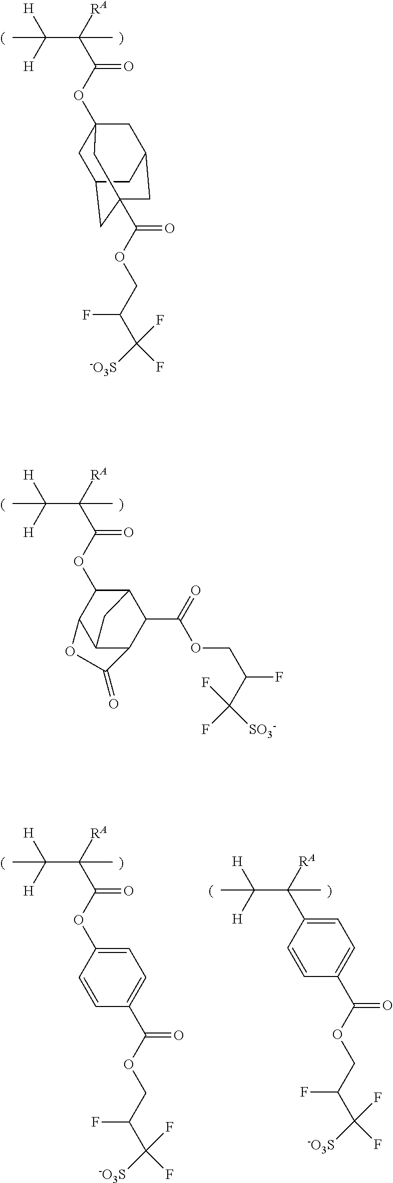

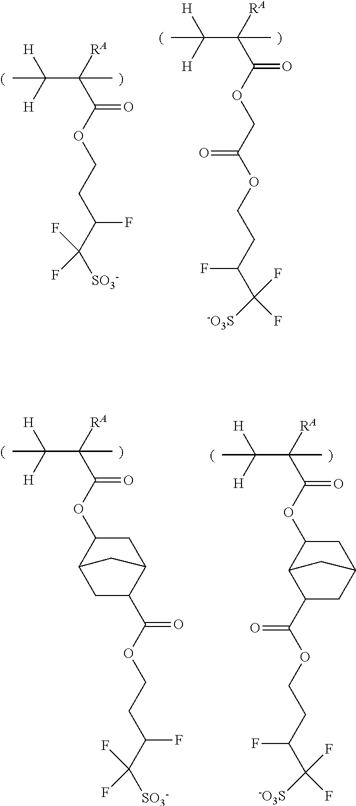

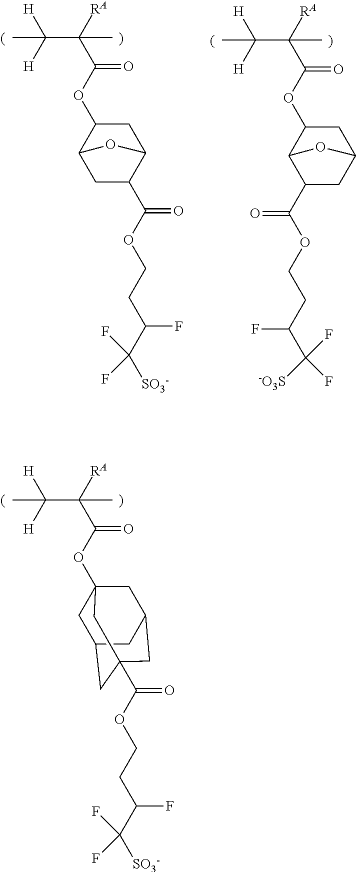

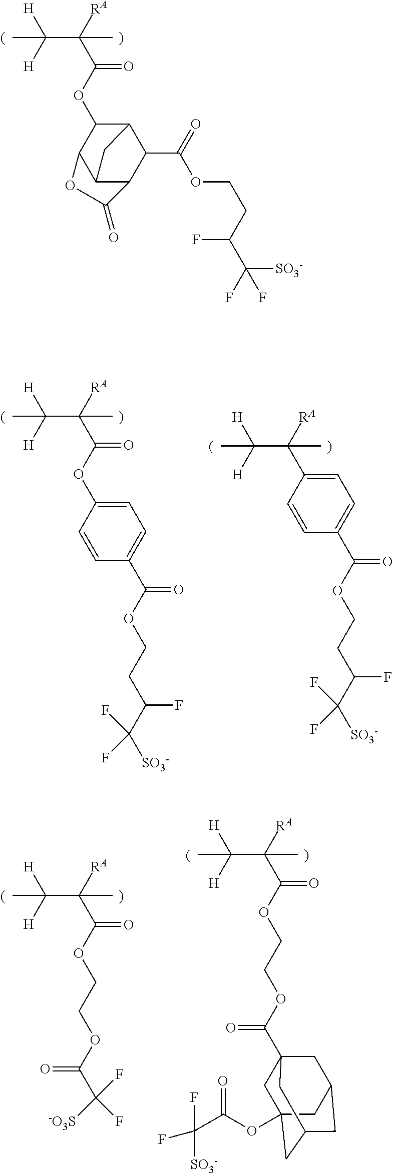

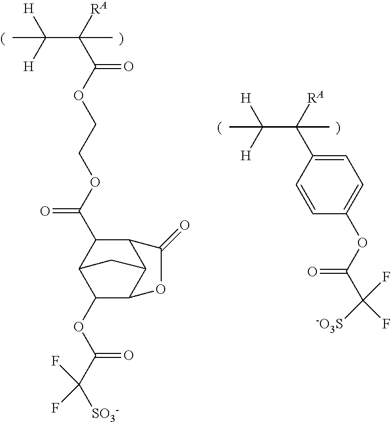

Examples of the anion in the repeat unit having formula (C3) are shown below, but not limited thereto. Herein R^{A} is as defined above.

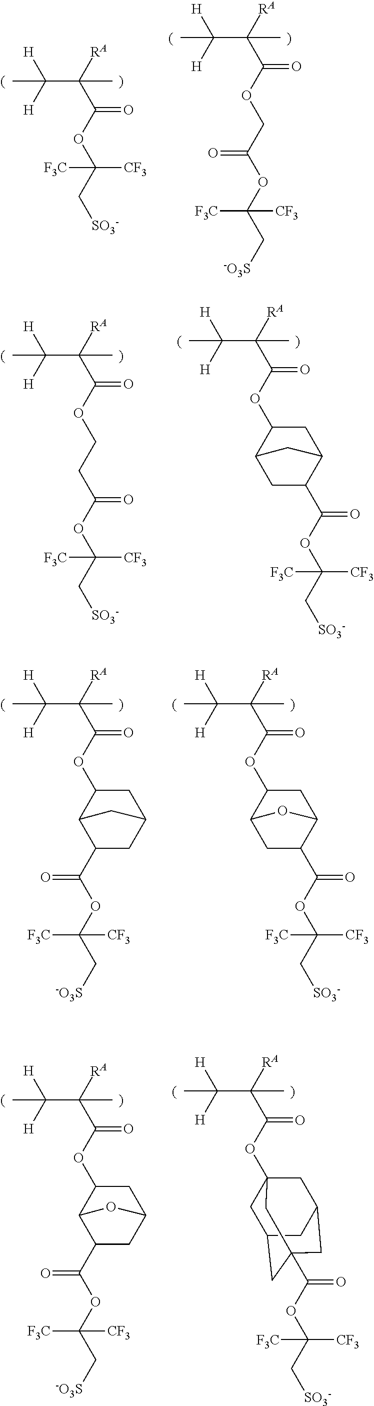

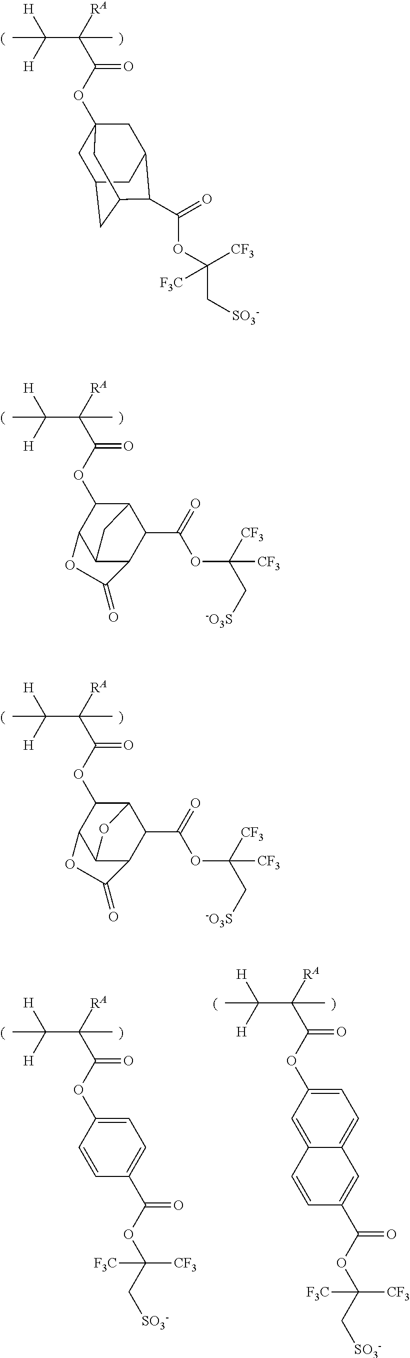

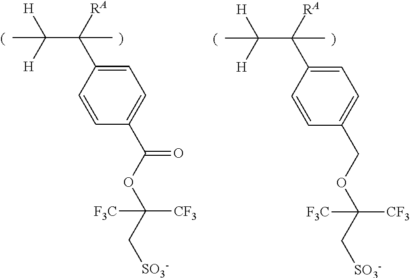

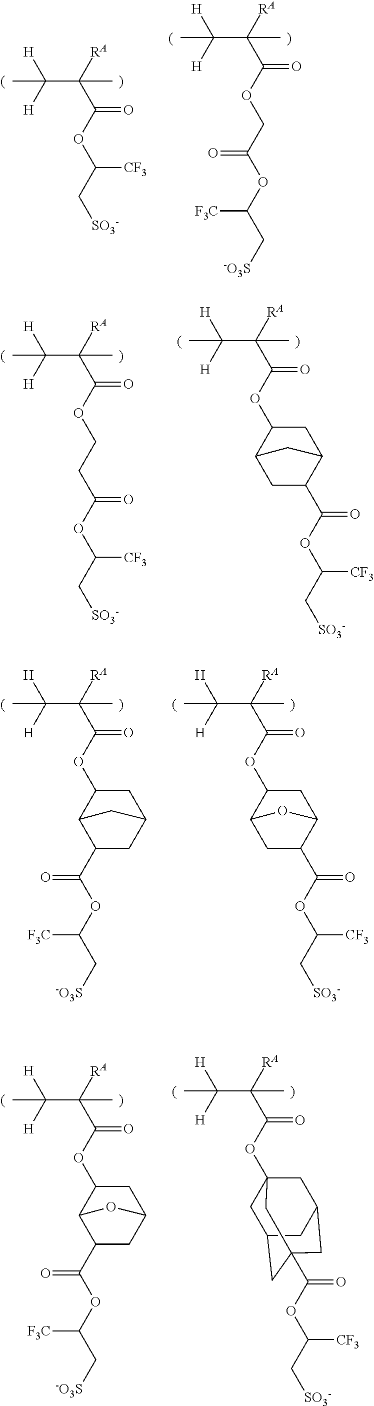

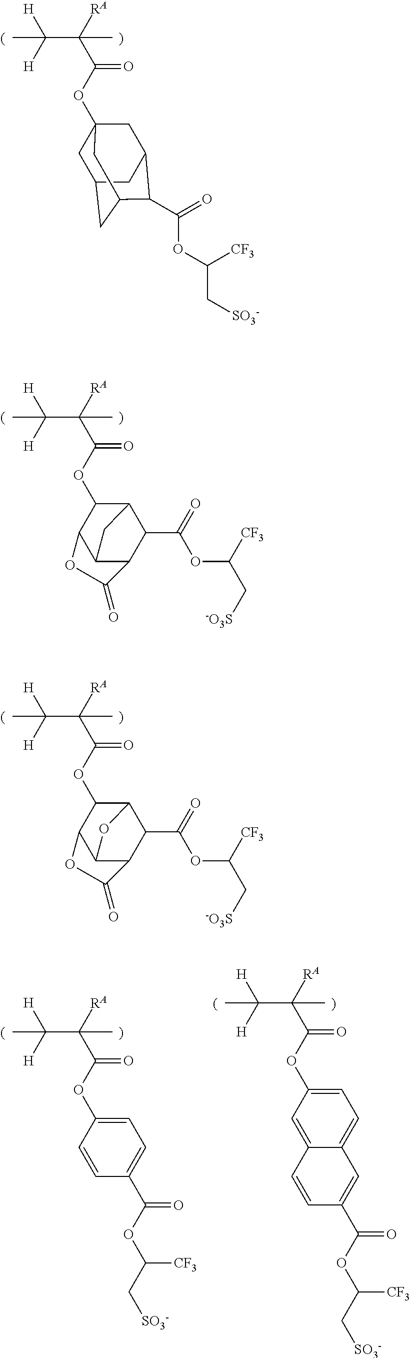

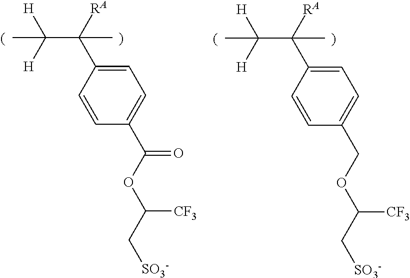

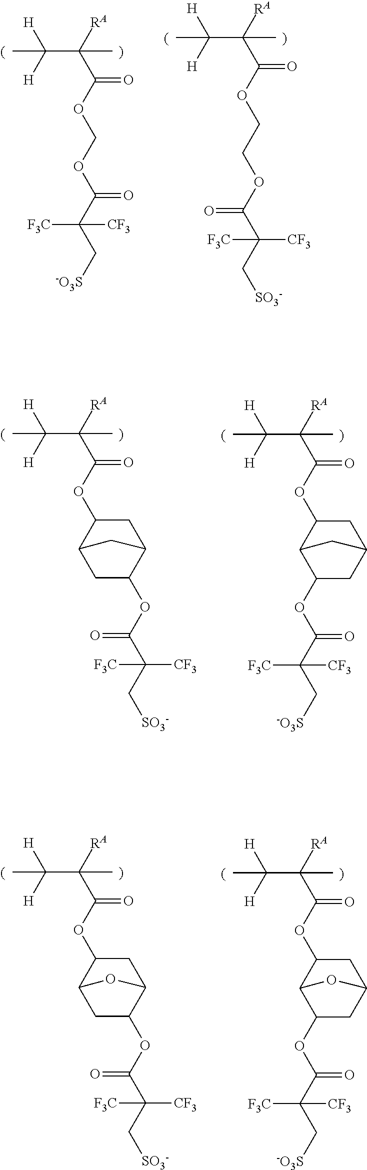

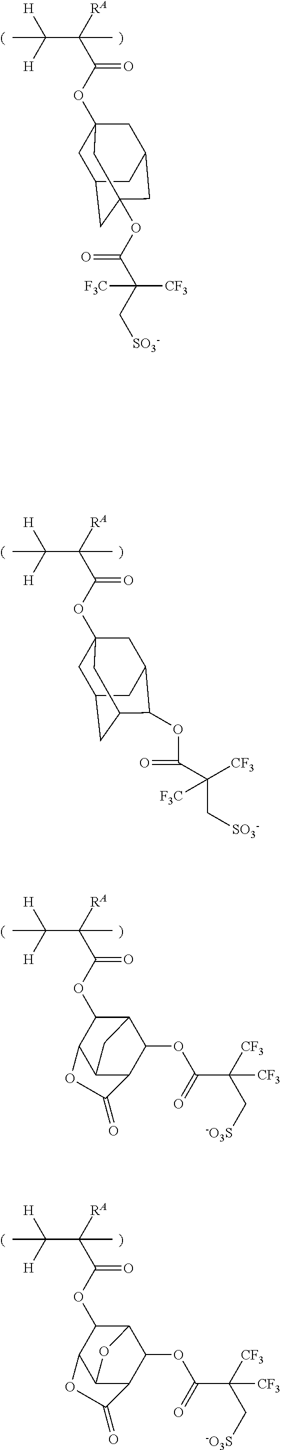

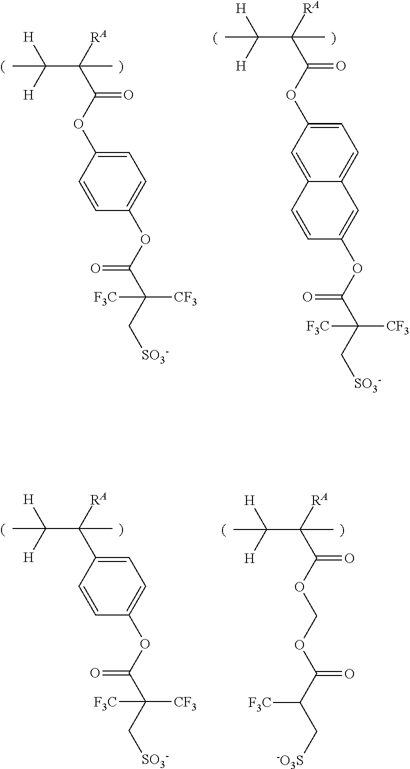

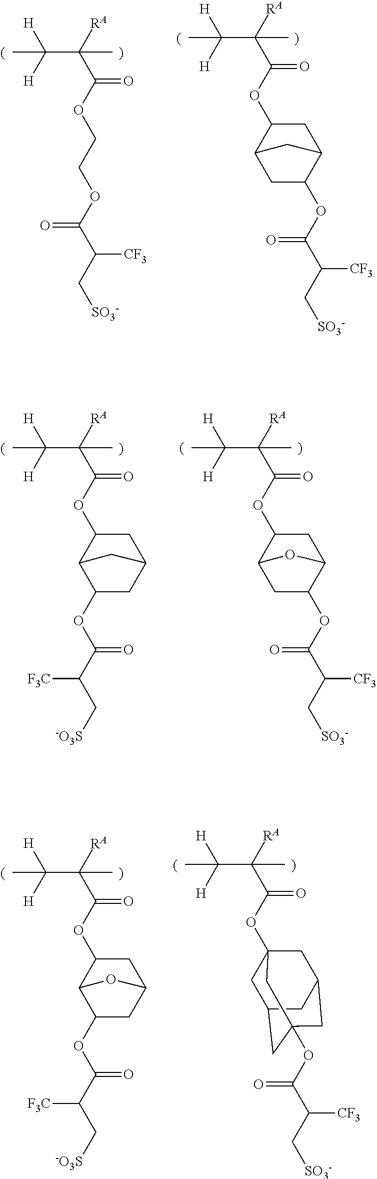

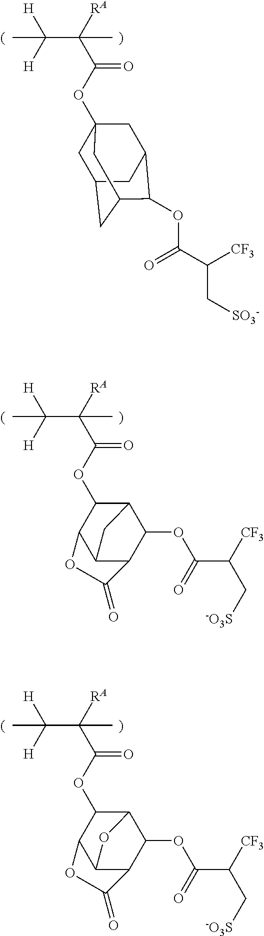

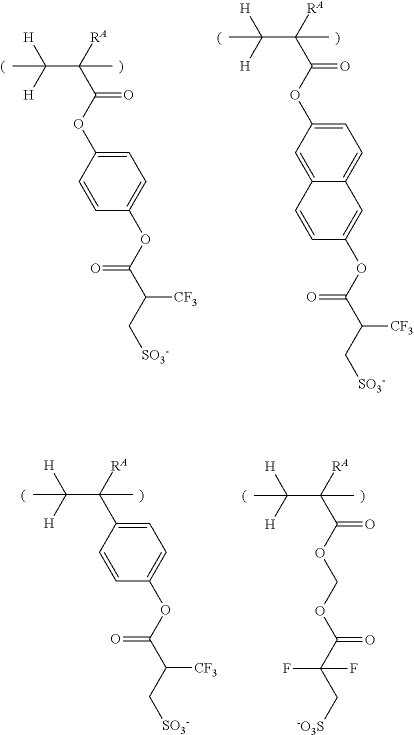

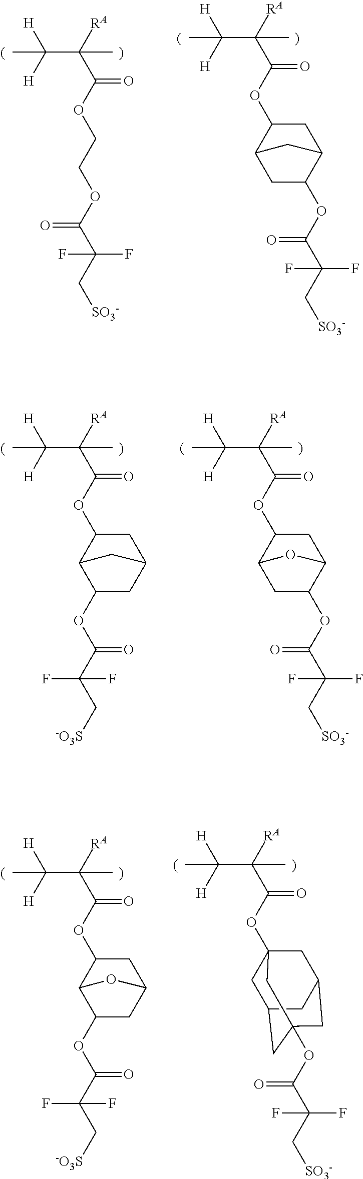

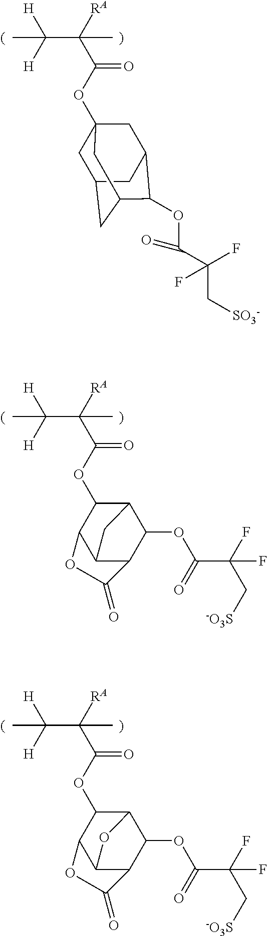

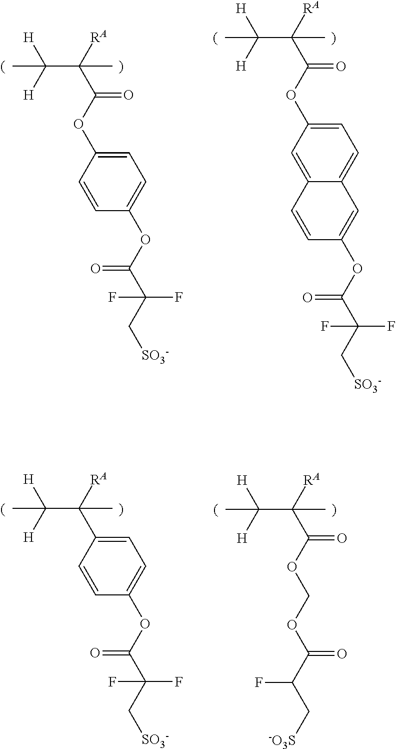

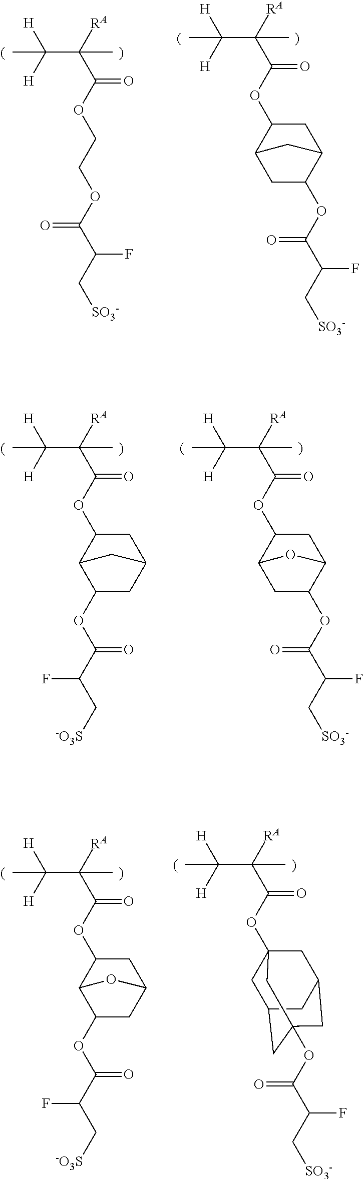

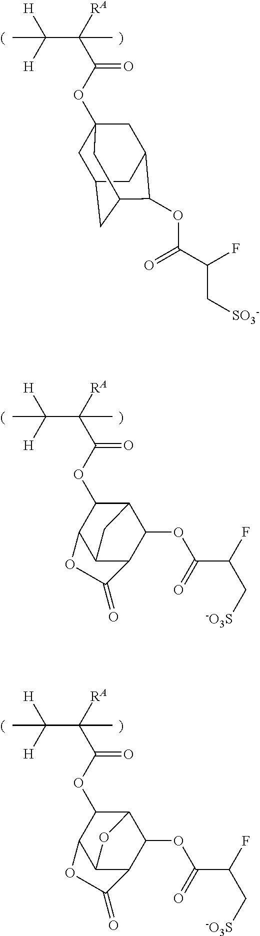

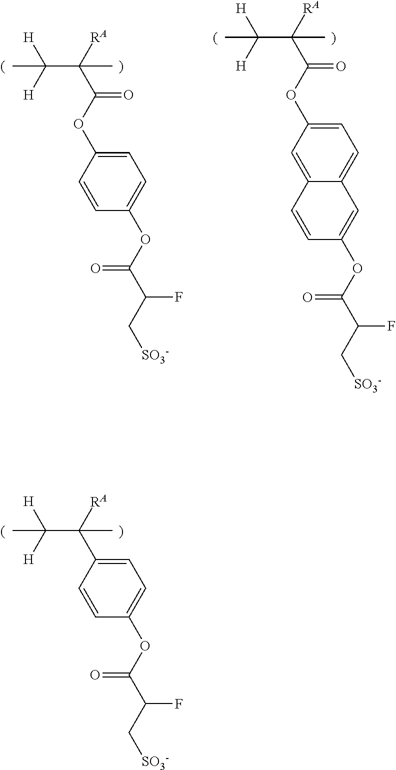

Examples of the anion in the repeat unit having formula (C4) are shown below, but not limited thereto. Herein R^{A} is as defined above.

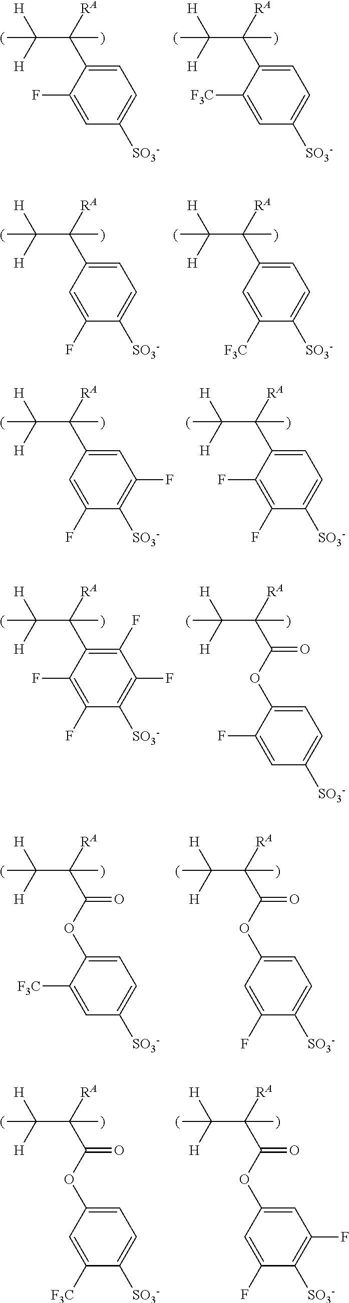

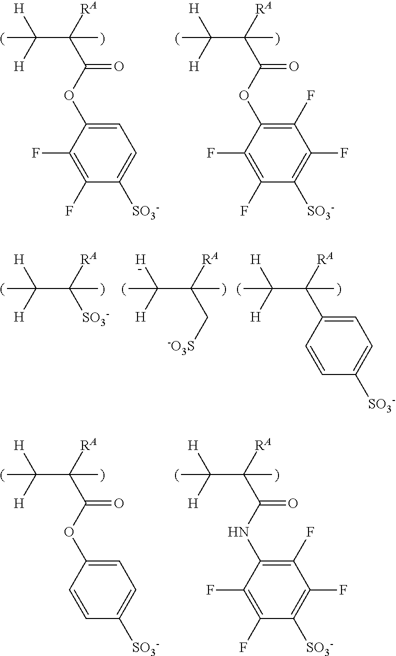

In formulae (C2) to (C4), A⁺ is an onium cation. Suitable onium cations include ammonium, sulfonium, and iodonium cations, with the sulfonium and iodonium cations being preferred. More preferred are sulfonium cations having the formula (cation-1) and iodonium cations having the formula (cation-2).

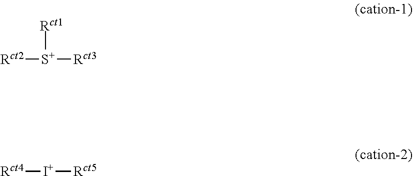

In formulae (cation-1) and (cation-2), R^{ct1} to R^{ct5} are each independently a C₁-C₂₀ hydrocarbyl group which may contain a heteroatom. The hydrocarbyl group may be saturated or unsaturated and straight, branched or cyclic. Examples thereof include C₁-C₂₀ alkyl groups such as methyl, ethyl, n-propyl, isopropyl, n-butyl, and tert-butyl; C₃-C₂₀ cyclic saturated hydrocarbyl groups such as cyclopropyl, cyclopentyl, cyclohexyl, cyclopropylmethyl, 4-methylcyclohexyl, cyclohexylmethyl norbornyl, and adamantyl; C₂-C₂₀ alkenyl groups such as vinyl, allyl, propenyl, butenyl and hexenyl; C₃-C₂₀ cyclic unsaturated hydrocarbyl groups such as cyclohexenyl; C₆-C₂₀ aryl groups such as phenyl, naphthyl, and thienyl; C₇-C₂₀ aralkyl groups such as benzyl, 1-phenylethyl and 2-phenylethyl, and mixtures thereof. Inter alia, aryl groups are preferred. In the hydrocarbyl group, some or all of the hydrogen atoms may be substituted by a moiety containing a heteroatom such as oxygen, sulfur, nitrogen or halogen, or some constituent —CH₂— may be replaced by a moiety containing a heteroatom such as oxygen, sulfur or nitrogen, so that the group may contain a hydroxy, fluorine, chlorine, bromine, iodine, cyano, carbonyl, ether bond, ester bond, sulfonic ester bond, carbonate bond, lactone ring, sultone ring, carboxylic anhydride (—C(═O)—O—C(═O)—) or haloalkyl moiety.

Also R^{ct1} and R^{ct2} may bond together to form a ring with the sulfur atom to which they are attached. Examples of the sulfonium cation having formula (cation-1) wherein R^{ct1} and R^{ct2} form a ring are shown below.

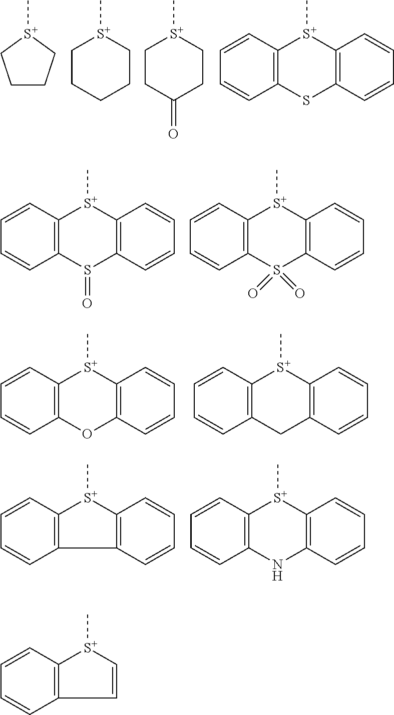

Herein the broken line designates a point of attachment to R^{ct3}.

Examples of the sulfonium cation having formula (cation-1) are shown below, but not limited thereto.

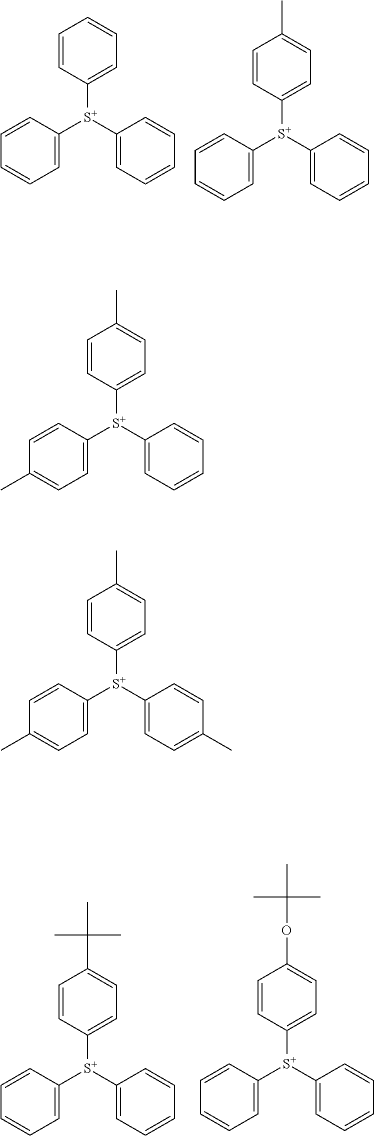

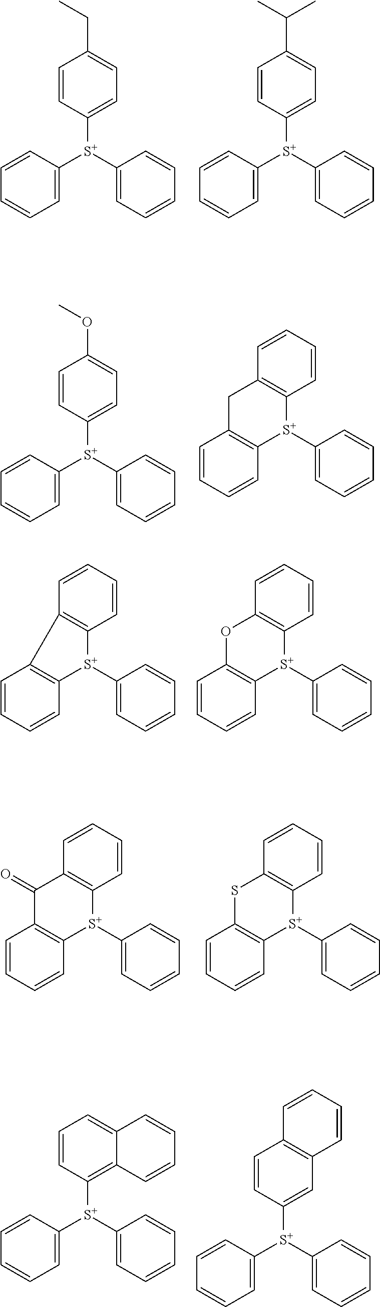

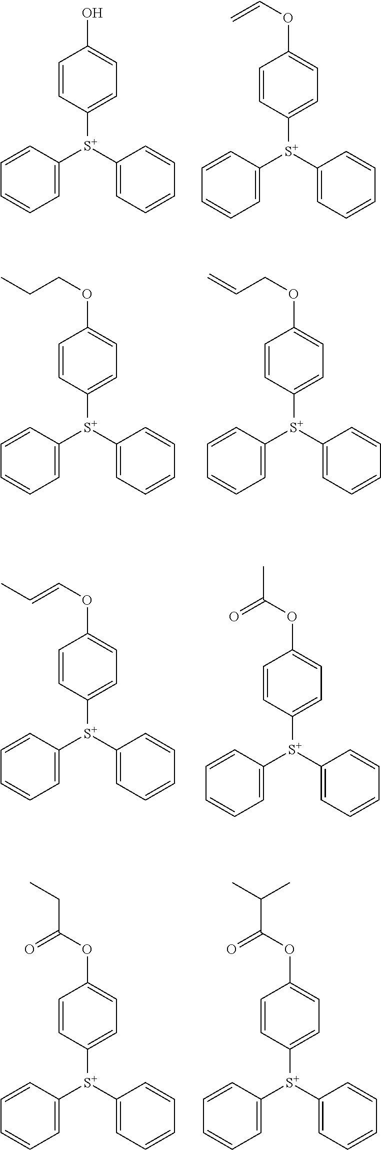

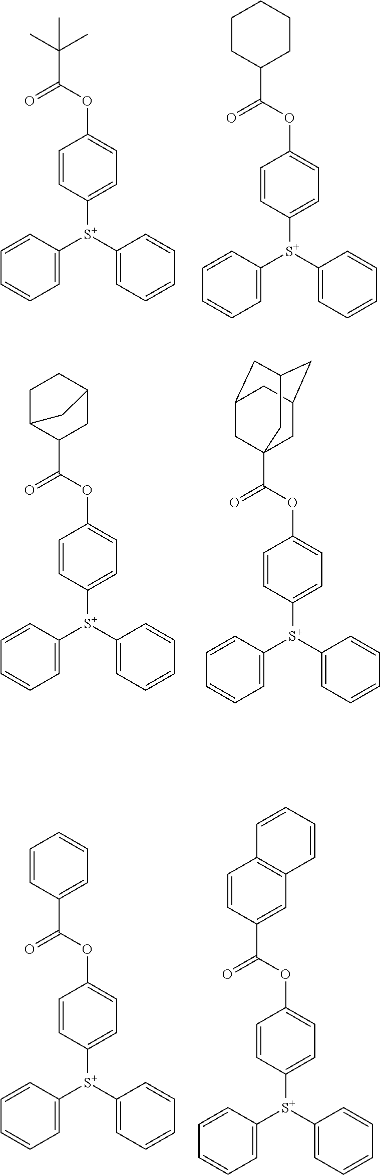 [SMILES: CC(C)(C)C(=O)Oc1ccc([S+](c2ccccc2)c2ccccc2)cc1 ; O=C(Oc1ccc([S+](c2ccccc2)c2ccccc2)cc1)C1CCCCC1 ; O=C(Oc1ccc([S+](c2ccccc2)c2ccccc2)cc1)C1CC2CCC1C2 ; O=C(Oc1ccc([S+](c2ccccc2)c2ccccc2)cc1)C12CC3CC(CC(C3)C1)C2 ; O=C(Oc1ccc([S+](c2ccccc2)c2ccccc2)cc1)c1ccccc1 ; O=C(Oc1ccc([S+](c2ccccc2)c2ccccc2)cc1)c1ccc2ccccc2c1]

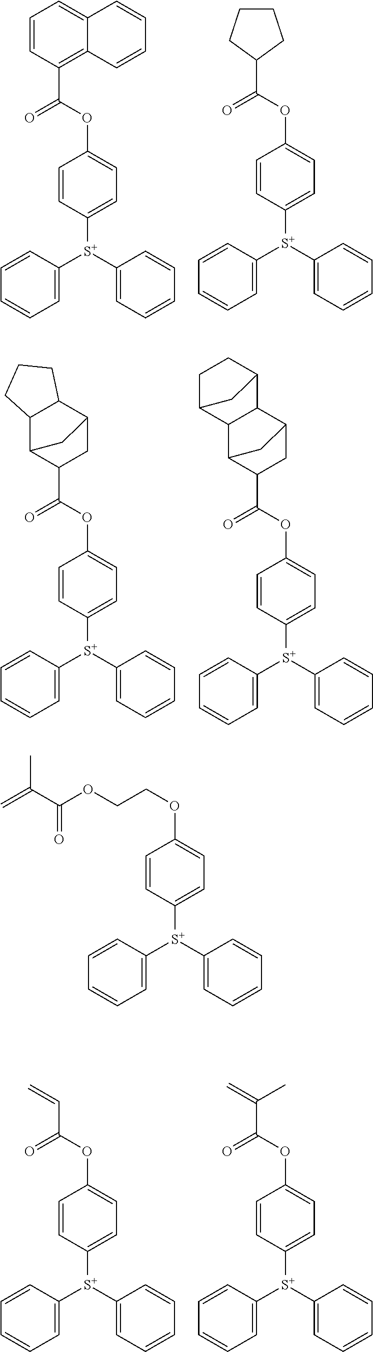

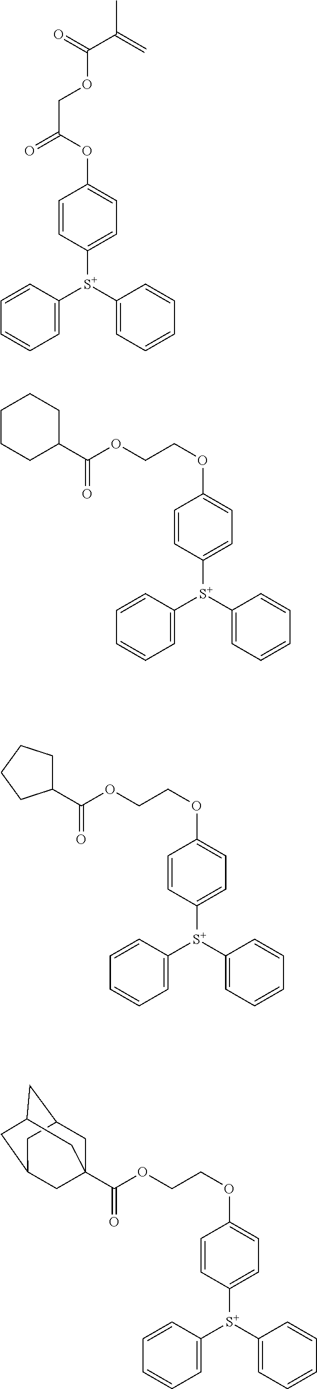 [SMILES: C=C(C)C(=O)OCC(=O)Oc1ccc([S+](c2ccccc2)c2ccccc2)cc1 ; O=C(OCCOc1ccc([S+](c2ccccc2)c2ccccc2)cc1)C1CCCCC1 ; O=C(OCCOc1ccc([S+](c2ccccc2)c2ccccc2)cc1)C1CCCC1 ; O=C(OCCOc1ccc([S+](c2ccccc2)c2ccccc2)cc1)C12CC3CC(CC(C3)C1)C2]

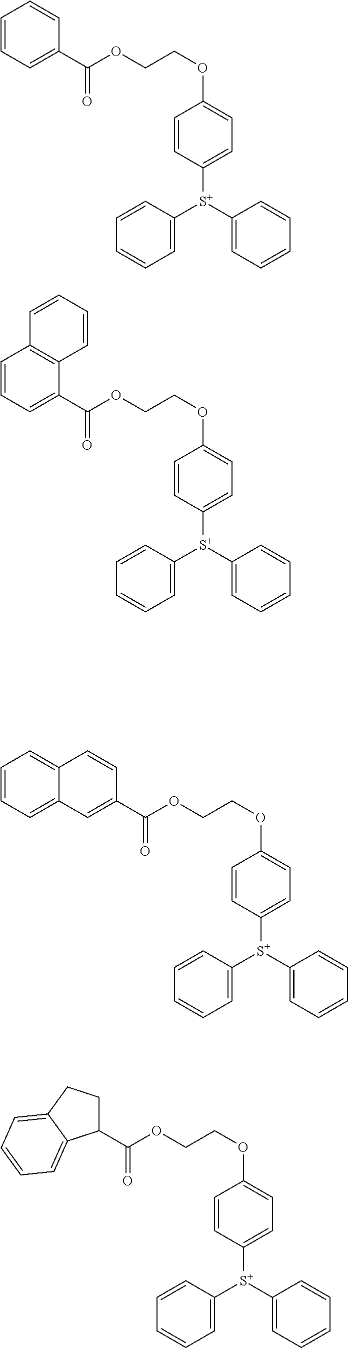 [SMILES: O=C(OCCOc1ccc([S+](c2ccccc2)c2ccccc2)cc1)c1ccccc1 ; O=C(OCCOc1ccc([S+](c2ccccc2)c2ccccc2)cc1)c1cccc2ccccc12 ; O=C(OCCOc1ccc([S+](c2ccccc2)c2ccccc2)cc1)c1ccc2ccccc2c1 ; O=C(OCCOc1ccc([S+](c2ccccc2)c2ccccc2)cc1)C1CCc2ccccc21]

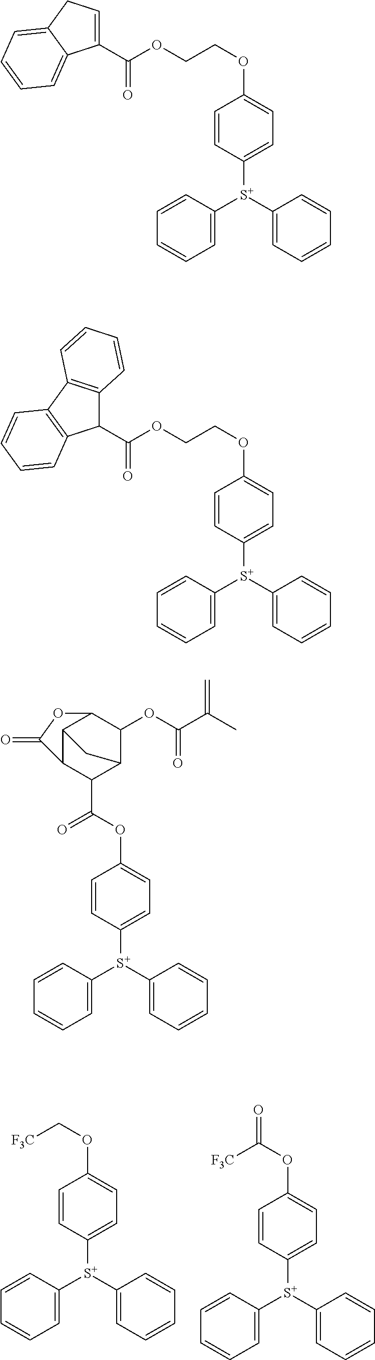 [SMILES: O=C(OCCOc1ccc([S+](c2ccccc2)c2ccccc2)cc1)C1=CCc2ccccc21 ; O=C(OCCOc1ccc([S+](c2ccccc2)c2ccccc2)cc1)C1c2ccccc2-c2ccccc21 ; C=C(C)C(=O)OC1C2CC3C1OC(=O)C3C2C(=O)Oc1ccc([S+](c2ccccc2)c2ccccc2)cc1 ; FC(F)(F)COc1ccc([S+](c2ccccc2)c2ccccc2)cc1 ; O=C(Oc1ccc([S+](c2ccccc2)c2ccccc2)cc1)C(F)(F)F]

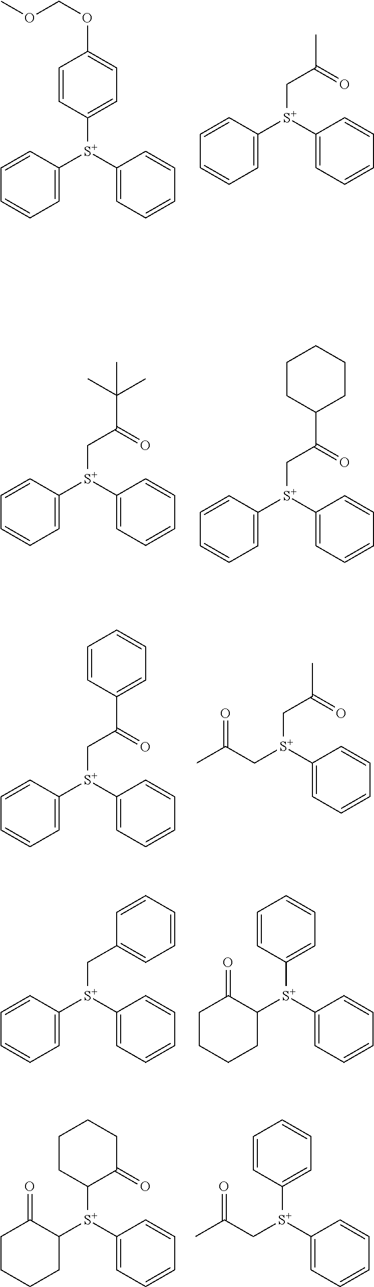

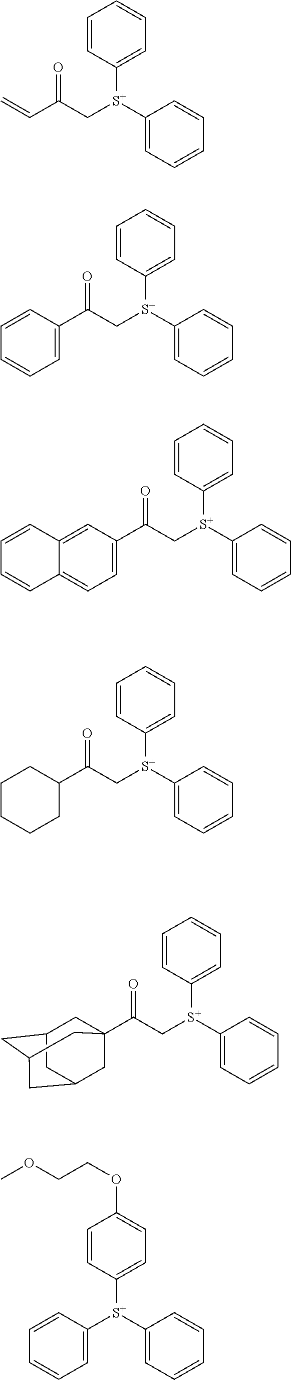 [SMILES: C=CC(=O)C[S+](c1ccccc1)c1ccccc1 ; O=C(C[S+](c1ccccc1)c1ccccc1)c1ccccc1 ; O=C(C[S+](c1ccccc1)c1ccccc1)c1ccc2ccccc2c1 ; O=C(C[S+](c1ccccc1)c1ccccc1)C1CCCCC1 ; O=C(C[S+](c1ccccc1)c1ccccc1)C12CC3CC(CC(C3)C1)C2 ; COCCOc1ccc([S+](c2ccccc2)c2ccccc2)cc1]

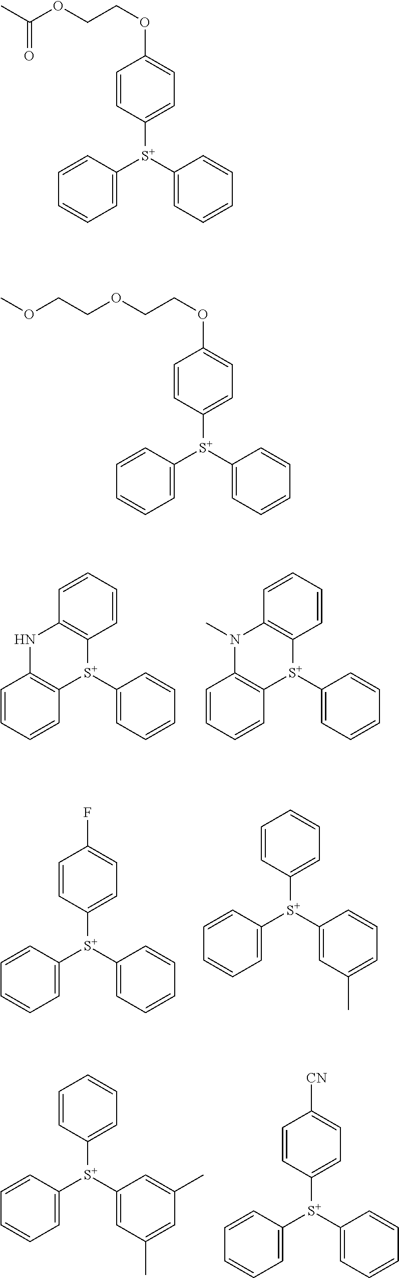

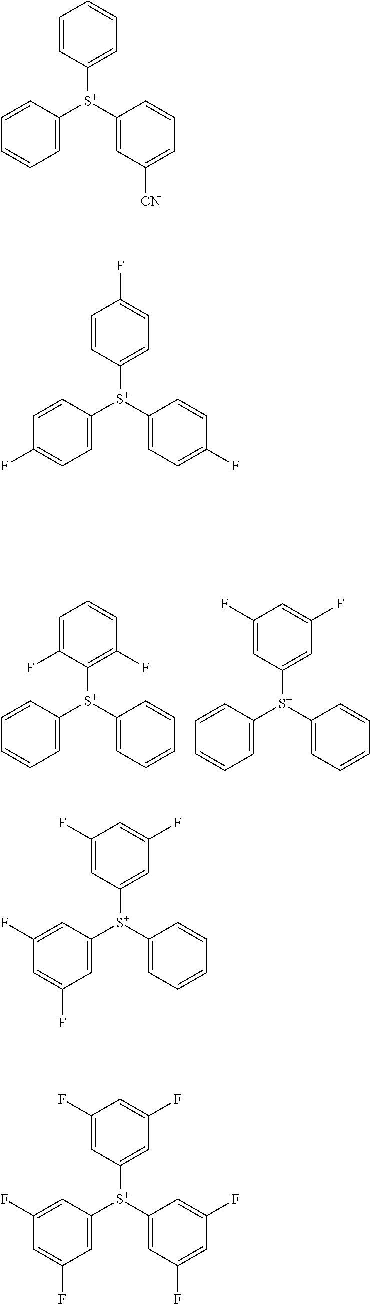 [SMILES: N#Cc1cccc([S+](c2ccccc2)c2ccccc2)c1 ; Fc1ccc([S+](c2ccc(F)cc2)c2ccc(F)cc2)cc1 ; Fc1cccc(F)c1[S+](c1ccccc1)c1ccccc1 ; Fc1cc(F)cc([S+](c2ccccc2)c2ccccc2)c1 ; Fc1cc(F)cc([S+](c2ccccc2)c2cc(F)cc(F)c2)c1 ; Fc1cc(F)cc([S+](c2cc(F)cc(F)c2)c2cc(F)cc(F)c2)c1]

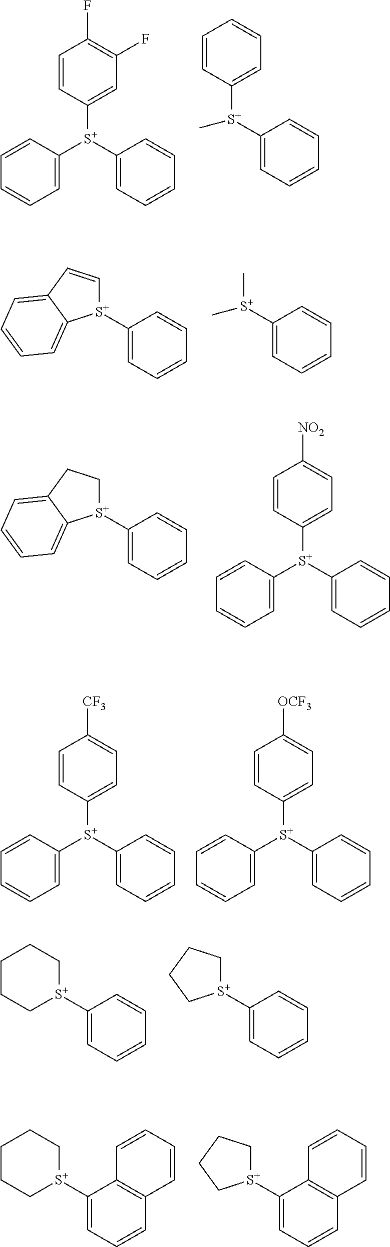

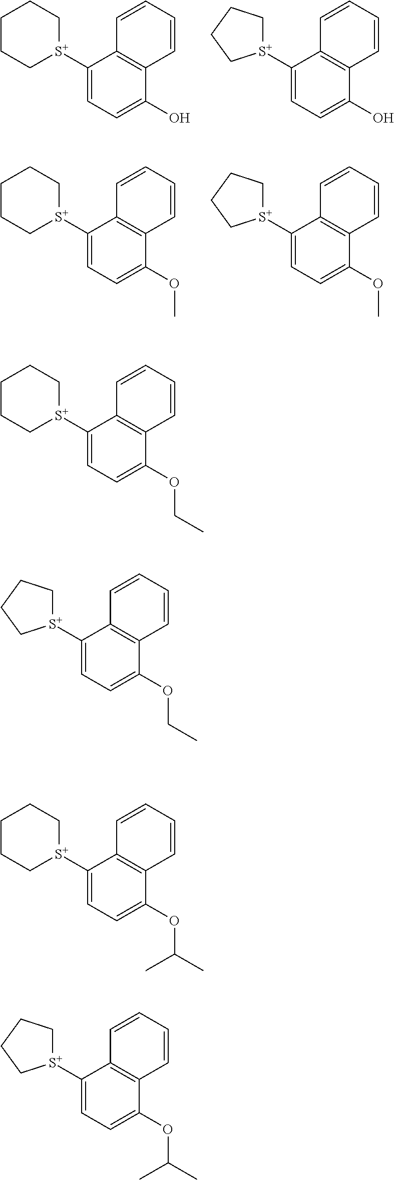

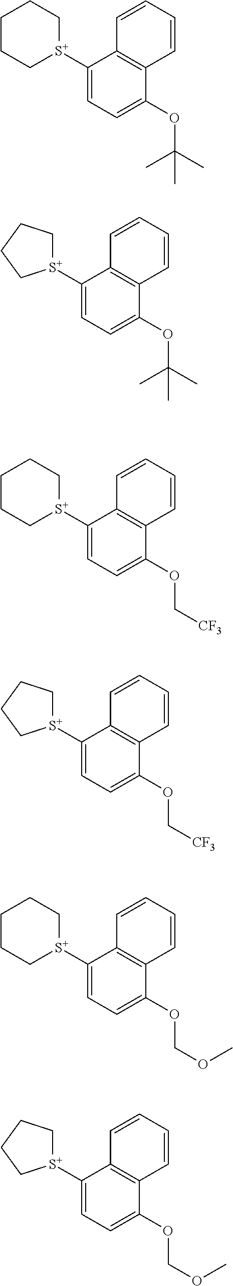 [SMILES: CC(C)(C)Oc1ccc([S+]2CCCCC2)c2ccccc12 ; CC(C)(C)Oc1ccc([S+]2CCCC2)c2ccccc12 ; FC(F)(F)COc1ccc([S+]2CCCCC2)c2ccccc12 ; FC(F)(F)COc1ccc([S+]2CCCC2)c2ccccc12 ; COCOc1ccc([S+]2CCCCC2)c2ccccc12 ; COCOc1ccc([S+]2CCCC2)c2ccccc12]

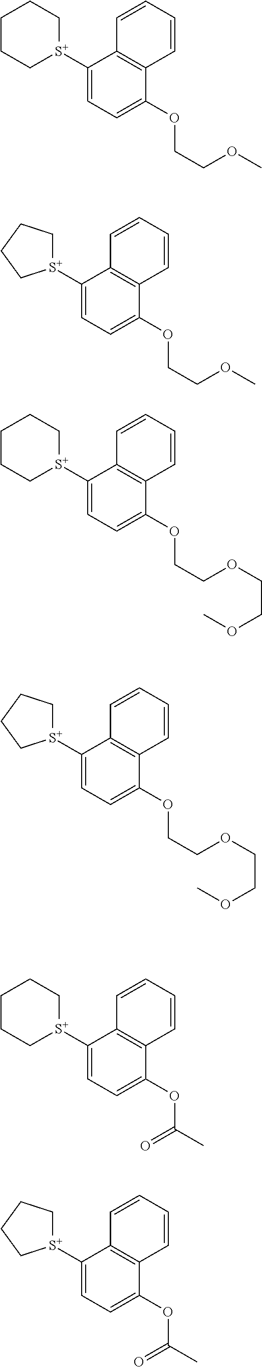 [SMILES: COCCOc1ccc([S+]2CCCCC2)c2ccccc12 ; COCCOc1ccc([S+]2CCCC2)c2ccccc12 ; COCCOCCOc1ccc([S+]2CCCCC2)c2ccccc12 ; COCCOCCOc1ccc([S+]2CCCC2)c2ccccc12 ; CC(=O)Oc1ccc([S+]2CCCCC2)c2ccccc12 ; CC(=O)Oc1ccc([S+]2CCCC2)c2ccccc12]

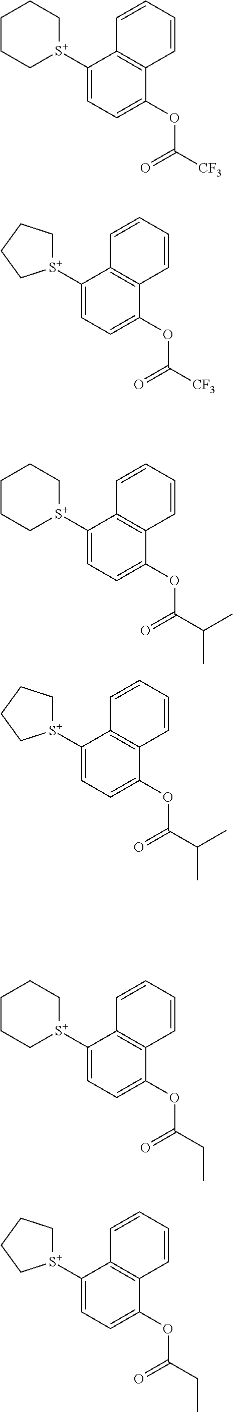 [SMILES: O=C(Oc1ccc([S+]2CCCCC2)c2ccccc12)C(F)(F)F ; O=C(Oc1ccc([S+]2CCCC2)c2ccccc12)C(F)(F)F ; CC(C)C(=O)Oc1ccc([S+]2CCCCC2)c2ccccc12 ; CC(C)C(=O)Oc1ccc([S+]2CCCC2)c2ccccc12 ; CCC(=O)Oc1ccc([S+]2CCCCC2)c2ccccc12 ; CCC(=O)Oc1ccc([S+]2CCCC2)c2ccccc12]

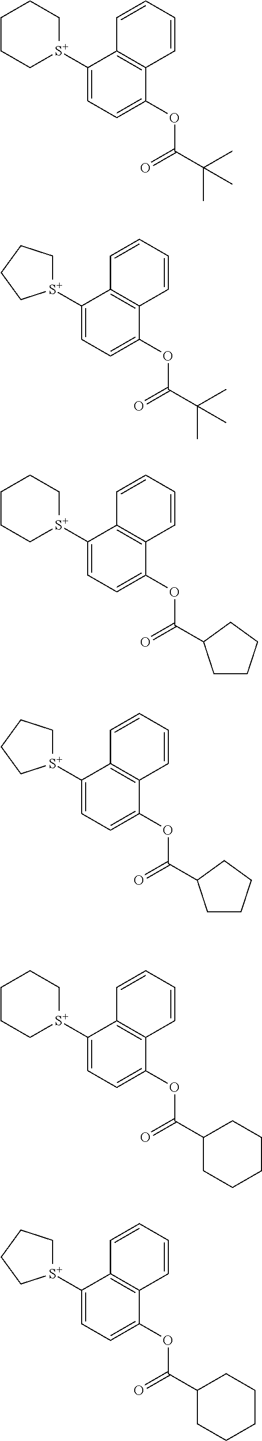 [SMILES: CC(C)(C)C(=O)Oc1ccc([S+]2CCCCC2)c2ccccc12 ; CC(C)(C)C(=O)Oc1ccc([S+]2CCCC2)c2ccccc12 ; O=C(Oc1ccc([S+]2CCCCC2)c2ccccc12)C1CCCC1 ; O=C(Oc1ccc([S+]2CCCC2)c2ccccc12)C1CCCC1 ; O=C(Oc1ccc([S+]2CCCCC2)c2ccccc12)C1CCCCC1 ; O=C(Oc1ccc([S+]2CCCC2)c2ccccc12)C1CCCCC1]

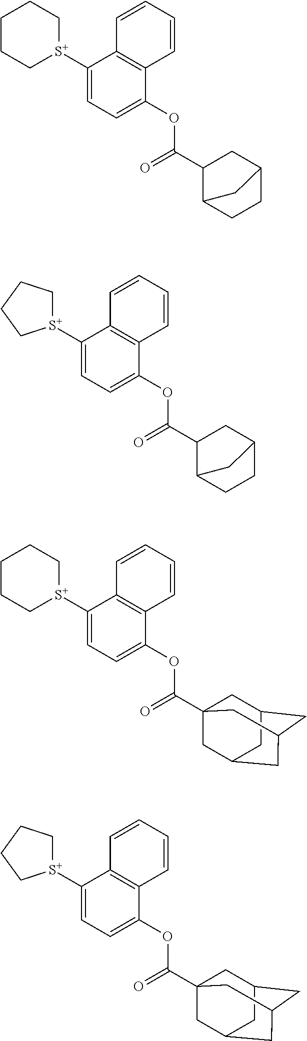 [SMILES: O=C(Oc1ccc([S+]2CCCCC2)c2ccccc12)C1CC2CCC1C2 ; O=C(Oc1ccc([S+]2CCCC2)c2ccccc12)C1CC2CCC1C2 ; O=C(Oc1ccc([S+]2CCCCC2)c2ccccc12)C12CC3CC(CC(C3)C1)C2 ; O=C(Oc1ccc([S+]2CCCC2)c2ccccc12)C12CC3CC(CC(C3)C1)C2]

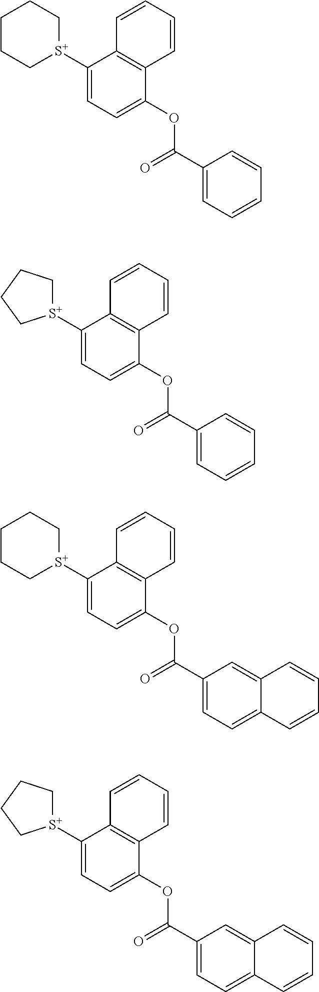 [SMILES: O=C(Oc1ccc([S+]2CCCCC2)c2ccccc12)c1ccccc1 ; O=C(Oc1ccc([S+]2CCCC2)c2ccccc12)c1ccccc1 ; O=C(Oc1ccc([S+]2CCCCC2)c2ccccc12)c1ccc2ccccc2c1 ; O=C(Oc1ccc([S+]2CCCC2)c2ccccc12)c1ccc2ccccc2c1]

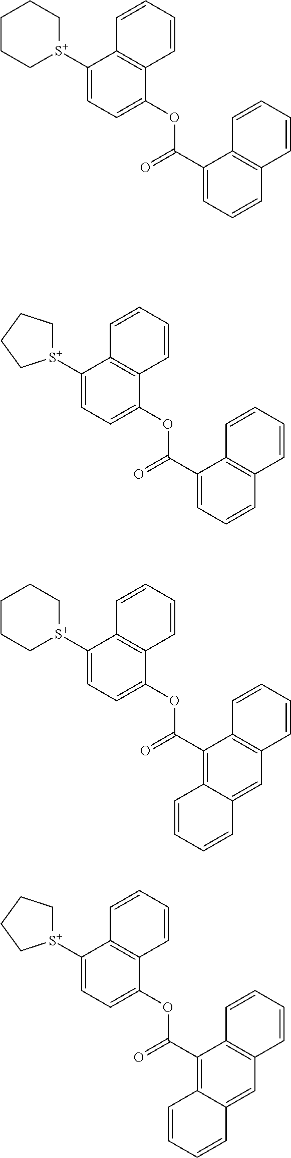 [SMILES: O=C(Oc1ccc([S+]2CCCCC2)c2ccccc12)c1cccc2ccccc12 ; O=C(Oc1ccc([S+]2CCCC2)c2ccccc12)c1cccc2ccccc12 ; O=C(Oc1ccc([S+]2CCCCC2)c2ccccc12)c1c2ccccc2cc2ccccc12 ; O=C(Oc1ccc([S+]2CCCC2)c2ccccc12)c1c2ccccc2cc2ccccc12]

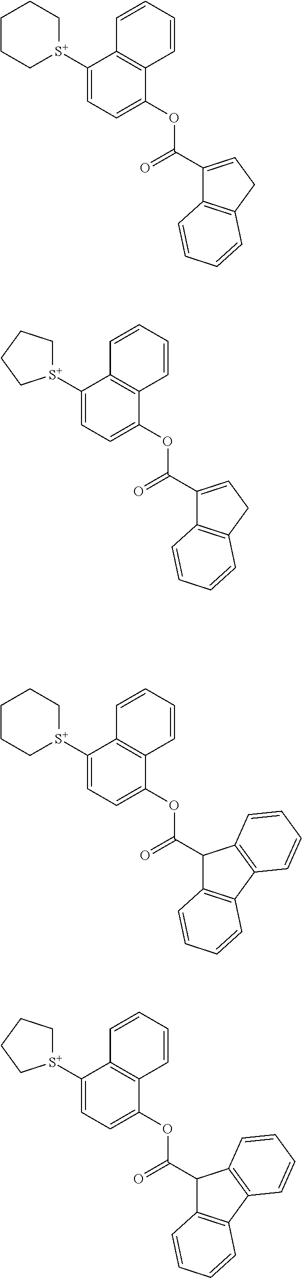 [SMILES: O=C(Oc1ccc([S+]2CCCCC2)c2ccccc12)C1=CCc2ccccc21 ; O=C(Oc1ccc([S+]2CCCC2)c2ccccc12)C1=CCc2ccccc21 ; O=C(Oc1ccc([S+]2CCCCC2)c2ccccc12)C1c2ccccc2-c2ccccc21 ; O=C(Oc1ccc([S+]2CCCC2)c2ccccc12)C1c2ccccc2-c2ccccc21]

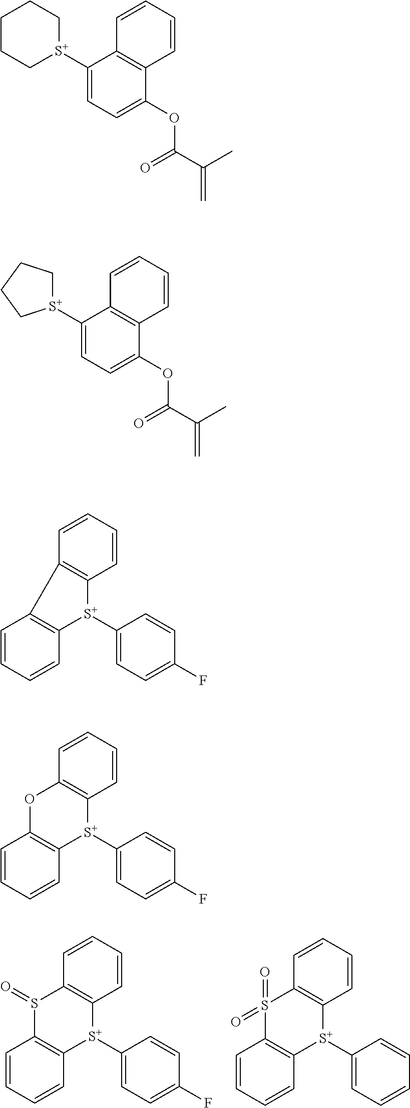 [SMILES: C=C(C)C(=O)Oc1ccc([S+]2CCCCC2)c2ccccc12 ; C=C(C)C(=O)Oc1ccc([S+]2CCCC2)c2ccccc12 ; Fc1ccc(-[s+]2c3ccccc3c3ccccc32)cc1 ; Fc1ccc([S+]2c3ccccc3Oc3ccccc32)cc1 ; O=S1c2ccccc2[S+](c2ccc(F)cc2)c2ccccc21 ; O=S1(=O)c2ccccc2[S+](c2ccccc2)c2ccccc21]

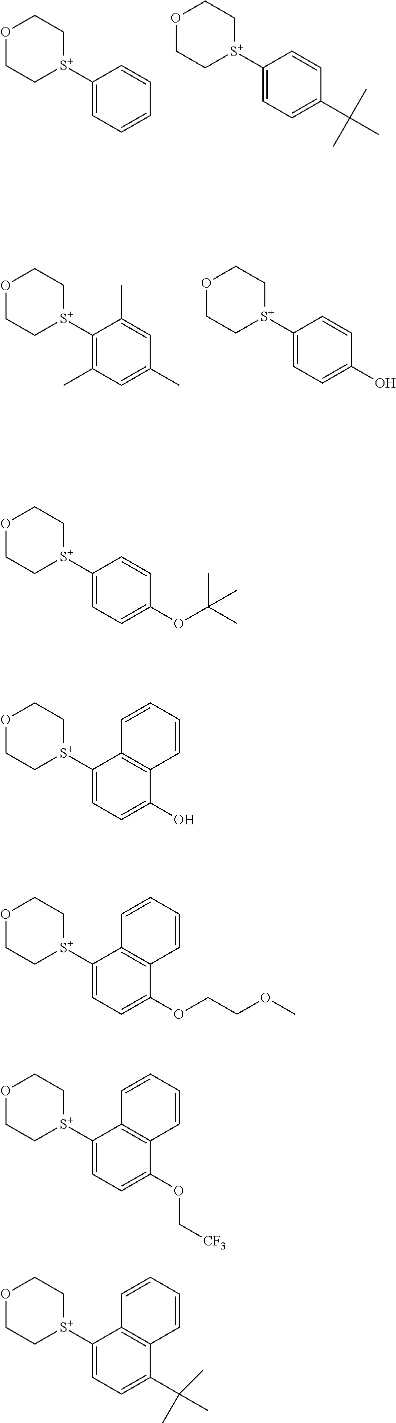

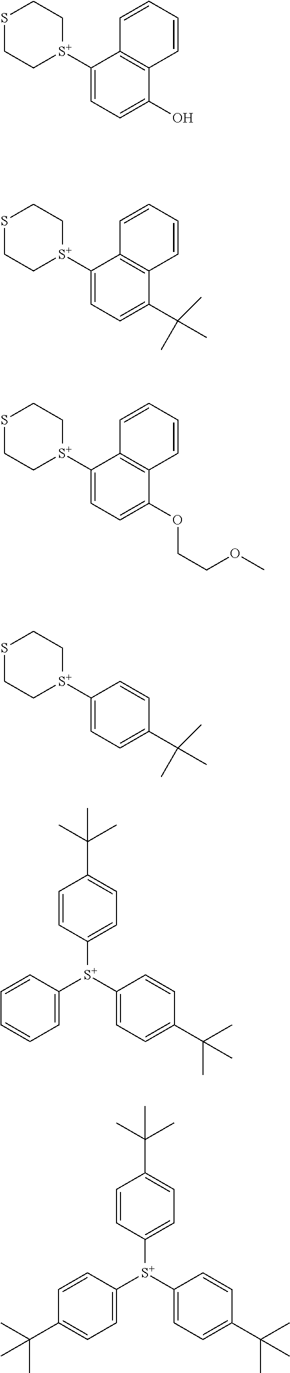

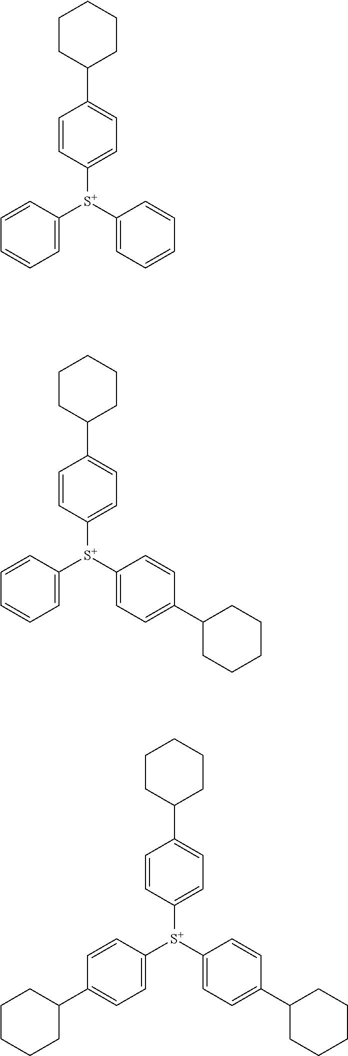 [SMILES: c1ccc([S+](c2ccccc2)c2ccc(C3CCCCC3)cc2)cc1 ; c1ccc([S+](c2ccc(C3CCCCC3)cc2)c2ccc(C3CCCCC3)cc2)cc1 ; c1cc([S+](c2ccc(C3CCCCC3)cc2)c2ccc(C3CCCCC3)cc2)ccc1C1CCCCC1]

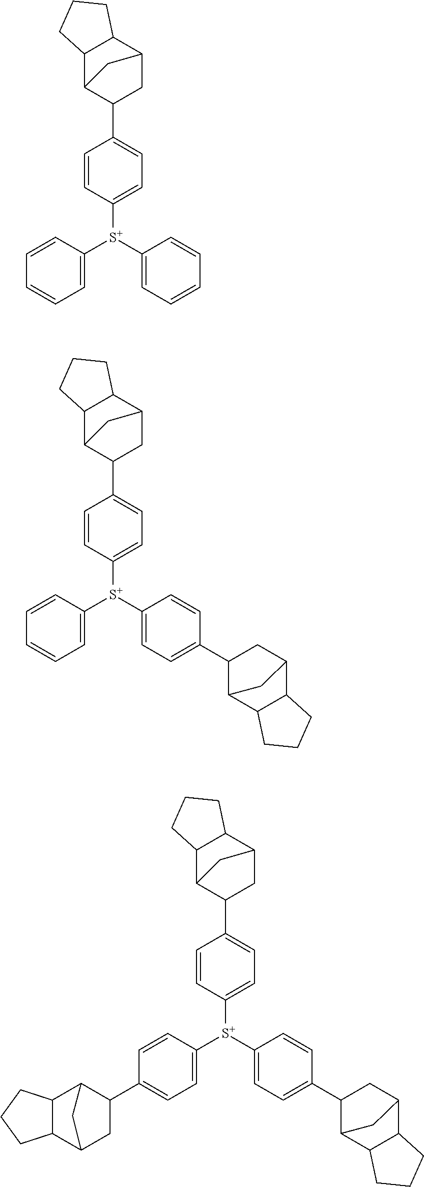 [SMILES: c1ccc([S+](c2ccccc2)c2ccc(C3CC4CC3C3CCCC43)cc2)cc1 ; c1ccc([S+](c2ccc(C3CC4CC3C3CCCC43)cc2)c2ccc(C3CC4CC3C3CCCC43)cc2)cc1 ; c1cc([S+](c2ccc(C3CC4CC3C3CCCC43)cc2)c2ccc(C3CC4CC3C3CCCC43)cc2)ccc1C1CC2CC1C1CCCC21]

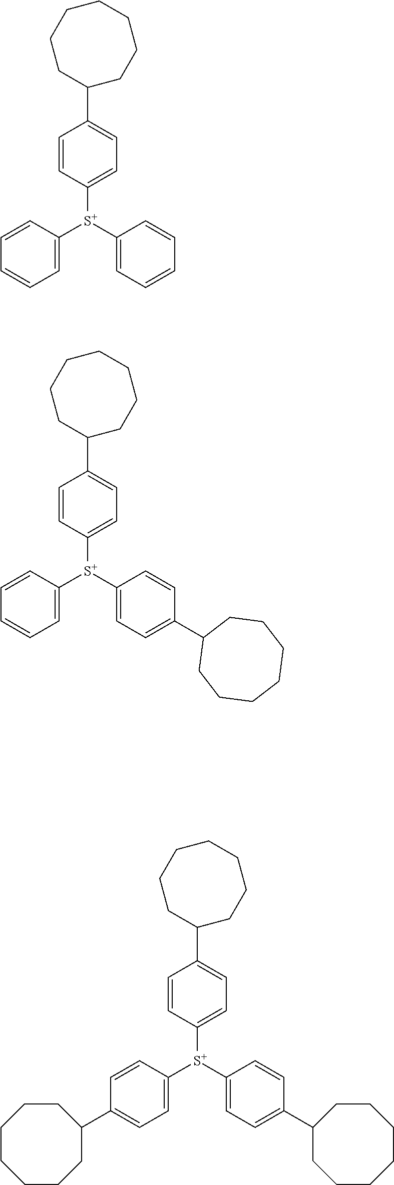 [SMILES: c1ccc([S+](c2ccccc2)c2ccc(C3CCCCCCC3)cc2)cc1 ; c1ccc([S+](c2ccc(C3CCCCCCC3)cc2)c2ccc(C3CCCCCCC3)cc2)cc1 ; c1cc([S+](c2ccc(C3CCCCCCC3)cc2)c2ccc(C3CCCCCCC3)cc2)ccc1C1CCCCCCC1]

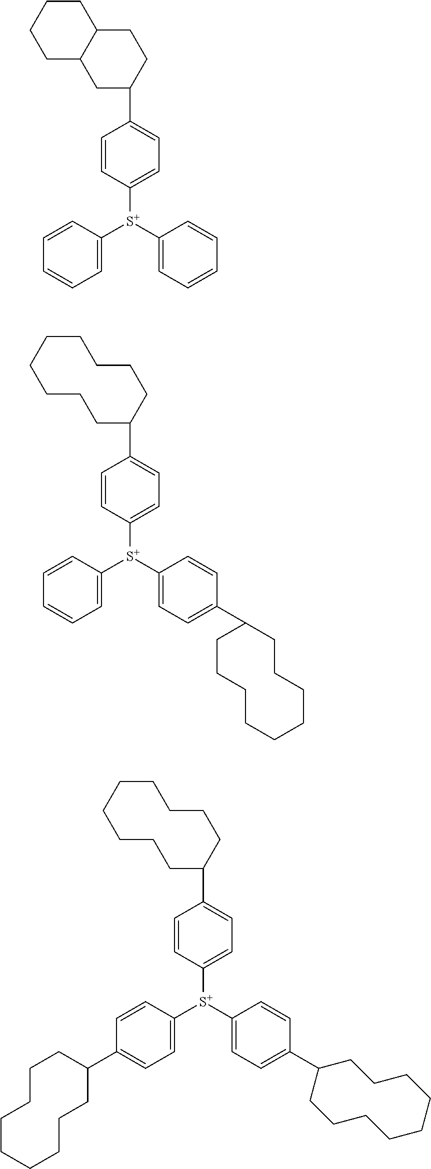 [SMILES: c1ccc([S+](c2ccccc2)c2ccc(C3CCC4CCCCC4C3)cc2)cc1 ; c1ccc([S+](c2ccc(C3CCCCCCCCC3)cc2)c2ccc(C3CCCCCCCCC3)cc2)cc1 ; c1cc([S+](c2ccc(C3CCCCCCCCC3)cc2)c2ccc(C3CCCCCCCCC3)cc2)ccc1C1CCCCCCCCC1]

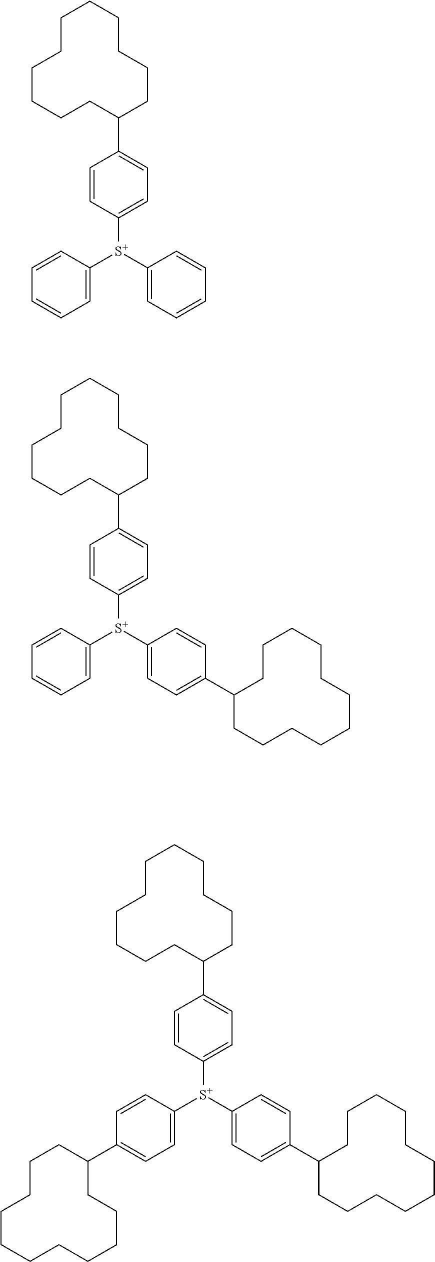 [SMILES: c1ccc([S+](c2ccccc2)c2ccc(C3CCCCCCCCCCC3)cc2)cc1 ; c1ccc([S+](c2ccc(C3CCCCCCCCCCC3)cc2)c2ccc(C3CCCCCCCCCCC3)cc2)cc1 ; c1cc([S+](c2ccc(C3CCCCCCCCCCC3)cc2)c2ccc(C3CCCCCCCCCCC3)cc2)ccc1C1CCCCCCCCCCC1]

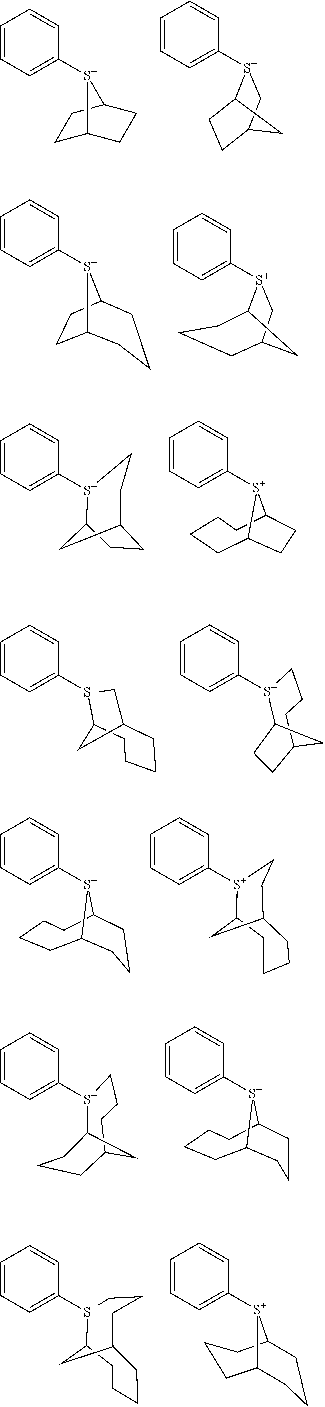

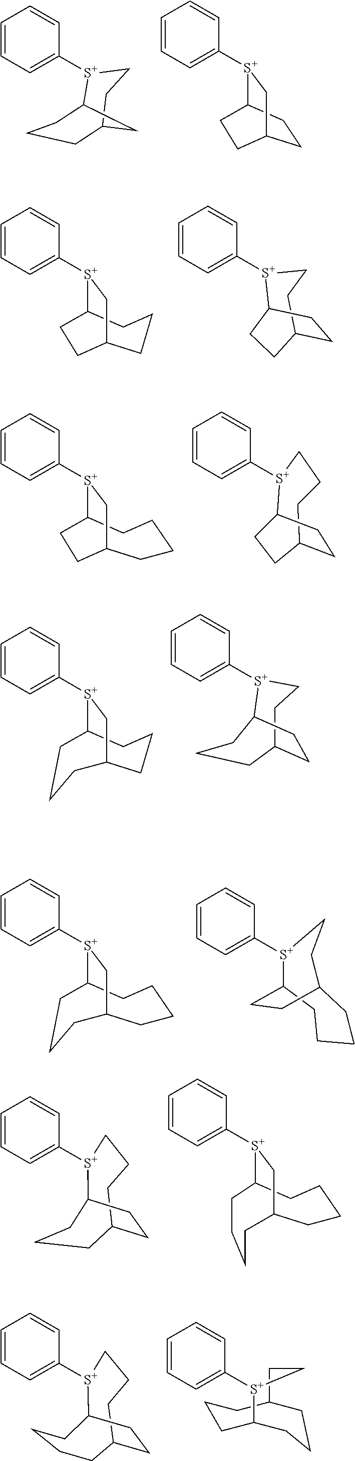

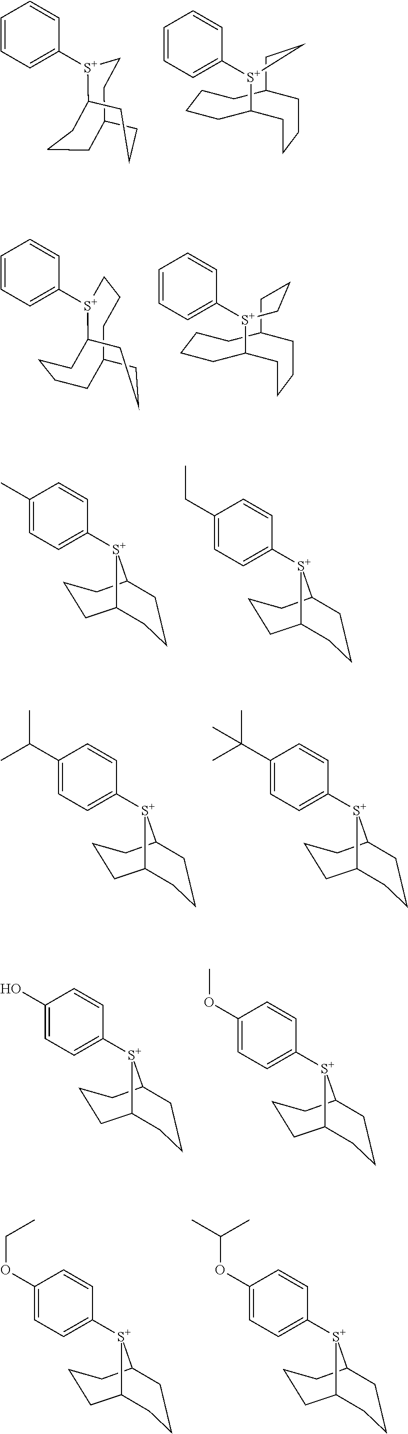

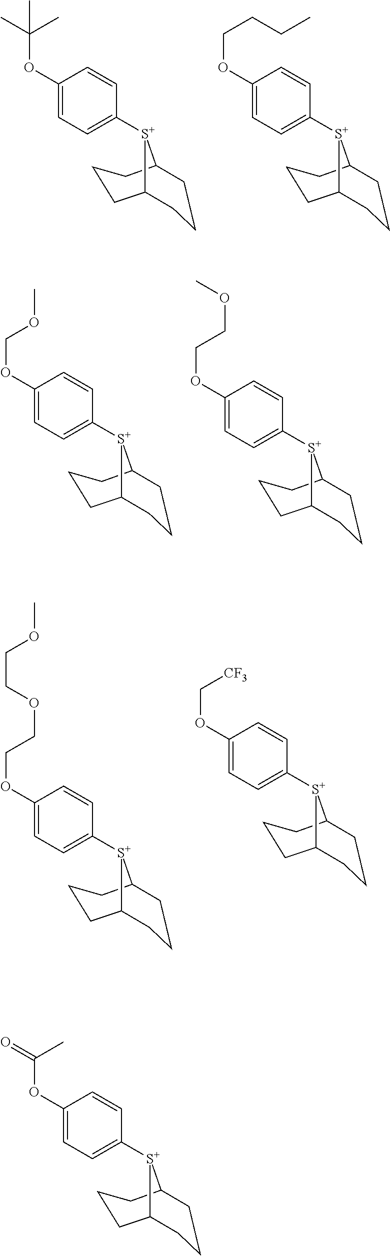

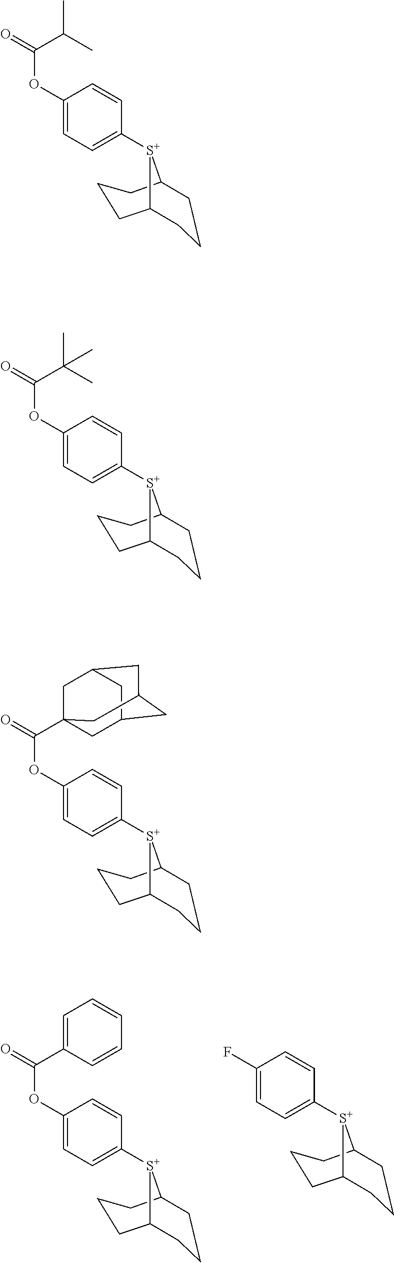 [SMILES: CC(C)C(=O)Oc1ccc([S+]2C3CCCC2CCC3)cc1 ; CC(C)(C)C(=O)Oc1ccc([S+]2C3CCCC2CCC3)cc1 ; O=C(Oc1ccc([S+]2C3CCCC2CCC3)cc1)C12CC3CC(CC(C3)C1)C2 ; O=C(Oc1ccc([S+]2C3CCCC2CCC3)cc1)c1ccccc1 ; Fc1ccc([S+]2C3CCCC2CCC3)cc1]

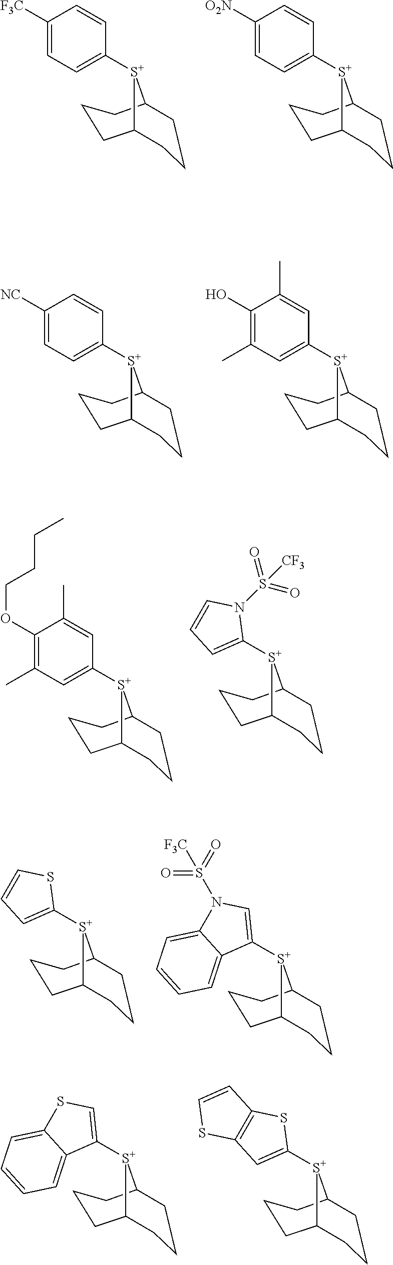

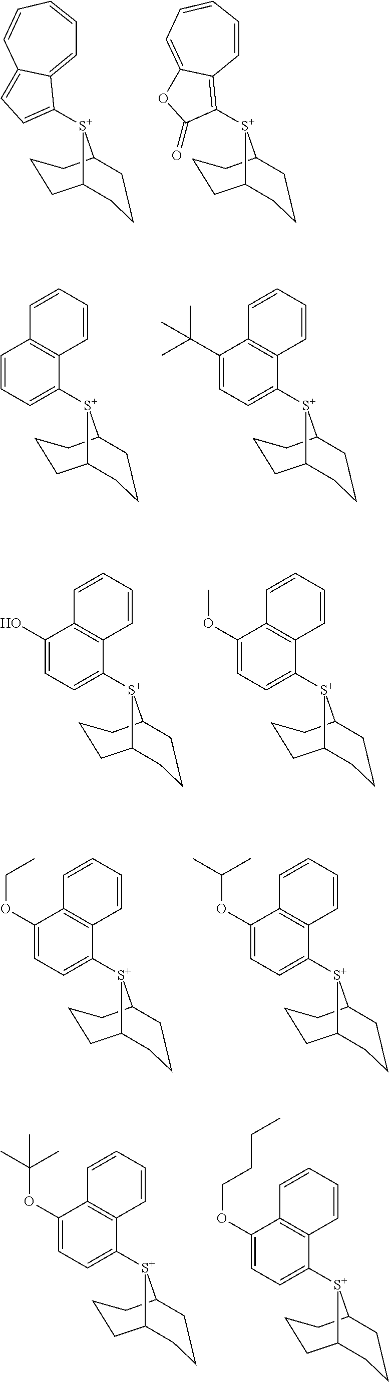

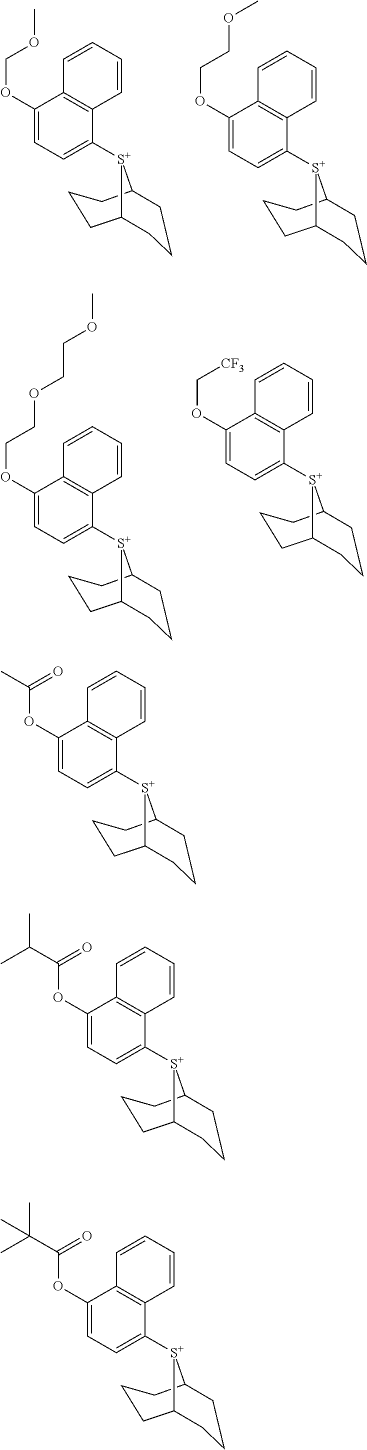

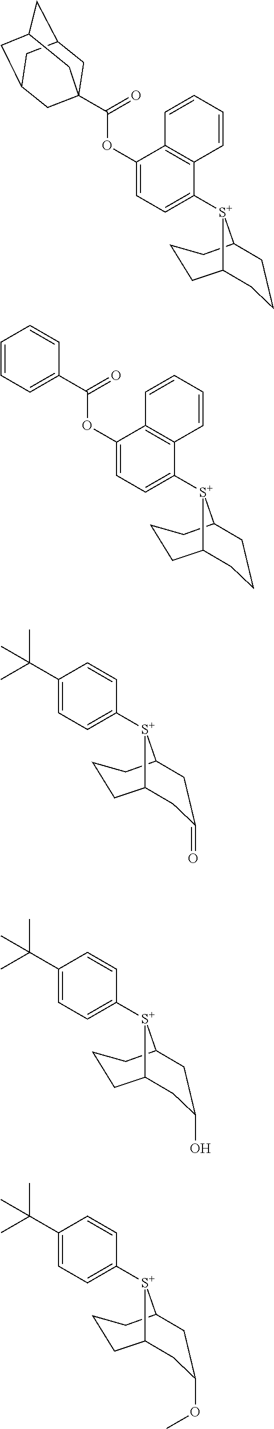 [SMILES: O=C(Oc1ccc([S+]2C3CCCC2CCC3)c2ccccc12)C12CC3CC(CC(C3)C1)C2 ; O=C(Oc1ccc([S+]2C3CCCC2CCC3)c2ccccc12)c1ccccc1 ; CC(C)(C)c1ccc([S+]2C3CCCC2CC(=O)C3)cc1 ; CC(C)(C)c1ccc([S+]2C3CCCC2CC(O)C3)cc1 ; COC1CC2CCCC(C1)[S+]2c1ccc(C(C)(C)C)cc1]

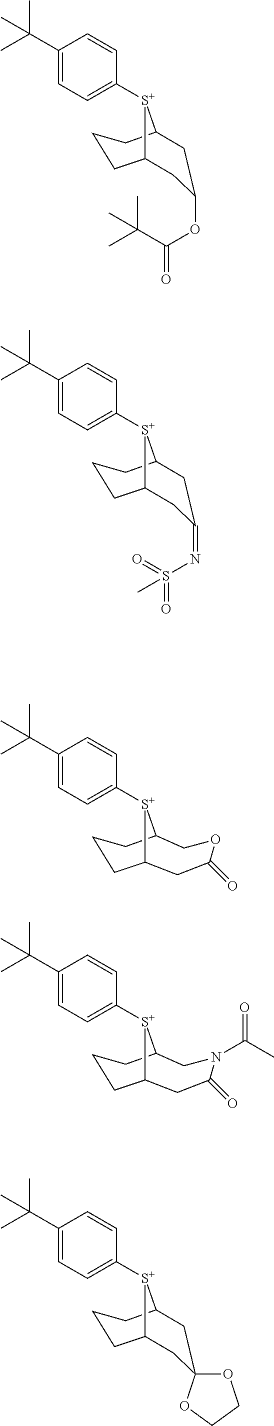

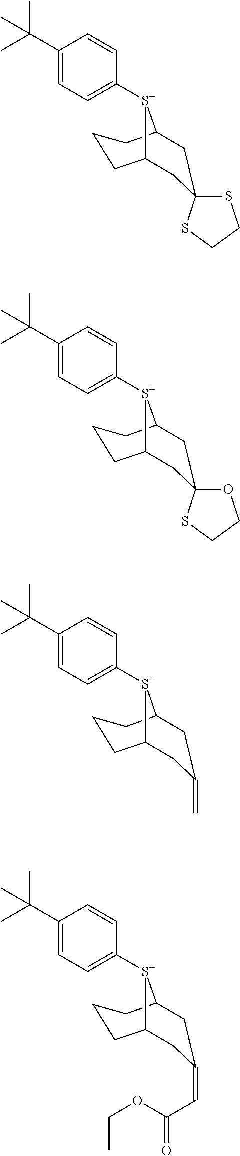

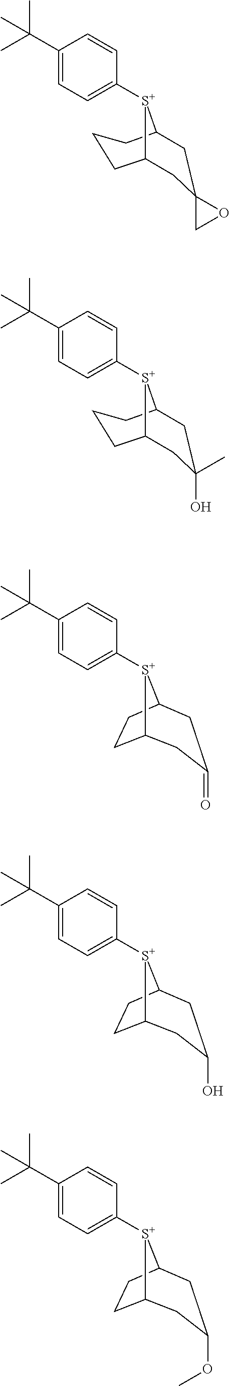

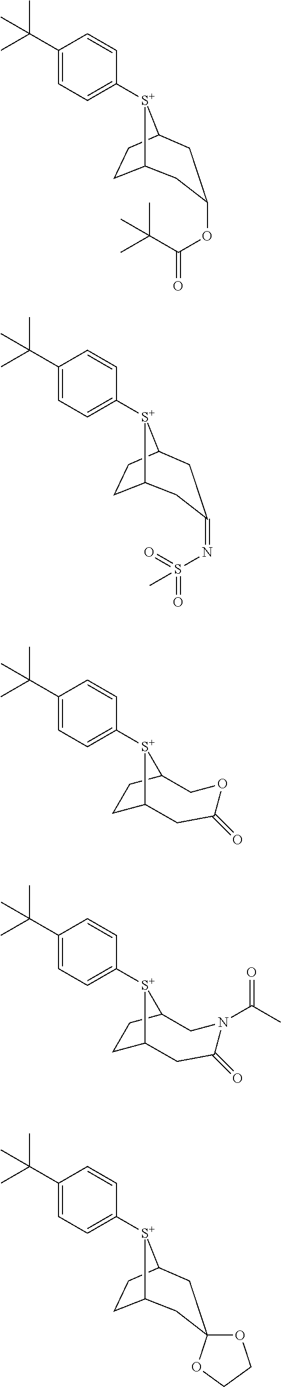

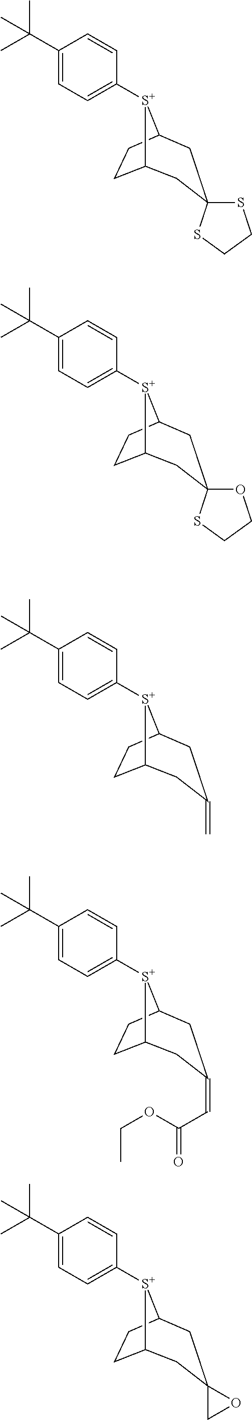

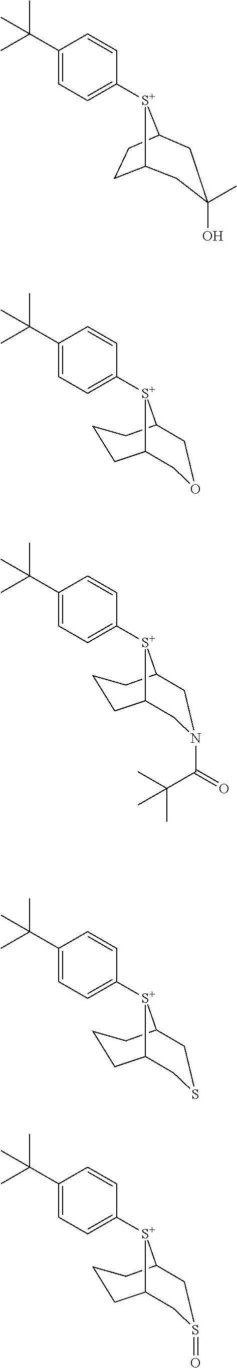

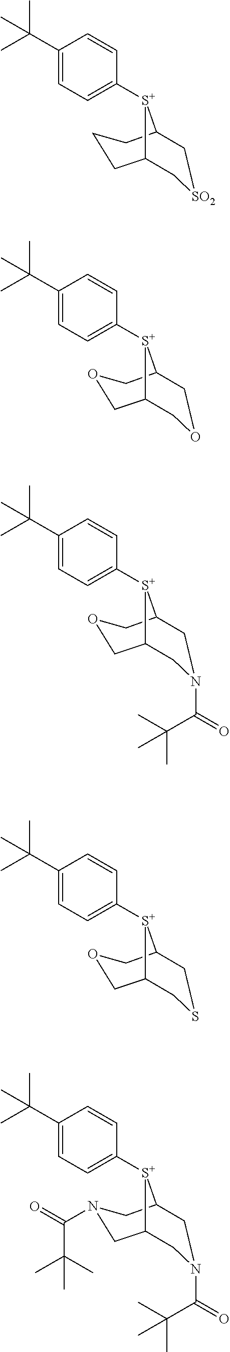 [SMILES: CC(C)(C)c1ccc([S+]2C3CCCC2CS(=O)(=O)C3)cc1 ; CC(C)(C)c1ccc([S+]2C3COCC2COC3)cc1 ; CC(C)(C)C(=O)N1CC2COCC(C1)[S+]2c1ccc(C(C)(C)C)cc1 ; CC(C)(C)c1ccc([S+]2C3COCC2CSC3)cc1 ; CC(C)(C)C(=O)N1CC2CN(C(=O)C(C)(C)C)CC(C1)[S+]2c1ccc(C(C)(C)C)cc1]

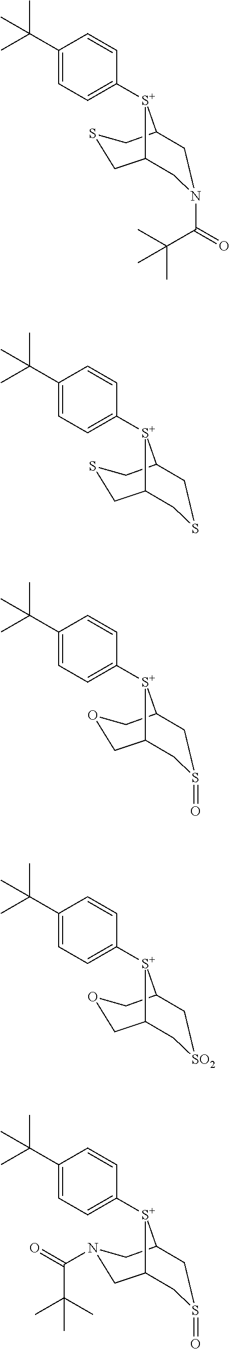 [SMILES: CC(C)(C)C(=O)N1CC2CSCC(C1)[S+]2c1ccc(C(C)(C)C)cc1 ; CC(C)(C)c1ccc([S+]2C3CSCC2CSC3)cc1 ; CC(C)(C)c1ccc([S+]2C3COCC2CS(=O)C3)cc1 ; CC(C)(C)c1ccc([S+]2C3COCC2CS(=O)(=O)C3)cc1 ; CC(C)(C)C(=O)N1CC2CS(=O)CC(C1)[S+]2c1ccc(C(C)(C)C)cc1]

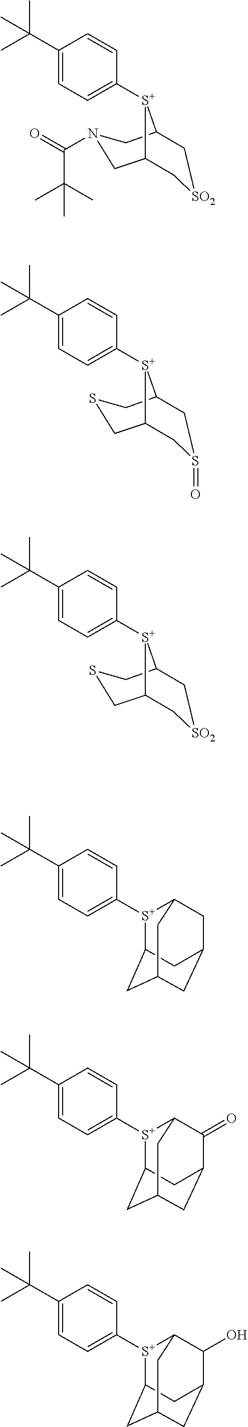 [SMILES: CC(C)(C)C(=O)N1CC2CS(=O)(=O)CC(C1)[S+]2c1ccc(C(C)(C)C)cc1 ; CC(C)(C)c1ccc([S+]2C3CSCC2CS(=O)C3)cc1 ; CC(C)(C)c1ccc([S+]2C3CSCC2CS(=O)(=O)C3)cc1 ; CC(C)(C)c1ccc([S+]2C3CC4CC(C3)CC2C4)cc1 ; CC(C)(C)c1ccc([S+]2C3CC4CC(C3)C(=O)C2C4)cc1 ; CC(C)(C)c1ccc([S+]2C3CC4CC(C3)C(O)C2C4)cc1]

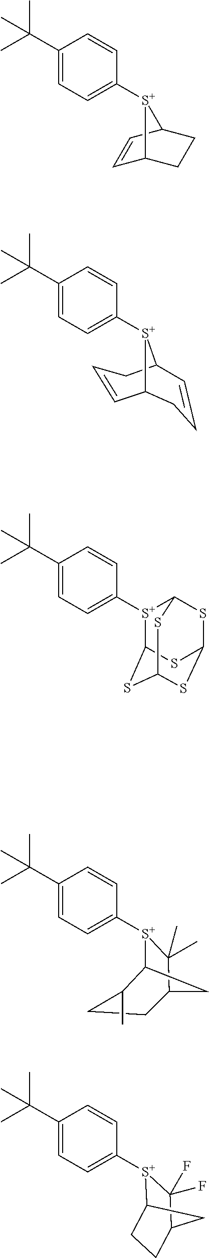 [SMILES: CC(C)(C)c1ccc([S+]2C3C=CC2CC3)cc1 ; CC(C)(C)c1ccc([S+]2C3C=CCC2C=CC3)cc1 ; CC(C)(C)c1ccc([S+]2C3SC4SC(S3)SC2S4)cc1 ; CC1CCC2CC1[S+](c1ccc(C(C)(C)C)cc1)C2(C)C ; CC(C)(C)c1ccc([S+]2C3CCC(C3)C2(F)F)cc1]

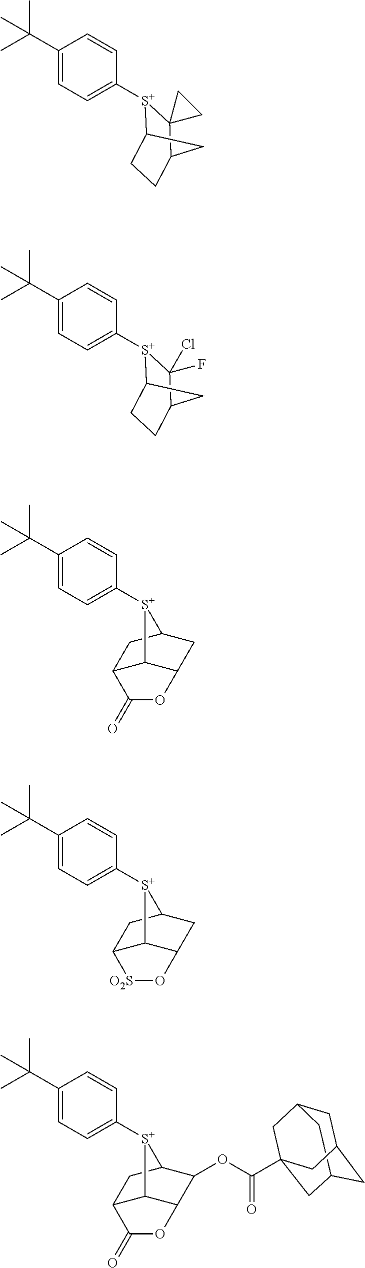 [SMILES: CC(C)(C)c1ccc([S+]2C3CCC(C3)C23CC3)cc1 ; CC(C)(C)c1ccc([S+]2C3CCC(C3)C2(F)Cl)cc1 ; CC(C)(C)c1ccc([S+]2C3CC4OC(=O)C(C3)C42)cc1 ; CC(C)(C)c1ccc([S+]2C3CC4OS(=O)(=O)C(C3)C42)cc1 ; CC(C)(C)c1ccc([S+]2C3CC4C(=O)OC(C3OC(=O)C35CC6CC(CC(C6)C3)C5)C42)cc1]

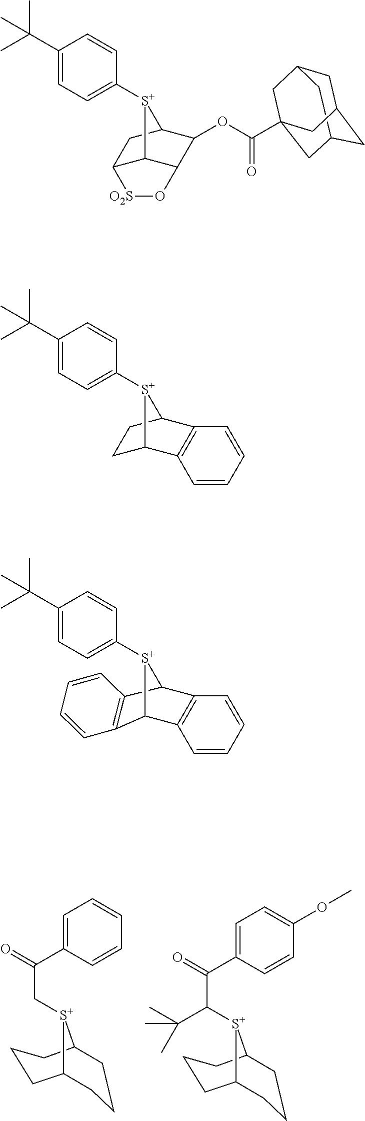 [SMILES: CC(C)(C)c1ccc([S+]2C3CC4C2C(OS4(=O)=O)C3OC(=O)C23CC4CC(CC(C4)C2)C3)cc1 ; CC(C)(C)c1ccc([S+]2C3CCC2c2ccccc23)cc1 ; CC(C)(C)c1ccc([S+]2C3c4ccccc4C2c2ccccc23)cc1 ; O=C(C[S+]1C2CCCC1CCC2)c1ccccc1 ; COc1ccc(C(=O)C([S+]2C3CCCC2CCC3)C(C)(C)C)cc1]

Examples of the iodonium cation having formula (cation-2) are shown below, but not limited thereto.

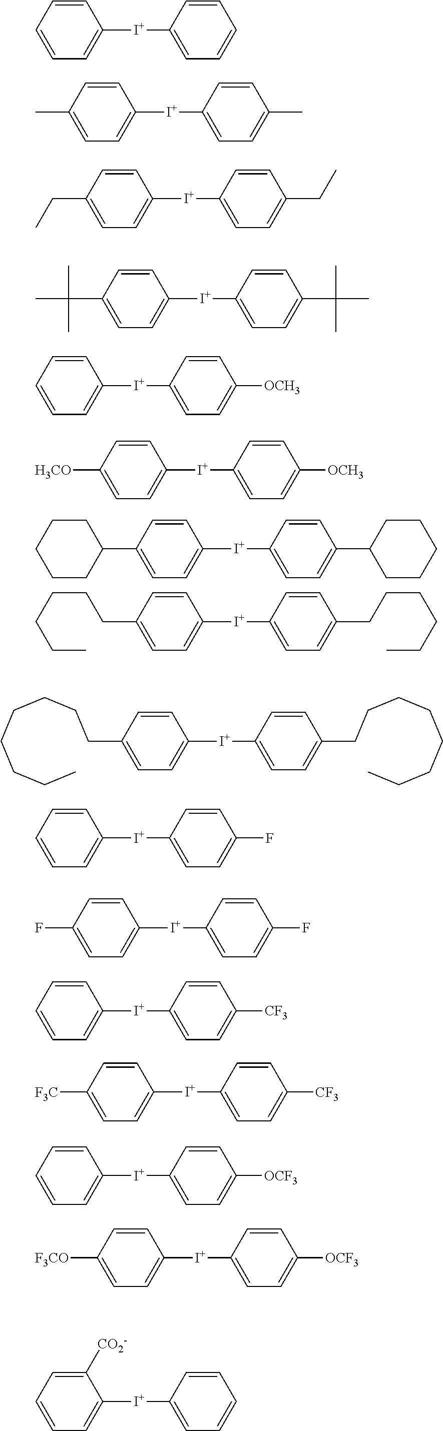

Illustrative strictures of the repeat units having formulae (C1) to (C4) include arbitrary combinations of anions with cations, both exemplified above.

Of the repeat units C, repeat units C2, C3 and C4 are preferred in view of acid diffusion control, repeat units C2 and C4 are more preferred in view of the strength of generated acid, and repeat units C2 are most preferred in view of solvent solubility.

The polymer in the chemically amplified resist composition is characterized by comprising repeat units having an acid labile group containing a fluorinated aromatic ring, repeat units having a phenolic hydroxy group, and repeat units adapted to generate an acid upon exposure. Upon exposure, the repeat unit having a phenolic hydroxy group generates secondary electrons, which are effectively conducted to the cation at the acid generating site whereby the sulfonium or iodonium cation is decomposed to generate the corresponding acid. Since the generated acid is bound to the polymer backbone, no excessive acid diffusion occurs. Also, the repeat unit having an acid labile group containing a fluorinated aromatic ring forms a stable tertiary benzyl cation after elimination reaction. Since the tertiary benzyl cation is more stable than carbo cations eliminated from ordinary acid labile groups of tertiary ester type, it is higher in acid-catalyzed reactivity. As a result, the resist film exhibits a high dissolution contrast in developer and is improved in sensitivity. Since the introduction of an acid labile group containing a fluorinated aromatic ring increases the concentration of fluorine in the polymer, the polymer increases its solubility in solvent and ensures uniform dissolution, substantially preventing polymer chains from agglomerating together. The synergy effect of three repeat units makes it possible to form patterns with a high sensitivity, high contrast, and improved LWR (of line patterns) or improved CDU (of hole patterns).

The polymer P may further comprise repeat units of at least one type selected from repeat units having the formula (a1) and repeat units having the formula (a2). These units are also referred to as repeat units (a1) and (a2), respectively.

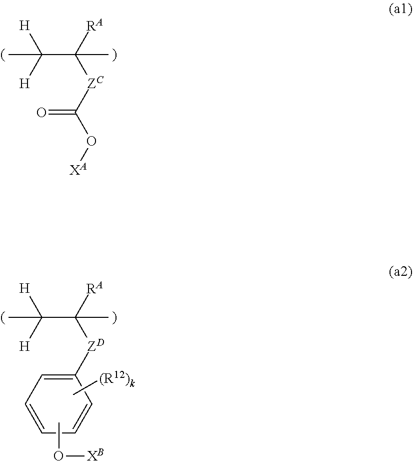

In formulae (a1) and (a2), R^{A} is as defined above. Z^{C} is a single bond, phenylene group, naphthylene group or *—C(═O)—O—Z^{C1}—, wherein Z^{C1} is a C₁-C₂₀ saturated hydrocarbylene group which may contain a hydroxy moiety, ether bond, ester bond or lactone ring, or a phenylene or naphthylene group. Z^{D} is a single bond or *—C(═O)—O—. The asterisk (*) designates a point of attachment to the carbon atom in the backbone. R¹² is a C₁-C₂₀ hydrocarbyl group which may contain a heteroatom. X^{A} and X^{B} are each independently an acid labile group free of fluorinated aromatic ring, and k is an integer of 0 to 4.

The acid labile groups represented by X^{A} and X^{B} in formulae (a1) and (a2) may be selected from a variety of such groups, for example, those groups described in JP A 2013-080033 (U.S. Pat. No. 8,574,817) and JP-A 2013-083821 (U.S. Pat. No. 8,846,303).

Typical of the acid labile group are groups of the following formulae (AL-1) to (AL-3).

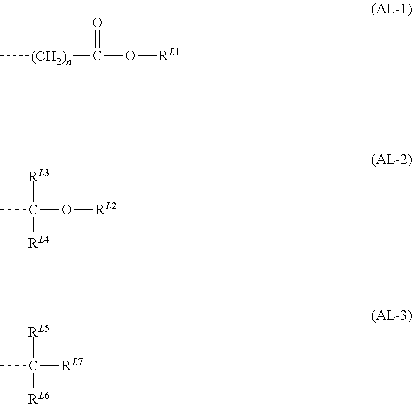

In formulae (AL-1) and (AL-2), R^{L1} and R^{L2} are each independently a C₁-C₄₀ saturated hydrocarbyl group which may contain a heteroatom such as oxygen, sulfur, nitrogen or fluorine. The saturated hydrocarbyl group may be straight, branched or cyclic. Preferred are C₁-C₂₀ saturated hydrocarbyl groups.

In formula (AL-1), “a” is an integer of 0 to 10, preferably 1 to 5.

In formula (AL-2), R^{L3} and R^{L4} are each independently hydrogen or a C₁-C₂₀ saturated hydrocarbyl group which may contain a heteroatom such as oxygen, sulfur, nitrogen or fluorine. The hydrocarbyl group may be straight, branched or cyclic. Any two of R^{L2}, R^{L3} and R^{L4} may bond together to form a C₃-C₂₀ ring with the carbon atom or carbon and oxygen atoms to which they are attached, the ring being preferably of 4 to 16 carbon atoms and more preferably alicyclic.

In formula (AL-3), R^{L5}, R^{L6} and R^{L7} are each independently a C₁-C₂₀ saturated hydrocarbyl group which may contain a heteroatom such as oxygen, sulfur, nitrogen or fluorine. The hydrocarbyl group may be straight, branched or cyclic. Any two of R^{L5}, R^{L6} and R^{L7} may bond together to form a C₃-C₂₀ ring with the carbon atom to which they are attached, the ring being preferably of 4 to 16 carbon atoms and more preferably alicyclic.

Examples of the repeat unit (a1) are shown below, but not limited thereto. R^{A} and X^{A} are as defined above.

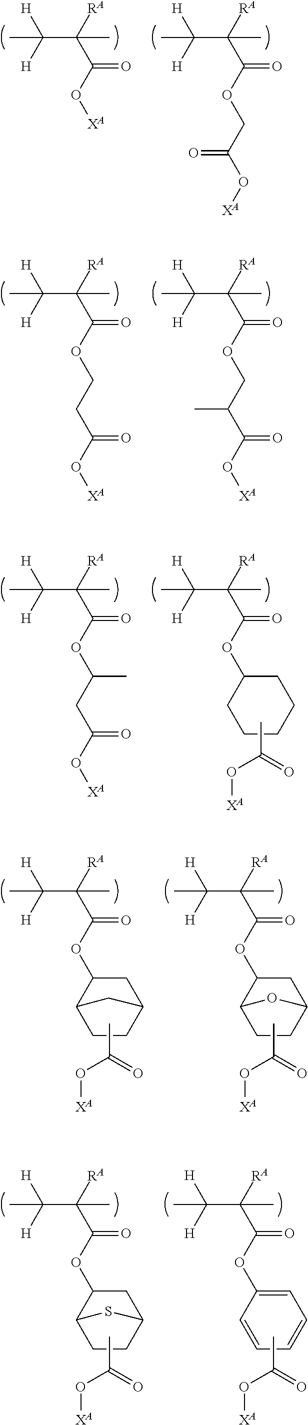

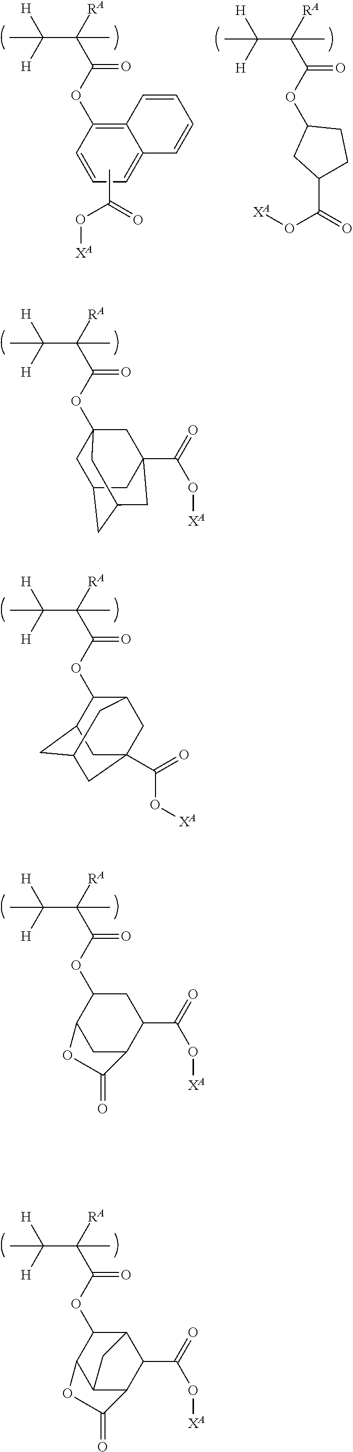

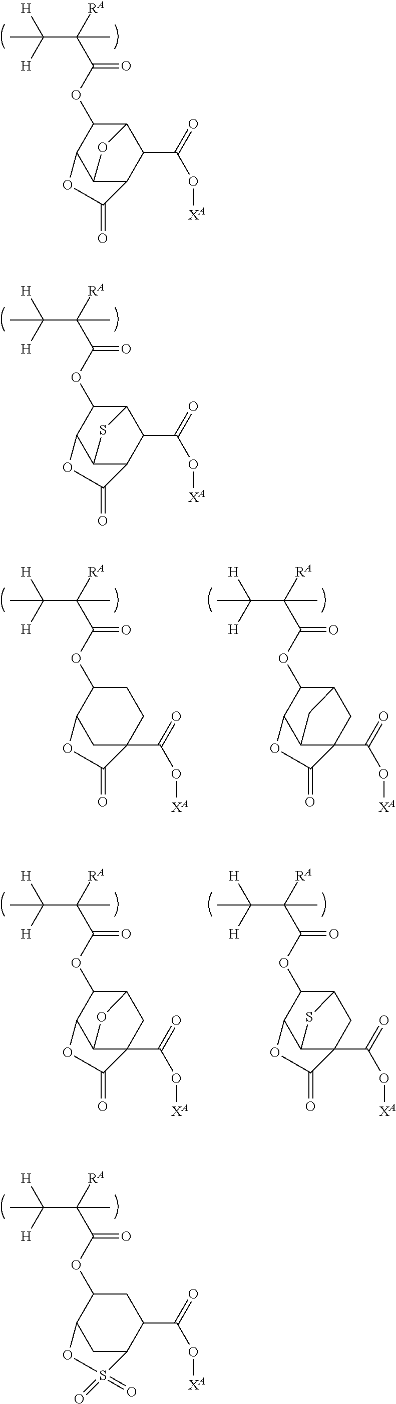

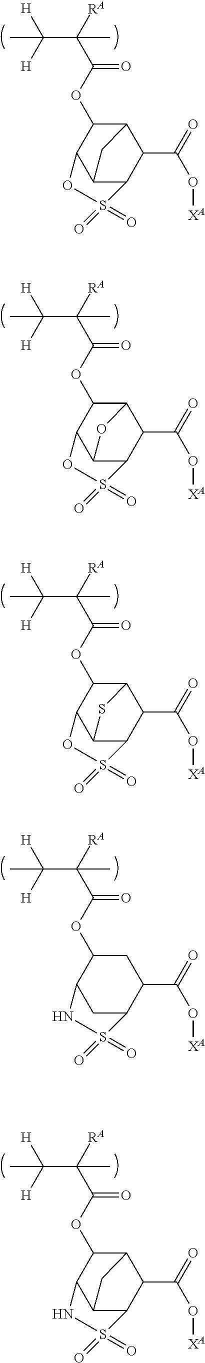

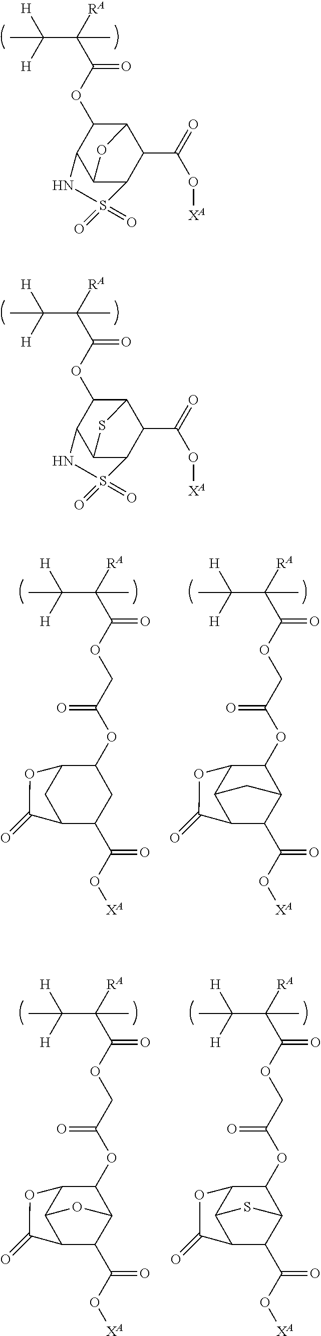

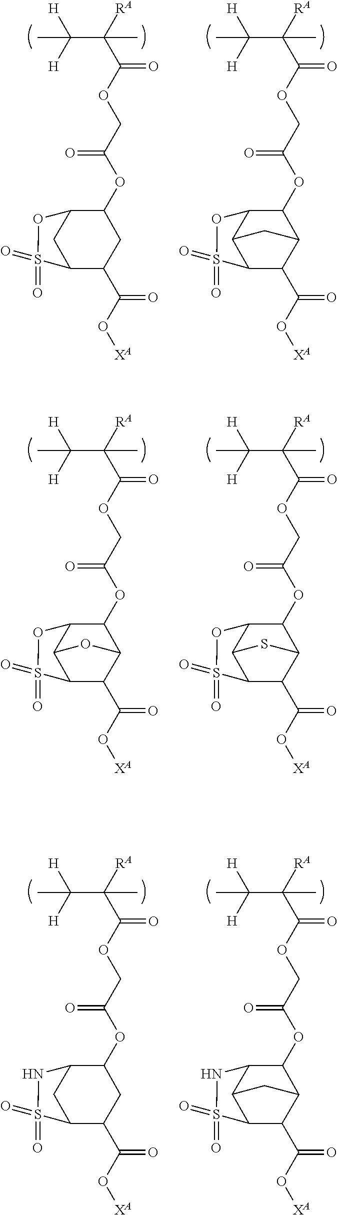

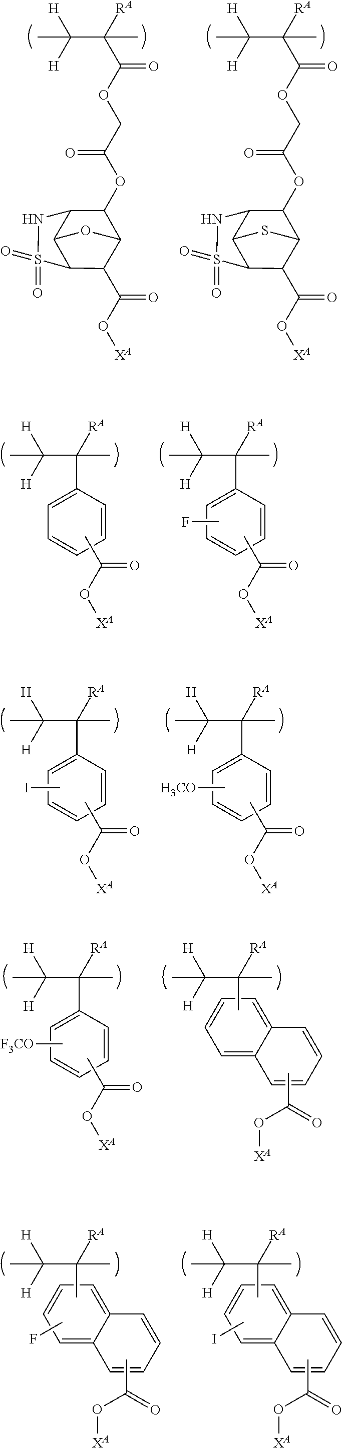

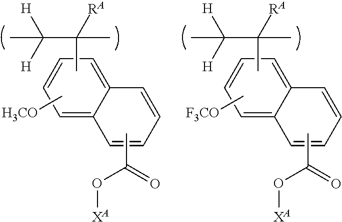

Examples of the repeat unit (a2) are shown below, but not limited thereto. R^{A} and X^{B} are as defined above.

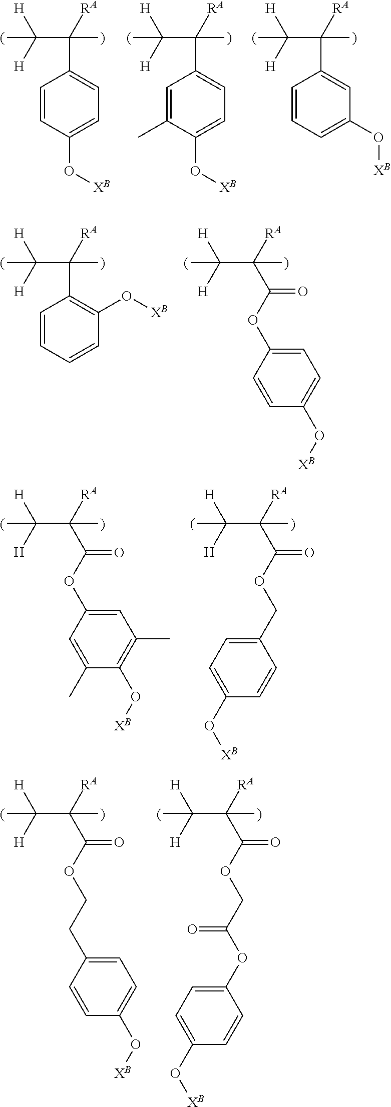

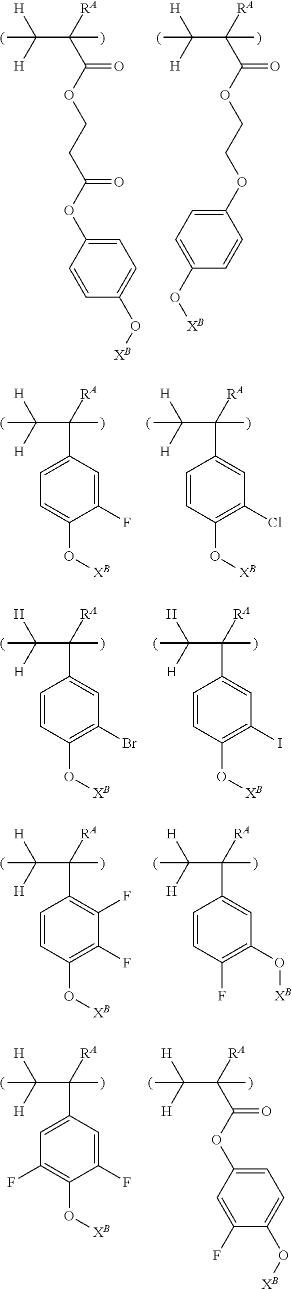

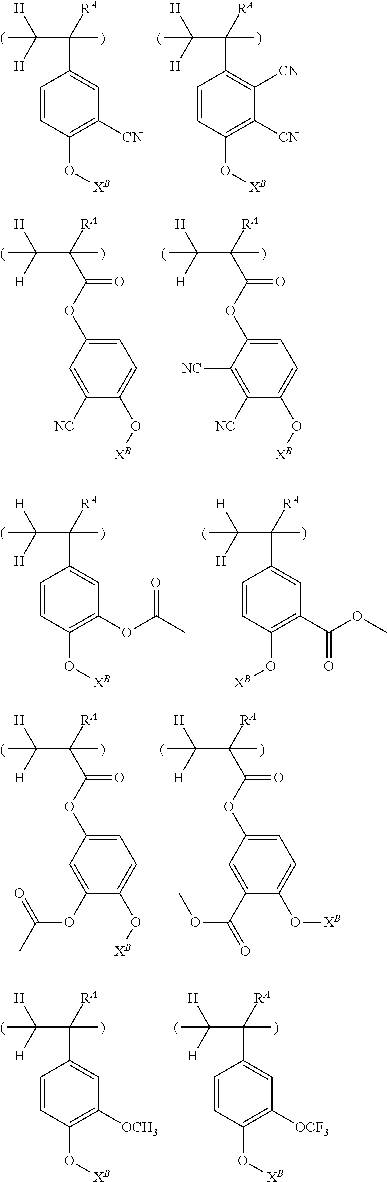

The polymer P may further comprise repeat units having the formula (D1), referred to as repeat units D.

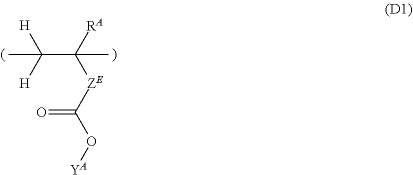

In formula (D1), R^{A} is as defined above. Z^{E} is a single bond, phenylene group, naphthylene group or *—C(═O)—O—Z^{E1}—, wherein Z^{E1} is a C₁-C₂₀ saturated hydrocarbylene group which may contain a hydroxy moiety, ether bond, ester bond or lactone ring, or a phenylene or naphthylene group. The asterisk (*) designates a point of attachment to the carbon atom in the backbone. Y^{A} is hydrogen or a polar group containing at least one moiety selected from the group consisting of hydroxy, cyano, carbonyl, carboxy, ether bond, ester bond sulfonic ester bond, carbonate bond, lactone ring, sultone ring, and carboxylic anhydride (—C(═O)—O—C(═O)—).

Examples of repeat unit D are shown below, but not limited thereto. R^{A} is as defined above.

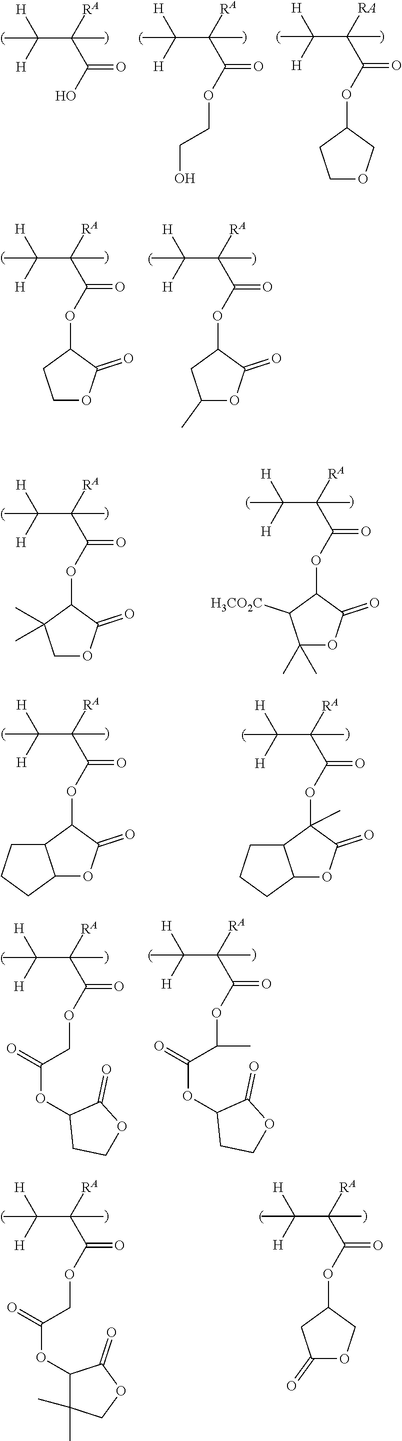

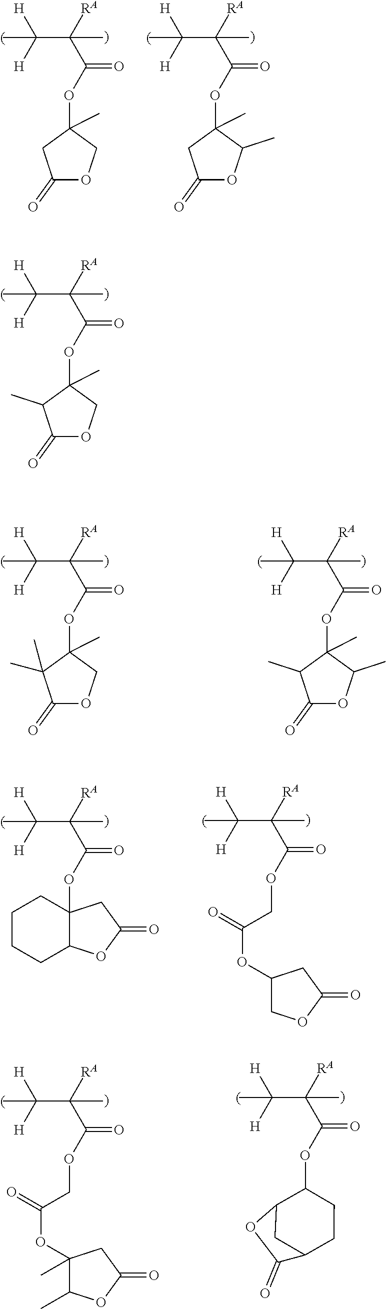

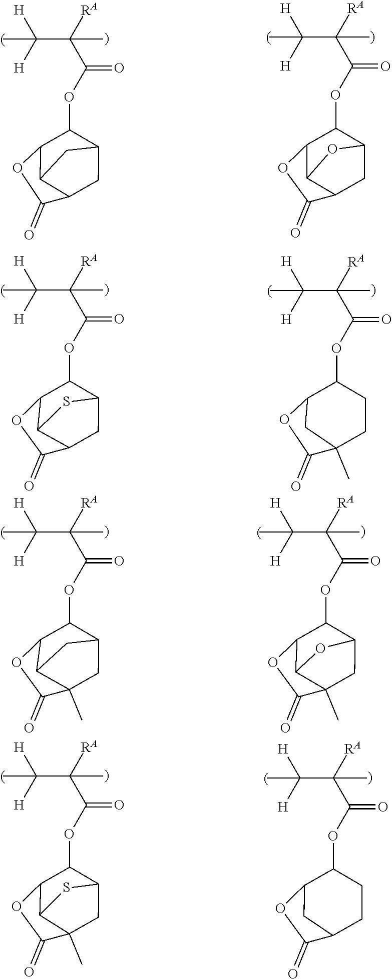

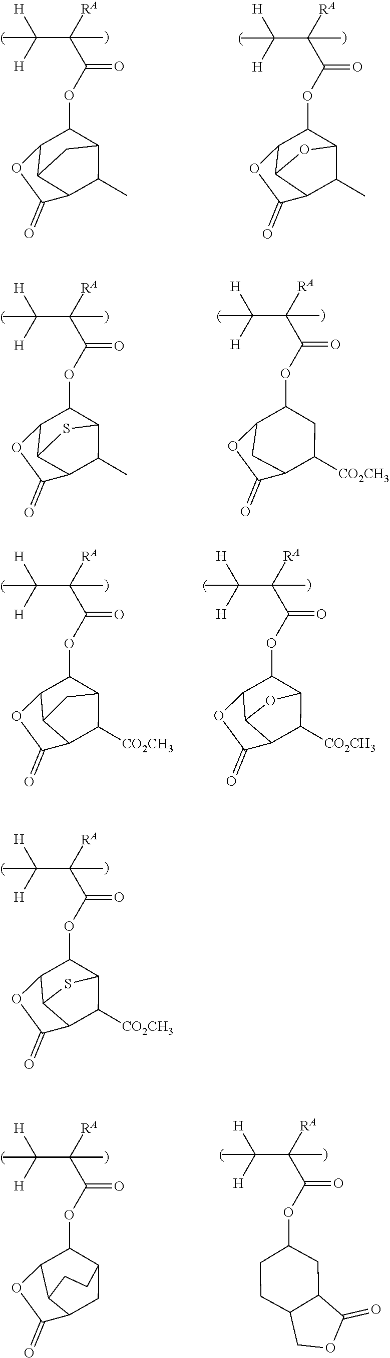

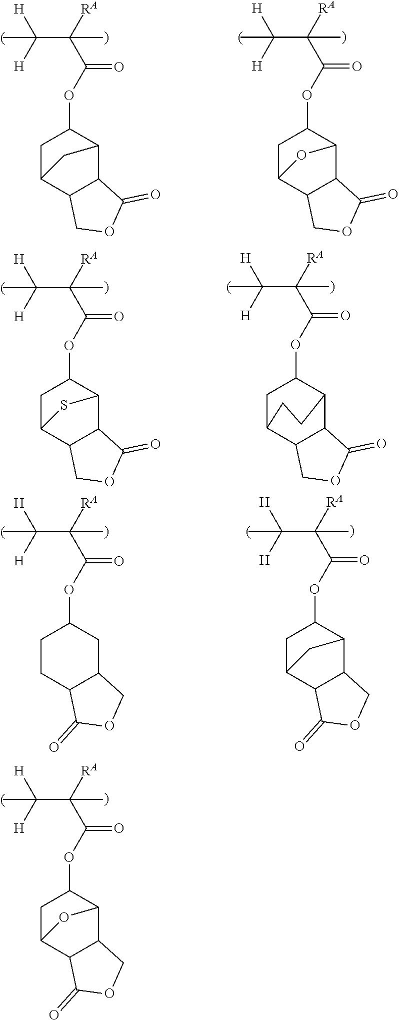

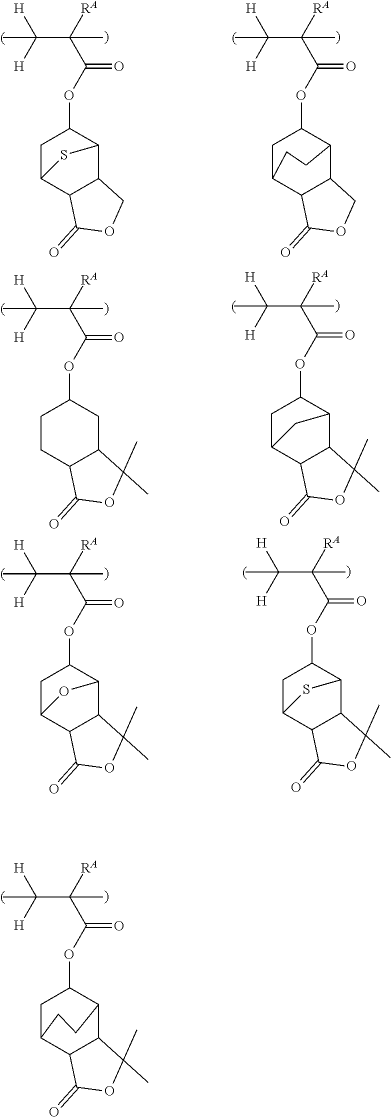

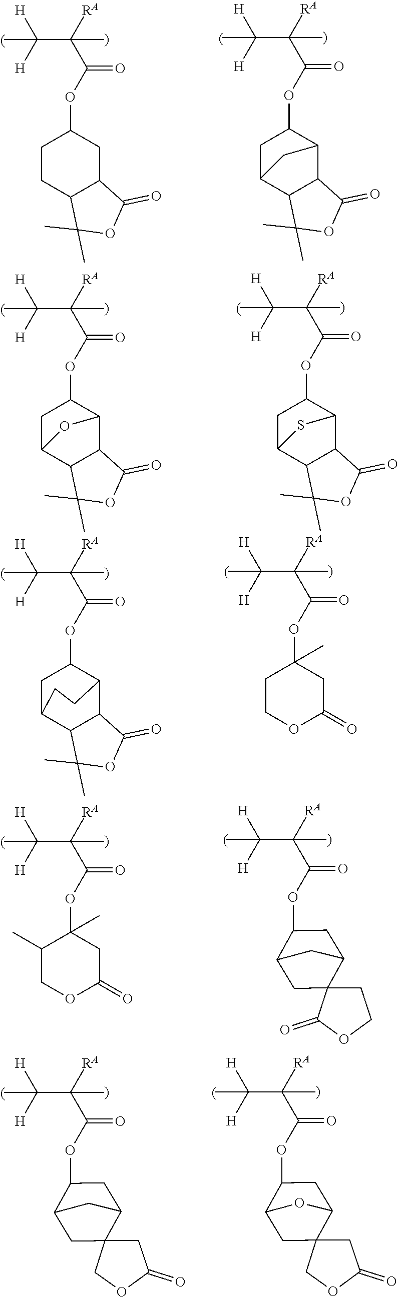

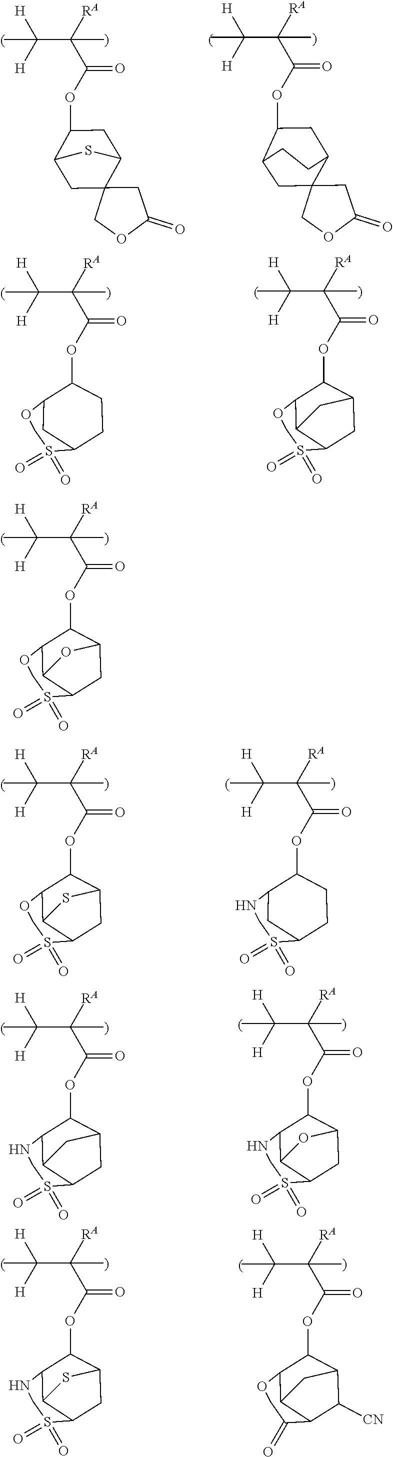

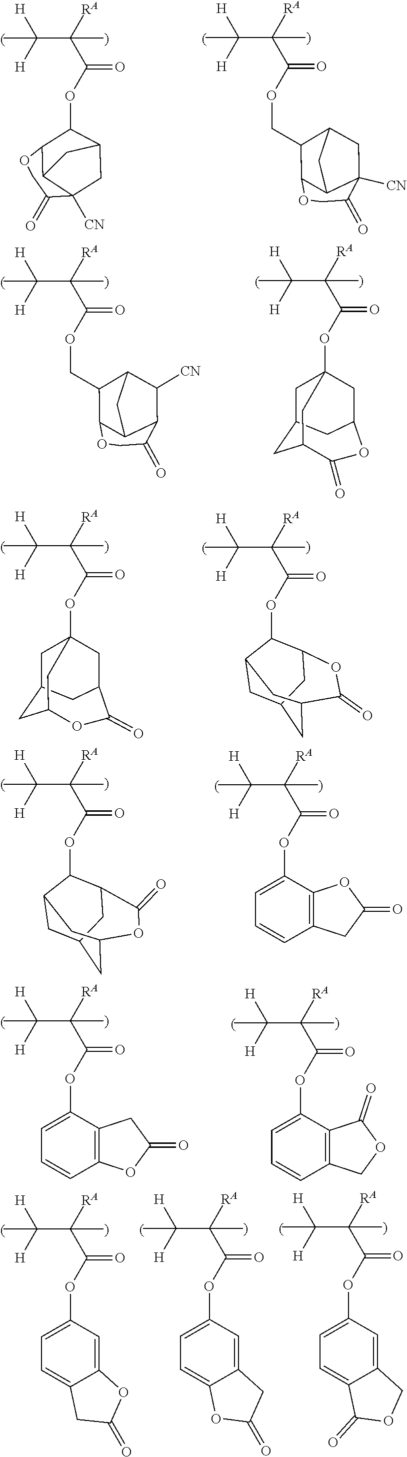

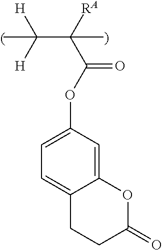

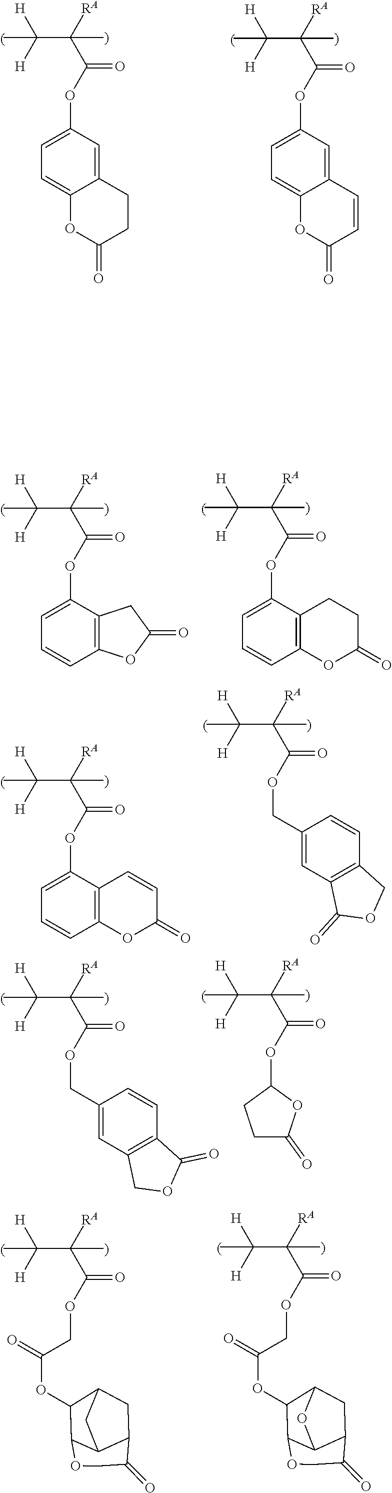

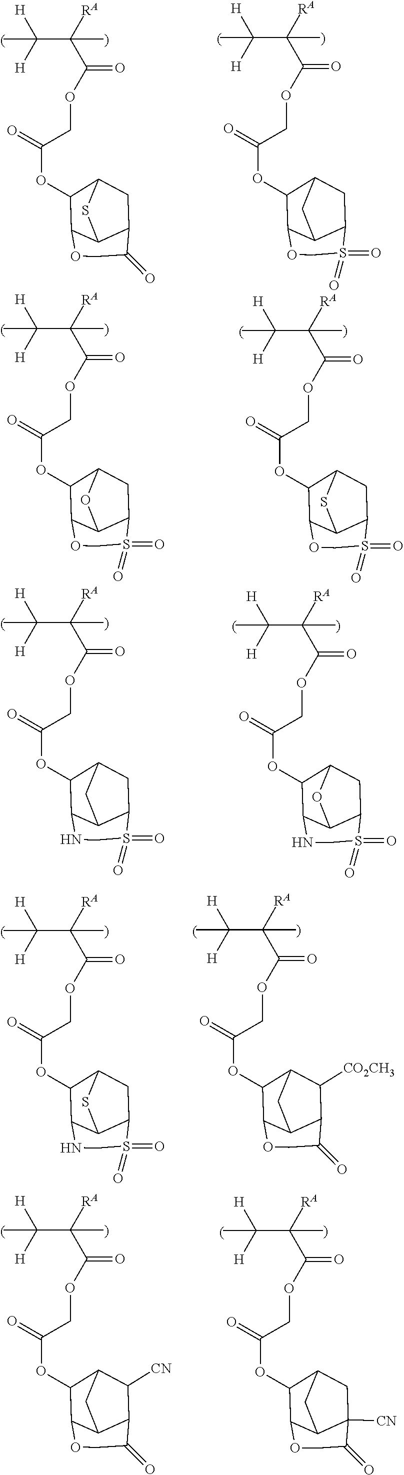

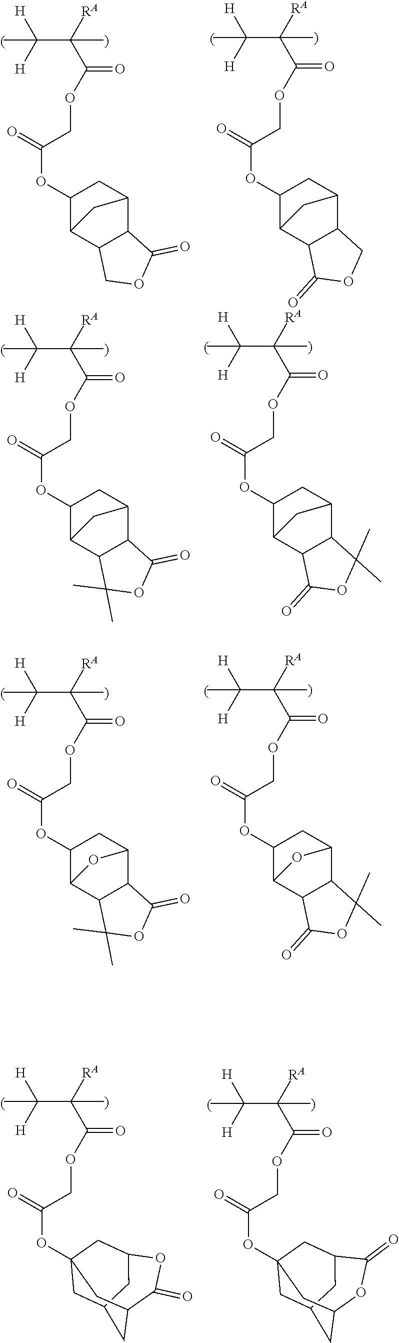

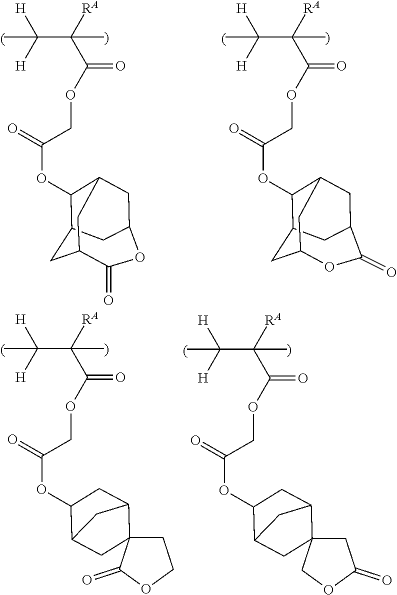

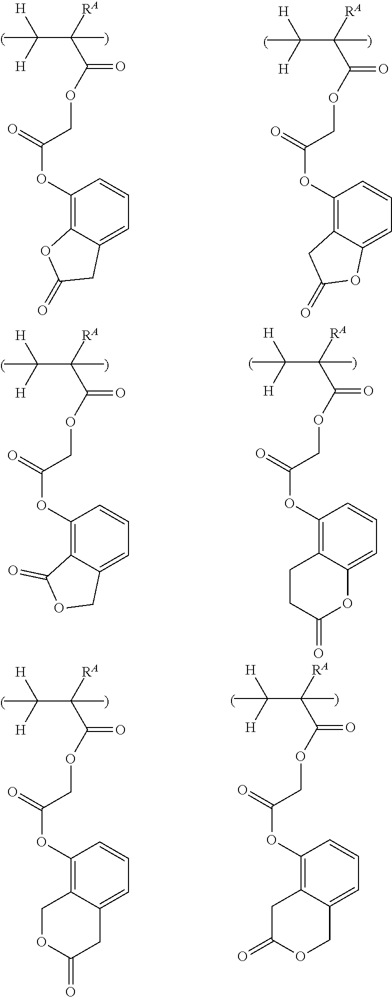

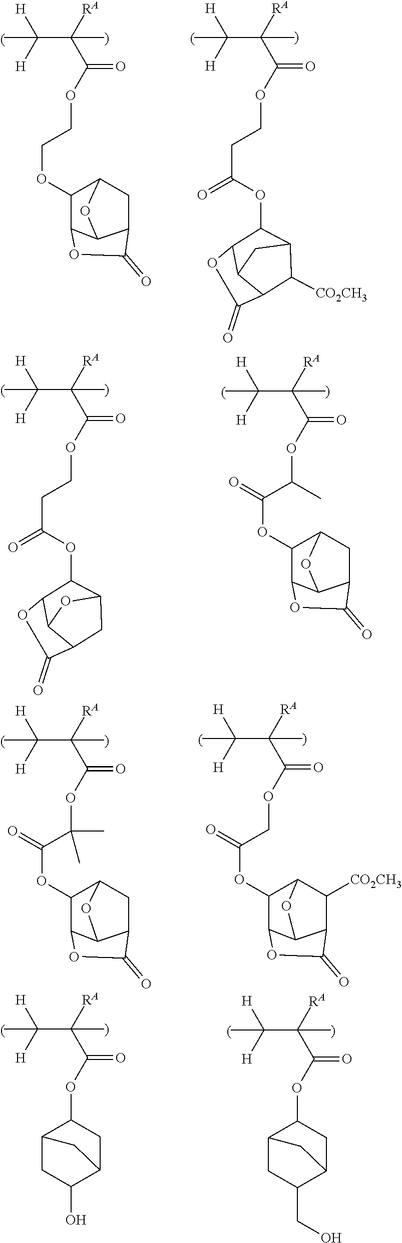

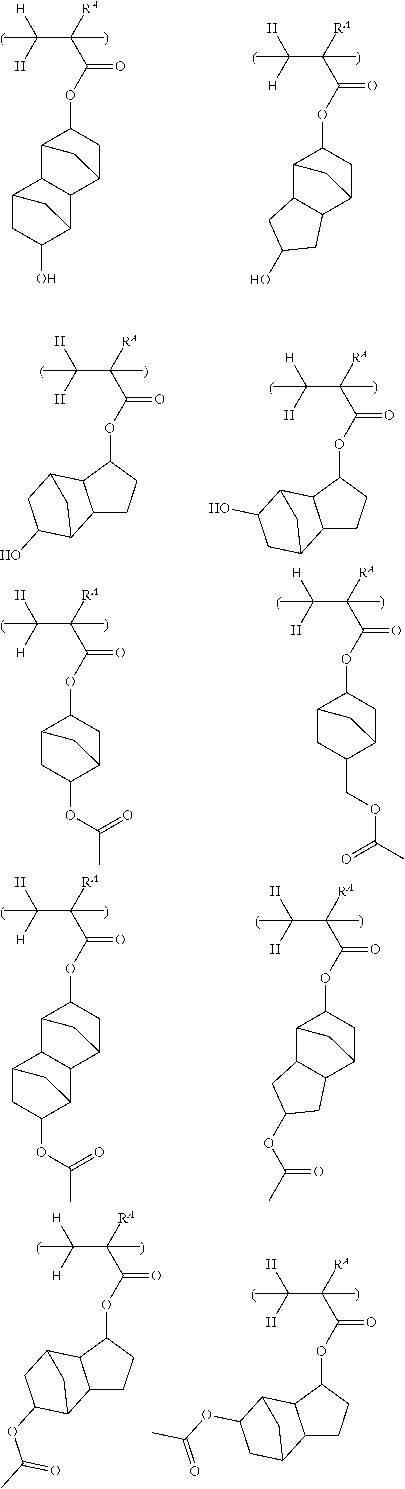

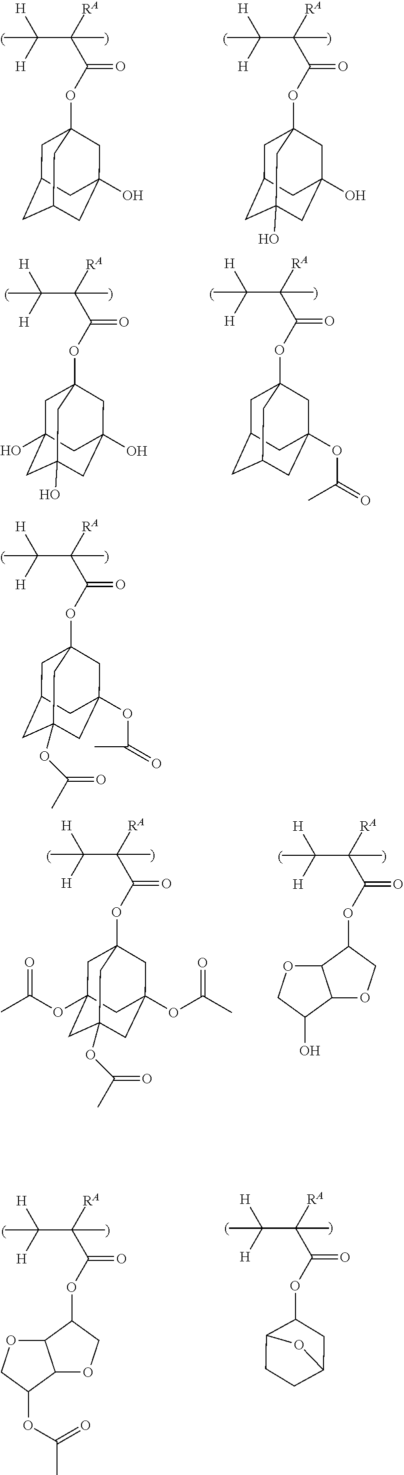

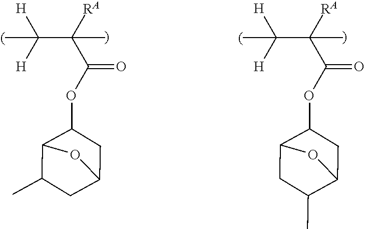

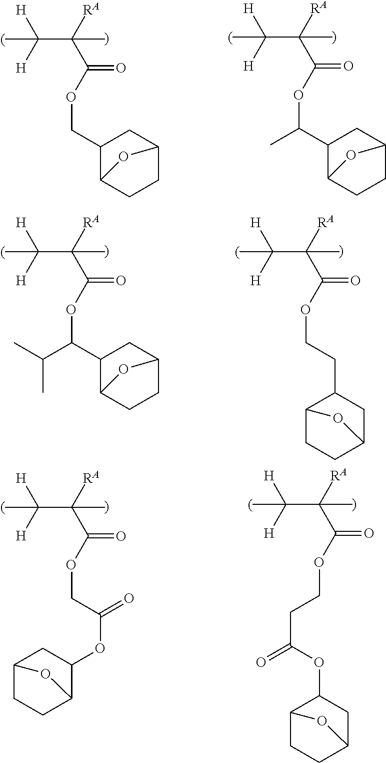

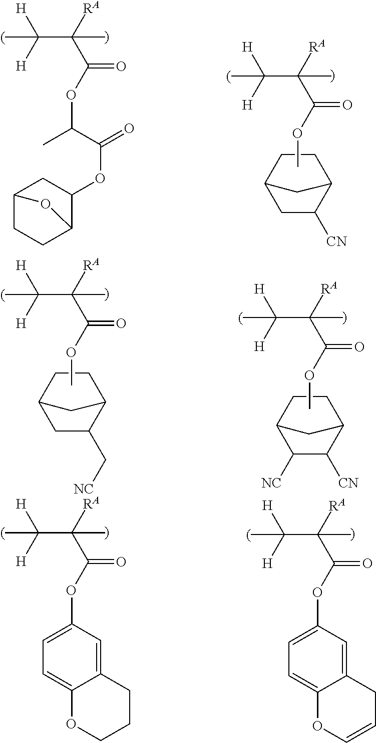

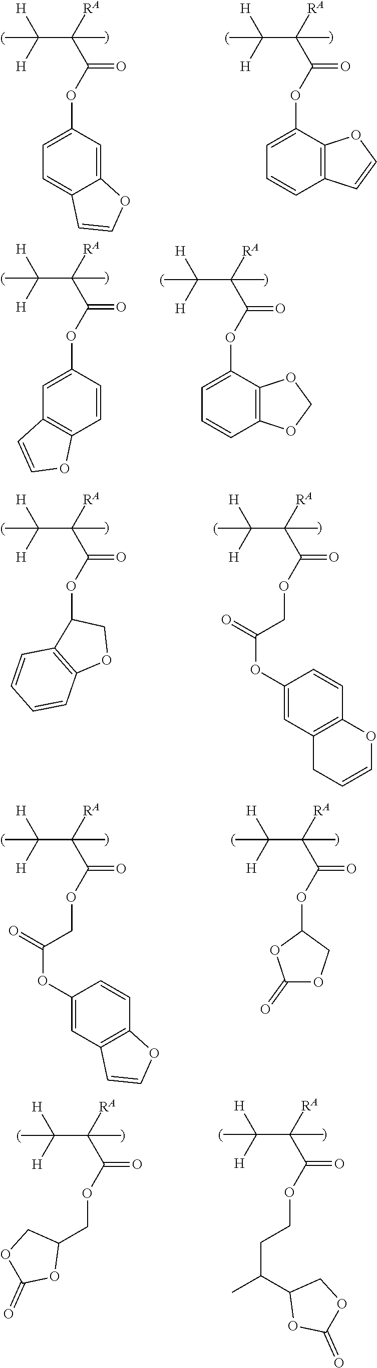

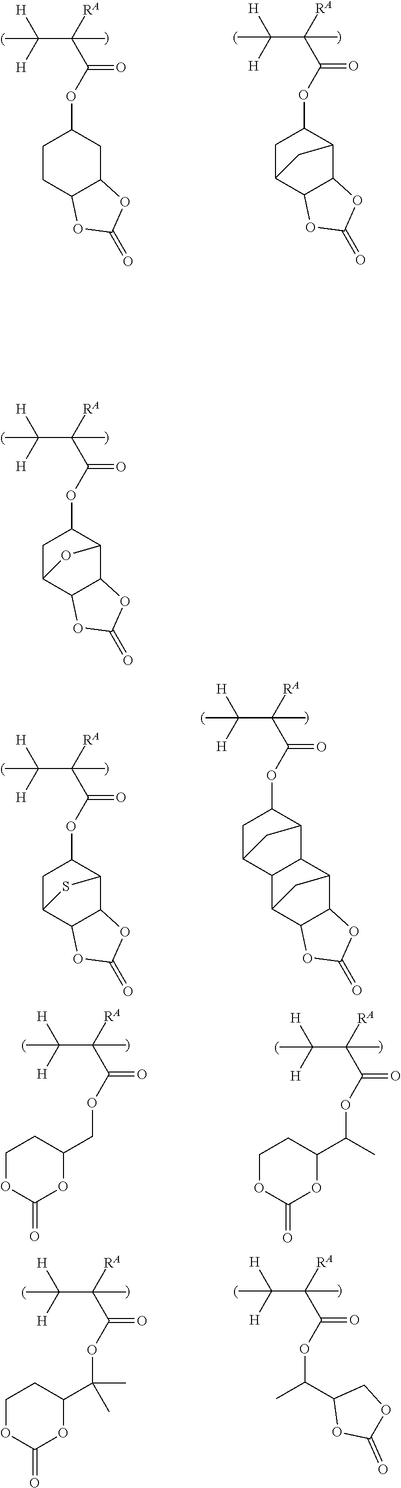

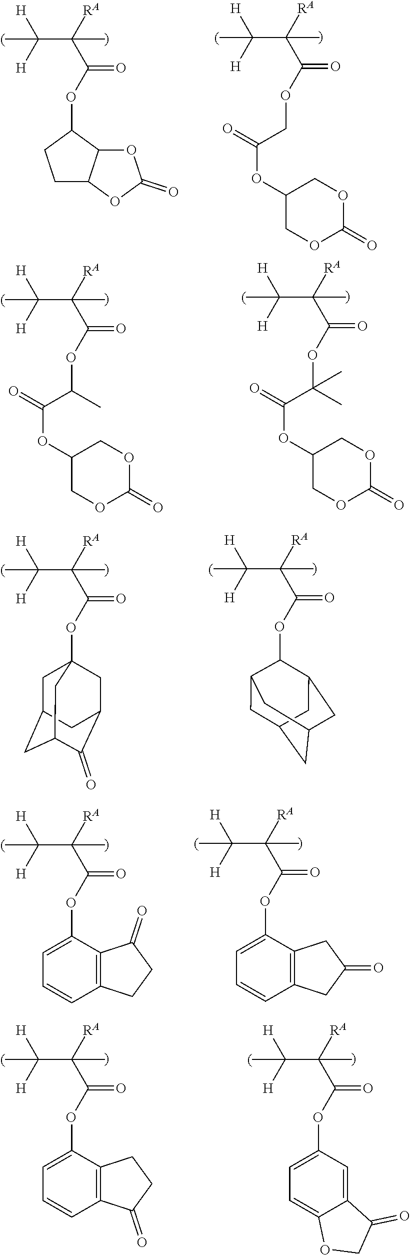

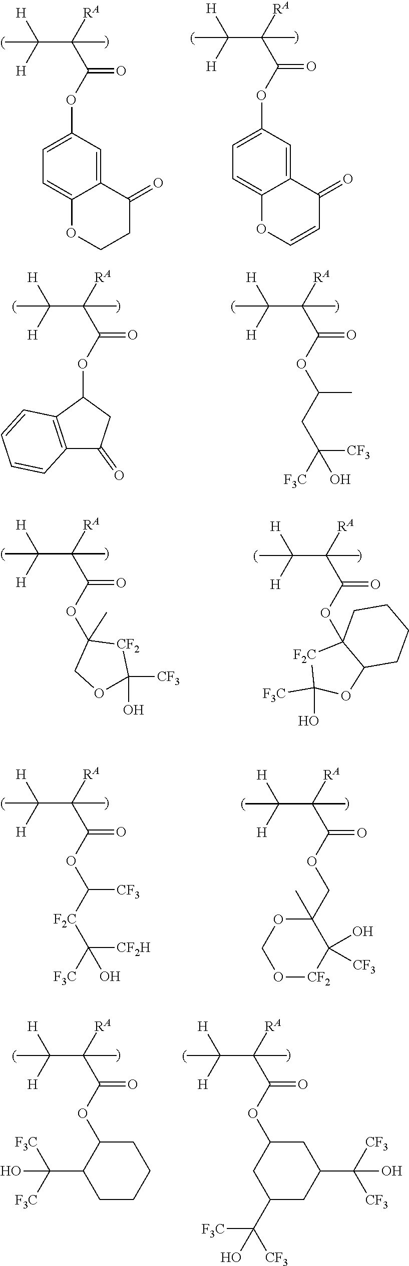

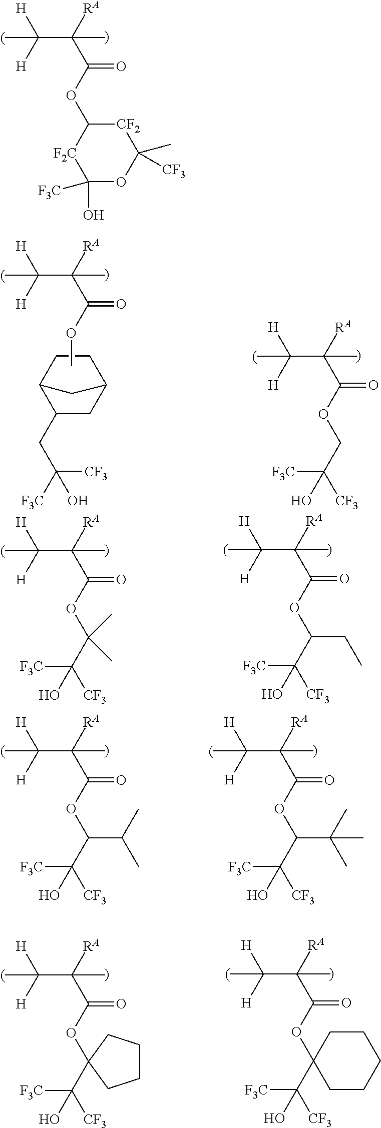

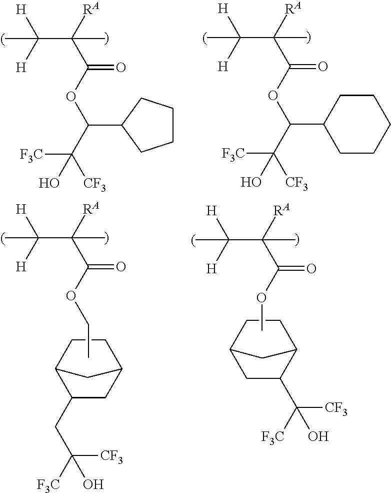

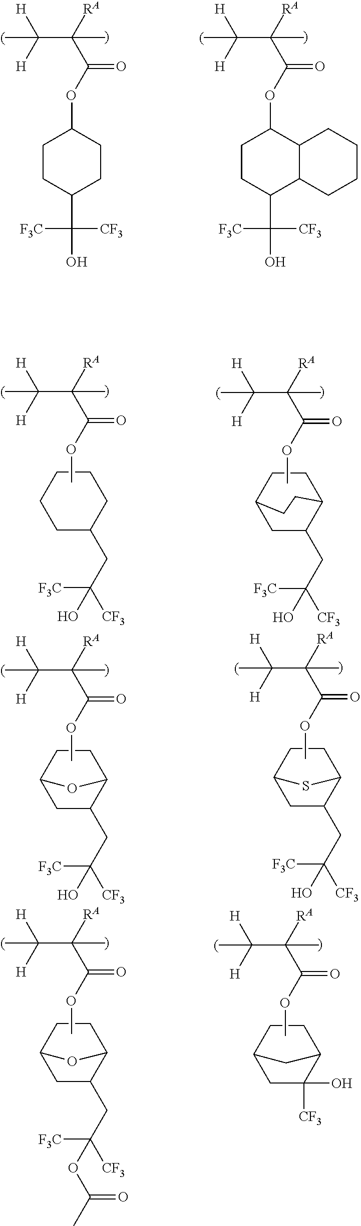

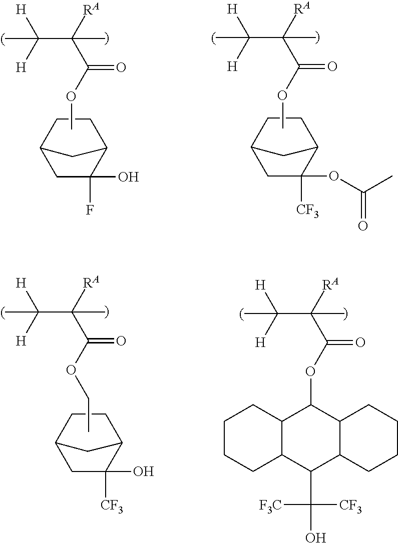

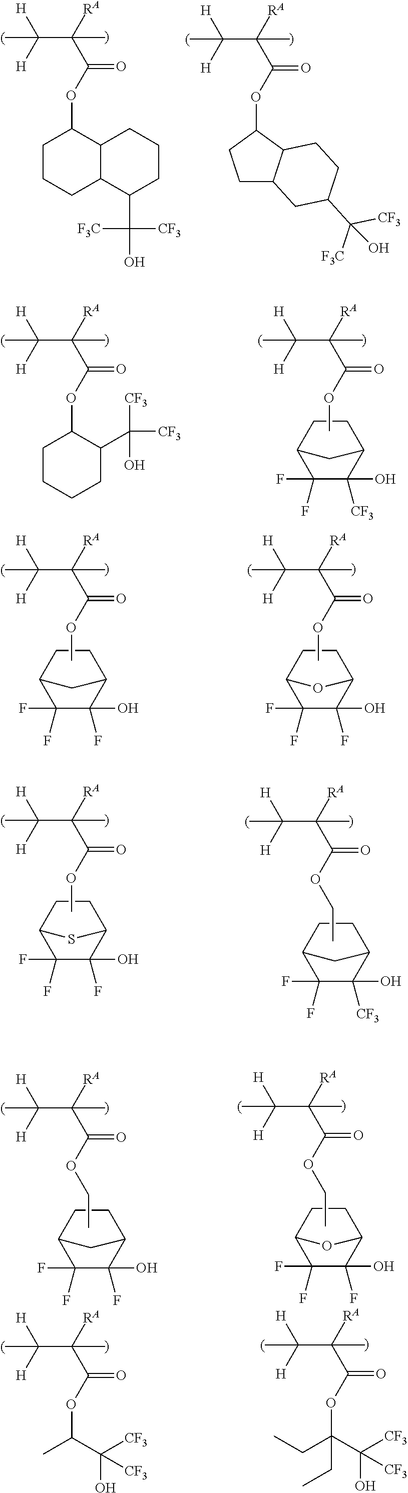

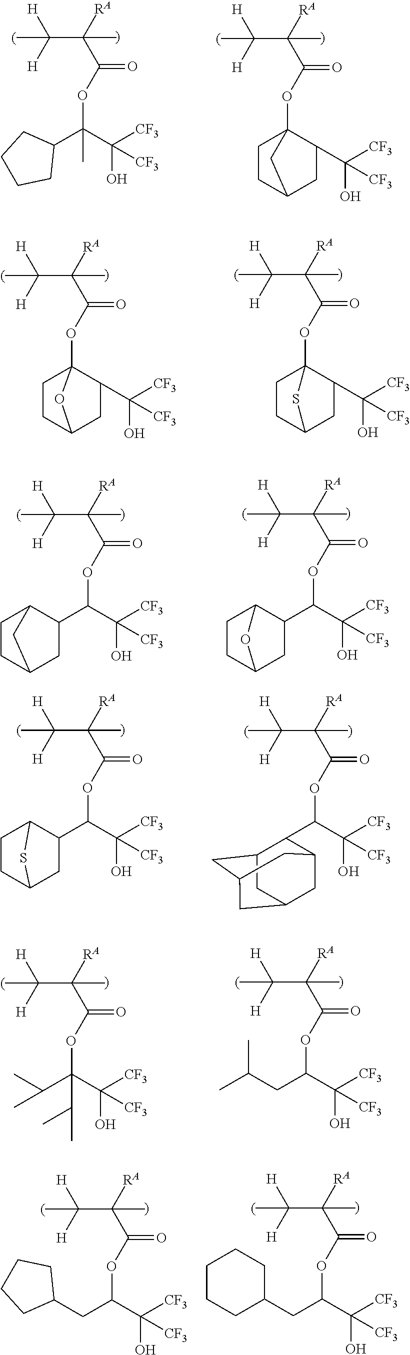

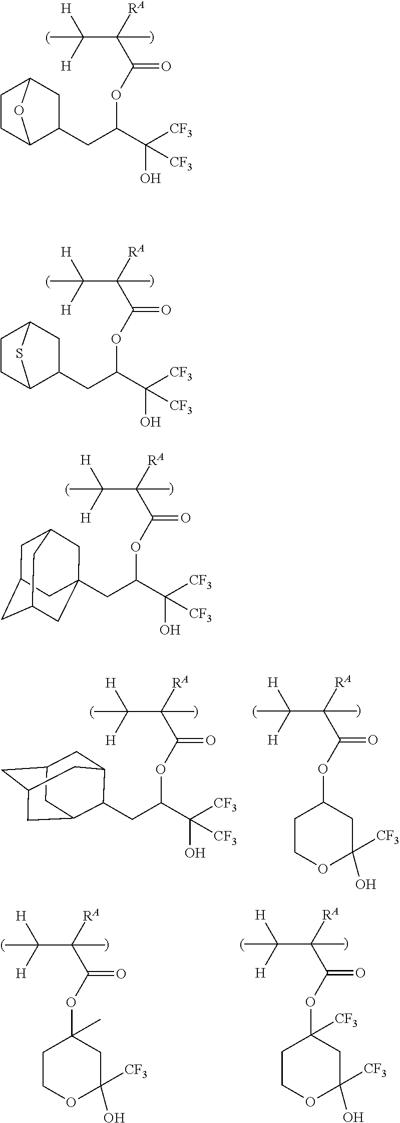

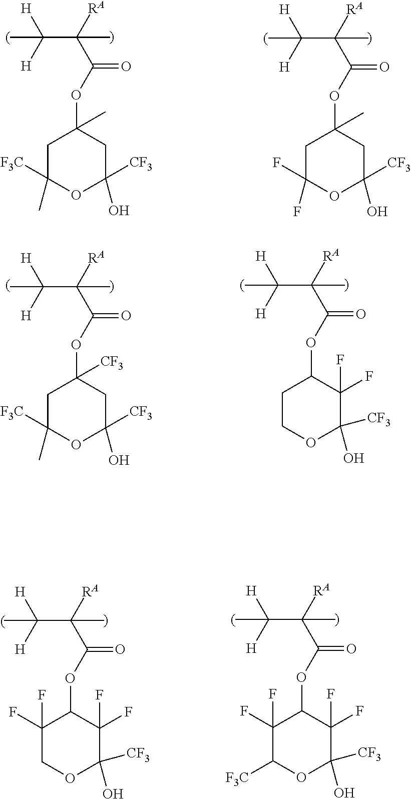

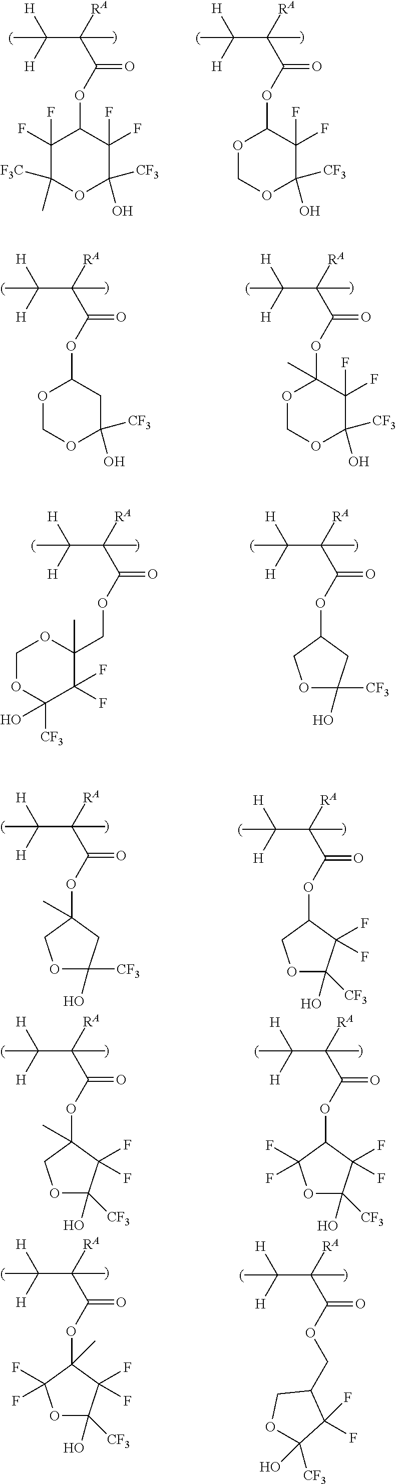

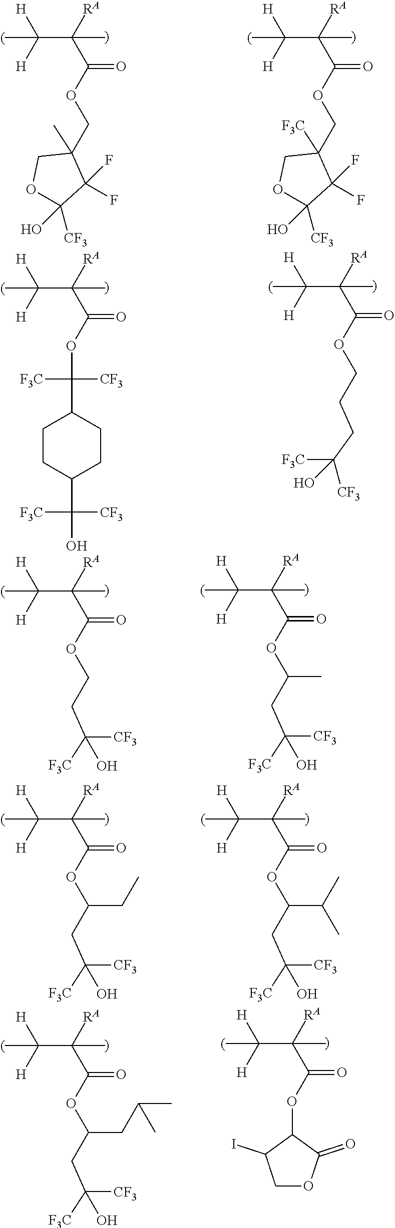

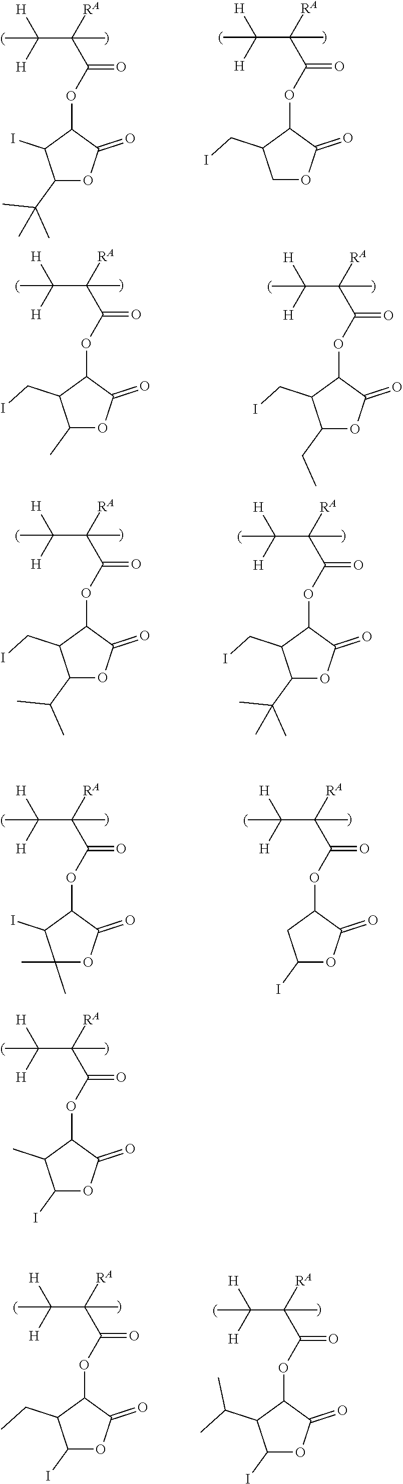

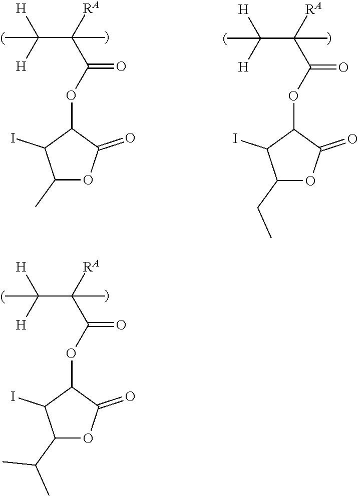

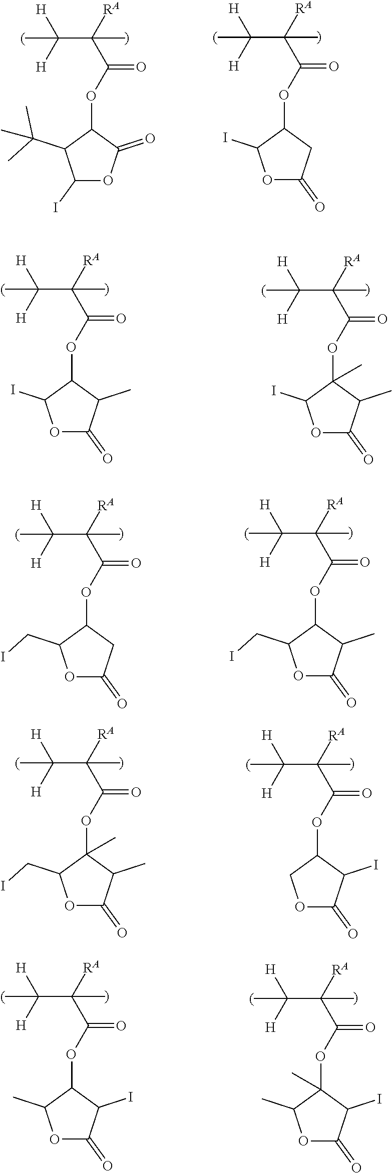

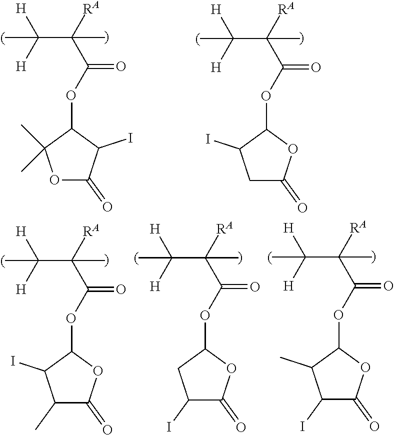

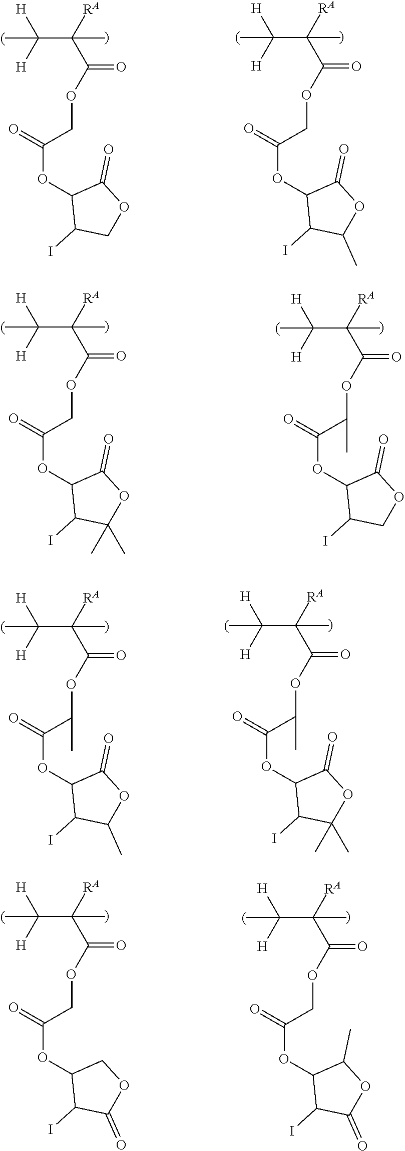

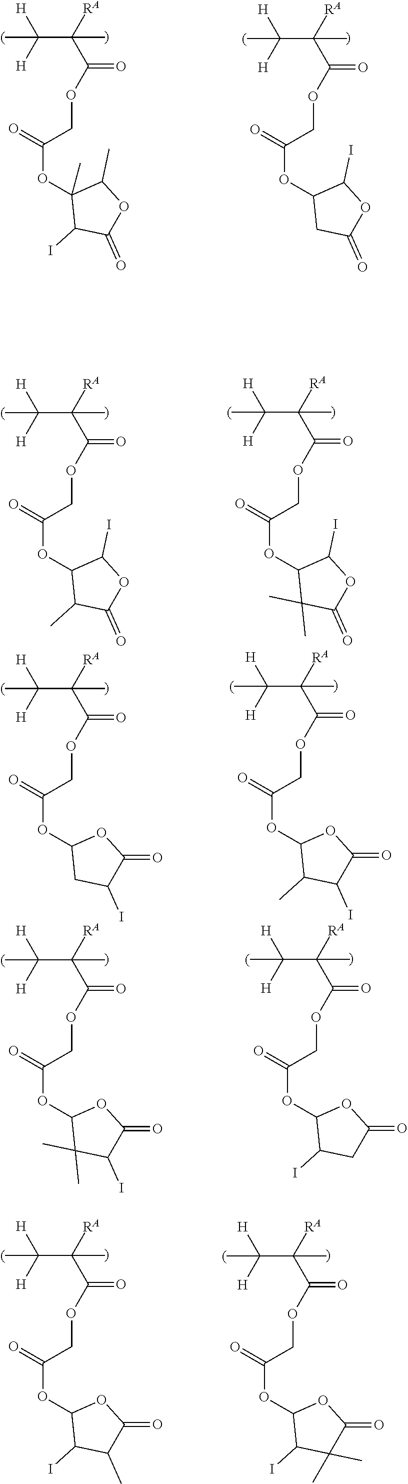

The polymer P may further comprise repeat units E derived from indene, benzofuran, benzothiophene, acenaphthylene, chromone, coumarin, norbornadiene, or derivatives thereof. Examples of suitable monomers from which repeat units E are derived are given below, but not limited thereto.

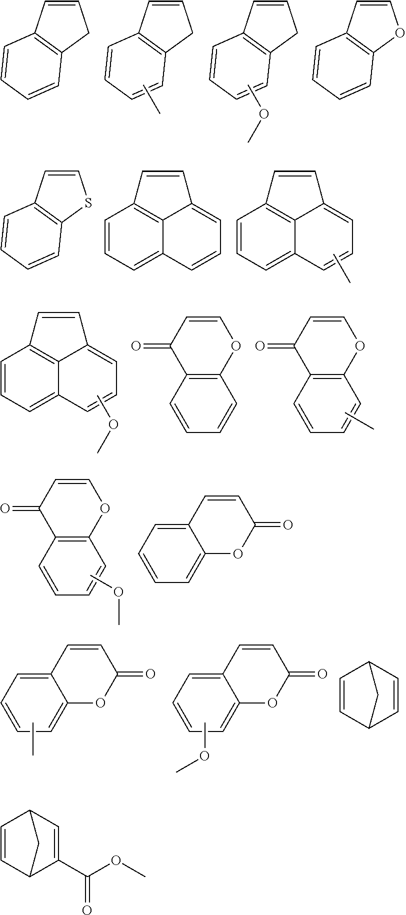

The polymer P may further comprise repeat units F derived from indane, vinylpyridine or vinylcarbazole.

While the polymer comprises repeat units A, a1, a2, B, C, D, E and F, a function of units is: preferably 0<A<1.0·0≤a1≤0.8, 0≤a2≤0.8, 0<B<1.0, 0<C<1.0, 0≤D≤0.8, 0≤E≤0.8, and 0≤F≤0.4;

more preferably 0.05≤A≤0.9, 0≤a1≤0.7, 0≤a2≤0.7, 0≤a1+a2≤0.7, 0.09≤B≤0.55, 0.01≤C≤0.4, 0≤D≤0.7, 0≤E≤0.7, and 0≤F≤0.3;
even more preferably 0.1≤A≤0.8, 0≤a1≤0.6, 0≤a2≤0.6, 0≤a1+a2≤0.4, 0.1≤B≤0.45, 0.1≤C≤0.45, 0≤D≤0.6, 0≤E≤0.6, and 0≤F≤0.2. Notably, C=C1+C2+C3+C4, meaning that unit C is at least one of units C1 to C4, and A+a1+a2+B+C+D+E+F=1.

The polymer P should preferably have a weight average molecular weight (Mw) in the range of 1,000 to 500,000, and more preferably 3,000 to 100,000, as measured by GPC versus polystyrene standards using tetrahydrofuran (THF) or N,N-dimethylformamide (DMF) solvent. A polymer having the range of Mw provides sufficient etching resistance and eliminates the risk of resolution lowering from a failure to establish a difference in dissolution rate before and after exposure.

If a polymer has a wide molecular weight distribution or dispersity (Mw/Mn), which indicates the presence of lower and higher molecular weight polymer fractions, there is a possibility that foreign matter is left on the pattern or the pattern profile is degraded. The influence of Mw/Mn becomes stronger as the pattern rule becomes finer. Therefore, the polymer should preferably have a narrow dispersity (Mw Mn) of 1.0 to 2.0 in order to provide a resist composition suitable for micropatterning to a cumin feature size.

The polymer may be synthesized by any desired methods, for example, by dissolving monomers corresponding to the foregoing repeat units in an organic solvent, adding a radical polymerization initiator thereto, and heating for polymerization. Examples of the organic solvent which can be used for polymerization include toluene, benzene, tetrahydrofuran (THF), diethyl ether, dioxane, cyclohexane, cyclopentane, methyl ethyl ketone (MEK), propylene glycol monomethyl ether acetate (PGMEA), and γ-butyrolactone (GBL). Examples of the polymerization initiator used herein include 2,2′-azobisisobutyronitrile (AIBN), 2,2′-azobis(2,4-dimethylvaleronitrile), dimethyl 2,2-azobis(2-methylpropionate), 1,1′-azobis(1-acetoxy-1-phenylethane), benzoyl peroxide, and lauroyl peroxide. The initiator is preferably added in an amount of 0.01 to 25 mol % based on the total of monomers. Preferably, the polymerization temperature is 50 to 150° C., more preferably 60 to 100° C., and the reaction time is 2 to 24 hours, more preferably 2 to 12 hours in view of production efficiency.

The polymerization initiator may be fed to the reactor either by adding the initiator to the monomer solution and feeding the solution to the reactor, or by dissolving the initiator in a solvent to form an initiator solution and feeding the initiator solution and the monomer solution independently to the reactor. Because of a possibility that in the standby duration, the initiator generates a radical which triggers polymerization reaction to form a ultra-high-molecular-weight polymer, it is preferred from the standpoint of quality control to prepare the monomer solution and the initiator solution separately and add them dropwise. The acid labile group that has been incorporated in the monomer may be kept as such, or polymerization may be followed by protection or partial protection. During the polymer synthesis, any known chain transfer agent such as dodecyl mercaptan or 2-mercaptoethanol may be added for molecular weight control purpose. The amount of chain transfer agent added is preferably 0.01 to 20 mol % based on the total of monomers.

Where a monomer having a hydroxy group is copolymerized, the hydroxy group may be replaced by an acetal group susceptible to deprotection with acid, typically ethoxyethoxy, prior to polymerization, and the polymerization be followed by deprotection with weak acid and water. Alternatively, the hydroxy group may be replaced by an acetyl, formyl, pivaloyl or similar group prior to polymerization, and the polymerization be followed by alkaline hydrolysis.

When hydroxystyrene or hydroxyvinylnaphthalene is copolymerized, one method is by dissolving hydroxystyrene or hydroxyvinylnaphthalene and other monomers in an organic solvent, adding a radical polymerization initiator thereto, and heating the solution for polymerization. In an alternative method, acetoxystyrene or acetoxyvinylnaphthalene is used instead, and after polymerization, the acetoxy group is deprotected by alkaline hydrolysis, for thereby converting the polymer product to polyhydroxystyrene or polyhydroxyvinylnaphthalene. For alkaline hydrolysis, a base such as aqueous ammonia or triethylamine may be used. Preferably the reaction temperature is −20° C. to 100° C. more preferably 0° C. to 60° C., and the reaction time is 0.2 to 100 hours, more preferably 0.5 to 20 hours.

The amounts of monomers in the monomer solution may be determined appropriate so as to provide the preferred fractions of repeat units.

It is now described how to use the polymer obtained by the above preparation method. The reaction solution resulting from polymerization reaction may be used as the final product. Alternatively, the polymer may be recovered in powder form through a purifying step such as re-precipitation step of adding the reaction solution to a poor solvent and letting the polymer precipitate as powder, after which the polymer powder is used as the final product. It is preferred from the standpoints of operation efficiency and consistent quality to handle a polymer solution which is obtained by dissolving the powder polymer resulting from the purifying step in a solvent, as the final product. The solvents which can be used herein are described in JP-A 2008-111103, paragraphs [0144]-[0145] (U.S. Pat. No. 7,537,880). Exemplary solvents include ketones such as cyclohexanone and methyl-2-n-pentyl ketone; alcohols such as 3-methoxybutanol, 3-methyl-3 methoxybutanol, 1-methoxy-2-propanol, 1-ethoxy-2-propanol; ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3 methoxypropionate, ethyl 3-ethoxypropionate, tert-butyl acetate, tert-butyl propionate, and propylene glycol mono-tert-butyl ether acetate; lactones such as γ-butyrolactone (GBL); keto-alcohols such as diacetone alcohol (DAA); and high-boiling alcohols such as diethylene glycol, propylene glycol, glycerol, 1,4-butanediol, and 1,3-butanediol, which may be used alone or in admixture.

The polymer solution preferably has a polymer concentration of 0.01 to 30% by weight, more preferably 0.1 to 20% by weight.

Prior to use, the reaction solution or polymer solution is preferably filtered through a filter. Filtration is effective for consistent quality because foreign particles and gel which can cause defects are removed.

Suitable materials of which the filter is made include fluorocarbon, cellulose, nylon, polyester, and hydrocarbon base materials. Preferred for the filtration of a resist composition are filters made of fluorocarbons commonly known as Teflon®, hydrocarbons such as polyethylene and polypropylene, and nylon. While the pore size of the filter may be selected appropriate to comply with the desired cleanness, the filter preferably has a pore size of up to 100 nm, more preferably up to 20 nm. A single filter may be used or a plurality of filters may be used in combination. Although the filtering method may be single pass of the solution, preferably the filtering step is repeated by flowing the solution in a circulating manner. In the polymer preparation process, the filtering step may be carried out any times, in any order and in any stage. The reaction solution as polymerized or the polymer solution may be filtered, preferably both are filtered.

The polymer may be a blend of two or more polymers which differ in compositional ratio, Mw or Mw/Mn.

### (B) Onium Salt Type Quencher

The onium salt type quencher as component (B) is typically represented by the formula (1) or (2). As used herein, the term “quencher” refers to a compound which traps the acid generated by the PAG in the resist composition in the exposed region to prevent the acid from diffusing into the unexposed region for thereby forming the desired pattern.

R^{q1}—SO₃⁻A⁺ (1)

R^{q2}—CO₂⁻A⁺ (2)

In formula (1), R^{q1} is hydrogen or a C₁-C₄₀ hydrocarbyl group which may contain a heteroatom, exclusive of a hydrocarbyl group in which hydrogen attached to the α-carbon relative to the sulfo group is substituted by fluorine or fluoroalkyl. In formula (2), R^{q2} is hydrogen or a C₁-C₄₀ hydrocarbyl group which may contain a heteroatom.

Examples of the hydrocarbyl group R^{q1} include C₁-C₄₀ alkyl groups such as methyl, ethyl, n-propyl, isopropyl, n-butyl, sec-butyl, tert-butyl, n-pentyl, tert-pentyl, n-hexyl, n-octyl, 2-ethylhexyl, n-nonyl, n-decyl; C₃-C₄₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, adamantyl; C₆-C₄₀ aryl groups such as phenyl, naphthyl, anthracenyl; and combinations thereof. In the hydrocarbyl groups, some or all of the hydrogen atoms may be substituted by a moiety containing a heteroatom such as oxygen, sulfur, nitrogen or halogen, or some —CH₂— may be replaced by a moiety containing a heteroatom such as oxygen, sulfur or nitrogen, so that the group may contain a hydroxy, fluorine, chlorine, bromine, iodine, cyano, carbonyl, ether bond, ester bond, sulfonic ester bond, carbonate bond, lactose ring, sultone ring, carboxylic anhydride (—C(═O)—O—C(═O)—) or haloalkyl moiety.

Examples of the hydrocarbyl group R^{q2} include those groups exemplified above for R^{q1} as well as fluorinated alkyl groups such as trifluoromethyl and trifluoroethyl and fluorinated aryl groups such as pentafluorophenyl and 4-trifluoromethylphenyl.

Examples of the anion of the onium salt having formula (1) are shown below, but not limited thereto.

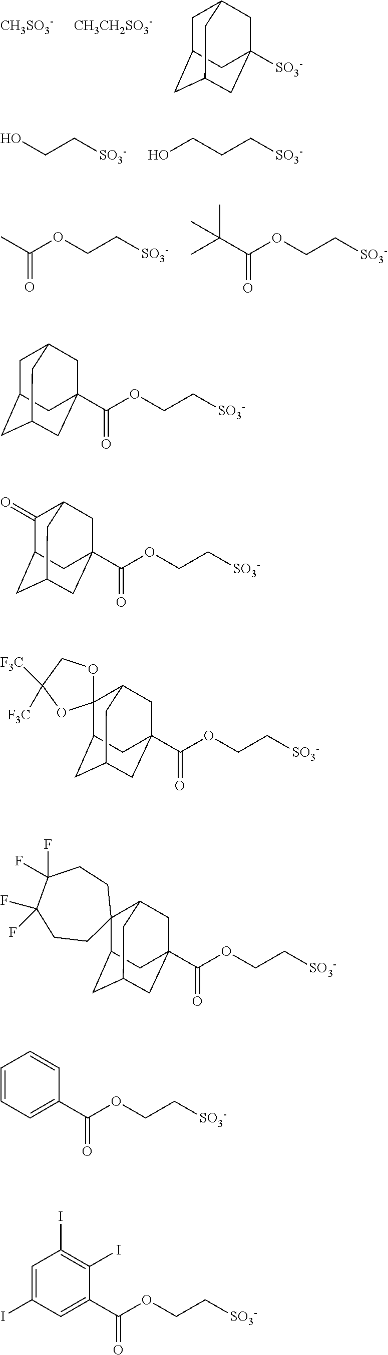

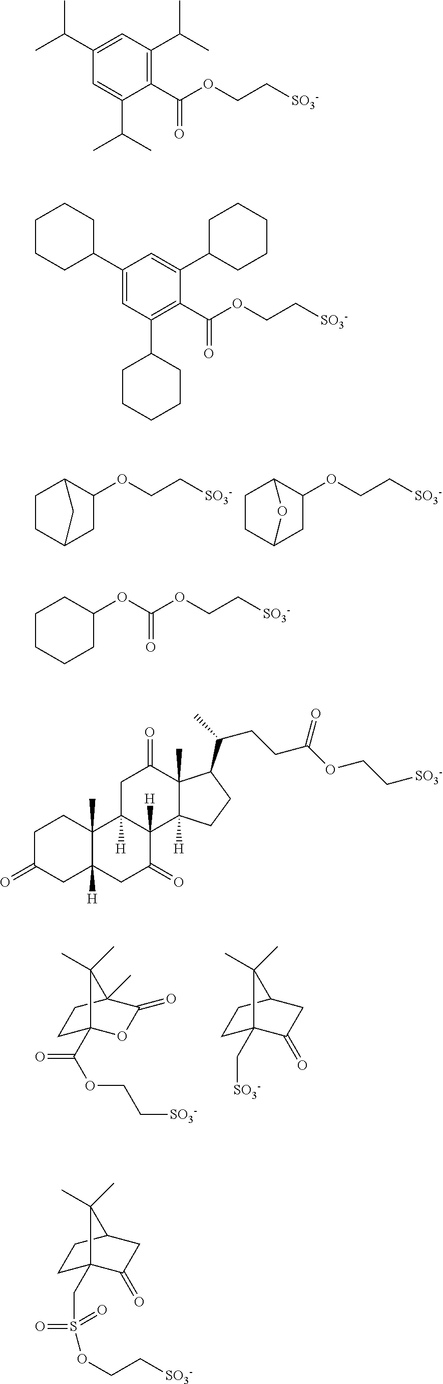

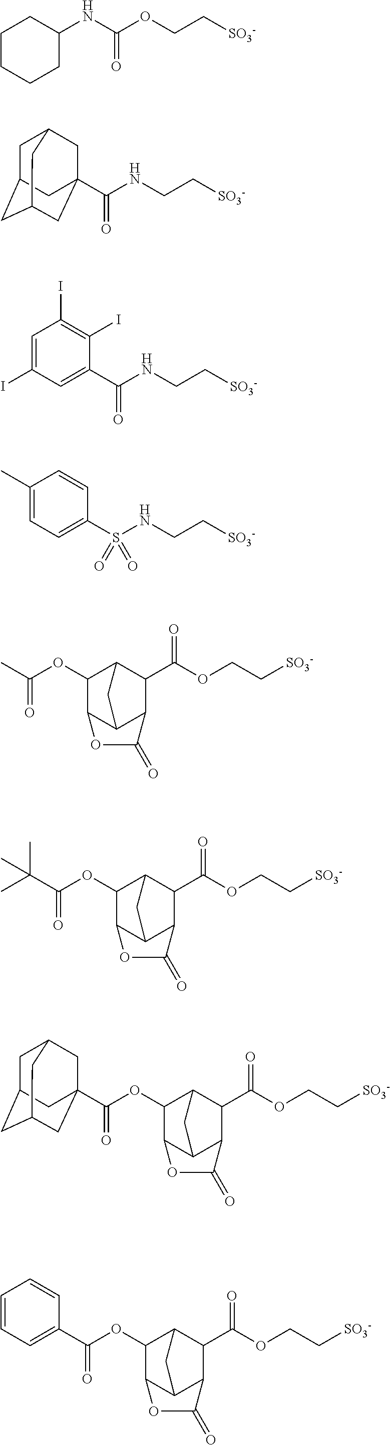

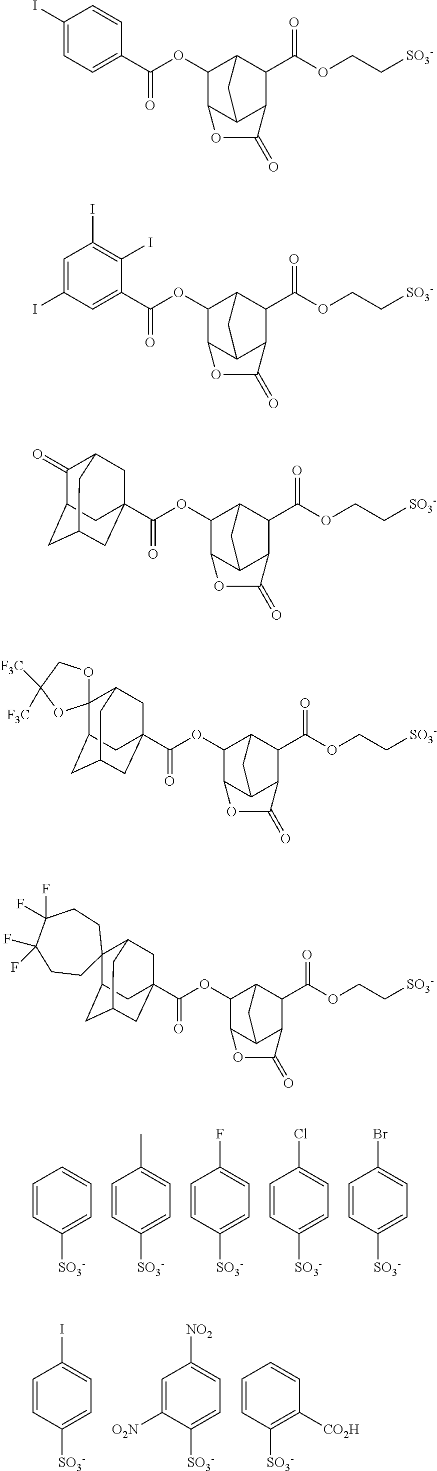

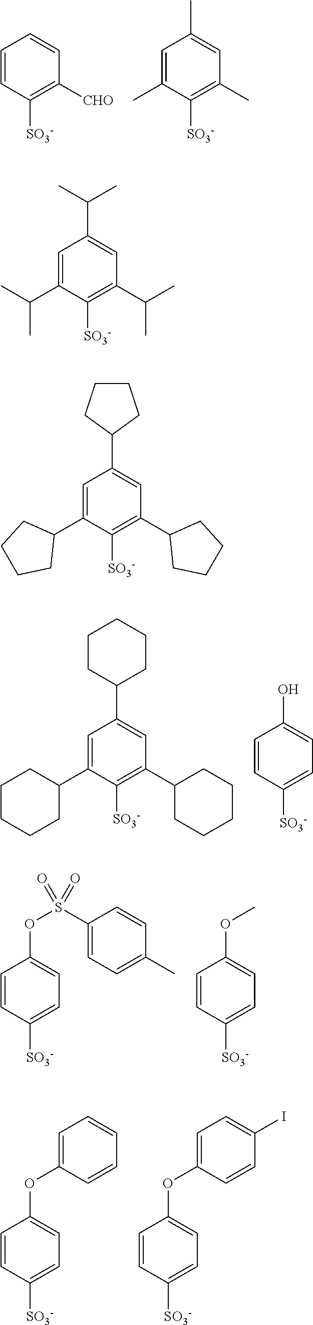

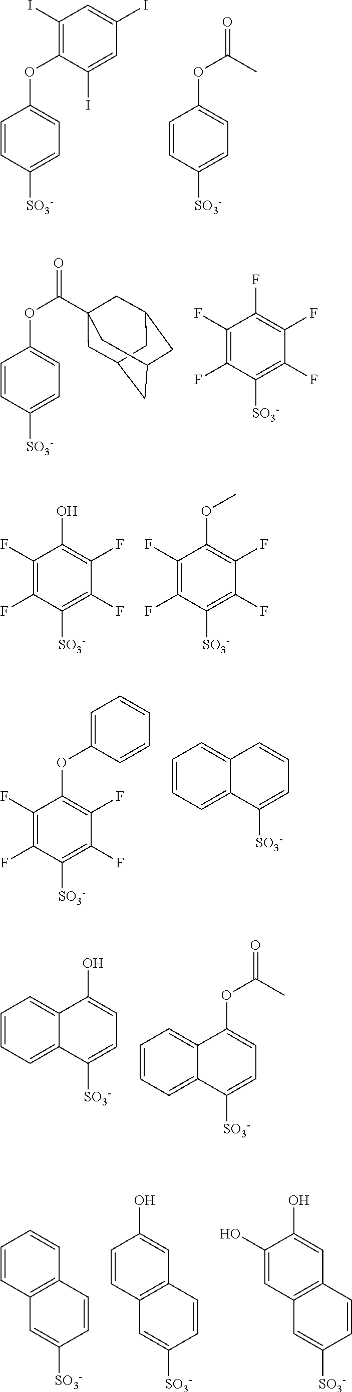

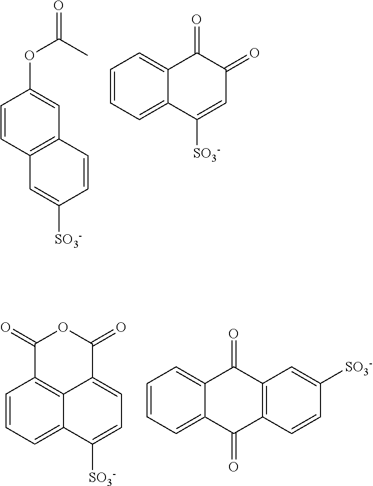

Examples of the anion of the opium salt having formula (2) are shown below, but not limited thereto.

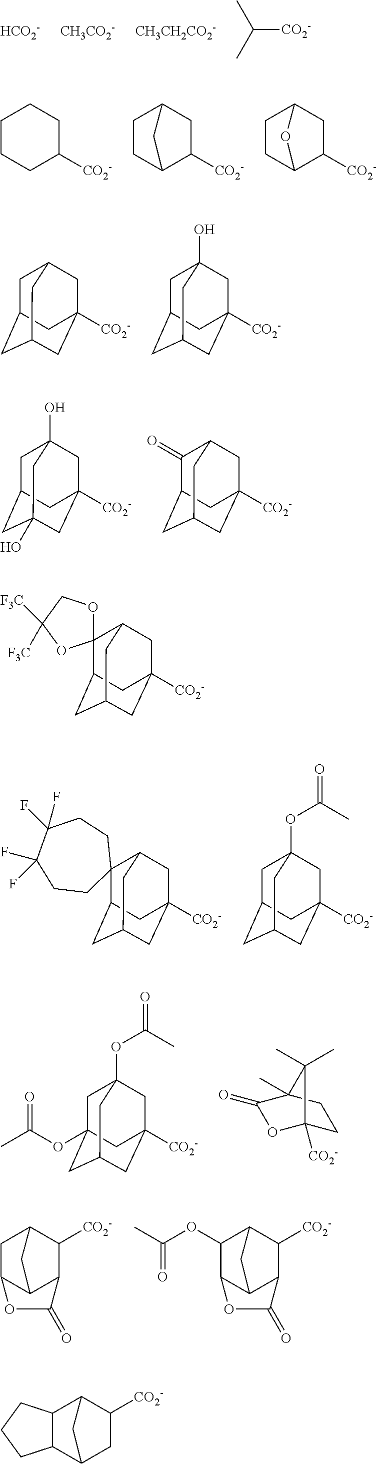

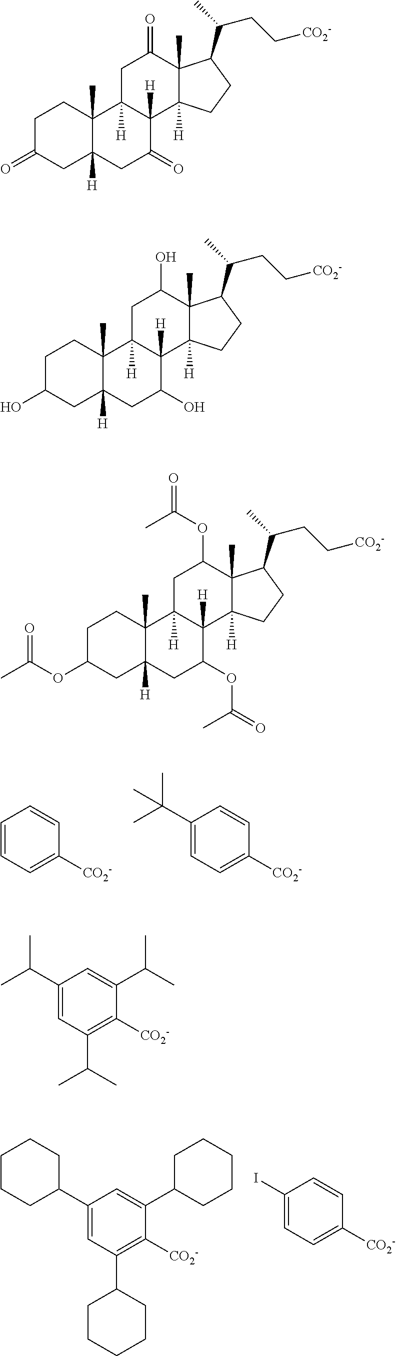

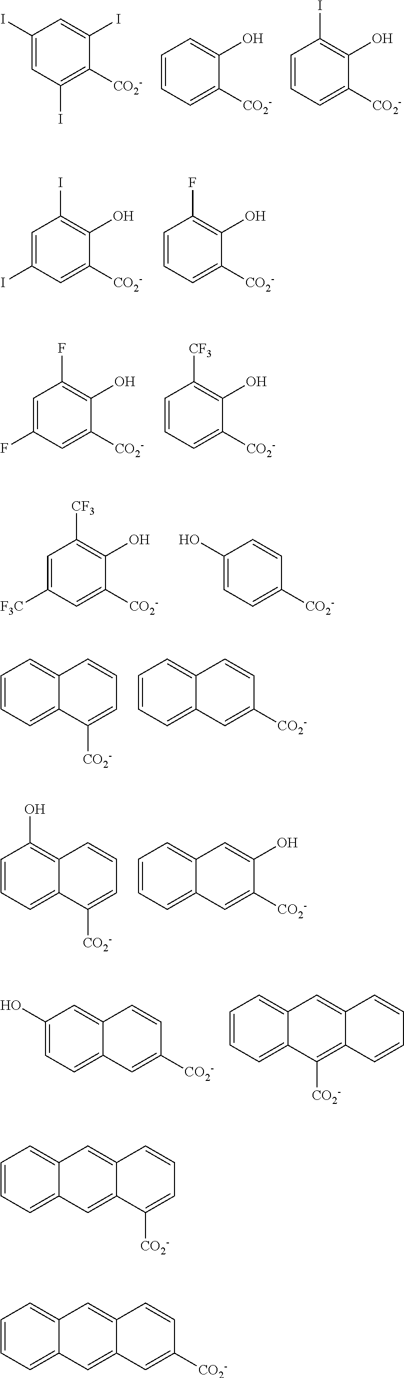

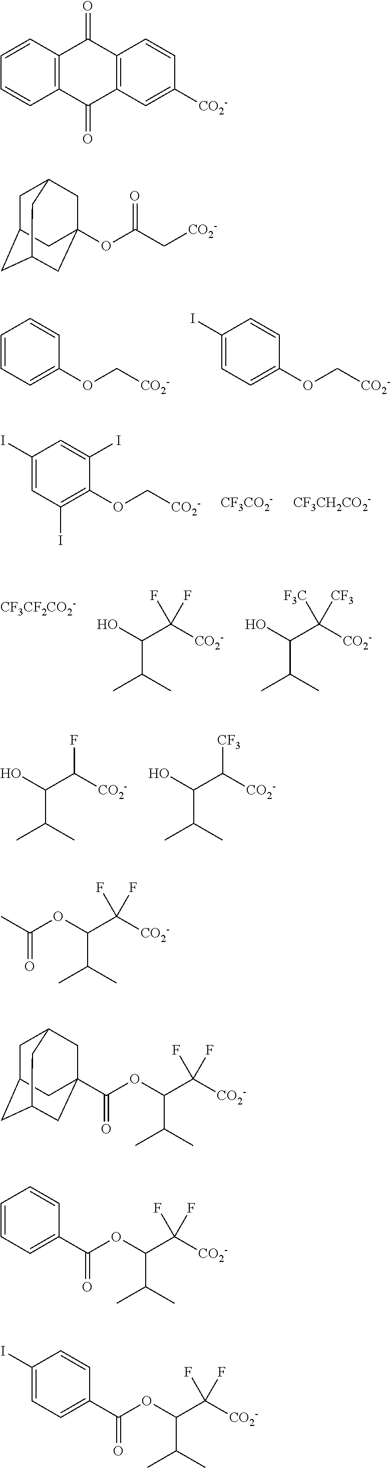

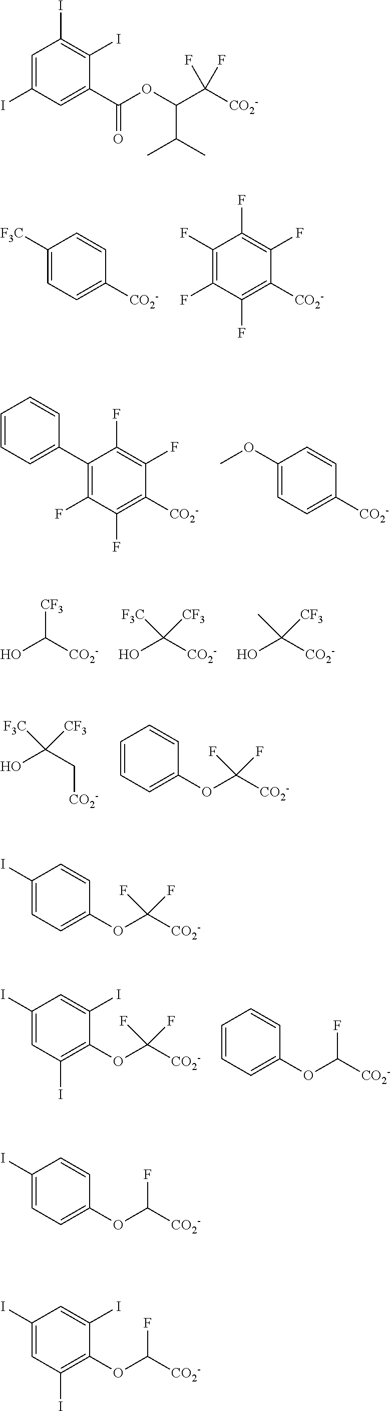

In formulae (1) and (2), A⁺ is an onium cation. Preferred as the opium cation are sulfonium cations having the above formula (cation-1), iodonium cations having the above formula (cation-2), and ammonium cations having the following formula (cation-3).

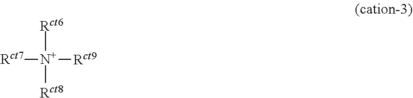

In formula (cation-3), R^{ct6} to R^{ct9} are each independently a C₁-C₄₀ hydrocarbyl group which may contain a heteroatom. R^{ct6} and R^{ct7} may bond together to form a ring with the nitrogen atom to which they are attached. Examples of the hydrocarbyl group are as exemplified above for the hydrocarbyl groups R^{ct1} to R^{ct5} in formulae (cation-1) and (cation-2).

Examples of the ammonium cation having formula (cation-3) are shown below, but not limited thereto.

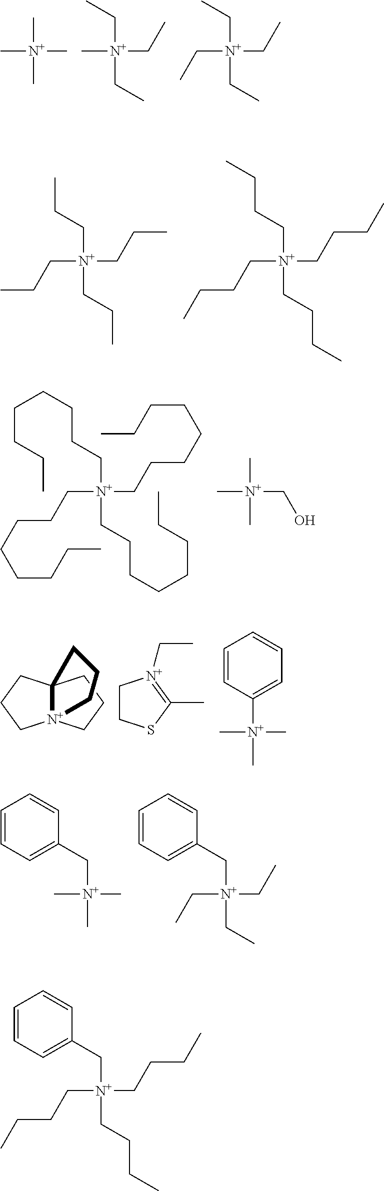

Examples of the onium salt having formula (1) or (2) include arbitrary combinations of anions with cations, both exemplified above. It is understood that these onium salts can be readily prepared by ion exchange reaction using any well-known organic chemistry techniques. For the ion exchange reaction, reference may be made to U.S. Pat. No. 7,511,169 (JP-A 2007-145797).

The onium salt having formula (1) or (2) functions as a quencher in the chemically amplified resist composition because the counter anion of the onium salt is a conjugated base of a weak acid. As used herein, the weak acid indicates an acidity insufficient to deprotect an acid labile group from an acid labile group-containing unit in the base polymer. The onium salt having formula (1) or (2) functions as a quencher when used in combination with an onium salt type PAG having a conjugated base of a strong acid (typically a sulfonic acid which is fluorinated at α-position) as the counter anion. In a system using a mixture of an onium salt capable of generating a strong acid (e.g., α-position fluorinated sulfonic acid) and an onion salt capable of generating a weak acid (e.g., non-fluorinated sulfonic acid or carboxylic acid), if the strong acid generated from the PAG upon exposure to high-energy radiation collides with the unreacted onium salt having a weak acid anion, then a salt exchange occurs whereby the weak acid is released and an onium salt having a strong acid anion is formed. In this course, the strong acid is exchanged into the weak acid having a low catalysis, incurring apparent deactivation of the acid for enabling to control acid diffusion.

If a PAG capable of generating a strong acid is an onium salt, an exchange from the strong acid generated upon exposure to high-energy radiation to a weak acid as above can take place, but it rarely happens that the weak acid generated upon exposure to high-energy radiation collides with the unreacted onium salt capable of generating a strong acid to induce a salt exchange. This is because of a likelihood of an onion cation forming an ion pair with a stronger acid anion.

In the chemically amplified resist composition, the amount of the opium salt type quencher (B) used is preferably 0.1 to 20 parts by weight, more preferably 0.1 to 10 parts by weight per 80 parts by weight of polymer P as component (A). As long as the amount of component (B) is in the range, a satisfactory resolution is available without a substantial lowering of sensitivity. The onium salt type quencher may be used alone or in admixture.

### (C) Organic Solvent

The organic solvent used as component (C) is not particularly limited as long as the foregoing and other components are soluble therein. Suitable solvents include ketones such as cyclopentanone, cyclohexanone, and methyl-2 n-pentyl ketone; alcohols such as 3-methoxybutanol, 3-methyl-3-methoxybutanol, 1-methoxy-2-propanol, and 1-ethoxy-2-propanol; keto-alcohols such as diacetone alcohol (DAA); ethers such as propylene glycol monomethyl ether (PGME), ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as γ-butyrolactone (GBL), and mixtures thereof. When a polymer containing an acid labile group of acetal form is used, a high-boiling alcohol solvent may be added for accelerating the deprotection reaction of acetal, for example, diethylene glycol, propylene glycol, glycerol, 1,4-butanediol or 1,3-butanediol.

Of the foregoing organic solvents, it is recommended to use 1-ethoxy-2-propanol, PGMEA, cyclohexanone, GBL, DAA and mixtures thereof because polymer P as component (A) is most soluble therein.

The organic solvent (C) is preferably added in an amount of 200 to 5,000 parts by weight, and more preferably 400 to 3,000 parts by weight per 80 parts by weight of polymer P as component (A). The solvent may be used alone or in admixture.

### (D) Photoacid Generator

The chemically amplified resist composition may comprise (D) a photoacid generator. The PAG is not particularly limited as long as it is capable of generating an acid upon exposure to high-energy radiation. The preferred PAG is a sulfonium salt having the formula (3).

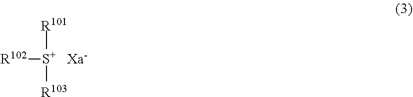

In formula (3), R¹⁰¹, R¹⁰² and R¹⁰³ are each independently a C₁-C₂₀ hydrocarbyl group which may contain a heteroatom. R¹⁰¹ and R¹⁰² may bond together to form a ring with the sulfur atom to which they are attached. The hydrocarbyl group may be saturated or unsaturated and straight, branched or cyclic. Examples thereof are as exemplified above for R^{ct1} to R^{ct5} in formulae (cation-1) and (cation-2). Examples of the cation in the sulfonium salt of formula (3) are as exemplified above for the sulfonium cation having formula (cation-1).

In formula (3), Xa⁻ is an anion selected from the formulae (3A) to (3D).

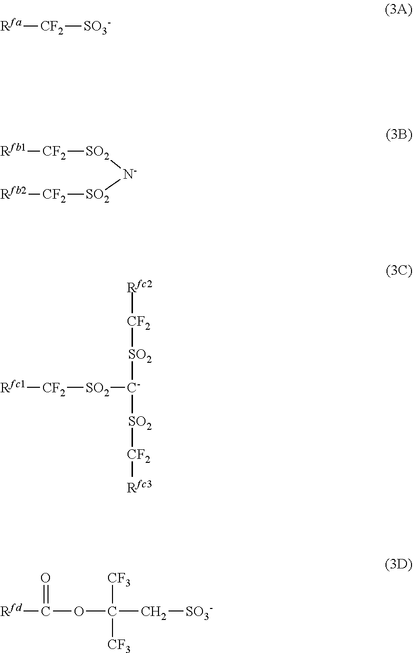

In formula (3A), R^{fa} is fluorine or a C₁-C₄₀ hydrocarbyl group which may contain a heteroatom. The hydrocarbyl group may be saturated or unsaturated and straight, branched or cyclic. Examples thereof are as will be exemplified later for R¹⁰⁵ in formula (3A′).

Of the anions having formula (3A), anions having the formula (3A′) are preferred.

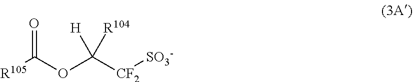

In formula (3A′). R¹⁰⁴ is hydrogen or trifluoromethyl, preferably trifluoromethyl.

R¹⁰⁵ is a C₁-C₃₈ hydrocarbyl group which may contain a heteroatom. Suitable heteroatoms include oxygen, nitrogen, sulfur and halogen, with oxygen being preferred. Of the hydrocarbyl groups, those of 6 to 30 carbon atoms are preferred because a high resolution is available in fine pattern formation. The hydrocarbyl group R¹⁰⁵ may be saturated or unsaturated and straight, branched or cyclic. Examples thereof include C₁-C₃₈ alkyl groups such as methyl, ethyl, n-propyl, isopropyl, n-butyl, isobutyl, sec-butyl, tert-butyl, pentyl, neopentyl, hexyl, heptyl, 2-ethylhexyl, nonyl, undecyl, tridecyl, pentadecyl, heptadecyl, and icosanyl; C₃-C₃₈ cyclic saturated hydrocarbyl groups such as cyclopentyl, cyclohexyl, 1-adamantyl, 2-adamantyl, 1-adamantylmethyl, norbornyl, norbornylmethyl, tricyclodecanyl, tetracyclododecanyl, tetracyclododecanylmethyl, and dicyclohexylmethyl; C₂-C₃₈ unsaturated aliphatic hydrocarbyl groups such as ally and 3-cyclohexenyl; C₆-C₃₈ aryl groups such as phenyl, 1-naphthyl and 2-naphthyl; and C₇-C₃₈ aralkyl groups such as benzyl and diphenylmethyl. Of these, aliphatic groups are preferred as R¹⁰⁵. In the hydrocarbyl group, some or all of the hydrogen atoms may be substituted by a moiety containing a heteroatom such as oxygen, sulfur, nitrogen or halogen, or some —CH₂— may be replaced by a moiety containing a heteroatom such as oxygen, sulfur or nitrogen, so that the group may contain a hydroxy, fluorine, chlorine, bromine, iodine, cyano, carbonyl, ether bond, ester bond, sulfonic ester bond, carbonate bond, lactone ring, sultone ring, carboxylic anhydride (—C(═O)—O—C(═O)—) or haloalkyl moiety. Examples of the heteroatom-containing hydrocarbyl group include tetrahydrofuryl, methoxymethyl, ethoxymethyl, methylthiomethyl, acetamidomethyl, trifluoroethyl, (2-methoxyethoxy)methyl, acetoxymethyl, 2-carboxy-1-cyclohexyl, 2-oxopropyl, 4-oxo-1-adamantyl, and 3-oxocyclohexyl.

With respect to the synthesis of the sulfonium salt having au anion of formula (3A′), reference may be made to JP-A 2007-145797, JP-A 2008-106045, JP-A 2009-007327, and JP A 2009-258695. Also useful are the sulfonium salts described in JP-A 2010-215608, JP A 2012-041320, JP-A 2012-106986, and JP A 2012-153644.

Examples of the anion having formula (3A) are as exemplified above for M⁻ in formula (C1).

In formula (3B), R^{fb1} and R^{fb2} are each independently fluorine or a C₁-C₄₀ hydrocarbyl group which may contain a heteroatom. The hydrocarbyl group may be saturated or unsaturated and straight, branched or cyclic. Examples thereof are as exemplified above for R¹⁰⁵ in formula (3A′). Preferably R^{fb1} and R^{fb2} are fluorine or C₁-C₄ straight fluorinated alkyl groups. Also, R^{fb1} and R^{fb2} may bond together to form a ring with the linkage: —CF₂—SO₂—N⁻—SO₂—CF₂— to which they are attached. It is preferred that a combination of Rea and lea be a fluorinated ethylene or fluorinated propylene group.

In formula (3C), R^{fc1}, R^{fc2} and R^{fc3} are each independently fluorine or a C₁-C₄₀ hydrocarbyl group which may contain a heteroatom. The hydrocarbyl group may be saturated or unsaturated and straight, branched or cyclic. Examples thereof are as exemplified for R¹⁰⁵. Preferably R^{fc1}, R^{fc2} and R^{fc3} are fluorine or C₁-C₄ straight fluorinated alkyl groups. Also, R^{fc1} and R^{fc2} may bond together to form a ring with the linkage: —CF₂—SO₂—C⁻—SO₂—CF₂— to which they are attached. It is preferred that a combination of R^{fc1} and R^{fc2} be a fluorinated ethylene or fluorinated propylene group.

In formula (3D), R^{fd} is a C₁-C₄₀ hydrocarbyl group which may contain a heteroatom. The hydrocarbyl group may be saturated or unsaturated and straight, branched or cyclic. Examples thereof are as exemplified above for R¹⁰⁵.

With respect to the synthesis of the sulfonium salt having an anion of formula (3D), reference may be made to JP-A 2010-215608 and JP-A 2014-133723.

Examples of the anion having formula (3D) are shown below, but not limited thereto.

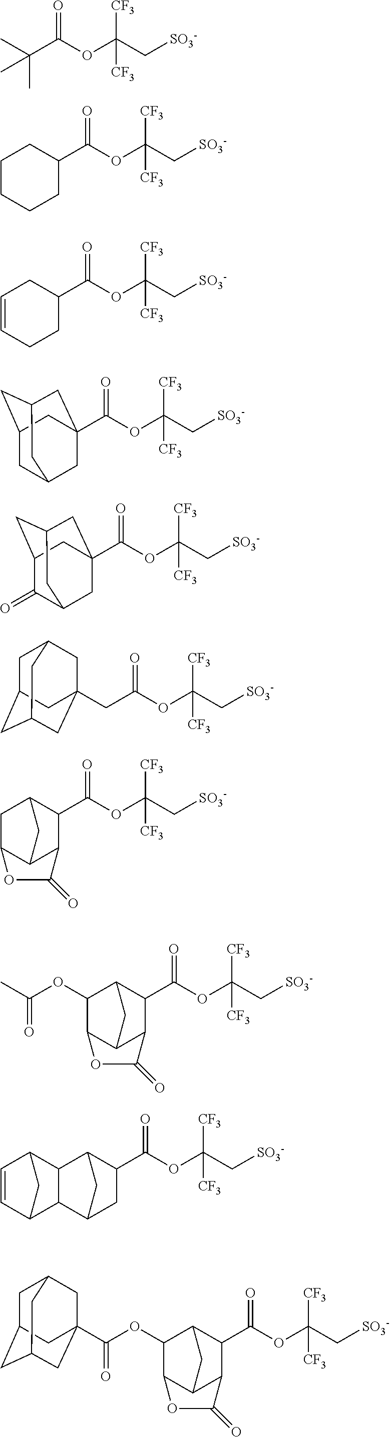

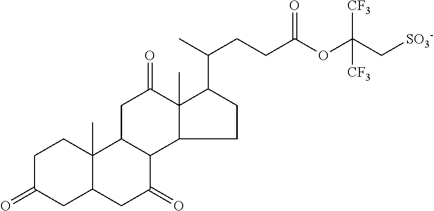

Notably, the compound having the anion of formula (3D) does not have fluorine at the α-position relative to the sulfo group, but two trifluoromethyl groups at the β-position. For this reason, it has a sufficient acidity to sever the acid labile groups in the base polymer. Thus the compound is an effective PAG.

Also a compound having the formula (4) is preferred as the PAG (D).

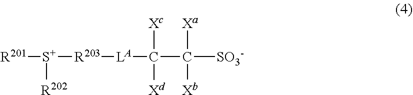

In formula (4), R²⁰¹ and R²⁰² are each independently a C₁-C₃₀ hydrocarbyl group which may contain a heteroatom. R²⁰³ is a C₁-C₃₀ hydrocarbylene group which may contain a heteroatom. Any two of R²⁰¹, R²⁰² and R²⁰³ may bond together to form a ring with the sulfur atom to which they are attached. Examples of the ring are as exemplified above as the ring that R²¹ and R²² in formula (C1), taken together, form with the sulfur atom.

The hydrocarbyl groups R²⁰¹ and R²⁰² may be saturated or unsaturated and straight, branched or cyclic. Examples thereof include C₁-C₃₀ alkyl groups such as methyl, ethyl, n-propyl, isopropyl, n-butyl, sec-butyl, tert-butyl, n-pentyl, tert-pentyl, n-hexyl, n-octyl, 2-ethylhexyl, n-nonyl, and n-decyl; C₃-C₃₀ cyclic saturated hydrocarbyl groups such as cyclopentyl, cyclohexyl, cyclopentylmethyl, cyclopentylethyl, cyclopentylbutyl, cyclohexylmethyl, cyclohexylethyl, cyclohexylbutyl, norbornyl, tricyclo[5.2.1.0^{2,6}]decanyl, and adamantyl; C₆-C₃₀ aryl groups such as phenyl, naphthyl and anthracenyl; and combinations thereof. In the hydrocarbyl group, some or all of the hydrogen atoms may be substituted by a moiety containing a heteroatom such as oxygen, sulfur, nitrogen or halogen, or some —CH₂— may be replaced by a moiety containing a heteroatom such as oxygen, sulfur or nitrogen, so that the group may contain a hydroxy, fluorine, chlorine, bromine, iodine, cyano, carbonyl, ether bond, ester bond, sulfonic ester bond, carbonate bond, lactone ring, sultone ring, carboxylic anhydride (—C(═O)—O—C(═O)—) or haloalkyl moiety.

The hydrocarbylene group R²⁰³ may be saturated or unsaturated and straight, branched or cyclic. Examples thereof include C₁-C₃₀ alkanediyl groups such as methanediyl, ethane-1,1-diyl, ethane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, decane-1,10-diyl, undecane-1,11-diyl, dodecane-1,12-diyl, tridecane-1,13-diyl, tetradecane-1,14-diyl, pentadecane-1,15-diyl, hexadecane-1,16-diyl, and heptadecane-1,17-diyl; C₃-C₃₀ cyclic saturated hydrocarbylene groups such as cyclopentanediyl, cyclohexanediyl, norbornanediyl and adamantanediyl; C₆-C₃₀ arylene groups such as phenylene, methylphenylene, ethylphenylene, n-propylphenylene, isopropylphenylene, n-butylphenylene, isobutylphenylene, sec-butylphenylene, tert-butylphenylene, naphthylene, methylnaphthylene, ethylnaphthylene, n-propylnaphthylene, isopropylnaphthylene, n-butylnaphthylene, isobutylnaphthylene, sec-butylnaphthylene, and tert-butylnaphthylene; and combinations thereof. In the hydrocarbylene group, some or all of the hydrogen atoms may be substituted by a moiety containing a heteroatom such as oxygen, sulfur, nitrogen or halogen, or some —CH₂— may be replaced by a moiety containing a heteroatom such as oxygen, sulfur or nitrogen, so that the group may contain a hydroxy, fluorine, chlorine, bromine, iodine, cyano, carbonyl, ether bond, ester bond, sulfonic ester bond, carbonate bond, lactone ring, sultone ring, carboxylic anhydride (—C(═O)—O—C(═O)—) or haloalkyl moiety. Of the heteroatoms, oxygen is preferred.

In formula (4), L^{A} is a single bond ether bond or a C₁-C₂₀ hydrocarbylene group which may contain a heteroatom. The hydrocarbylene group may be saturated or unsaturated and straight, branched or cyclic. Examples thereof are as exemplified above for the hydrocarbylene group R²⁰³.

In formula (4), X^{a}, X^{b}, X^{c} and X^{d} are each independently hydrogen, fluorine or trifluoromethyl, with the proviso that at least one of X^{a}, X^{b}, X^{c} and X^{d} is fluorine or trifluoromethyl.

Of the PAGs having formula (4), those having formula (4′) are preferred.

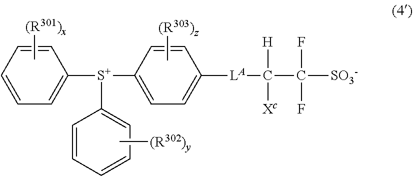

In formula (4′), L^{A} is as defined above. X^{e} is hydrogen or trifluoromethyl, preferably trifluoromethyl. R³⁰¹, R³⁰² and R³⁰³ are each independently hydrogen or a C₁-C₂₀ hydrocarbyl group which may contain a heteroatom. The hydrocarbyl group may be saturated or unsaturated and straight, branched or cyclic. Examples thereof are as exemplified above for R¹⁰⁶ in formula (3A′). The subscripts x and y are each independently an integer of 0 to 5, and z is an integer of 0 to 4.

Examples of the PAG having formula (4) include those described as the PAG having formula (2) in JP-A 2017-026980.

Of the foregoing PAGs, those having an anion of formula (3A′) or (3D) are especially preferred because of reduced acid diffusion and high solubility in the resist solvent. Also those having formula (4′) are especially preferred because of extremely reduced acid diffusion.

Also onium salts having the formulae (5-1) and (5-2) may be used as the PAG.

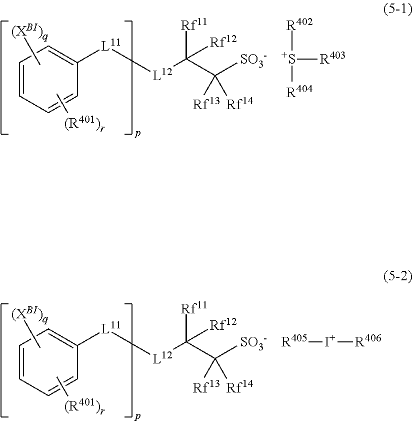

In formulae (5-1) and (5-2), p is an integer of 1 to 3, q is an integer of 1 to 5, r is an integer of 0 to 3, and 1≤q+r≤5. Preferably, q is an integer of 1 to 3, more preferably 2 or 3, and r is an integer of 0 to 2.

X^{BI} is iodine or bromine, and may be identical or different when p and/or q is 2 or more.

L¹¹ is a single bond, ether bond, ester bond, or a C₁-C₆ saturated hydrocarbylene group which may contain au ether bond or ester bond. The saturated hydrocarbylene group may be straight, branched or cyclic.

L¹² is a single bond or a C₁-C₂₀ divalent linking group when p=1, or a C₁-C₂₀ (p+1)-valent linking group when p=2 or 3. The linking group may contain an oxygen, sulfur or nitrogen atom.

In formulae (5-1) and (5-2), R⁴⁰¹ is hydroxy, carboxy, fluorine, chlorine, bromine, amino group, or a C₁-C₂₀ saturated hydrocarbyl, C₁-C₂₀ saturated hydrocarbyloxy, C₂-C₁₀ saturated hydrocarbyloxycarbonyl, C₂-C₂₀ saturated hydrocarbylcarbonyloxy, or C₁-C₂₀ saturated hydrocarbylsulfonyloxy group, which may contain fluorine, chlorine, bromine, hydroxy, amino or ether bond, or —N(R^{401a})(R^{401B}), —N(R^{401C})—C(═O)—R^{401D} or —N(R^{401C})—C(═O)—O—R^{401D}. R^{401A} and R^{401B} are each independently hydrogen or a C₁-C₆ saturated hydrocarbyl group. R^{401C} is hydrogen, or a C₁-C₆ saturated hydrocarbyl group which may contain halogen, hydroxy, C₁-C₆ saturated hydrocarbyloxy, C₂-C₆ saturated hydrocarbylcarbonyl or C₂-C₆ saturated hydrocarbylcarbonyloxy moiety. R^{401D} is a C₁-C₁₆ aliphatic hydrocarbyl group, C₆-C₁₂ aryl group or C₇-C₁₅ aralkyl group, which may contain halogen, hydroxy, C₁-C₆ saturated hydrocarbyloxy, C₂-C₆ saturated hydrocarbylcarbonyl or C₂-C₆ saturated hydrocarbylcarbonyloxy moiety. The aliphatic hydrocarbyl group may be saturated or unsaturated and straight, branched or cyclic. The hydrocarbyl, hydrocarbyloxy, hydrocarbyloxycarbonyl, hydrocarbylcarbonyl, and hydrocarbylcarbonyloxy groups may be straight, branched or cyclic. Groups R⁴⁰¹ may be identical or different when p and/or r is 2 or more.

Of these, R⁴⁰¹ is preferably hydroxy, —N(R^{401C})—C(═O)—R^{401D}, —N(R^{401C})—C(═O)—O—R^{401D}, fluorine, chlorine, bromine, methyl or methoxy.

Rf¹¹ to Rf¹⁴ are each independently hydrogen, fluorine or trifluoromethyl, at least one of Rf¹¹ to Rf¹⁴ is fluorine or trifluoromethyl. Rf¹¹ and Rf¹², taken together, may form a carbonyl group. More preferably, both Rf¹³ and Rf¹⁴ are fluorine.

R⁴⁰², R⁴⁰³, R⁴⁰⁴, R⁴⁰⁵ and R⁴⁰⁶ are each independently halogen or a C₁-C₂₀ hydrocarbyl group which may contain a heteroatom. The hydrocarbyl group may be saturated or unsaturated and straight, branched or cyclic. Examples thereof are as exemplified above for the hydrocarbyl groups R¹⁰¹ to R¹⁰³ in formula (3). In the hydrocarbyl group, some or all hydrogen may be substituted by a hydroxy, carboxy, halogen, cyan, nitro, mercapto, sultone, sulfone or sulfonium salt-containing moiety, or some —CH₂— may be replaced by an ether bond, ester bond, carbonyl, amide bond, carbonate bond or sulfonic ester bond. R⁴⁰² and R⁴⁰³ may bond together to form a ring with the sulfur atom to which they are attached. Examples of the ring are as exemplified above as the ring that R¹⁰¹ and R¹⁰² in formula (3), taken together, form with the sulfur atom.

Examples of the cation in the sulfonium salt having formula (5-1) are as exemplified above as the sulfonium cation having formula (C4). Examples of the cation in the iodonium salt having formula (5-2) are as exemplified above as the iodonium cation having formula (cation-2).

Examples of the anion in the onium salts having formulae (5-1) and (5-2) include those exemplified as the anion in the onium salts having formula (3-1) and (3-2) in JP-A 2020-118959.

When used, the PAG (D) is preferably added in an amount of 0.1 to 40 parts, and more preferably 0.5 to 20 parts by weight per 80 parts by weight of polymer P as component (A). As long as the amount of the PAG is in the range, good resolution is achievable and the risk of foreign particles being formed after development or during stripping of resist film is avoided. The PAG may be used alone or in admixture.

### (E) Nitrogen-Containing Quencher

The resist composition may further contain (E) a nitrogen-containing quencher. Suitable nitrogen-containing compounds include primary, secondary and tertiary amine compounds, specifically amine compounds having a hydroxy group, ether bond, ester bond, lactone ring, cyano group or sulfonate bond, as described in JP-A 2008-111103, paragraphs [0146]-[0164] (U.S. Pat. No. 7,537,880), and primary or secondary amine compounds protected with a carbamate group, as described in JP 3790649.

A sulfonic acid sulfonium salt having a nitrogen-containing substituent may also be used as the nitrogen-containing quencher. This compound functions as a quencher in the unexposed region, but as a so-called photo-degradable base in the exposed region because it loses the quencher function in the exposed region due to neutralization thereof with the acid generated by itself. Using a photo-degradable base, the contrast between exposed and unexposed regions can be further enhanced. With respect to the photo-degradable base, reference may be made to JP-A 2009-109595 and JP-A 2012-046501, for example.

When the nitrogen-containing quencher (E) is used in the resist composition, the amount of the nitrogen-containing compound used is preferably 0.001 to 12 parts by weight, more preferably 0.01 to 8 parts by weight per 80 parts by weight of polymer P as component (A). The nitrogen-containing quencher may be used alone or in admixture.

### (F) Surfactant

The chemically amplified resist composition may further include (F) a surfactant. Component (F) is preferably a surfactant which is insoluble or substantially insoluble in water and soluble in alkaline developer, or a surfactant which is insoluble or substantially insoluble in water and alkaline developer. For the surfactant, reference should be made to those compounds described in JP A 2010-215608 and JP-A 2011-016746.

While many examples of the surfactant which is insoluble or substantially insoluble in water and alkaline developer are described in the patent documents cited herein, preferred examples are surfactants FC-4430 (3M), Olfine® E1004 (Nissin Chemical Co., Ltd), Surflon® S-381, KH-20 and KH-30 (AGC Seimi Chemical Co., Ltd.). Partially fluorinated oxetane ring-opened polymers having the formula (surf-1) are also useful.

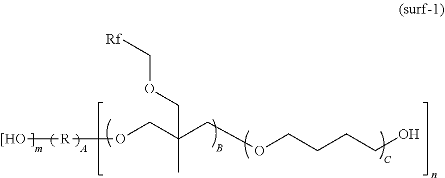

It is provided herein that R, Rf, A, B, C, m, and n are applied to only formula (surf-1), independent of their descriptions other than for the surfactant. R is a di- to tetra-valent C₂-C₅ aliphatic group. Exemplary divalent aliphatic groups include ethylene, 1,4-butylene, 1,2-propylene, 2,2-dimethyl-1,3-propylene and 1,5-pentylene. Exemplary tri- and tetra-valent groups are shown below.

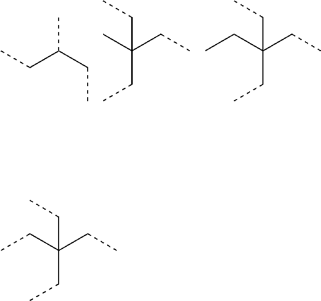

Herein the broken line denotes a valence bond. These formulae are partial structures derived from glycerol, trimethylol ethane, trimethylol propane, and pentaerythritol, respectively. Of these, 1,4-butylene and 2,2-dimethyl-1,3 propylene are preferably used.

Rf is trifluoromethyl or pentafluoroethyl, and preferably trifluoromethyl. The letter m is an integer of 0 to 3, n is an integer of 1 to 4, and the sum of m and n, which represents the valence of R, is an integer of 2 to 4. “A” is equal to 1, B is an integer of 2 to 25, and C is an integer of 0 to 10. Preferably, B is an integer of 4 to 20, and C: is 0 or 1. Note that the formula (surf-1) does not prescribe the arrangement of respective constituent units while they may be arranged either blockwise or randomly. For the preparation of surfactants in the form of partially fluorinated oxetane ring-opened polymers, reference should be made to U.S. Pat. No. 5,650,483, for example.

The surfactant which is insoluble or substantially insoluble in water and soluble in alkaline developer is useful when ArF immersion lithography is applied to the resist composition in the absence of a resist protective film. In this embodiment, the surfactant has a propensity to segregate on the resist surface after coating for achieving a function of minimizing water penetration or leaching. The surfactant is also effective for preventing water-soluble components from being leached out of the resist film for minimizing any damage to the exposure tool. The surfactant becomes solubilized during alkaline development following exposure and PEB, and thus forms few or no foreign particles which become defects. The preferred surfactant is a polymeric surfactant which is insoluble or substantially insoluble in water, but soluble in alkaline developer, also referred to as “hydrophobic resin” in this sense, and especially which is water repellent and enhances water sliding.

Suitable polymeric surfactants include those containing repeat units of at least one type selected from the formulae (6A) to (6E).

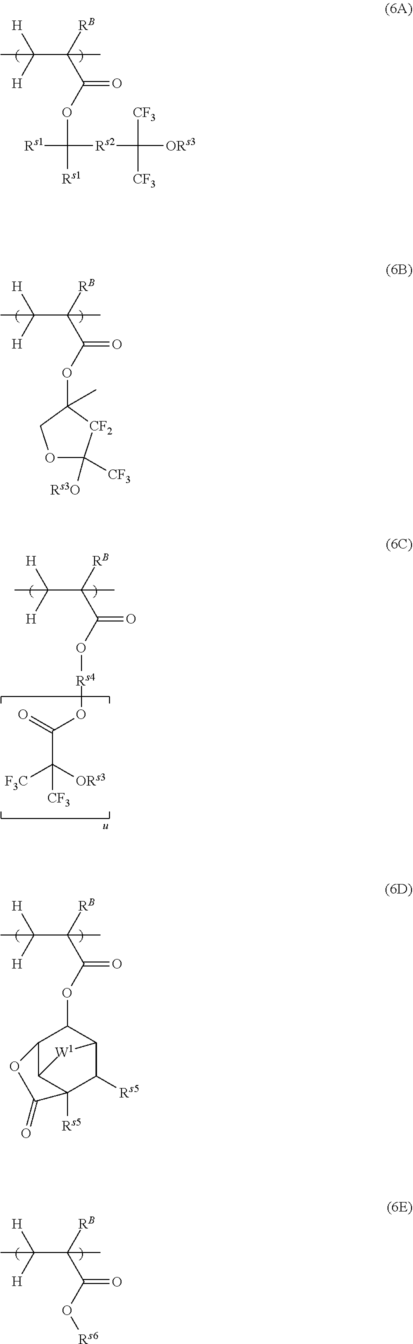

Herein, R^{B} is hydrogen, fluorine, methyl or trifluoromethyl. W¹ is —CH₂—, —CH₂CH₂— or —O—, or two separate —H. R^{s1} is each independently hydrogen or a C₁-C₁₀ hydrocarbyl group. R^{s2} is a single bond or a C₁-C₅ straight or branched hydrocarbylene group. R^{s3} is each independently hydrogen, a C₁-C₁₅ hydrocarbyl or fluorinated hydrocarbyl group, or an acid labile group. When R^{s3} is a hydrocarbyl or fluorinated hydrocarbyl group, an ether bond (—O—) or carbonyl moiety (—C(═O)—) may intervene in a carbon-carbon bond. R^{s4} is a C₁-C₂₀ (u+1)-valent hydrocarbon or fluorinated hydrocarbon group, and u is an integer of 1 to 3. R^{s5} is each independently hydrogen or a group having the formula: —C(═P)—O—R^{sa} wherein R^{sa} is a C₁-C₂₀ fluorinated hydrocarbyl group. R^{s6} is a C₁-C₁₅ hydrocarbyl or fluorinated hydrocarbyl group in which an ether bond or carbonyl moiety may intervene in a carbon-carbon bond.

The hydrocarbyl group represented by R^{s1} is preferably saturated and may be straight, branched or cyclic. Examples thereof include alkyl groups such as methyl, ethyl, n-propyl, isopropyl, n-butyl, isobutyl, sec-butyl, tert-butyl, n-pentyl, n-hexyl, n-heptyl, n-octyl, n-nonyl, and n-decyl, and cyclic saturated hydrocarbyl groups such as cyclopropyl, cyclobutyl, cyclopentyl, cyclohexyl, adamantyl, and norbornyl. Inter alia, C₁-C₆ hydrocarbyl groups are preferred.

The hydrocarbylene group represented by R^{s2} is preferably saturated and may be straight, branched or cyclic. Examples thereof include methylene, ethylene, propylene, butylene and pentylene.

The hydrocarbyl group represented by R^{s3} or R^{s6} may be saturated or unsaturated and straight, branched or cyclic. Examples thereof include saturated hydrocarbyl groups, and aliphatic unsaturated hydrocarbyl groups such as alkenyl and alkynyl groups, with the saturated hydrocarbyl groups being preferred. Suitable saturated hydrocarbyl groups include those exemplified for the hydrocarbyl group represented by R^{s1} as well as n-undecyl, n-dodecyl, tridecyl, tetradecyl, and pentadecyl. Examples of the fluorinated hydrocarbyl group represented by R^{s3} or R^{s6} include the foregoing hydrocarbyl groups in which some or all carbon-bonded hydrogen atoms are substituted by fluorine atoms. In these groups, an ether bond or carbonyl moiety may intervene in a carbon-carbon bond as mentioned above.

Examples of the acid labile group represented by R^{s3} include groups of the above formulae (AL-1) to (AL-3), trialkylsilyl groups in which each alkyl moiety has 1 to 6 carbon atoms, and C₄-C₂₀ oxoalkyl groups.

The (u+1)-valent hydrocarbon or fluorinated hydrocarbon group represented by R^{s4} may be straight, branched or cyclic and examples thereof include the foregoing hydrocarbyl or fluorinated hydrocarbyl groups from which the number (u) of hydrogen atoms are eliminated.

The fluorinated hydrocarbyl group represented by R^{sa} is preferably saturated and may be straight, branched or cyclic. Examples thereof include the foregoing hydrocarbyl groups in which some or all hydrogen atoms are substituted by fluorine atoms. Illustrative examples include trifluoromethyl, 2,2,2-trifluoroethyl, 3,3,3-trifluoro-1-propyl, 3,3,3-trifluoro-2-propyl, 2,2,3,3-tetrafluoropropyl, 1,1,1,3,3,3-hexafluoroisopropyl, 2,2,3,3,4,4,4-heptafluorobutyl, 2,2,3,3,4,4,5,5-octafluoropentyl, 2,2,3,3,4,4,5,5,6,6,7,7-dodecafluoroheptyl, 2-(perfluorobutyl)ethyl, 2-(perfluorohexyl)ethyl, 2-(perfluorooctyl)ethyl, and 2-(perfluorodecyl)ethyl.

Examples of the repeat units having formulae (6A) to (6E) are shown below, but not limited thereto. Herein R^{B} is as defined above.

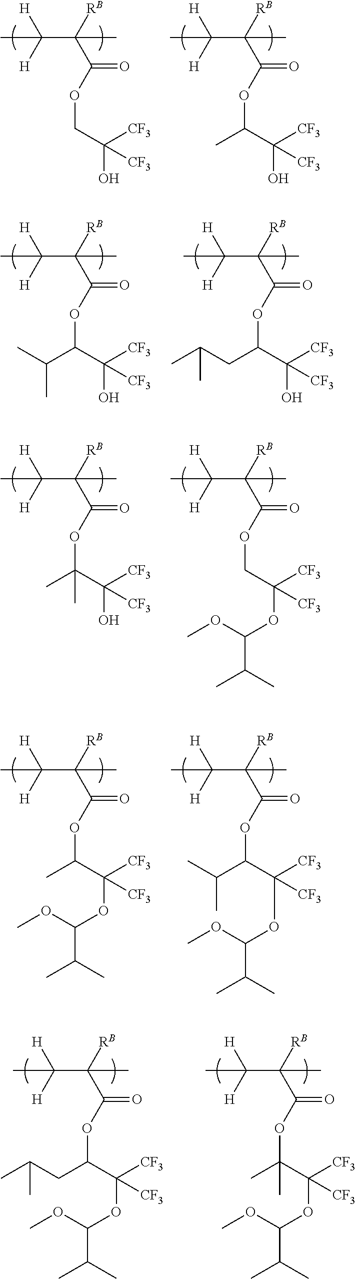

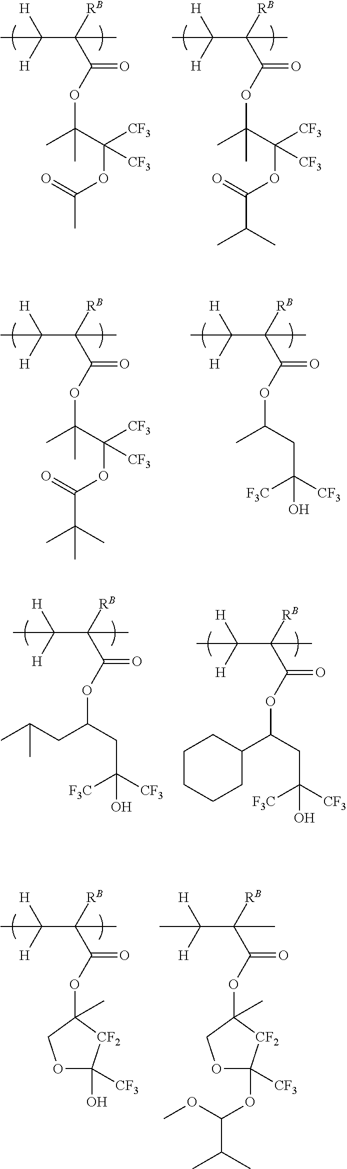

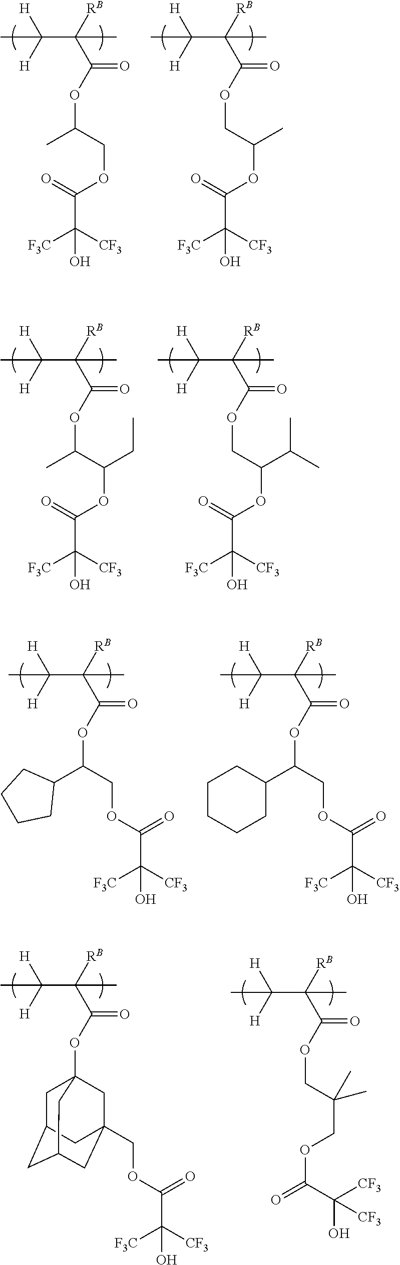

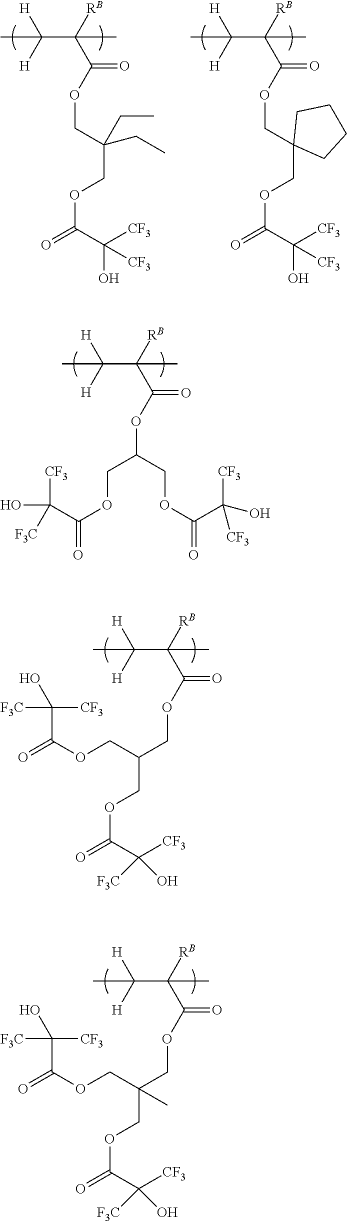

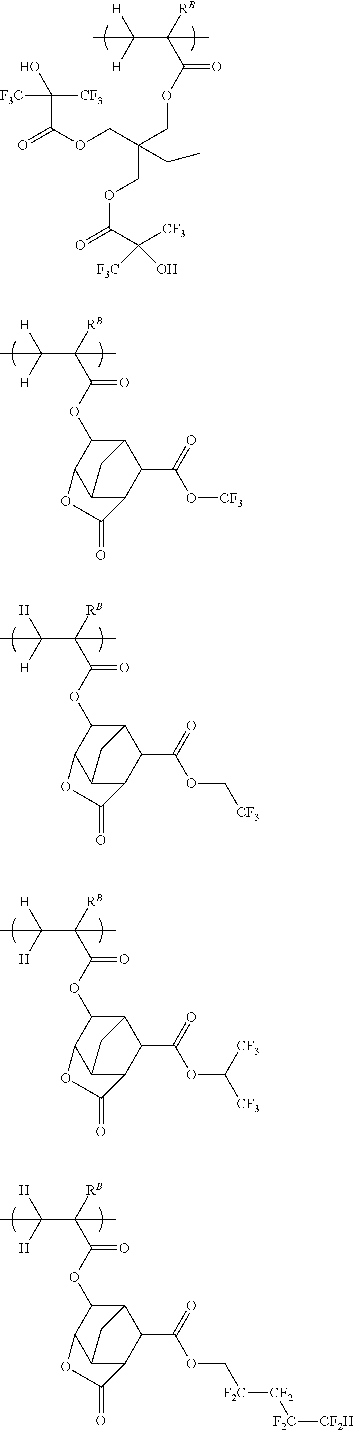

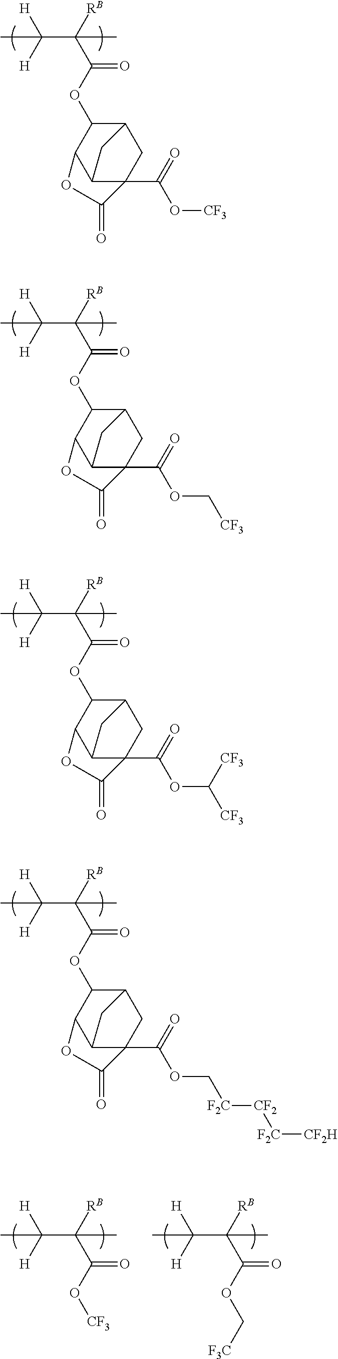

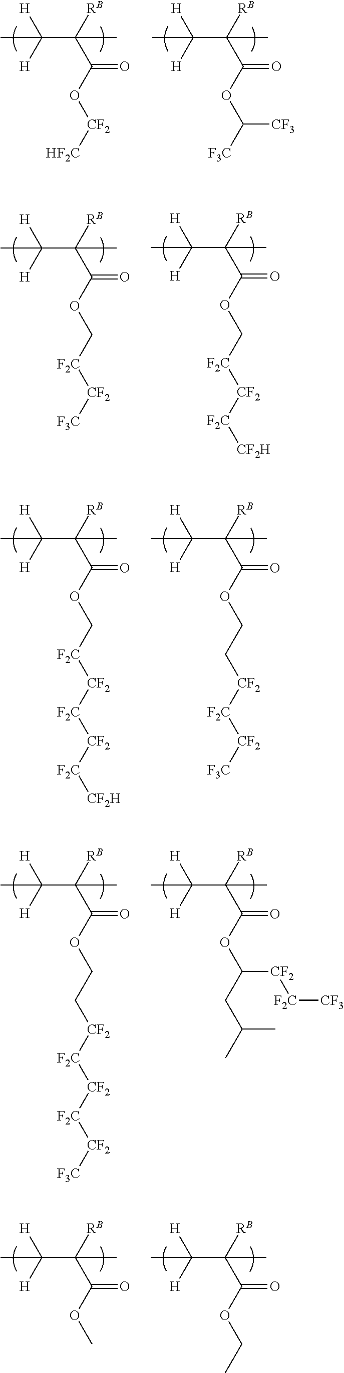

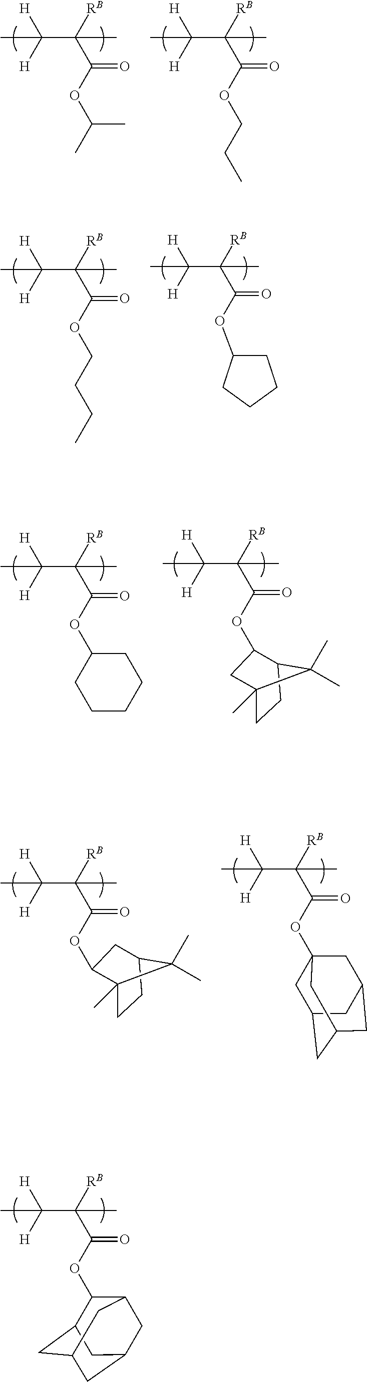

The polymeric surfactant may further contain repeat units other than the repeat units having formulae (6A) to (6E). Typical other repeat units are those derived from methacrylic acid and α-trifluoromethylacrylic acid derivatives. In the polymeric surfactant, the content of the repeat units having formulae (6A) to (6E) is preferably at least 20 mol %, more preferably at least 60 mol %, most preferably 100 mol % of the overall repeat units.

The polymeric surfactant preferably has a Mw of 1,000 to 500.000, more preferably 3,000 to 100,000 and a Mw/Mn of 1.0 to 2.0, more preferably 1.0 to 1.6.

The polymeric surfactant may be synthesized by any desired method, for example, by dissolving an unsaturated bond-containing monomer or monomers providing repeat units having formula (6A) to (6E) and optionally other repeat units in an organic solvent, adding a radical initiator, and heating for polymerization. Suitable organic solvents used herein include toluene, benzene, THF, diethyl ether, and dioxane. Examples of the polymerization initiator used herein include AIBN, 2,2′-azobis(2,4-dimethylvaleronitrile), dimethyl 2,2-azobis(2-methylpropionate), benzoyl peroxide, and lauroyl peroxide. Preferably the reaction temperature is 50 to 100° C. and the reaction time is 4 to 24 hours. The acid labile group that has been incorporated in the monomer may be kept as such, or the polymer may be protected or partially protected therewith at the end of polymerization.

During the synthesis of polymeric surfactant, any blown chain transfer agent such as dodecyl mercaptan or 2-mercaptoethanol may be added for molecular weight control purpose. The amount of chain transfer agent added is preferably 0.01 to 10 mol % based on the total moles of monomers to be polymerized.

When the resist composition contains a surfactant (F), the amount thereof is preferably 0.1 to 50 parts by weight, and more preferably 0.5 to 10 parts by weight per 80 parts by weight of polymer P as component (A). At least 0.1 part of the surfactant is effective in improving the receding contact angle with water of the resist film at its surface. Up to 50 parts of the surfactant is effective in forming a resist film having a low rate of dissolution in a developer and capable of maintaining the height of a fine pattern formed therein.

### (G) Other Components

The resist composition may further comprise (G) another component, for example, a compound which is decomposed with an acid to generate another acid (i.e., acid amplifier compound), an organic acid derivative, a fluorinated alcohol, and a compound having a Mw of up to 3,000 which changes its solubility in developer under the action of an acid (i.e., dissolution inhibitor). Specifically, the acid amplifier compound is described in JP-A 2009-269953 and JP-A 2010-215608 and preferably used in an amount of 0 to 5 parts, more preferably 0 to 3 parts by weight per 80 parts by weight of polymer P as component (A). An extra amount of the acid amplifier compound can make the acid diffusion control difficult and cause degradations to resolution and pattern profile. With respect to the remaining additives, reference should be made to JP-A 2009-269953 and JP-A 2010-215608.

### Process

Another embodiment of the invention is a pattern forming process using the chemically amplified resist composition defined above. A pattern may be formed from the resist composition using any well-known lithography process. The preferred process includes the steps of applying the chemically amplified resist composition onto a substrate to form a resist film thereon, exposing the resist film to high-energy radiation, and developing the exposed resist film in a developer. Any desired steps may be added to the process if necessary.

The substrate used herein may be a substrate for integrated circuitry fabrication, e.g., Si, SiO₂, SiN, SiON, TiN, WSi, BPSG, SOG, organic antireflective film, etc. or a substrate for mask circuitry fabrication, e.g., Cr, CrO, CrON, MoSi₂, SiO₂, etc.

The resist composition is applied onto a substrate by a suitable coating technique such as spin coating. The coating is prebaked on a hot plate preferably at a temperature of 60 to 150° C. for 1 to 10 minutes, more preferably at 80 to 140° C. for 1 to 5 minutes. The resulting resist film preferably has a thickness of 0.05 to 2 μm.

Then the resist film is exposed patternwise to high-energy radiation, for example, i-line, KrF or ArF excimer laser, EUV or EB. On use of i-line, KrF excimer laser, ArF excimer laser or EUV of wavelength 13.5 nm the resist film is exposed through a mask having a desired pattern, preferably in a dose of 1 to 200 mJ/cm², more preferably 10 to 100 mJ/cm². On use of EB, a pattern may be written directly or through a mask having the desired pattern, preferably in a dose of 1 to 300 μC/cm², more preferably 10 to 200 μC/cm².

The exposure may be performed by conventional lithography whereas the immersion lithography of holding a liquid having a refractive index of at least 1.0 between the resist film and the projection lens may be employed if desired. The liquid is typically water, and in this case, a protective film which is insoluble in water may be formed on the resist film.

While the water-insoluble protective film serves to prevent any components from being leached out of the resist film and to improve water sliding on the film surface, it is generally divided into two types. The first type is an organic solvent-strippable protective film which must be stripped prior to alkaline development, with an organic solvent in which the resist film is not dissolvable. The second type is an alkali-soluble protective film which is soluble in an alkaline developer so that it can be removed simultaneously with the removal of solubilized regions of the resist film. The protective film of the second type is preferably of a material comprising a polymer having a 1,1,1,3,3,3-hexafluoro-2-propanol residue (which is insoluble in water and soluble in an alkaline developer) as a base in an alcohol solvent of at least 4 carbon atoms, an ether solvent of 8 to 12 carbon atoms or a mixture thereof. Alternatively, the aforementioned surfactant which is insoluble in water and soluble in an alkaline developer may be dissolved in an alcohol solvent of at least 4 carbon atoms, an ether solvent of 8 to 12 carbon atoms or a mixture thereof to form a material from which the protective film of the second type is formed.

After the exposure, the resist film may be baked (PEB), for example, on a hotplate at 60 to 150° C. for 1 to 5 minutes, preferably at 80 to 140° C. for 1 to 3 minutes.

The resist film is then developed with a developer in the form of an aqueous base solution, for example, 0.1 to 5 wt %, preferably 2 to 3 wt % aqueous solution of tetramethylammonium hydroxide (TMAH) for 0.1 to 3 minutes, preferably 0.5 to 2 minutes by conventional techniques such as dip, puddle and spray techniques. In this way, a desired resist pattern is formed on the substrate.

Any desired step may be added to the pattern forming process. For example, after the resist film is formed, a step of rinsing with pure water (post-soaking) may be introduced to extract the acid generator or the like from the film surface or wash away particles. After exposure, a step of rinsing (post-soaking) may be introduced to remove any water remaining on the film after exposure.

Also, a double patterning process may be used for pattern formation. The double patterning process includes a trench process of processing an underlay to a 1:3 trench pattern by a first step of exposure and etching, shifting the position, and forming a 1:3 trench pattern by a second step of exposure, for forming a 1:1 pattern; and a line process of processing a first underlay to a 1:3 isolated left pattern by a first step of exposure and etching, shifting the position, processing a second underlay formed below the first underlay by a second step of exposure through the 1:3 isolated left pattern, for forming a half-pitch 1:1 pattern.

In the pattern forming process, negative tone development may also be used. That is, an organic solvent may be used instead of the aqueous alkaline solution as the developer for developing and dissolving away the unexposed region of the resist film.

The organic solvent used as the developer is preferably selected from 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, isopentyl acetate, butenyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, prowl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, benzyl formate, phenylethyl formate, methyl 3-phenylpropionate, benzyl propionate, ethyl phenylacetate, and 2-phenylethyl acetate. These organic solvents may be used alone or in admixture of two or more.

### EXAMPLES

Synthesis Examples, Examples and Comparative Examples are given below by way of illustration and not by way of limitation. The abbreviation “pbw” is parts by weight. For all polymers, Mw and Mn are determined by GPC versus polystyrene standards using DMF solvent. Analysis is made by IR spectroscopy and NMR spectroscopy using analytic instruments as shown below.

### IR: NICOLET 6700 by Thermo Fisher Scientific Inc.

### ¹H-NMR: ECA-500 by JEOL Ltd.

### ¹⁹F-NMR: ECA-500 by JEOL Ltd.

### [1] Synthesis of Monomers

### Synthesis Example 1-1

Synthesis of Monomer MA-1

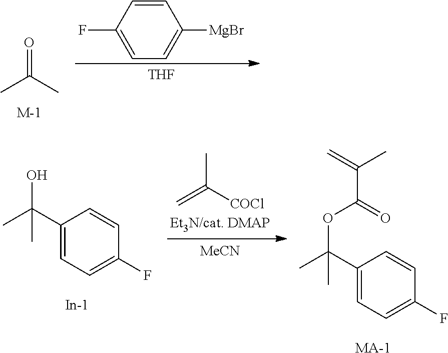

### (1) Synthesis of Intermediate In-1

In nitrogen atmosphere, a Grignard reagent was prepared using 160.5 g of magnesium, 1,155 g of 4-bromofluorobenzene, and 3,300 g of THF. While the internal temperature was kept below 45° C., a solution of 348.5 g of Reactant M-1 in 700 g of THF was added dropwise to the Grignard reagent. The solution was stirred for 2 hours at an internal temperature of 50° C. The reaction solution was ice cooled, after which a mixture of 660 g of ammonium chloride and 3,960 g of 3.0 wt % hydrochloric acid aqueous solution was added dropwise to quench the reaction. 4,500 mL of toluene was added to the solution, followed by ordinary aqueous workup, solvent stripping, and distillation for purification. There was obtained 865 g of Intermediate In-1 as colorless oily matter (yield 94%).

### (2) Synthesis of Monomer MA-1

In nitrogen atmosphere, 821 g of methacrylic chloride was added dropwise to a solution of 865 g of Intermediate In-1, 1,022 g of triethylamine, 68.5 g of dimethylaminopyridine, and 3,150 mL of acetonitrile at an internal temperature below 60° C. The solution was aged for 20 hours at an internal temperature of 55° C. The reaction solution was ice cooled, after which 2,000 mL of saturated sodium hydrogencarbonate solution was added dropwise to quench the reaction. This was followed by extraction with 4,200 mL of toluene, ordinary aqueous workup, solvent stripping, and vacuum distillation. There was obtained 1,012 g of Monomer MA-1 as colorless transparent oily matter (yield 81%).

Monomer MA-1 was analyzed by IR and ¹H- and ¹⁹F-NMR spectroscopy, with the data shown below.

IR (D-ATR): ν=2982, 2930, 1717, 1637, 1603, 1512, 1454, 1406, 1383, 1366, 1329, 1304, 1271, 1234, 1179, 1163, 1137, 1105, 1095, 1015, 941, 835, 813, 724, 655, 607, 556, 533 cm⁻¹

¹H-NMR (600 MHz in DMSO-d6):
δ=7.38 (2H, dd), 7.14 (2H, dd), 6.02 (1H, d), 5.64 (1H, d), 1.84 (3H, s), 1.73 (6H, s) ppm

¹⁹F-NMR (600 MHz in DMSO-d6):
δ=−117.49 (1F, m) ppm

### Synthesis Example 1-2

Synthesis of Monomer MA-2

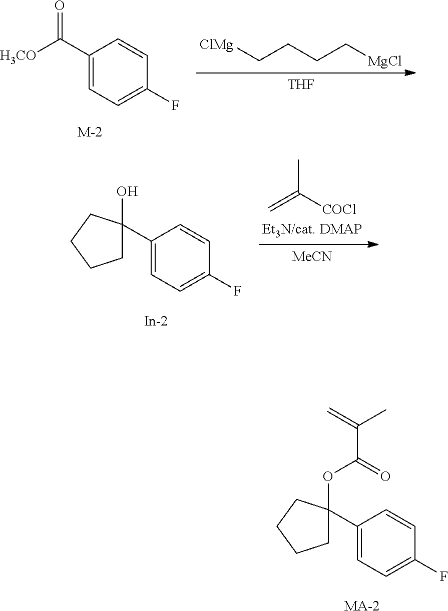

### (1) Synthesis of Intermediate In-2

In nitrogen atmosphere, a Grignard reagent was prepared using 59 g of magnesium, 146 g of 1,4-dichlorobutane, and 1,000 mL of THF. While the internal temperature was kept below 50° C., a solution of 154 g of Reactant M-2 in 150 mL of THF was added dropwise to the Grignard reagent. The solution was stirred for 2 hours at an internal temperature of 50° C. The reaction solution was ice cooled, after which a mixture of 240 g of ammonium chloride and 1.450 g of 3.0 wt % hydrochloric acid aqueous solution was added dropwise to quench the reaction. 800 mL of toluene was added to the solution, followed by ordinary aqueous workup, solvent stripping, and vacuum distillation. There was obtained 175 g of Intermediate In-2 as colorless transparent oily matter (yield 98%).

### (2) Synthesis of Monomer MA-2

Synthesis was performed by the same procedure as Synthesis Example 1-1 (2) aside from using Intermediate In-2 instead of Intermediate In-1. There was obtained Monomer MA-2 as colorless transparent oily matter (yield 82%).

Monomer MA-2 was analyzed by IR and ¹H- and ¹⁹F-NMR spectroscopy, with the data shown below.

IR (D-ATR): ν=3048, 2960, 2877, 1885, 1717, 1636, 1606, 1512, 1451, 1407, 1377, 1331, 1302, 1231, 1165, 1151, 1098, 1043, 1014, 982, 967, 941, 898, 833, 814, 725, 652, 581, 550 cm⁻¹

¹H-NMR (600 MHz in DMSO-d6):
δ=7.38 (2H, dd), 7.12 (2H, dd), 6.00 (1H, d), 5.62 (1H, d), 2.37 (2H, m), 2.03 (2H, m), 1.81 (3H, s), 1.77-1.72 (4H, m) ppm

¹⁹F-NMR (600 MHz in DMSO-d6):
δ=−117.13 (1F, m) ppm

### Synthesis Examples 1-3 to 1-18

Synthesis of Monomers MA-3 to MA-18

Monomers MA-3 to MA-18 were similarly synthesized using the corresponding reactants.

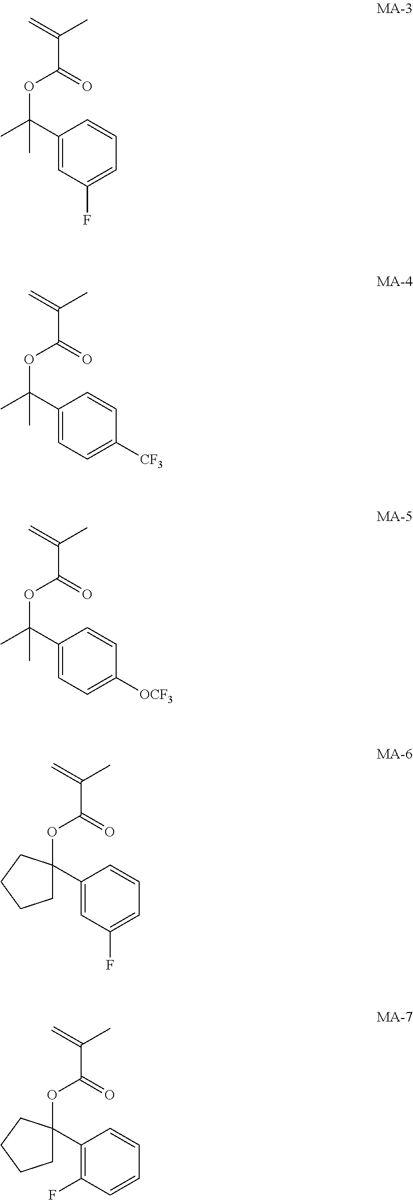 [SMILES: C=C(C)C(=O)OC(C)(C)c1cccc(F)c1 ; C=C(C)C(=O)OC(C)(C)c1ccc(C(F)(F)F)cc1 ; C=C(C)C(=O)OC(C)(C)c1ccc(OC(F)(F)F)cc1 ; C=C(C)C(=O)OC1(c2cccc(F)c2)CCCC1 ; C=C(C)C(=O)OC1(c2ccccc2F)CCCC1]

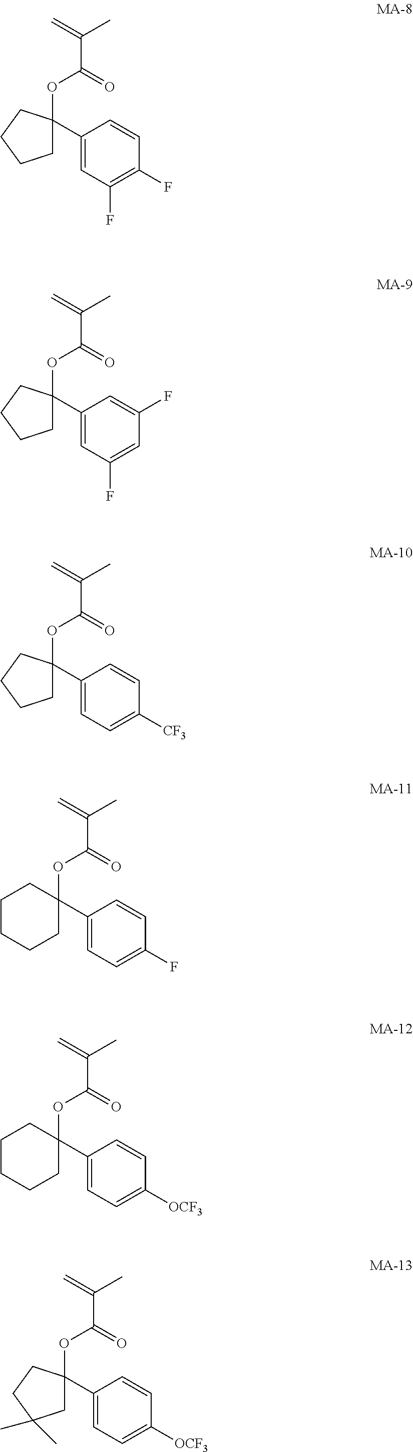 [SMILES: C=C(C)C(=O)OC1(c2ccc(F)c(F)c2)CCCC1 ; C=C(C)C(=O)OC1(c2cc(F)cc(F)c2)CCCC1 ; C=C(C)C(=O)OC1(c2ccc(C(F)(F)F)cc2)CCCC1 ; C=C(C)C(=O)OC1(c2ccc(F)cc2)CCCCC1 ; C=C(C)C(=O)OC1(c2ccc(OC(F)(F)F)cc2)CCCCC1 ; C=C(C)C(=O)OC1(c2ccc(OC(F)(F)F)cc2)CCC(C)(C)C1]

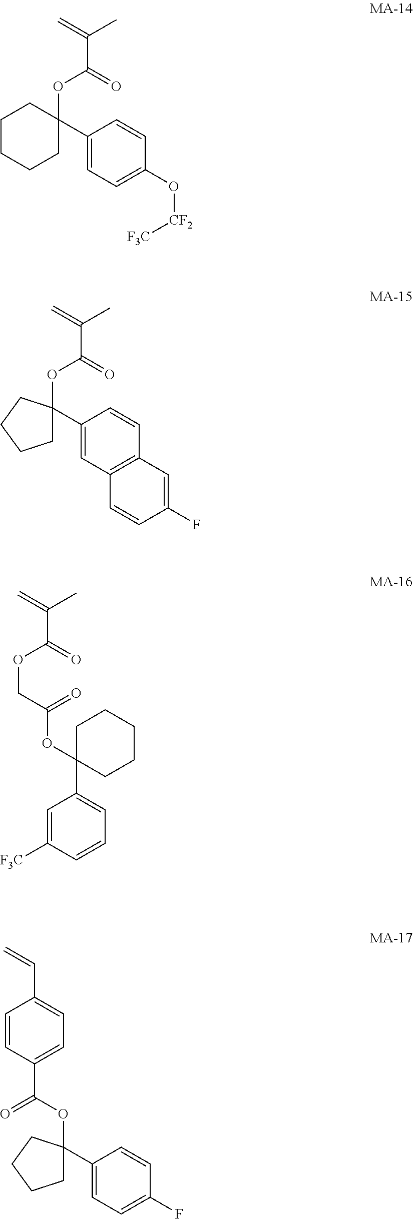 [SMILES: C=C(C)C(=O)OC1(c2ccc(OC(F)(F)C(F)(F)F)cc2)CCCCC1 ; C=C(C)C(=O)OC1(c2ccc3cc(F)ccc3c2)CCCC1 ; C=C(C)C(=O)OCC(=O)OC1(c2cccc(C(F)(F)F)c2)CCCCC1 ; C=Cc1ccc(C(=O)OC2(c3ccc(F)cc3)CCCC2)cc1]

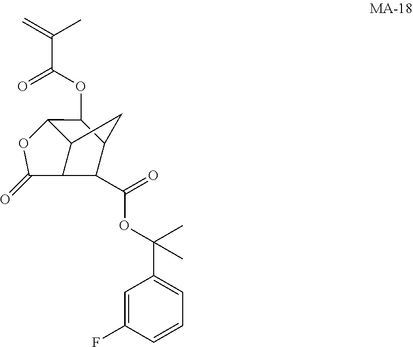 [SMILES: C=C(C)C(=O)OC1C2CC3C1OC(=O)C3C2C(=O)OC(C)(C)c1cccc(F)c1]

IR and ¹H- and ¹⁹F-NMR spectroscopy data of Monomer MA-3 are shown below.

IR (D-ATR): ν=2983, 2930, 1720, 1637, 1616, 1592, 1489, 1446, 1435, 1401, 1383, 1366, 1329, 1302, 1284, 1273, 1176, 1135, 1101, 1069, 1009, 939, 895, 872, 830, 814, 785, 698, 653, 573, 518, 471 cm⁻¹

¹H-NMR (600 MHz in DMSO-d6):
δ=7.37 (1H, m), 7.18 (1H, m), 7.14 (1H, m), 7.06 (1H, m), 6.04 (1H, d), 5.66 (1H, d), 1.85 (3H, s), 1.73 (6H, s) ppm

¹⁹F-NMR (600 MHz in DMSO-d6):
δ=−114.35 (1F, m) ppm

IR and ¹H- and ¹⁹F-NMR spectroscopy data of Monomer MA-4 are shown below.

IR (D-ATR): ν=2985, 1720, 1638, 1621, 1452, 1411, 1384, 1367, 1328, 1303, 1271, 1167, 1128, 1115, 1100, 1068, 1017, 942, 841, 814, 715, 651, 620, 605, 544 cm⁻¹

¹H-NMR (600 MHz in DMSO-d6):
δ=7.69 (2H, d), 7.56 (2H, d), 6.06 (1H, d), 5.67 (1H, d), 1.85 (3H, s), 1.75 (6H, s) ppm

¹⁹F-NMR (600 MHz in DMSO-d6):
δ=−62.13 (3F, s) ppm

IR and ¹H- and ¹⁹F-NMR spectroscopy data of Monomer MA-5 are shown below.

IR (D-ATR): ν=2984, 1720, 1638, 1512, 1454, 1410, 1384, 1367, 1330, 1303, 1259, 1223, 1170, 1139, 1098, 1019, 941, 850, 813, 672, 613, 560 cm⁻¹

¹H-NMR (600 MHz in DMSO-d6):
δ=7.4.6 (2H, dd), 7.31 (2H, dd), 6.04 (1H, d), 5.66 (1H, d), 1.85 (3H, s), 1.73 (6H, s) ppm

¹⁹F-NMR (600 MHz in DMSO-d6):
δ=−57.98 (3F, s) ppm

IR and ¹H- and ¹⁹F-NMR spectroscopy data of Monomer MA-6 are shown below.

IR (D-ATR): ν=2960, 2877, 1719, 1637, 1616, 1591, 1490, 1443, 1401, 1378, 1331, 1301, 1269, 1198, 1155, 1077, 1046, 1008, 976, 941, 867, 838, 816, 783, 696, 658, 523, 462 cm⁻¹

¹H-NMR (600 MHz in DMSO-d6):
δ=7.35 (1H, m), 7.17 (1H, m), 7.12 (1H, m), 7.06 (1H, m), 6.03 (1H, s), 5.64 (1H, s), 2.34 (2H, m), 2.06 (2H, m), 1.83 (3H, s), 1.77-1.74 (4H, m) ppm

¹⁹F-NMR (600 MHz in DMSO-d6):
δ=−114.61 (1F, m) ppm

IR and ¹H- and ¹⁹F-NMR spectroscopy data of Monomer MA-7 are shown below.

IR (D-ATR): ν=2958, 2877, 1717, 1637, 1616, 1581, 1491, 1450, 1402, 1377, 1330, 1303, 1218, 1176, 1154, 1103, 1041, 1008, 983, 970, 938, 900, 862, 814, 756, 653, 550, 479 cm⁻¹

¹H-NMR (600 MHz in DMSO-d6):
δ=7.43 (1H, m), 7.29 (1H, m), 7.12 (2H, m), 5.97 (1H, s), 5.60 (1H, s), 2.46 (2H, m), 2.10 (2H, m), 1.80 (3H, s), 1.77-1.72 (4H, m) ppm

¹⁹F-NMR (600 MHz in DMSO-d6):
δ=−113.83 (1F, m) ppm

IR and ¹H- and ¹⁹F-NMR spectroscopy data of Monomer MA-8 are shown below.

IR (D-ATR): ν=2961, 2878, 1719, 1637, 1610, 1520, 1451, 1424, 1378, 1330, 1298, 1285, 1196, 1159, 1118, 1044, 1008, 977, 942, 868, 816, 775, 709, 650, 617, 579, 460 cm⁻¹

¹H-NMR (600 MHz in DMSO-d6):
δ=7.37 (2H, m), 7.19 (1H, m), 6.02 (1H, s), 5.63 (1H, s), 2.35 (2H, m), 2.04 (2H, m), 1.82 (3H, s), 1.77-1.73 (4H, m) ppm

¹⁹F-NMR (600 MHz in DMSO-d6):
δ=−140.13 (1F, m), −142.34 (1F, m) ppm

IR and ¹H- and ¹⁹F-NMR spectroscopy data of Monomer MA-9 are shown below.

IR (D-ATR): ν=3048, 2960, 2877, 1885, 1717, 1636, 1606, 1512, 1451, 1407, 1377, 1331, 1302, 1231, 1165, 1151, 1098, 1043, 1014, 982, 967, 941, 898, 833, 814, 725, 652, 581, 550 cm⁻¹

¹H-NMR (600 MHz in DMSO-d6):
δ=7.38 (2H, dd), 7.12 (2H, dd), 6.00 (1H, d), 5.62 (1H, d), 2.37 (2H, m), 2.03 (2H, m), 1.81 (3H, s), 1.78-1.74 (4H, m) ppm

¹⁹F-NMR (600 MHz in DMSO-d6):
δ=−111.10 (2F, m) ppm

IR and ¹H- and ¹⁹F-NMR spectroscopy data of Monomer MA-10 are shown below.

IR (D-ATR): ν=2962, 2879, 1719, 1637, 1620, 1451, 1411, 1378, 1327, 1159, 1125, 1071, 1017, 984, 943, 899, 839, 816, 650, 602, 523 cm⁻¹

¹H-NMR (600 MHz in DMSO-d6):
δ=7.67 (2H, dd), 7.55 (2H, dd), 6.05 (1H, d), 5.66 (1H, d), 2.35 (2H, m), 2.10 (2H, m), 1.83 (3H, s), 1.81-1.74 (4H, m) ppm

¹⁹F-NMR (600 MHz in DMSO-d6):
δ=−62.15 (3F, s) ppm

IR and ¹H- and ¹⁹F-NMR spectroscopy data of Monomer MA-11 are shown below.

IR (D-ATR): ν=3048, 2936, 2862, 1719, 1637, 1602, 1513, 1450, 1409, 1377, 1364, 1328, 1303, 1280, 1253, 1223, 1171, 1162, 1130, 1103, 1035, 1013, 961, 939, 916, 906, 847, 833, 824, 810, 778, 723, 652, 604, 578, 550, 506 cm⁻¹

¹H-NMR (600 MHz in DMSO-d6):
δ=7.35 (2H, dd), 7.14 (2H, dd), 6.06 (1H, d), 5.66 (1H, d), 2.39 (2H, m), 1.86 (3H, s), 1.78-1.52 (7H, m), 1.29 (1H, m) ppm

¹⁹F-NMR (600 MHz in DMSO-d6):
δ=−117.42 (1F, m) ppm

IR and ¹H- and ¹⁹F-NMR spectroscopy data of Monomer MA-12 are shown below.

IR (D-ATR): ν=2937, 2863, 1721, 1637, 1595, 1511, 1451, 1402, 1378, 1328, 1303, 1260, 1219, 1166, 1130, 1113, 1035, 1015, 962, 940, 924, 907, 847, 806, 678, 640, 614, 556 cm⁻¹

¹H-NMR (600 MHz in DMSO-d6):
δ=7.44 (2H, dd), 7.30 (2H, dd), 6.07 (1H, d), 5.67 (1H, d), 2.38 (2H, dm), 1.87 (3H, s), 1.76 (2H, tm), 1.68-1.50 (5H, m), 1.29 (1H, m) ppm

¹⁹F-NMR (600 MHz in DMSO-d6):
δ=−57.96 (3F, s) ppm

### Comparative Synthesis Examples 1-1 to 1-8

Synthesis of Comparative Monomers MAX-1 to MAX-8

Comparative Monomers MAX-1 to MAX-8 were similarly synthesized using the corresponding reactants.

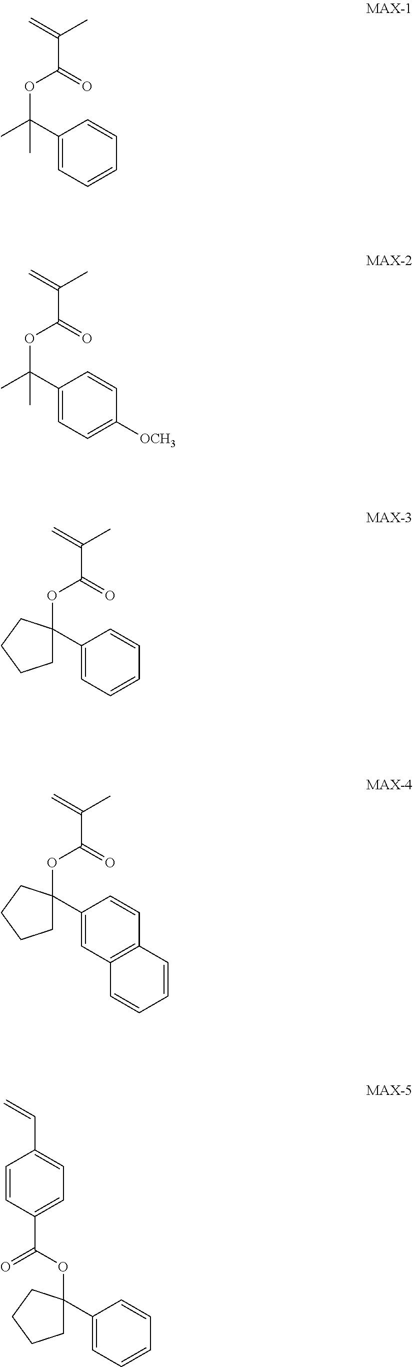 [SMILES: C=C(C)C(=O)OC(C)(C)c1ccccc1 ; C=C(C)C(=O)OC(C)(C)c1ccc(OC)cc1 ; C=C(C)C(=O)OC1(c2ccccc2)CCCC1 ; C=C(C)C(=O)OC1(c2ccc3ccccc3c2)CCCC1 ; C=Cc1ccc(C(=O)OC2(c3ccccc3)CCCC2)cc1]

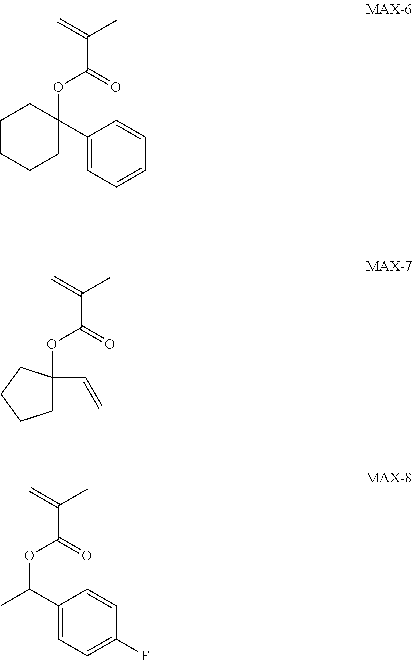

### [2] Synthesis of Polymers

Monomers MA-1 to MA-18, Comparative Monomers MAX-1 to MAX-8, and the monomers shown below were used in the synthesis of polymers.

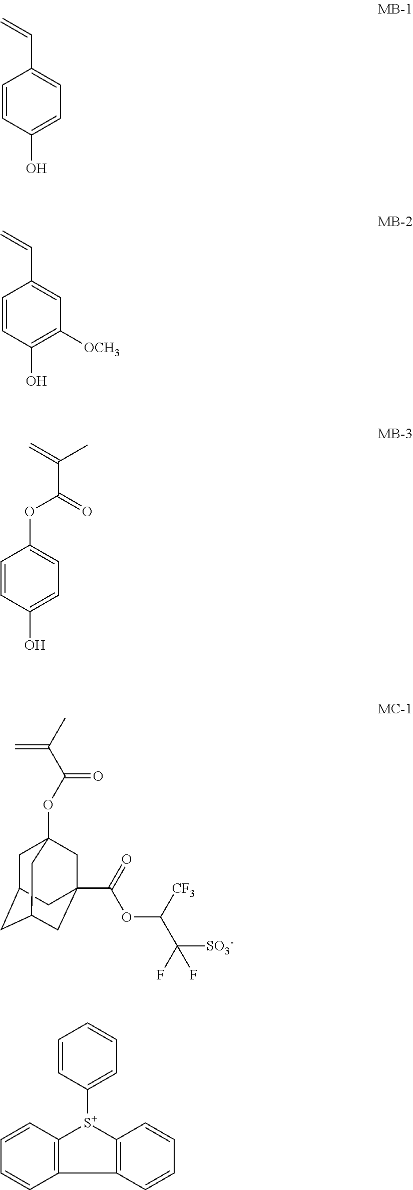

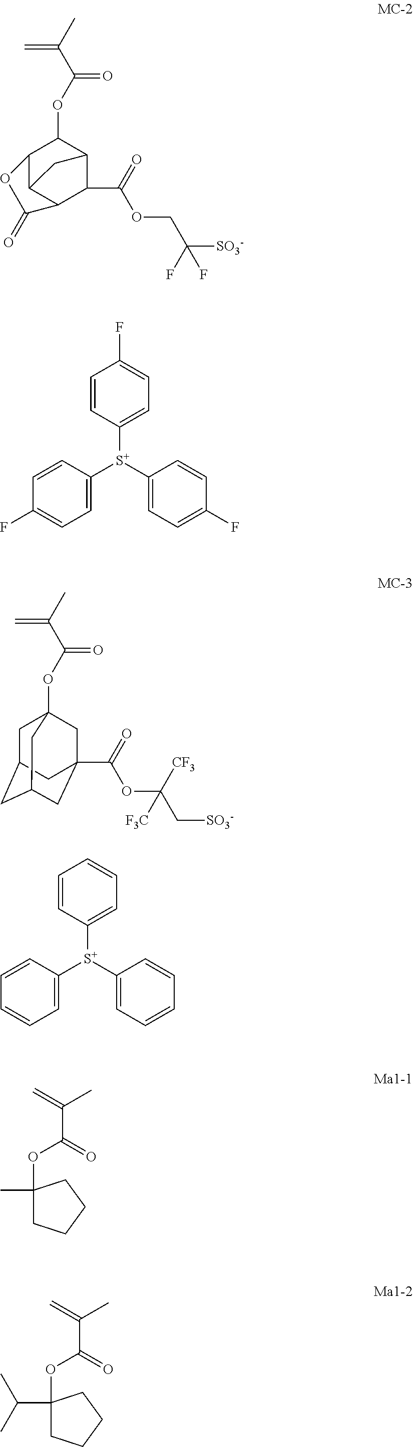

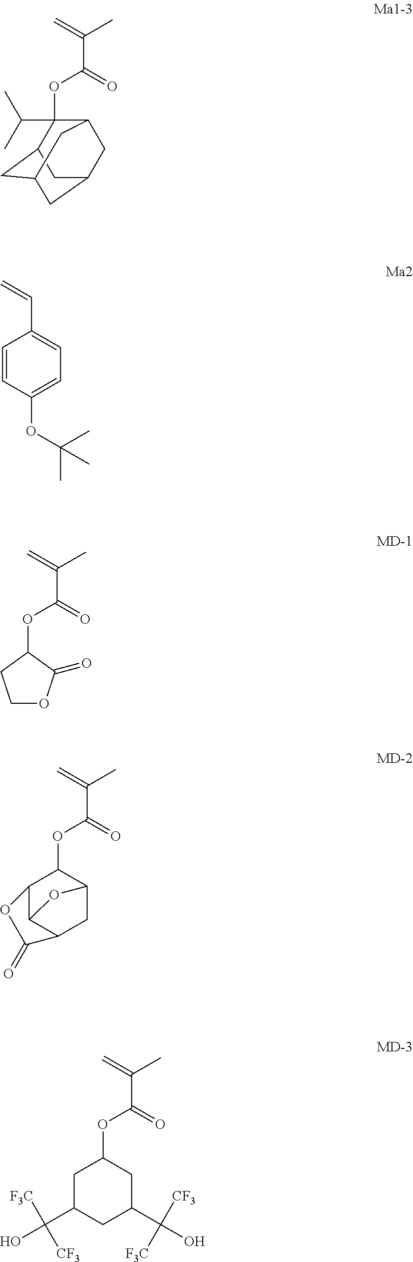 [SMILES: C=C(C)C(=O)OC1(C(C)C)C2CC3CC(C2)CC1C3 ; C=Cc1ccc(OC(C)(C)C)cc1 ; C=C(C)C(=O)OC1CCOC1=O ; C=C(C)C(=O)OC1C2CC3C(=O)OC1C3O2 ; C=C(C)C(=O)OC1CC(C(O)(C(F)(F)F)C(F)(F)F)CC(C(O)(C(F)(F)F)C(F)(F)F)C1]

### Synthesis Example 2-1

Synthesis of Polymer P-1

In a funnel under nitrogen atmosphere, 50.1 g of Monomer MA-1, 24.8 g of Monomer MB-1, 38.0 g of Monomer MC-1, 3.96 g of dimethyl 2,2′-azobis(2-methylpropionate) (11-601 by Fujifilm Wako Pure Chemical Corp.), and 127 g of MEK were combined to form a monomer % initiator solution. A flask in nitrogen atmosphere was charged with 46 g of MEL which was heated at 80° C. with stirring. With stirring, the monomer/initiator solution was added dropwise to the flask over 4 hours. After the completion of dropwise addition, the polymerization solution was continuously stirred for 2 hours while maintaining the temperature of 80° C. The polymerization solution was cooled to mom temperature, whereupon it was added dropwise to 2,000 g of hexane with vigorous stirring. The precipitate was collected by filtration, washed twice with 600 g of hexane, and vacuum dried at 50° C. for 20 hours, obtaining Polymer P-1 in white powder form (amount 98.1 g, yield 98%). On GPC analysis, Polymer P-1 had a Mw of 10,900 and a Mw/Mn of 1.82.

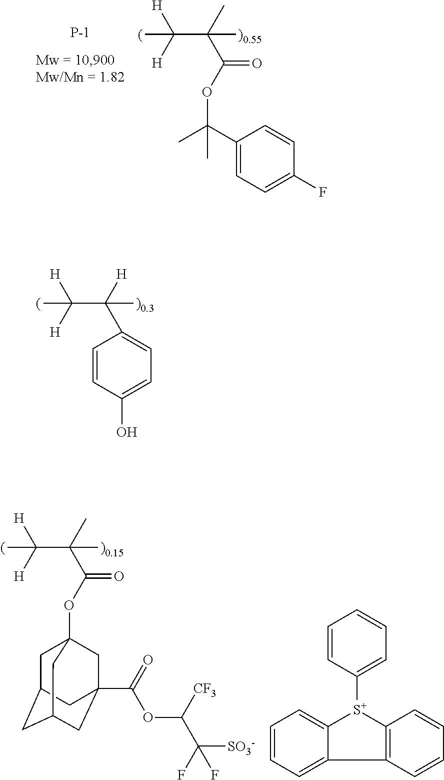

### Synthesis Examples 2-2 to 2-30 and Comparative Synthesis Examples 2-1 to 2-15

Synthesis of Polymers P-2 to P-30 and CP-1 to CP-15

Polymers as shown in Tables 1 to 3 were synthesized by the same procedure as in Synthesis Example 2-1 aside from changing the type and amount of monomers. The introduction ratio in Tables 1 to 3 designates mol % of the relevant unit.

TABLE 1

| | Monomer A | Monomer a | Monomer B | Monomer C | Monomer D | | |
|---|---|---|---|---|---|---|---|
| Polymer | (rato) | (ratio) | (rato) | (ratio) | (ratio) | Mw | Mw/Mn |
| P-1 | MA-1 (55) | — | MB-1 (30) | MC-1 (15) | — | 10,900 | 1.82 |
| P-2 | MA-2 (55) | — | MB-1 (30) | MC-1 (15) | — | 10.800 | 1.81 |
| P-3 | MA-3 (55) | — | MB-1 (30) | MC-1 (15) | — | 10,600 | 1.79 |
| P-4 | NIA-4 (55) | — | MB-1 (30) | MC-1 (15) | — | 10,900 | 1.83 |
| P-5 | MA-5 (55) | — | MB-1 (30) | MC-1 (15) | — | 10,100 | 1.82 |
| P-6 | MA-6 (50) | — | MB-1 (35) | MC-1 (15) | — | 10,300 | 1.84 |
| P-7 | MA-7 (50) | — | MB-1 (35) | MC-1 (15) | — | 10,700 | 1.82 |
| P-8 | MA-8 (50) | — | MB-1 (35) | MC-1 (15) | — | 10,300 | 1.82 |
| P-9 | MA-9 (50) | — | MB-1 (35) | MC-1 (15) | — | 11.000 | 1.83 |
| P-10 | MA-10 (50) | — | MB-1 (35) | MC-1 (15) | — | 11,100 | 1.81 |
| P-11 | MA-11 (55) | — | MB-1 (30) | MC-1 (15) | — | 10,900 | 1.85 |
| P-12 | MA-12 (55) | — | MB-1 (30) | MC-1 (15) | — | 10,800 | 1.82 |
| P-13 | MA-13 (55) | — | MB-1 (30) | MC-1 (15) | — | 11.100 | 1.82 |
| P-14 | MA-14 (55) | — | MB-1 (30) | MC-1 (15) | — | 11,200 | 1.80 |
| P-15 | MA-15 (25 ) | Ma1-1 (25) | MB-2 (35) | MC-1 (15) | — | 10,700 | 1.82 |

TABLE 2

| | Monomer A | Monomer a | Monomer B | Monomer C | Monomer D | | |
|---|---|---|---|---|---|---|---|
| Polymer | (ratio) | (ratio) | (ratio) | (ratio) | (ratio) | Mw | Mw/Mn |
| P-16 | MA-16 (30) | Ma1-1 (25) | MB-1 (30) | MC-1 (15) | — | 11,100 | 1.83 |
| P-17 | MA-17 (25) | Ma1-2 (25) | MB-1 (35) | MC-1 (15) | — | 11,200 | 1.85 |
| P-18 | MA-18 (20) | Ma1-1 (35) | MB-3 (30) | MC-1 (15) | — | 11,200 | 1.84 |
| P-19 | MA-1 (55) | — | MB-1 (30) | MC-2 (15 | — | 10,500 | 1.82 |
| P-20 | MA-2 (55) | — | MB-3 (30) | MC-3 (15 | — | 11,000 | 1.82 |
| P-21 | MA-1 (50) | — | MB-1 (20) | MC-1 (15) | — | 11,200 | 1.85 |
| | | | MB-2 (15) | | | | |
| P-22 | MA-1 (50) | — | MB-1 (35) | MC-1 (15) | — | 11,000 | 1.83 |
| P-23 | MA-1 (60) | — | MB-1 (15) | MC-1 (25) | — | 12,400 | 1.91 |
| P-24 | MA-1 (20) | Ma1-1 (40) | MB-1 (30) | MC-1 (20) | — | 10,500 | 1.82 |
| P-25 | MA-4 (40) | Ma1-2 (20) | MB-1 (30) | MC-2 (20) | — | 10,700 | 1.84 |
| P-26 | MA-8 (50) | — | MB-1 (45) | MC-1 (5) | — | 9,900 | 1.83 |
| P-27 | MA-1 (60) | — | MB-2 (25) | MC-1 (15) | — | 10,700 | 1.83 |
| P-28 | MA-17 (30) | Ma2 (20) | MB-1 (35) | MC-1 (15) | — | 10,800 | 1.84 |
| P-29 | MA-8 (30) | Ma1-1 (25) | MB-1 (30) | MC-2 (15) | — | 10,900 | 1.86 |
| P-30 | MA-18 (20) | Ma1-3 (30) | MB-3 (25) | MC-3 (20) | MD-3 (5) | 11,300 | 1.84 |

TABLE 3

| | Monomer A | Monomer a | Monomer B | Monomer C | Monomer D | | |
|---|---|---|---|---|---|---|---|
| Polymer | (ratio) | (ratio) | (ratio) | (ratio) | (ratio) | Mw | Mw/Mn |
| CP-1 | MAX-1 (55) | — | MB-1 (30) | MC-1 (15) | — | 10,800 | 1.82 |
| CP-2 | MAX-2 (55) | — | MB-1 (30) | MC-1 (15) | — | 10,700 | 1.82 |
| CP-3 | MAX-3 (55) | — | MB-1 (30) | MC-1 (15) | — | 10,900 | 1.82 |
| CP-4 | MAX-4 (55) | — | MB-1 (30) | MC-1 (15) | — | 11,000 | 1.81 |
| CP-5 | MAX-5 (55) | — | MB-1 (30) | MC-1 (15) | — | 10,400 | 1.87 |
| CP-6 | MAX-6 (55) | — | MB-1 (30) | MC-1 (15) | — | 10,800 | 1.84 |
| CP-7 | MAX-7 (55) | — | MB-1 (30) | MC-1 (15) | — | 10,100 | 1.81 |
| CP-8 | MAX-8 (55) | — | MB-1 (30) | MC-1 (15) | — | 10,700 | 1.81 |
| CP-9 | — | Ma1-1 (55) | MB-1 (30) | MC-1 (15) | — | 10,300 | 1.81 |
| CP-10 | MA-1 (30) | — | MB-3 (30) | MC-1 (10) | MD-2 (30) | 10,200 | 1.82 |
| CP-11 | MAX-3 (50) | — | MB-1 (40) | — | MD-3 (10) | 7,800 | 1.69 |
| CP-12 | MAX-3 (50) | — | MB-1 (20) | — | MD-1 (20) | 7,300 | 1.61 |
| | | | | | MD-3 (10) | | |
| CP-13 | MA-5 (22) | Ma1-2 (22) | MB-1 (54) | — | — | 8,700 | 1.84 |
| | | Ma1-3 (22) | | | | | |
| CP-14 | MA-1 (50) | — | MB-1 (50) | — | — | 8,300 | 1.81 |
| CP-15 | MAX-3 (50) | — | MB-1 (50) | — | — | 8,500 | 1.80 |

### [3] Preparation of Chemically Amplified Resist Compositions

### Examples 1-1 to 1-31 and Comparative Examples 1-1 to 1-15

Chemically amplified resist compositions were prepared by dissolving polymer P (Polymers P-1 to P-30) or comparative polymer (CP-1 to CP-15), photoacid generator (PAG-1, PAG-2), and quencher (SQ-1 to SQ-3, AQ-1) in a solvent containing 100 ppm of surfactant FC-4430 (3M) in accordance with the formulation shown in Tables 4 to 6, and filtering the solution through a Teflon® filter with a pore size of 0.2 μm.

TABLE 4

| | | Resist | Base polymer | PAG | Quencher | Solvent 1 | Solvent 2 |
|---|---|---|---|---|---|---|---|
| | | composition | (pbw) | (pbw) | (pbw) | (pbw) | (pbw) |
| Example | 1-1 | R-1 | P-1 (80) | — | SQ-1 (7.8) | PGMEA (2,200) | DAA (900) |
| | 1-2 | R-2 | P-1 (80) | — | SQ-2 (7.8) | PGMEA (2,200) | DAA (900) |
| | 1-3 | R-3 | P-2 (80) | — | SQ-1 (7.8) | PGMEA (2,200) | DAA (900) |
| | 1-4 | R-4 | P-3 (80) | — | SQ-1 (7.8) | PGMEA (2,200) | DAA (900) |
| | 1-5 | R-5 | P-4 (80) | — | SQ-1 (7.8) | PGMEA (2,200) | DAA (900) |
| | 1-6 | R-6 | P-5 (80) | — | SQ-1 (7.8) | PGMEA (2,200) | DAA (900) |
| | 1-7 | R-7 | P-6 (80) | — | SQ-2 (8.0) | PGMEA (2,200) | DAA (900) |
| | 1-8 | R-8 | P-7 (80) | — | SQ-1 (7.8) | PGMEA (2,200) | DAA (900) |
| | 1-9 | R-9 | P-8 (80) | — | SQ-1 (7.8) | PGMEA (2,200) | DAA (900) |
| | 1-10 | R-10 | P-9 (80) | — | SQ-2 (8.2) | PGMEA (2,200) | DAA (900) |
| | 1-11 | R-11 | P-10 (80) | — | SQ-1 (7.8) | PGMEA (2,200) | DAA (900) |
| | 1-12 | R-12 | P-11 (80) | — | SQ-1 (7.8) | PGMEA (2,200) | DAA (900) |
| | 1-13 | R-13 | P-12 (80) | — | SQ-1 (7.8) | PGMEA (2,200) | DAA (900) |
| | 1-14 | R-14 | P-13 (80) | — | SQ-1 (7.8) | PGMEA (2,200) | DAA (900) |
| | 1-15 | R-15 | P-14 (80) | — | SQ-1 (7.8) | PGMEA (2,200) | DAA (900) |
| | 1-16 | R-16 | P-15 (80) | — | SQ-2 (7.6) | PGMEA (2,200) | DAA (900) |

TABLE 5

| | | Resist | Base polymer | PAG | Quencher | Solvent 1 | Solvent 2 |
|---|---|---|---|---|---|---|---|
| | | composition | (pbw) | (pbw) | (pbw) | (pbw) | (pbw) |
| Example | 1-17 | R-17 | P-16 (80) | — | SQ-1 (7.8) | PGMEA (2,200) | DAA (900) |
| | 1-18 | R-18 | P-17 (80) | — | SQ-3 (8.1) | PGMEA (2,200) | DAA (900) |
| | 1-19 | R-19 | P-18 (80) | — | SQ-1 (7.8) | PGMEA (2,200) | DAA (900) |
| | 1-20 | R-20 | P-19 (80) | — | SQ-2 (8.0) | PGMEA (2,200) | DAA (900) |
| | 1-21 | R-21 | P-20 (80) | — | SQ-1 (7.8) | PGMEA (2,200) | DAA (900) |
| | 1-22 | R-22 | P-21 (80) | PAG-1 (12) | SQ-1 (8.5) | PGMEA (2,200) | DAA (900) |
| | 1-23 | R-23 | P-22 (80) | — | SQ-2 (8.5) | PGMEA (2,200) | DAA (900) |
| | 1-24 | R-24 | P-23 (80) | — | SQ-1 (7.8) | PGMEA (2,200) | DAA (900) |
| | 1-25 | R-25 | P-24 (80) | — | SQ-3 (8.0) | PGMEA (2,200) | DAA (900) |
| | 1-26 | R-26 | P-25 (80) | PAG-1 (12) | SQ-3 (8.0) | PGMEA (2,200) | DAA (900) |
| | 1-27 | R-27 | P-26 (80) | PAG-1 (12) | SQ-1 (7.8) | PGMEA (2,200) | DAA (900) |
| | 1-28 | R-28 | P-27 (80) | PAG-2 (10) | SQ-1 (7.8) | PGMEA (2,200) | DAA (900) |
| | 1-29 | R-29 | P-28 (80) | — | SQ-1 (7.8) | PGMEA (2,200) | DAA (900) |
| | 1-30 | R-30 | P-29 (80) | — | SQ-1 (7.8) | PGMEA (2,200) | DAA (900) |
| | 1-31 | R-31 | P-30 (80) | — | SQ-2 (7.8) | PGMEA (2,200) | DAA (900) |

TABLE 6

| | | Resist | Base polymer | PAG | Quencher | Solvent 1 | Solvent 2 |
|---|---|---|---|---|---|---|---|
| | | composition | (pbw) | (pbw) | (pbw) | (pbw) | (pbw) |
| Comparative | 1-1 | CR-1 | CP-1 (80) | — | SQ-1 (7.8) | PGMEA (1,400) | DAA (900) |
| Example | 1-2 | CR-2 | CP-2 (80) | — | SQ-2 (7.8) | PGMEA (1,400) | DAA (900) |
| | 1-3 | CR-3 | CP-3 (80) | — | SQ-1 (7.8) | PGMEA (1,400) | DAA (900) |
| | 1-4 | CR-4 | CP-4 (80) | — | SQ-1 (7.8) | PGMEA (1,400) | DAA (900) |
| | 1-5 | CR-5 | CP-5 (80) | — | SQ-2 (8.2) | PGMEA (1,400) | DAA (900) |
| | 1-6 | CR-6 | CP-6 (80) | — | SQ-1 (7.8) | PGMEA (1,400) | DAA (900) |
| | 1-7 | CR-7 | CP-7 (80) | — | SQ-7 (8.2) | PGMEA (1,400) | DAA (900) |
| | 1-8 | CR-8 | CP-8 (80) | — | SQ-1 (7.8) | PGMEA (1,400) | DAA (900) |
| | 1-9 | CR-9 | CP-9 (80) | — | SQ-1 (7.8) | PGMEA (1,400) | DAA (900) |
| | 1-10 | CR-10 | CP-10 (80) | — | AQ-1 (7.8) | PGMEA (1,400) | DAA (900) |
| | 1-11 | CR-11 | CP-11 (80) | PAG-1 (14) | SQ-3 (5.6) | PGMEA (1,400) | DAA (900) |
| | 1-12 | CR-12 | CP-12 (80) | PAG-2 (16) | SQ-1 (7.8) | PGMEA (1,400) | DAA (900) |
| | 1-13 | CR-13 | CP-13 (80) | PAG-2 (25) | SQ-3 (5.6) | PGMEA (1,400) | DAA (900) |
| | 1-14 | CR-14 | CP-14 (80) | PAG-1 (24) | SQ-1 (7.8) | PGMEA (1,400) | DAA (900) |
| | 1-15 | CR-15 | CP-15 (80) | PAG-2 (24) | SQ-1 (7.8) | PGMEA (1,400) | DAA (900) |

The components in Tables 4 to 6 are identified below.

### Solvent:

PGMEA (propylene glycol monomethyl ether acetate)

DAA (diacetone alcohol)

### Photoacid Generator: PAG-1 and PAG-2

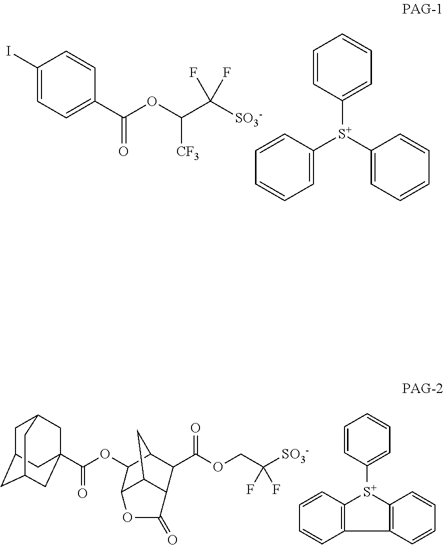

### Quencher: SQ-1 to SQ-3, AQ-1

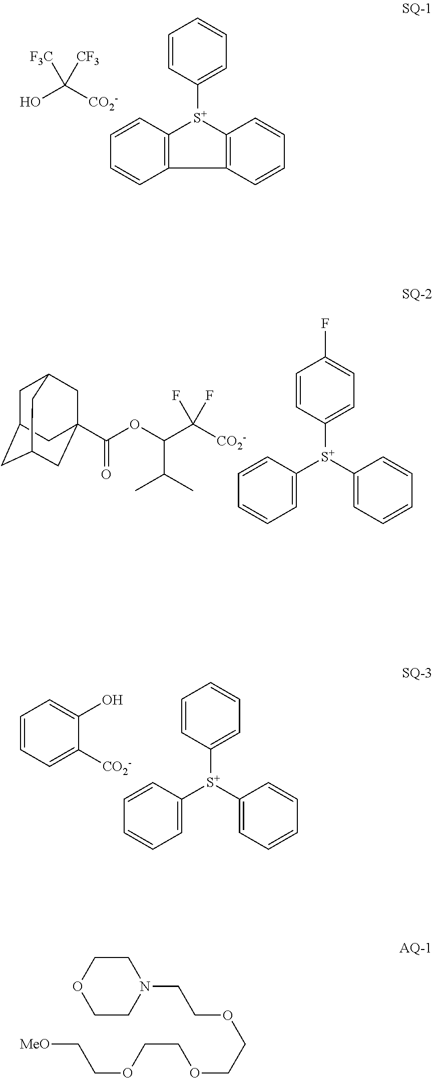

### [4] EUV Lithography Test #1

### Examples 2-1 to 2-31 and Comparative Examples 2-1 to 2-15

Each of the chemically amplified resist compositions (R-1 to R-31, CR-1 to CR-15) was spin coated on a silicon substrate having a 20-nm coating of silicon-containing spin-on hard mask SHB-A940 (Shin-Etsu Chemical Co., Ltd., silicon content 43 wt %) and prebaked on a hotplate at 100° C. for 60 seconds to form a resist film of 50 nm thick. Using an EUV scanner NXE3300 (ASML, NA 0.33, σ 0.9/0.6, dipole illumination), the resist film was exposed to EUV through a mask bearing a LS pattern having a size of 18 urn and a pitch of 36 nm (on-wafer size) while varying the dose and focus (dose pitch: 1 mJ/cm², focus pitch: 0.020 μm). After exposure, the resist film was baked (PEB) at the temperature shown in Tables 7 to 9 for 60 seconds and puddle developed in a 2.38 wt % TMAH aqueous solution for 30 seconds, rinsed with a rinse fluid containing surfactant, and spin dried to form a positive pattern.

The LS pattern as developed was observed under CD-SEM (CG6300, Hitachi High-Technologies Corp.) whereupon sensitivity, exposure latitude (EL), LWR, depth of focus (DOF), and collapse limit were evaluated by the following methods. The results are shown in Tables 7 to 9.

### Evaluation of Sensitivity

The optimum dose Eop (mJ/cm²) which provided a LS pattern with a line width of 18 nm and a pitch of 36 nm was determined as an index of sensitivity. A smaller value indicates a higher sensitivity.

### Evaluation of EL

The exposure dose which provided a LS pattern with a space width of 18 nm±10% (i.e., 16.2 to 19.8 nm) was determined. EL (%) is calculated from the exposure doses according to the following equation:

EL (%)=(|E1−E2|/Eop)×100

wherein E1 is an optimum exposure dose which provides a LS pattern with a line width of 16.2 nm and a pitch of 36 nm, E2 is an optimum exposure dose which provides a LS pattern with a line width of 19.8 nm and a pitch of 36 nm, and Eop is an optimum exposure dose which provides a LS pattern with a line width of 18 nm and a pitch of 36 nm. A larger value indicates better performance.

### Evaluation of LWR

For the LS pattern formed by exposure at the optimum dose Eop, the line width was measured at 10 longitudinally spaced apart points, from which a 3-fold value (3σ) of standard deviation (σ) was determined and reported as LWR. A smaller value of 3σ indicates a pattern having small roughness and uniform line width.

### Evaluation of DOF

As an index of DOF, a range of focus which provided a LS pattern with a size of 18 nm±10% (i.e., 16.2 to 19.8 nm) was determined. A greater value indicates a wider DOF.

### Evaluation of Collapse Limit of Line Pattern

For the LS pattern formed by exposure at the dose corresponding to the optimum focus, the line width was measured at 10 longitudinally spaced apart points. The minimum line size above which lines could be resolved without collapse was determined and reported as collapse limit. A smaller value indicates better collapse limit.

TABLE 7

| | | Resist | PEB | | | | | Collapse |
|---|---|---|---|---|---|---|---|---|
| | | compo- | temp. | Eop | EL | LWR | DOF | limit |
| | | sition | (° C.) | (mJ/cm²) | (%) | (mil) | (am) | (nm) |
| Example | 2-1 | R-1 | 95 | 42 | 19 | 2.7 | 120 | 12.3 |
| | 2-2 | R-2 | 95 | 42 | 18 | 2.8 | 120 | 12.1 |
| | 2-3 | R-3 | 95 | 41 | 18 | 2.9 | 110 | 10.5 |
| | 2-4 | R-4 | 95 | 42 | 17 | 3 | 110 | 11.8 |
| | 2-5 | R-5 | 95 | 43 | 19 | 2.9 | 120 | 12.1 |
| | 2-6 | R-6 | 90 | 42 | 18 | 2.8 | 110 | 10.1 |
| | 2-7 | R-7 | 90 | 43 | 17 | 2.8 | 120 | 11.6 |
| | 2-8 | R-8 | 90 | 45 | 19 | 3 | 100 | 10.3 |
| | 2-9 | R-9 | 90 | 42 | 17 | 2.9 | 110 | 10.5 |
| | 2-10 | R-10 | 90 | 41 | 18 | 3 | 110 | 11.8 |
| | 2-11 | R-11 | 90 | 41 | 18 | 3.1 | 120 | 10.3 |
| | 2-12 | R-12 | 90 | 43 | 18 | 3 | 120 | 11.4 |
| | 2-13 | R-13 | 90 | 43 | 19 | 2.9 | 110 | 10.6 |
| | 2-14 | R-14 | 90 | 42 | IS | 2.9 | 110 | 10.9 |
| | 2-15 | R-15 | 90 | 44 | 18 | 3 | 100 | 11.2 |
| | 2-16 | R-16 | 90 | 43 | 17 | 3 | 100 | 11 |

TABLE 8

| | | Resist | PEB | | | | | Collapse |
|---|---|---|---|---|---|---|---|---|
| | | compo- | temp. | Eop | EL | LWR | DOF | limit |
| | | sition | (° C.) | (mJ/cm²) | (%) | (nm) | (nm) | (nm) |
| Example | 2-17 | R-17 | 90 | 41 | 19 | 2.9 | 110 | 10.9 |
| | 2-18 | R-18 | 95 | 42 | 18 | 2.9 | 120 | 10.7 |
| | 2-19 | R-19 | 95 | 41 | 19 | 3.1 | 100 | 11.1 |
| | 2-20 | R-20 | 100 | 44 | 18 | 2.9 | 120 | 10.5 |
| | 2-21 | R-21 | 95 | 41 | 17 | 2.8 | 110 | 12.1 |
| | 2-22 | R-22 | 95 | 41 | 16 | 2.7 | 110 | 10.6 |
| | 2-23 | R-23 | 95 | 42 | 18 | 3 | 100 | 10.8 |
| | 2-24 | R-24 | 95 | 41 | 17 | 2.9 | 110 | 10.3 |
| | 2-25 | R-25 | 95 | 41 | 18 | 2.9 | 100 | 10.1 |
| | 2-26 | R-26 | 95 | 42 | 17 | 3 | 120 | 11.6 |
| | 2-27 | R-27 | 90 | 43 | 17 | 3.1 | 110 | 10.5 |
| | 2-28 | R-28 | 95 | 44 | 18 | 2.7 | 100 | 11.9 |
| | 2.20 | R-29 | 95 | 41 | 16 | 2.9 | 110 | 11.4 |
| | 2-30 | R-30 | 95 | 42 | 18 | 3.1 | 110 | 10.8 |
| | 2-31 | R-31 | 95 | 41 | 17 | 3 | 100 | 10.6 |

TABLE 9

| | | Resist | PEB | | | | | Collapse |
|---|---|---|---|---|---|---|---|---|
| | | compo- | temp. | Eop | EL | LWR | DOF | limit |
| | | sition | (° C.) | (mJ/cm²) | (%) | (nm) | (nm) | (nm) |
| Compar- | 2-1 | CR-1 | 95 | 42 | 19 | 3.5 | 90 | 14.5 |
| ative | 2-2 | CR-2 | 95 | 40 | 18 | 3.4 | 90 | 14.8 |
| Example | 2-3 | CR-3 | 90 | 43 | 18 | 3.6 | 90 | 14.3 |
| | 2-4 | CR-4 | 90 | 42 | 17 | 3.4 | 90 | 14.2 |
| | 2-5 | CR-5 | 90 | 43 | 19 | 3.5 | 80 | 13.8 |
| | 2-6 | CR-6 | 90 | 43 | 18 | 3.4 | 90 | 15.1 |
| | 2-7 | CR-7 | 95 | 44 | 17 | 3.7 | 80 | 13.5 |
| | 2-8 | CR-8 | 90 | 60 | 19 | 4.5 | 60 | 14.6 |
| | 2-9 | CR-9 | 100 | 44 | 17 | 3.3 | 100 | 13.9 |
| | 2-10 | CR-10 | 95 | 46 | 18 | 3.6 | 90 | 14.8 |
| | 2-11 | CR-11 | 95 | 49 | 18 | 3.8 | 70 | 15.1 |
| | 2-12 | CR-12 | 100 | 50 | 18 | 3.7 | 70 | 13.8 |
| | 2-13 | CR-13 | 95 | 51 | 19 | 3.8 | 80 | 13.5 |
| | 2-14 | CR-14 | 95 | 52 | IS | 3.8 | 70 | 14.2 |
| | 2-15 | CR-15 | 100 | 51 | 18 | 3.9 | 70 | 14.1 |

It is demonstrated in Tables 7 to 9 that chemically amplified resist compositions within the scope of the invention exhibit a high sensitivity and improved lithography properties and resistance to pattern collapse.

### [5] EUV Lithography Test #2

### Examples 3-1 to 3-31 and Comparative Examples 3-1 to 3-15

Each of the chemically amplified resist compositions (R-1 to R-31, CR 1 to CR-15) was spin coated on a silicon substrate having a 20-nm coating of silicon-containing spin-on hard mask SHB-A940 (Shin-Etsu Chemical Co., Ltd, silicon content 43 wt %) and prebaked on a hotplate at 105° C. for 60 seconds to form a resist film of 50 nm thick. Using an EUV scanner NXE3400 (ASML, NA 0.33, σ 0.9/0.6, quadrupole illumination), the resist film was exposed to EUV through a mask bearing a hole pattern having a pitch of 46 mu (on-wafer size) and +20% bias. The resist film was baked (PEB) on a hotplate at the temperature shown in Tables 10 to 12 for 60 seconds and developed in a 2.38 wt % TMAH aqueous solution for 30 seconds to form a hole pattern with a size of 23 nm.

The hole pattern was observed under CD-SEM (CG6300, Hitachi High Technologies Corp.). The exposure dose that provides a hole pattern having a size of 23 mm is reported as sensitivity. The size of 50 holes was measured, from which a 3-fold value (3σ) of standard deviation (σ) was computed and reported as size variation or CDU. The results are shown in Tables 10 to 12.

TABLE 10

| | | Resist | PEB temp. | Eop | CDU |
|---|---|---|---|---|---|
| | | composition | (° C.) | (mJ/cm²) | (nm) |
| Example | 3-1 | R-1 | 90 | 26 | 2.4 |
| | 3-2 | R-2 | 90 | 25 | 2.3 |
| | 3-3 | R-3 | 90 | 26 | 2.4 |
| | 3-4 | R-4 | 90 | 27 | 2.5 |
| | 3-5 | R-5 | 90 | 27 | 2.5 |
| | 3-6 | R-6 | 85 | 25 | 2.6 |
| | 3-7 | R-7 | 85 | 26 | 2.5 |
| | 3-8 | R-8 | 85 | 26 | 2.6 |
| | 3-9 | R-9 | 85 | 25 | 2.5 |
| | 3-10 | R-10 | 85 | 26 | 2.5 |
| | 3-11 | R-11 | 85 | 26 | 2.6 |
| | 3-12 | R-12 | 85 | 25 | 2.7 |
| | 3-13 | R-13 | 85 | 26 | 2.6 |
| | 3-14 | R-14 | 85 | 26 | 2.5 |
| | 3-15 | R-15 | 85 | 25 | 2.6 |
| | 3-16 | R-16 | 85 | 26 | 2.6 |

TABLE 11

| | | Resist | PEB temp. | Eop | CDU |
|---|---|---|---|---|---|
| | | composition | (° C.) | (mJ/cm²) | (nm) |
| Example | 3-17 | R-17 | 85 | 27 | 2.7 |
| | 3-18 | R-18 | 85 | 25 | 2.8 |
| | 3-19 | R-19 | 90 | 26 | 2.5 |
| | 3-20 | R-20 | 95 | 26 | 2.6 |
| | 3-21 | R-21 | 90 | 27 | 2.7 |
| | 3-22 | R-22 | 90 | 27 | 2.6 |
| | 3-23 | R-23 | 90 | 25 | 2.8 |
| | 3-24 | R-24 | 85 | 26 | 2.6 |
| | 3-25 | R-25 | 90 | 26 | 2.7 |
| | 3-26 | R-26 | 85 | 26 | 2.6 |
| | 3-27 | R-27 | 85 | 27 | 2.8 |
| | 3-28 | R-28 | 90 | 25 | 2.6 |
| | 3-29 | R-29 | 85 | 26 | 2.7 |
| | 3-30 | R-30 | 90 | 26 | 2.7 |
| | 3-31 | R-31 | 90 | 25 | 2.8 |

TABLE 12

| | | Resist | PEB temp. | Eop | CDU |
|---|---|---|---|---|---|
| | | composition | (° C.) | (mJ/cm²) | (nm) |
| Comparative | 3-1 | CR-1 | 95 | 28 | 3.1 |
| Example | 3-2 | CR-2 | 95 | 27 | 3.1 |
| | 3-3 | CR-3 | 90 | 28 | 3.2 |
| | 3-4 | CR-4 | 90 | 26 | 3.1 |
| | 3-5 | CR-5 | 90 | 28 | 3 |
| | 3-6 | CR-6 | 95 | 29 | 3.1 |
| | 3-7 | CR-7 | 95 | 27 | 3.2 |
| | 3-8 | CR-3 | 105 | 45 | 4.7 |
| | 3-9 | CR-9 | 100 | 25 | 3.3 |
| | 3-10 | CR-10 | 95 | 26 | 3.3 |
| | 3-11 | CR-11 | 100 | 34 | 3.3 |
| | 3-12 | CR-12 | 100 | 33 | 3.5 |
| | 3-13 | CR-13 | 100 | 33 | 3.6 |
| | 3-14 | CR-14 | 100 | 34 | 3.7 |
| | 3-15 | CR-15 | 100 | 35 | 3.8 |

It is demonstrated in Tables 10 to 12 that chemically amplified resist compositions within the scope of the invention exhibit a high sensitivity and improved CDU.

Japanese Patent Application No. 2021-186799 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A chemically amplified resist composition comprising
(A) a polymer P comprising repeat units having an acid labile group containing a fluorinated aromatic ring, represented by the formula (A1), repeat units having a phenolic hydroxy group, and repeat units adapted to generate an acid upon exposure, represented by any one of the formulae (C1) to (C4), the polymer P adapted to change its solubility in developer under the action of acid,
(B) an onium salt type quencher, and
(C) a solvent, 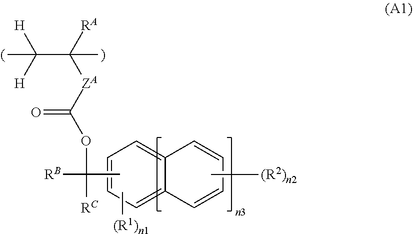
wherein R^{A} is hydrogen, fluorine, methyl or trifluoromethyl,
Z^{A} is a single bond, phenylene group, naphthylene group or *—C(═O)—O—Z^{A1}—, Z^{A1} is a C₁-C₂₀ aliphatic hydrocarbylene group which may contain a hydroxy moiety, ether bond ester bond or lactone ring, or a phenylene or naphthylene group, the asterisk (*) designates a point of attachment to the carbon atom in the backbone,
R^{B} and R^{C} are each independently a C₁-C₁₀ hydrocarbyl group which may contain a heteroatom, R^{B} and R^{C} may bond together to form a ring with the carbon atom to which they are attached,
R¹ is each independently fluorine, a C₁-C₅ fluorinated alkyl group or C₁-C₅ fluorinated alkoxy group,
R² is each independently a C₁-C₁₀ hydrocarbyl group which may contain a heteroatom,
n1 is an integer of 1 or 2, n2 is an integer of 0 to 5, and n3 is an integer of 0 to 2; 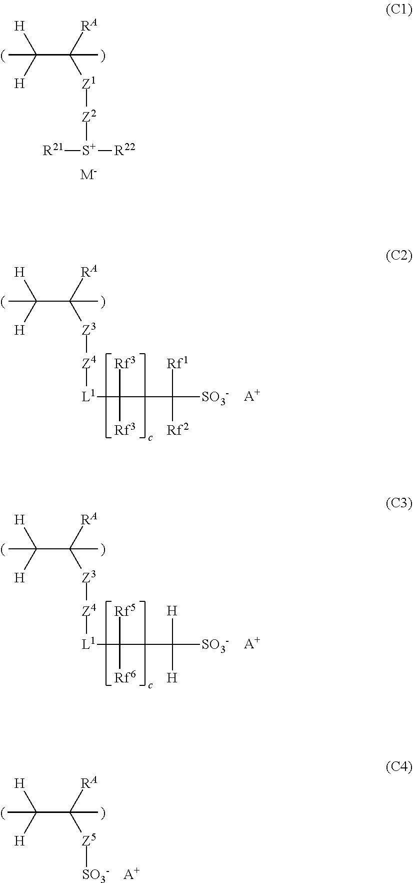
wherein R^{A} is as defined above,
Z¹ is a single bond or phenylene group,
Z² is *—C(═O)—O—Z²¹—, *—C(═)—NH—Z²¹— or *—O—Z²¹—, Z²¹ is a C₁-C₆ aliphatic hydrocarbylene group, phenylene group or divalent group obtained by combining the foregoing, which may contain a carbonyl moiety, ester bond ether bond or hydroxy moiety,
Z³ is a single bond, phenylene group, naphthylene group or *—C(═O)—O—Z³¹—, Z³¹ is a C₁-C₁₀ aliphatic hydrocarbylene group which may contain a hydroxy moiety, ether bond, ester bond or lactone ring, or a phenylene or naphthylene group,
Z⁴ is a single bond or *—Z⁴¹—C(═O)—O—, Z⁴¹ is a C₁-C₂₀ hydrocarbylene group which may contain a heteroatom,
Z⁵ is a single bond, methylene, ethylene, phenylene, fluorinated phenylene, trifluoromethyl-substituted phenylene, *—C(═O)—O—Z⁵¹—, *—C(═O)—N(H)—Z⁵¹— or *—O—Z⁵¹—, Z⁵¹ is a C₁-C₆ aliphatic hydrocarbylene group, phenylene, fluorinated phenylene or trifluoromethyl-substituted phenylene group, which may contain a carbonyl moiety, ester bond, ether bond or hydroxy moiety,
the asterisk (*) designates a point of attachment to the carbon atom in the backbone,
R²¹ and R²² are each independently a C₁-C₂₀ hydrocarbyl group which may contain a heteroatom, R²¹ and R²² may bond together to form a ring with the sulfur atom to which they are attached,
L¹ is a single bond, ether bond, ester bond, carbonyl group, sulfonic ester bond, carbonate bond or carbamate bond,
Rf¹ and Rf² are each independently fluorine or a C₁-C₆ fluorinated alkyl group,
Rf³ and Rf⁴ are each independently hydrogen, fluorine or a C₁-C₆ fluorinated alkyl group,
Rf⁵ and Rf⁶ are each independently hydrogen, fluorine or a C₁-C₆ fluorinated alkyl group, excluding that all Rf⁵ and Rf⁶ are hydrogen at the same time,
M⁻ is a non-nucleophilic counter ion,
A⁺ is an onium cation, and
c is an integer of 0 to 3.

2. The resist composition of claim 1 wherein the repeat units having formula (A1) are represented by the formula (A2): 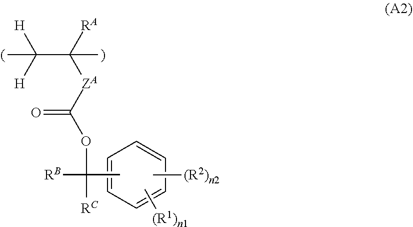
wherein R^{A}, Z^{A}, R^{B}, R^{C}, R¹, R², n1 and n2 are as defined above.

3. The resist composition of claim 2 wherein R¹ is fluorine, trifluoromethyl or trifluoromethoxy.

4. The resist composition of claim 1 wherein the repeat units having a phenolic hydroxy group are represented by the formula (B1): 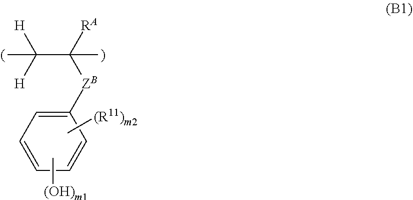
wherein R^{A} is as defined above,
Z^{B} is a single bond or *—C(═O)—O—, the asterisk (*) designates a point of attachment to the carbon atom in the backbone,
R¹¹ is halogen, cyano, a C₁-C₂₀ hydrocarbyl group which may contain a heteroatom, a C₁-C₂₀ hydrocarbyloxy group which may contain a heteroatom, a C₂-C₂₀ hydrocarbylcarbonyl group which may contain a heteroatom, a C₂-C₂₀ hydrocarbylcarbonyloxy group which may contain a heteroatom, or a C₂-C₂₀ hydrocarbyloxycarbonyl group which may contain a heteroatom,
m1 is an integer of 1 to 4, m2 is an integer of 0 to 4, the sum of m1+m2 is from 1 to 5.

5. The resist composition of claim 1 wherein the onium salt type quencher is represented by the formula (1) or (2):
R^{q1}—SO₃⁻A⁺ (1)
R^{q2}—CO₂⁻A⁺ (2)
wherein R^{q1} is hydrogen or a C₁-C₄₀ hydrocarbyl group which may contain a heteroatom, exclusive of a hydrocarbyl group in which hydrogen attached to the α-carbon relative to the sulfo group is substituted by fluorine or fluoroalkyl,
R^{q2} is hydrogen or a C₁-C₄₀ hydrocarbyl group which may contain a heteroatom, and
A⁺ is an onium cation.

6. The resist composition of claim 1 wherein A⁺ is a cation having the formula (cation-1) or (cation-2): 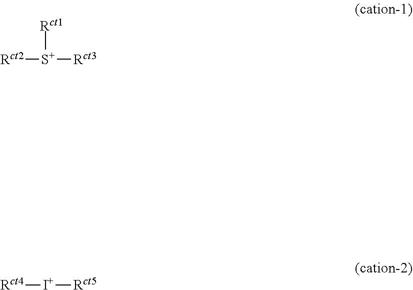
wherein R^{ct1} to R^{ct5} are each independently a C₁-C₂₀ hydrocarbyl group which may contain a heteroatom, R^{ct1} and R^{ct2} may bond together to form a ring with the sulfur atom to which they are attached.

7. The resist composition of claim 1 wherein polymer P further comprise repeat units having the formula (a1) or (a2): 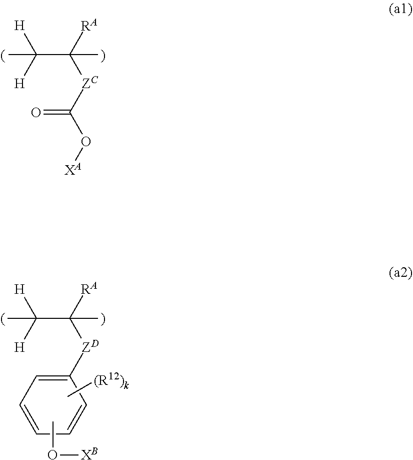
wherein R^{A} is as defined above,
Z^{c} is a single bond, phenylene group, naphthylene group or *—C(═O)—O—Z^{C1}—, Z^{C1} is a C₁-C₂₀ saturated hydrocarbylene group which may contain a hydroxy moiety, ether bond, ester bond or lactone ring, or a phenylene or naphthylene group,
Z^{D} is a single bond or *—C(═O)—O—,
the asterisk (*) designates a point of attachment to the carbon atom in the backbone,
R¹² is a C₁-C₂₀ hydrocarbyl group which may contain a heteroatom,
X^{A} and X^{B} are each independently an acid labile group free of fluorinated aromatic ring, and
k is an integer of 0 to 4.

8. The resist composition of claim 1 wherein polymer P further comprise repeat units having the formula (D1): 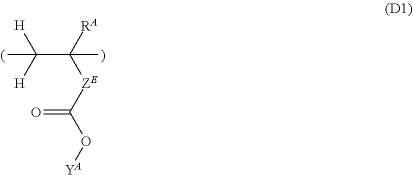
wherein R^{A} is as defined above,
Z^{E} is a single bond, phenylene group, naphthylene group or *—C(═O)—O—Z^{E1}—, Z^{E1} is a C₁-C₂₀ saturated hydrocarbylene group which may contain a hydroxy moiety, ether bond, ester bond or lactone ring, or a phenylene or naphthylene group,
the asterisk (*) designates a point of attachment to the carbon atom in the backbone, and
Y^{A} is hydrogen or a polar group containing at least one moiety selected from the group consisting of hydroxy, cyano, carbonyl, carboxy, ether bond, ester bond, sulfonic ester bond carbonate bond, lactone ring, sultone ring, and carboxylic anhydride (—C(═O)—O—C(═O)—).

9. The resist composition of claim 1, further comprising a photoacid generator.

10. The resist composition of claim 1, further comprising a surfactant.

11. A process for forming a pattern comprising the steps of applying the chemically amplified resist composition of claim 1 to a substrate to form a resist film thereon, exposing the resist film to high-energy radiation, and developing the exposed resist film in a developer.

12. The process of claim 11 wherein the high-energy radiation is i-line, KrF excimer laser, ArF excimer laser, EB, or EUV of wavelength 3 to 15 nm.
